(19) United States
(12) Patent Application Publication
(10) Pub. No.: US 2014/0349225 A1
(43) Pub. Date: Nov. 27, 2014

(54) PATTERN FORMING METHOD, ACTINIC RAY-SENSITIVE OR RADIATION-SENSITIVE RESIN COMPOSITION, RESIST FILM, METHOD FOR MANUFACTURING ELECTRONIC DEVICE, AND ELECTRONIC DEVICE

(71) Applicant: FUJIFILM Corporation, Tokyo (JP)

(72) Inventors: Kei YAMAMOTO, Haibara-gun (JP); Hidenori TAKAHASHI, Haibara-gun (JP); Shuhei YAMAGUCHI, Haibara-gun (JP); Junichi ITO, Haibara-gun (JP)

(73) Assignee: FUJIFILM CORPORATION, Tokyo (JP)

(21) Appl. No.: 14/456,309

(22) Filed: Aug. 11, 2014

Related U.S. Application Data
(63) Continuation of application No. PCT/JP2013/054424, filed on Feb. 15, 2013.

(30) Foreign Application Priority Data
Feb. 17, 2012 (JP) 2012-033396
Feb. 13, 2013 (JP) 2013-025645

(51) Int. Cl. G03F 7/038; G03F 7/20

(52) U.S. Cl. CPC G03F 7/0388; G03F 7/20; G03F 7/038
USPC 430/18; 430/325; 430/285.1; 430/311; 430/281.1

(57) ABSTRACT

There is provided a pattern forming method, including: (a) forming a film by an actinic ray-sensitive or radiation-sensitive resin composition containing: (A) a resin capable of increasing polarity by an action of an acid to decrease solubility in an organic solvent-containing developer, (B) a compound capable of generating an acid upon irradiation with an actinic ray or radiation, (C) a solvent, and (D) a resin, which contains substantially no fluorine atom and silicon atom and is other than the resin (A), (b) exposing the film; and (c) performing development using the organic solvent-containing developer to form a negative type pattern, wherein a receding contact angle of water on the film formed by (a) is 70° or more.

### CROSS REFERENCE TO RELATED APPLICATION

This is a continuation of International Application No. PCT/JP2013/054424 filed on Feb. 15, 2013, and claims priority from Japanese Patent Application Nos. 2012-033396 filed on Feb. 17, 2012, and 2013-025645 filed on Feb. 13, 2013, the entire disclosures of which are incorporated herein by reference.

### TECHNICAL FIELD

The present invention relates to a pattern forming method, an actinic ray-sensitive or radiation-sensitive resin composition, a resist film, a method for manufacturing an electronic device, and an electronic device. More specifically, the present invention relates to a pattern forming method suitably used for a manufacturing process of a semiconductor such as an IC, a manufacturing process of a circuit board of a liquid crystal, a thermal head or the like, and other lithography processes of photofabrication, an actinic ray-sensitive or radiation-sensitive resin composition, a resist film, a method for manufacturing an electronic device, and an electronic device. Particularly, the present invention relates to a pattern forming method suitably used for the exposure in an ArF exposure apparatus or an ArF liquid immersion projection exposure apparatus, which uses far-ultraviolet rays having a wavelength of 300 nm or less as a light source and an EUV exposure apparatus, an actinic ray-sensitive or radiation-sensitive resin composition, a resist film, a method for manufacturing an electronic device, and an electronic device.

### BACKGROUND ART

Since a resist for a KrF excimer laser (248 nm) was developed, an image forming method called chemical amplification has been used as an image forming method of a resist in order to compensate for desensitization caused by light absorption. When an image forming method of a positive type chemical amplification is exemplified and described, the method is an image forming method in which an acid-generator of an exposed portion is decomposed by exposure to produce an acid, and then, by using the generated acid as a reaction catalyst in PEB (Post Exposure Bake), an alkali-insoluble group is changed to an alkali-soluble group to remove the exposed portion by alkali development. The positive type image forming method using the chemical amplification mechanism has become a mainstream.

Further, as an object of achieving high resolution by making a wavelength further shorter, a so-called immersion method has been known, which fills the space between a projection lens and a test sample with a liquid having a high refractive index (hereinafter also referred to as “an immersion liquid”). For example, Japanese Patent Application Laid-Open No. 2008-268933 describes an example that an immersion liquid follow-up property has been improved by containing a resin having a specific acid-decomposable repeating unit and a specific resin that does not contain a fluorine atom and a silicon atom in a positive type resist composition.

However, in the above-described positive type image forming method, an isolated line or dot pattern may be formed well, but the shapes of patterns easily deteriorate when an isolated space or fine pattern is formed.

Therefore, in respects to the demand for further refinement of a pattern, recently, a technology, in which an organic-based developer is used to a resist film obtained by a chemical amplification resist composition as well as the positive type resist composition which is a current mainstream to resolve a negative type pattern, has also been known. As the technology, for example, in a negative type pattern forming method by an organic-based developer using an immersion method, a technology in which a resin containing a silicon atom or a fluorine atom is added has been known (see, for example, Japanese Patent Application Laid-Open No. 2008-309879).

However, more recently, a need for a fine pattern having a line width of 60 nm or less is sharply increased, and in response to this, when a fine negative type pattern having a line width of 60 nm or less is formed on a resist film by a immersion method using an organic-based development solution, it is required that uniformity of the film thickness is further improved and bridge defects and watermark defects are further reduced.

### SUMMARY OF INVENTION

The present invention has been made in consideration of the aforementioned problem, and an object thereof is to provide a pattern forming method in which uniformity of the film thickness is excellent and bridge defects and watermark defects are suppressed from occurring in the formation of a fine pattern having a line width of 60 nm or less by an immersion method using an organic-based developer, an actinic ray-sensitive or radiation-sensitive resin composition used therein, a resist film, a method for manufacturing an electronic device, and an electronic device.

The present invention has the following configuration, and the object of the present invention is accordingly achieved.

(1) A pattern forming method, including: (a) forming a film by using an actinic ray-sensitive or radiation-sensitive resin composition containing: (A) a resin capable of increasing polarity by an action of an acid to decrease solubility in an organic solvent-containing developer, (B) a compound capable of generating an acid upon irradiation with an actinic ray or radiation, (C) a solvent, and (D) a resin, which contains substantially no fluorine atom and silicon atom and is different from the resin (A), (b) exposing the film; and (c) performing development by using the organic solvent-containing developer to form a negative pattern, wherein a receding contact angle of water on the film formed by (a) is 70° or more.

(2) The method according to (1), wherein the solvent (C) is a mixed solvent containing two or more solvents, the two or more solvents containing at least one solvent having a boiling point of 200° C. or more.

(3) The method according to (2), wherein the at least one solvent having a boiling point of 200° C. or more is a solvent represented by one of Formulas (S1) to (S3):

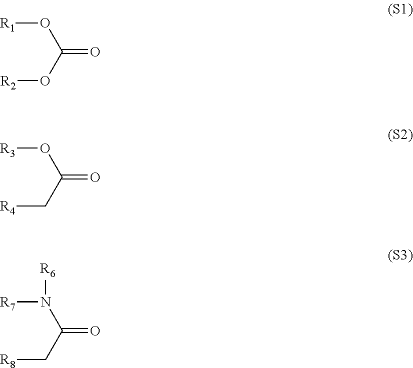

wherein, each of R₁ to R₄ and R₆ to R₈ independently represents an alkyl group, a cycloalkyl group or an aryl group, and R₁ and R₂, R₃ and R₄, or R₇ and R₈ may be linked to each other to form a ring.

(4) The method according to (2) or (3), wherein a content of the at least one solvent having a boiling point of 200° C. or more is 1% by mass or more based on the mixed solvent.

(5) The method according to any one of (1) to (4), wherein the resin (A) contains a repeating unit including a group capable of decomposing by the action of an acid to generate a polar group, and the repeating unit consists of at least one repeating unit represented by Formula (I):

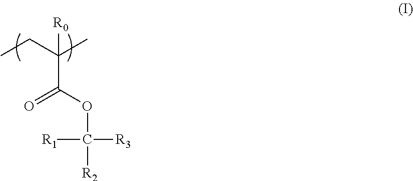

wherein, R₀ represents a hydrogen atom or an alkyl group, each of R₁ to R₃ independently represents an alkyl group or a cycloalkyl group, and two of R₁ to R₃ may be bonded to each other to form a monocyclic or polycyclic cycloalkyl group.

(6) The method according to any one of (1) to (5), wherein the resin (D) has at least one repeating unit represented by the following Formula (II) or (III):

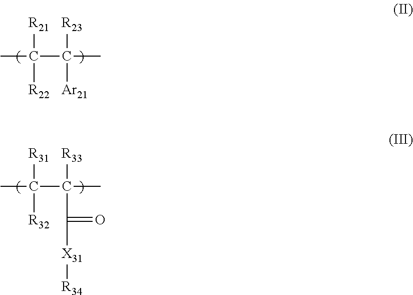

wherein, in Formula (II), each of R₂₁ to R₂₃ independently represents a hydrogen atom or an alkyl group, Ar₂₁ represents an aromatic group, R₂₂ and Ar₂₁ may form a ring, and in that case, R₂₂ represents an alkylene group, in Formula (III), each of R₃₁ to R₃₃ independently represents a hydrogen atom or an alkyl group, X₃₁ represents —O— or —NR₃₅—, R₃₅ represents a hydrogen atom or an alkyl group, and R₃₄ represents an alkyl group or a cycloalkyl group.

(7) The method according to (6), wherein a content of the repeating unit represented by Formula (II) or (III) is 50% by mole to 100% by mole based on all the repeating units in the resin (D).

(8) The method according to any one of (1) to (7), wherein the organic solvent-containing developer is a developer containing at least one organic solvent selected from the group consisting of a ketone-based solvent, an ester-based solvent, an alcohol-based solvent, an amide-based solvent and an ether-based solvent.

(9) The method according to any one of (1) to (8), further including: (d) performing washing by using a rinsing solution containing an organic solvent.

(10) The method according to any one of (1) to (9), wherein the exposure in (b) is an immersion exposure.

(11) An actinic ray-sensitive or radiation-sensitive resin composition used in the method according to (2).

(12) An actinic ray-sensitive or radiation-sensitive resin composition used in the method according to (3).

(13) An actinic ray-sensitive or radiation-sensitive resin composition used in the method according to (4).

(14) An actinic ray-sensitive or radiation-sensitive resin composition used in the method according to (5).

(15) An actinic ray-sensitive or radiation-sensitive resin composition used in the method according to (6).

(16) An actinic ray-sensitive or radiation-sensitive resin composition used in the method according to (7).

(17) A resist film formed by the actinic ray-sensitive or radiation-sensitive resin composition according to any one of (11) to (16).

(18) A method for manufacturing an electronic device including the method according to any one of (1) to (10).

(19) An electronic device manufactured by the method according to (18).

It is further preferred that the present invention has the following constitution.

(20) The pattern forming method according to any one of (1) to (10), in which a C log P value of the resin (D) is 2.8 or more.

(21) The pattern forming method according to any one of (1) to (10), and (21), in which the resin (D) contains a repeating unit corresponding to a monomer having a C log P value of 2.8 or more.

(22) The pattern forming method according to any one of (1) to (10), (20) and (21), in which the resin (D) containing a repeating unit having 3 or more CH₃ partial structures at a side chain.

(23) The pattern forming method according to any one of (1) to (10), and (20) to (22), in which the resin (D) does not have a repeating unit having an acid-decomposable group.

(24) The pattern forming method according to any one of (1) to (10), and (20) to (23), in which the resin (D) does not have a repeating unit having an acid group (an alkali-soluble group).

(25) The pattern forming method according to any one of (1) to (10) and (20) to (24), in which the resin (D) does not have a repeating unit having a lactone structure.

(26) The pattern forming method according to any one of (1) to (10) and (20) to (25), in which the exposure in (b) is an ArF exposure.

(27) The pattern forming method according to any one of (1) to (10), and (20) to (26), in which the resin (A) contains a repeating unit containing a structure capable of generating an alcoholic hydroxyl group at a side chain, as a repeating unit containing an acid decomposable group.

(28) The pattern forming method according to any one of (1) to (10), and (20) to (27), in which the compound (B) is a compound represented by Formula (ZI-4′):

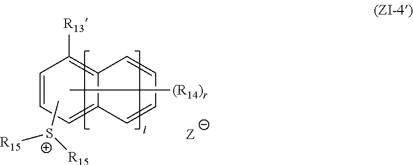

wherein, in Formula (ZI-4′), R₁₃′ represents a branched alkyl group,

R₁₄, when a plurality of R₁₄s are present, each independently represents a hydroxyl group, an alkyl group, a cycloalkyl group, an alkoxy group, an alkoxycarbonyl group, an alkyl carbonyl group, an alkylsulfonyl group, a cycloalkylsulfonyl group, or a group having a cycloalkyl group,

R₁₅ each independently represents an alkyl group, a cycloalkyl group, or a naphthyl group, and two of R₁₅ may be linked to form a ring,

l represents an integer of 0 to 2,

r represents an integer of 0 to 8, and

Z⁻ represents a non-nuclephilic anion.

(29) The pattern forming method according to any one of (1) to (10), and (20) to (28), in which the compound (B) is a compound represented by Formula (ZI) or Formula (ZII):

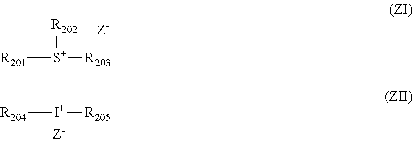

wherein, each of R₂₀₁, R₂₀₂, and R₂₀₃ independently represents an organic group, two of R₂₀₁, R₂₀₂, and R₂₀₃ may be linked to form a ring, and the ring may contain an oxygen atom, a sulfur atom, an ester bond, an amide bond, and a carbonyl group,

each of R₂₀₄ and R₂₀₅ independently represents an aryl group, an alkyl group, or a cycloalkyl group, and

Z⁻ represents a non-nuclephilic anion.

(30) The pattern forming method according to (29), in which the non-nuclephilic anion of Z⁻ is an anion capable of generating an organic acid represented by Formula (III) or Formula (IV):

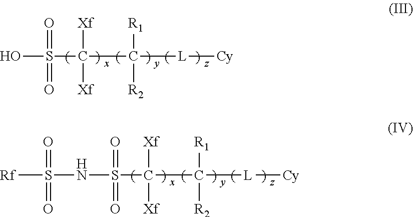

wherein each of Ef independently represents a fluorine atom, or a alkyl group substituted by at least one of fluorine atom,

each of R₁ and R₂ independently represents a hydrogen atom, a fluorine atom, or an alkyl group,

each of L independently represents a divalent linking group,

Cy represents a cyclic organic group,

Rf a group containing a fluorine atom,

x represents an integer of 1 to 20,

y represents an integer of 0 to 20, and

z represents an integer of 0 to 10.

(31) The pattern forming method according to (30), in which the cyclic organic group of Cy is a group containing a steroidal backbone.

(32) The pattern forming method according to (29), in which the non-nuclephilic anion of Z⁻ is a sulfonate anion represented by Formula (B-1):

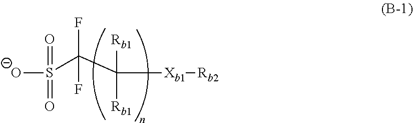

wherein each of R_{b1} independently represents a hydrogen atom, a fluorine atom, or a trifluoromethyl group (CF₃),

n represents an integer of 0 to 4,

X_{b1} represents a single bond, an alkylene group, an ether bond, an ester bond (—OCO— or —COO—), a sulfonic ester bond (—OSO₂— or —SO₂—), or a combination thereof, and

R_{b2} represents an organic group having 6 or more carbon atoms.

(33) The pattern forming method according to any one of (1) to (10) and (20) to (32), in which the actinic ray-sensitive or radiation-sensitive resin composition further contains N-alkylcaprolactam.

(34) The actinic ray-sensitive or radiation-sensitive resin composition according to any one of (11) to (16), which is a chemical amplification resist composition for organic solvent development.

(35) The actinic ray-sensitive or radiation-sensitive resin composition according to any one of (11) to (16) and (34), which is a composition for immersion exposure.

According to the present invention, it is possible to provide a pattern forming method in which uniformity of the film thickness is excellent and bridge defects and watermark defects are suppressed from occurring in the formation of a fine pattern having a line width of 60 nm or less by an immersion method using an organic-based developer, an actinic ray-sensitive or radiation-sensitive resin composition used therein, a resist film, a method for manufacturing an electronic device, and an electronic device.

### DESCRIPTION OF EMBODIMENTS

Hereinafter, embodiments of the present invention will be described in detail.

In representing a group (atomic group) in the present specification, the representation which does not describe the substitution and unsubstitution also includes having substituents along with having no substituent. For example, “an alkyl group” includes not only an alkyl group having no substituent (an unsubstituted alkyl group) but also an alkyl group having a substituent (a substituted alkyl group).

The term “actinic ray” or “radiation” in the present specification refers to, for example, a bright line spectrum of a mercury lamp, far-ultraviolet rays represented by an excimer laser, extreme ultraviolet (EUV) rays, X-rays, an electron beam (EB) and the like. Further, the term “light” in the present invention refers to the actinic rays or the radiations.

In addition, unless otherwise specifically indicated, the term “exposure” in the present specification includes not only the exposure performed using a mercury lamp, far-ultraviolet rays represented by an excimer laser, extreme ultraviolet rays, X-rays, EUV rays and the like, but also drawing performed by a particle beam such as an electron beam and an ion beam.

The pattern forming method for the present invention includes

(a) forming a film by an actinic ray-sensitive or radiation-sensitive resin composition containing (A) a resin capable of increasing the polarity by the action of an acid to decrease the solubility thereof in a developer including an organic solvent, (B) a compound capable of generating an acid upon irradiation with an actinic ray or radiation, (C) a solvent, and (D) a resin, which contains substantially no fluorine atom and silicon atom and is other than the resin (A),

(b) exposing the film, and

(c) performing development using a developer including an organic solvent to form a negative type pattern,

in which a receding contact angle of water on the film formed by (a) is 70° or more.

The reason why the pattern forming method for the present invention, in which a receding contact angle of water on a film formed by the film-forming step (a) by using an actinic ray-sensitive or radiation-sensitive resin composition containing the resin (D) that contains substantially no fluorine atom and silicon atom is 70° or more, has excellent uniformity of the film thickness and suppresses the occurrence of bridge defects and water mark defects in the formation of a fine pattern having a line width of 60 nm or less by a negative type pattern formation using a developer including an organic solvent is unclear, but is assumed as follows.

In the positive type immersion method in the related art, in order to solve adverse effects caused by the use of an immersion liquid, a method making the hydrophobic resin localize at a surface of the resist film by mixing a small amount of a resin having low surface free energy and high hydrophobicity (hereinafter simply referred to as a “hydrophobic resin”) in addition to a main resin in the resist composition has been performed. Here, it is required that even a resin having low surface free energy and high hydrophobicity is dissolved in an alkali developer at the time of development, and thus the hydrophobic resin is required to have alkali solubility, for example, by having a group capable of generating an alkali-soluble group, and the like, and as a result, from the viewpoint of achieving high hydrophobicity (and low surface free energy) that is opposite thereto, it is substantially required that a fluorine atom and a silicon atom are contained in the hydrophobic resin.

However, when a fluorine atom and a silicon atom are contained in the resin in the resist composition, the contact angle characteristics of the immersion liquid are impaired and the immersion liquid remains as a water drop during the exposure scanning, and as a result, there is a problem in that watermark defects are generated after the development.

On the contrary, in a negative type pattern forming method of performing development using a developer including an organic solvent according to the present invention, in order to solve adverse effects caused by using the immersion liquid, the above-described alkali solubility is not demanded in a hydrophobic resin contained in a small amount thereof in a resist composition, and as a result, it is even not required that a fluorine atom and a silicon atom are possessed. In addition, substantially no fluorine atom and silicon atom are possessed, so that the problem caused by containing a silicon atom and a silicon atom is solved, and thus the receding contact angle of the immersion liquid may be improved and contact angle characteristics (the difference between the forward contact angle and the receding contact angle is decreased) of the immersion liquid may also be improved. As described above, it is assumed that a fluorine atom and a silicon atom are not possessed and the receding contact angle is set to 70° or more, so that the method may be suitably used in the immersion method, thereby reducing water mark defects.

Further, when the hydrophobic resin contained in a small amount in the resist composition has a fluorine atom and a silicon atom, the solubility of the hydrophobic resin in the solvent (C) is decreased, and thus a film formed by the film-formation step (a) may also be responsible for impairing uniformity of the film thickness.

On the contrary, it is assumed that the resin (D) in the present invention has substantially no fluorine atom and silicon atom, and thus the solubility thereof in the solvent (C) is excellent and a film formed by the film-formation step (a) also has excellent uniformity of the film thickness.

Further, when a resist film formed by using an actinic ray-sensitive or radiation-sensitive resin composition containing the compound (B) (hereinafter also referred to as an acid generator) is subjected to exposure, an exposed degree and concentration of a generated acid of the top layer portion of the resist film is higher than that of the internal portion thereof, and thus the reaction between the acid and the resin (A) tends to proceed further. In addition, when a developer including an organic solvent is used to develop the exposed film, there is concern in that the pattern shape may deteriorate.

On the contrary, in the actinic ray-sensitive or radiation-sensitive resin composition in the present invention, it is assumed that the resin (D) that substantially no fluorine atom and silicon atom is easily distributed unevenly in the top layer portion of the resist film.

The resin (D) is unevenly distributed at high concentration in the top layer portion of the resist film, and thus the solubility of the top layer portion of the resist film in the developer including an organic solvent is improved. As a result, it is assumed that the deterioration in the pattern shape caused by an acid excessively generated, which is unevenly distributed in the top layer of the exposed portion, may be offset or suppressed by improvement of the solubility thereof in the developer including the organic solvent by the resin (D).

Also, it is presumed that a factor of the bridge defects may be a resin component sparingly soluble in an organic solvent-containing developer at the surface of the resist film.

As mentioned above, it is presumed that the resin (D) tends to localize at the surface part of the resist film, and thereby the solubility at the surface part of the resit film in an organic solvent-containing developer is enhanced. As a result, it is presumed that a component sparingly soluble in an organic solvent-containing developer, which may be a factor of the bridge defects can be dissolved and removed.

Further, as described above, in the positive type image forming method, a fine pattern, in which the shape of the pattern easily deteriorates and it is substantially difficult to form the pattern, is present. This results from the fact that when the pattern is formed by a positive type image forming method, an area on which a pattern is to be formed becomes an exposed portion, but it is optically difficult to expose the fine exposed portion and resolve the portion.

In the pattern forming method of the present invention, it is preferred that the developer is a developer containing at least one organic solvent selected from the group consisting of a ketone-based solvent, an ester-based solvent, an alcohol-based solvent, an amide-based solvent and an ether-based solvent.

It is preferred that the pattern forming method of the present invention further includes (d) performing washing using a rinsing liquid including an organic solvent.

It is preferred that the rinsing liquid is a rinsing liquid containing at least one organic solvent selected from the group consisting of a hydrocarbon-based solvent, a ketone-based solvent, an ester-based solvent, an alcohol-based solvent, an amide-based solvent and an ether-based solvent.

It is preferred that the pattern forming method of the present invention has (e) a heating step after the exposure step (b).

In the pattern forming method of the present invention, the resin (A) is a resin capable of increasing the polarity by the action of an acid to increase the solubility in the alkali developer, and the method may further have (f) performing development using the alkali developer.

The pattern forming method of the present invention may have several times of the exposure step (b).

The pattern forming method of the present invention may have several times of the heating step (e).

The resist film of the present invention is a film formed by the actinic ray-sensitive or radiation-sensitive resin composition, and for example, a film formed by applying the actinic ray-sensitive or radiation-sensitive resin composition on a substrate.

Hereinafter, an actinic ray-sensitive or radiation-sensitive resin composition that may be used in the present invention will be described.

Further, the present invention also relates to the actinic ray-sensitive or radiation-sensitive resin composition that will be described below.

The actinic ray-sensitive or radiation-sensitive resin composition according to the present invention is used in a negative type development (development in which when a resist film is exposed, the solubility thereof in the developer is decreased, and thus the exposed portion remains as a pattern and the unexposed portion is removed) particularly when a fine pattern having a line width of, for example, 60 nm or less is formed on the resist film. That is, the actinic ray-sensitive or radiation-sensitive resin composition relating to the present invention may be used as an actinic ray-sensitive or radiation-sensitive resin composition for organic solvent development, which is used for development using a developer including an organic solvent. Here, the term, for organic solvent development refers to a use that is used in a step of performing development using a developer including at least an organic solvent.

It is preferred that the actinic ray-sensitive or radiation-sensitive resin composition of the present invention is typically a resist composition and a negative type resist composition (that is, a resist composition for organic solvent development), from the viewpoint of obtaining a particularly good effect may be obtained. In addition, the composition relating to the present invention is typically a chemical amplification resist composition.

In general, the negative type image forming method using a developer including an organic solvent has a lower dissolution contrast of the unexposed portion and the exposed portion against the developer than the positive type image forming method using an alkali developer. Accordingly, in order to form a fine pattern, a negative type image forming method is adopted for the above-described reason, but the negative type image forming method has a greater effect by the variation (that is, the fact that an acid is present in an excessive amount on the top layer portion of the exposed portion) in concentration of the acid in the film thickness direction of the exposed portion of the resist film than the positive type image forming method having a large dissolution contrast of the unexposed portion and the exposed portion against the developer.

Therefore, the present invention may solve non-uniformity of the film thickness that becomes easily apparent in the negative type image forming method, and as a result, the technical significance thereof is great in that the uniformity of the film thickness is excellent while a fine pattern is formed.

[1] (A) Resin Capable of Increasing the Polarity by the Action of an Acid to Decrease the Solubility Thereof in a Developer Including an Organic Solvent

As a resin capable of increasing the polarity by the action of an acid to decrease the a solubility thereof in a developer including an organic solvent, which is used in the actinic ray-sensitive or radiation-sensitive resin composition according to the present invention, examples thereof include a resin (hereinafter also referred to as an “acid-decomposable resin” or “resin (A)”) having a group (hereinafter also referred to as an “acid-decomposable group”) capable of decomposing by the action of an acid to generate a polar group at both the main chain or side chain of the resin, or at both the main chain and the side chain.

It is preferred that the acid-decomposable group has a structure protected with a group capable of decomposing and leaving a polar group by the action of an acid.

The polar group is not particularly limited as long as the group is a group that is sparingly soluble or insoluble in a developer including an organic solvent, but examples thereof include an acidic group (a group dissociated in 2.38% by mass of an aqueous tetramethylammonium hydroxide solution which has been used as a developer of a resist in the related art) such as a phenolic hydroxyl group, a carboxyl group, a fluorinated alcohol group (preferably a hexafluoroisopropanol group), a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group and a tris(alkylsulfonyl)methylene group, an alcoholic hydroxyl group, or the like.

Further, the alcoholic hydroxyl group is a hydroxyl group that is bonded to a hydrocarbon group, and refers to a hydroxyl group other than a hydroxyl group (phenolic hydroxyl group) that is directly bonded to an aromatic ring, and the alcoholic hydroxyl group does not include an aliphatic alcohol (for example, a fluorinated alcohol group (a hexafluoroisopropanol group or the like)) in which an α-position has been substituted with an electron-withdrawing group such as a fluorine atom, as a hydroxyl group. The alcoholic hydroxyl group is preferably a hydroxyl group having a pKa of 12 to 20.

Examples of a preferred polar group include a carboxyl group, a fluorinated alcohol group (preferably a hexafluoroisopropanol group) and a sulfonic acid group.

A preferred acid-decomposable group is a group obtained by substituting a hydrogen atom of the groups with a group capable of leaving by the action of an acid.

Examples of the group capable of leaving by the action of an acid include —C(R₃₆)(R₃₇)(R₃₈), —C(R₃₆)(R₃₇)(OR₃₉), —C(R₀₁)(R₀₂)(OR₃₉) and the like.

In the Formula, each of R₃₆ to R₃₉ independently represents an alkyl group, a cycloalkyl group, an aryl group, an aralkyl group, or an alkenyl group. R₃₆ and R₃₇ may be bonded to each other to form a ring.

Each of R₀₁ and R₀₂ independently represents a hydrogen atom, an alkyl group, a cycloalkyl group, an aryl group, an aralkyl group, or an alkenyl group.

The alkyl group of R₃₆ to R₃₉ and R₀₁ and R₀₂ is preferably an alkyl group having 1 to 8 carbon atoms, and examples thereof include a methyl group, an ethyl group, a propyl group, an n-butyl group, a sec-butyl group, a hexyl group, an octyl group and the like.

The cycloalkyl group of R₃₆ to R₃₉ and R₀₁ and R₀₂ may be monocyclic or polycyclic. The monocyclic cycloalkyl group is preferably a cycloalkyl group having 3 to 8 carbon atoms, and examples thereof include a cyclopropyl group, a cyclobutyl group, a cyclopentyl group, a cyclohexyl group, a cyclooctyl group, and the like. The polycyclic cycloalkyl group is preferably a cycloalkyl group having 6 to 20 carbon atoms, and examples thereof include an adamantyl group, a norbornyl group, an isobomyl group, a camphanyl group, a dicyclopentyl group, an α-pinel group, a tricyclodecanyl group, a tetracyclododecyl group, an androstanyl group and the like. In addition, at least one carbon atom in the cycloalkyl group may be substituted with a heteroatom such as an oxygen atom.

The aryl group of R₃₆ to R₃₉ and R₀₁ and R₀₂ is preferably an aryl group having 6 to 10 carbon atoms, and examples thereof include a phenyl group, a naphthyl group, an anthryl group and the like.

The aralkyl group of R₃₆ to R₃₉ and R₀₁ and R₀₂ is preferably an aralkyl group having 7 to 12 carbon atoms, and examples thereof include a benzyl group, a phenethyl group, a naphthylmethyl group and the like.

The alkenyl group of R₃₆ to R₃₉ and R₀₁ and R₀₂ is preferably an alkenyl group having 2 to 8 carbon atoms, and examples thereof include a vinyl group, an allyl group, a butenyl group, a cyclohexenyl group and the like.

The ring that R₃₆ and R₃₇ form by combining with each other is preferably a cycloalkyl group (monocyclic or polycyclic). As the cycloalkyl group, a monocyclic cycloalkyl group such as a cyclopentyl group and a cyclohexyl group, and a polycyclic cycloalkyl group such as a norbornyl group, a tetracyclodecanyl group, a tetracyclododecanyl group and an adamantyl group are preferred. A monocyclic cycloalkyl group having 5 to 6 carbon atoms is more preferred, and a monocyclic cycloalkyl group having 5 carbon atoms is particularly preferred.

As the acid-decomposable group, a cumyl ester group, an enol ester group, an acetal ester group, a tertiary alkyl ester group and the like are preferred. The group is more preferably a tertiary alkyl ester group.

The resin (A) preferably contains a repeating unit having an acid decomposable group.

As the repeating unit having an acid-decomposable group, which is contained in the resin (A), the repeating unit represented by the following Formula (I) is preferred.

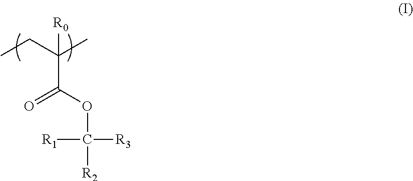

In Formula (I),

R₀ represents a hydrogen atom, or a straight chained or branched alkyl group. Each of R₁ to R₃ independently represents a straight chained or branched alkyl group, or a monocyclic or polycyclic cycloalkyl group.

Two of R₁ to R₃ may be bonded to each other to form a monocyclic or polycyclic cycloalkyl group.

The straight chained or branched alkyl group relating to R₀ may have a substituent and is preferably a straight chained or branched alkyl group having 1 to 4 carbon atoms, and examples thereof include a methyl group, an ethyl group, an n-propyl group, an isopropyl group, an n-butyl group, an isobutyl group, a t-butyl group and the like. Examples of the substituent include a hydroxyl group, a halogen atom (for example, a fluorine atom) and the like.

R₀ is preferably a hydrogen atom, a methyl group, a trifluoromethyl group or a hydroxymethyl group.

The alkyl group of R₁ to R₃ is preferably a methyl group, an ethyl group, an n-propyl group, an isopropyl group, an n-butyl group, an isobutyl group, a t-butyl group or the like having 1 to 4 carbon atoms.

The cycloalkyl group of R₁ to R₃ is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group and an adamantyl group.

The cycloalkyl group that two of R₁ to R₃ form by combining with each other is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group and an adamantyl group. A monocyclic cycloalkyl group having 5 or 6 carbon atoms is particularly preferred.

Examples of a preferred aspect include an aspect in which R₁ is a methyl group or an ethyl group, and R₂ to R₃ are bonded to each other to form the above-described cycloalkyl group.

Each group may have a substituent, and examples of the substituent include a hydroxyl group, a halogen atom (for example, a fluorine atom), an alkyl group (having 1 to 4 carbon atoms), a cycloalkyl group (having 3 to 8 carbon atoms), an alkoxy group (having 1 to 4 carbon atoms), a carboxyl group, an alkoxycarbonyl group (having 2 to 6 carbon atoms) and the like, and a group having 8 or less carbon atoms is preferred.

A particularly preferred aspect of the repeating unit represented by Formula (I) is an aspect in which each of R₁, R₂ and R₃ independently represents a straight chained or branched alkyl group.

In this aspect, the straight chained or branched alkyl group relating to R₁, R₂ and R₃ is preferably an alkyl group having 1 to 4 carbon atoms, and examples thereof include a methyl group, an ethyl group, an n-propyl group, an isopropyl group, an n-butyl group, an isobutyl group, and a t-butyl group.

R₁ is preferably a methyl group, an ethyl group, an n-propyl group and an n-butyl group, more preferably a methyl group and an ethyl group, and particularly preferably a methyl group.

R₂ is preferably a methyl group, an ethyl group, an n-propyl group, an isopropyl group and an n-butyl group, more preferably a methyl group and an ethyl group, and particularly preferably a methyl group.

R₃ is preferably a methyl group, an ethyl group, an n-propyl group, an isopropyl group, an n-butyl group, an isobutyl group and a t-butyl group, more preferably a methyl group, an ethyl group, an isopropyl group and an isobutyl group, and particularly preferably a methyl group, an ethyl group and an isopropyl group.

Preferred specific example of a repeating unit having the acid-decomposable group will be illustrated below, but the present invention is not limited thereto.

In the specific examples, Rx represents a hydrogen atom, CH₃, CF₃ or CH₂OH. Each of Rxa and Rxb represents an alkyl group having 1 to 4 carbon atoms. Z represents a substituent, and when there is a plurality of Z's, each Z may be the same as or different from every other Z. p represents 0 or a positive integer. Specific and preferred examples of Z are the same as the specific and preferable examples of a substituent that may have each group of R₁ to R₃ and the like.

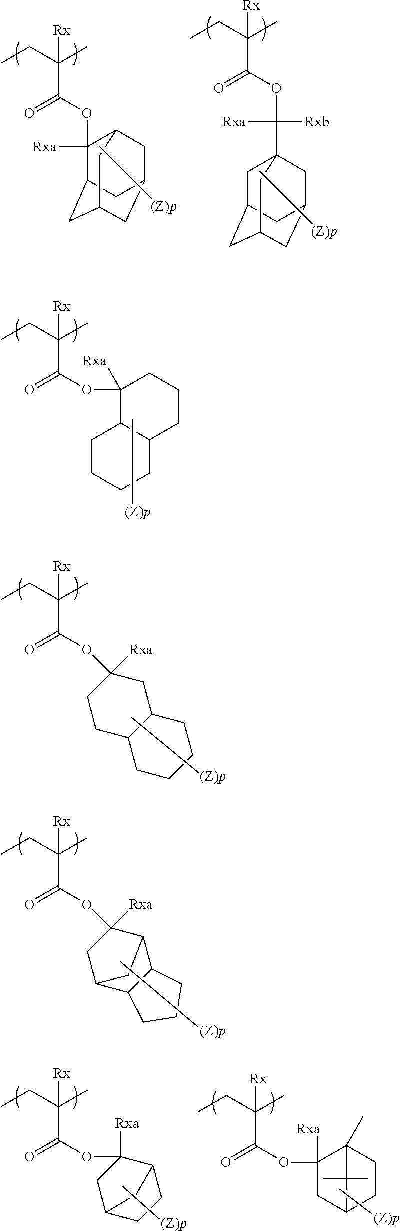

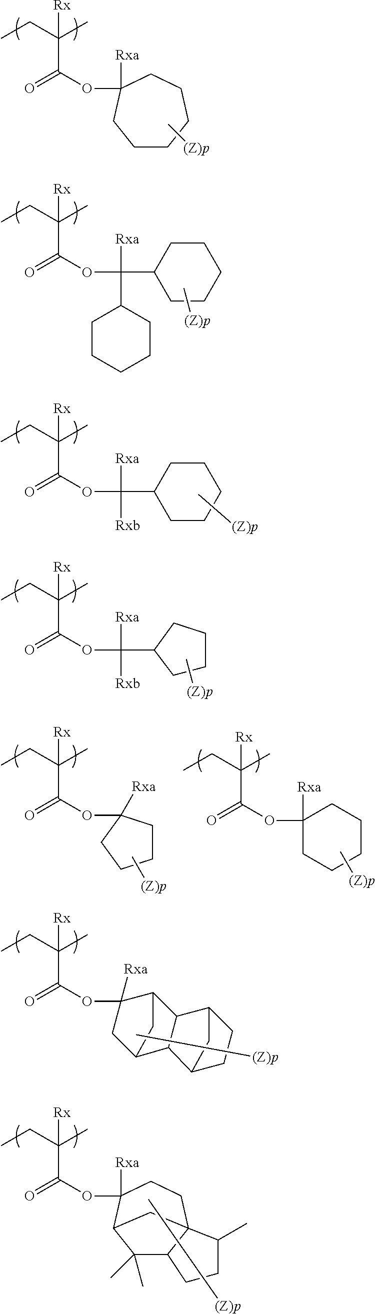

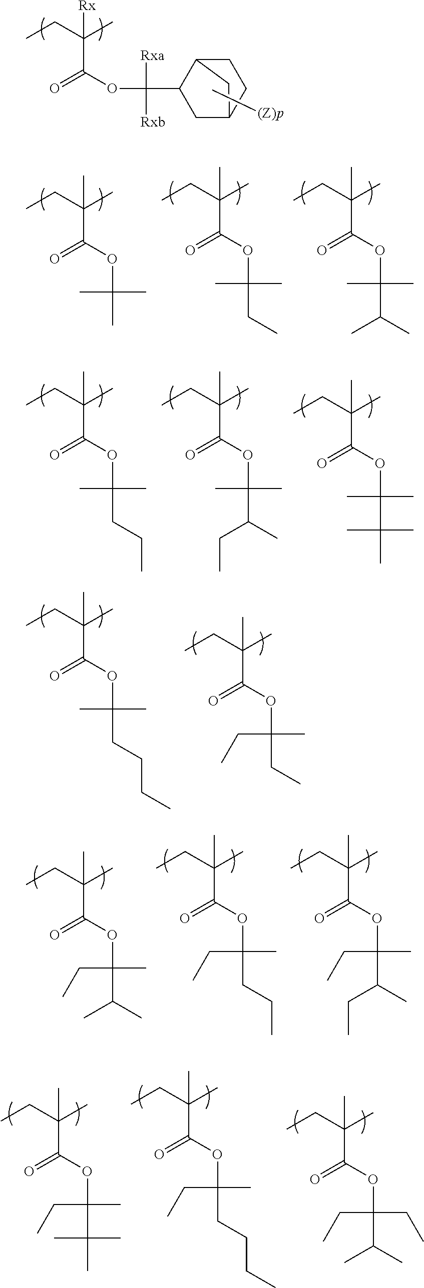

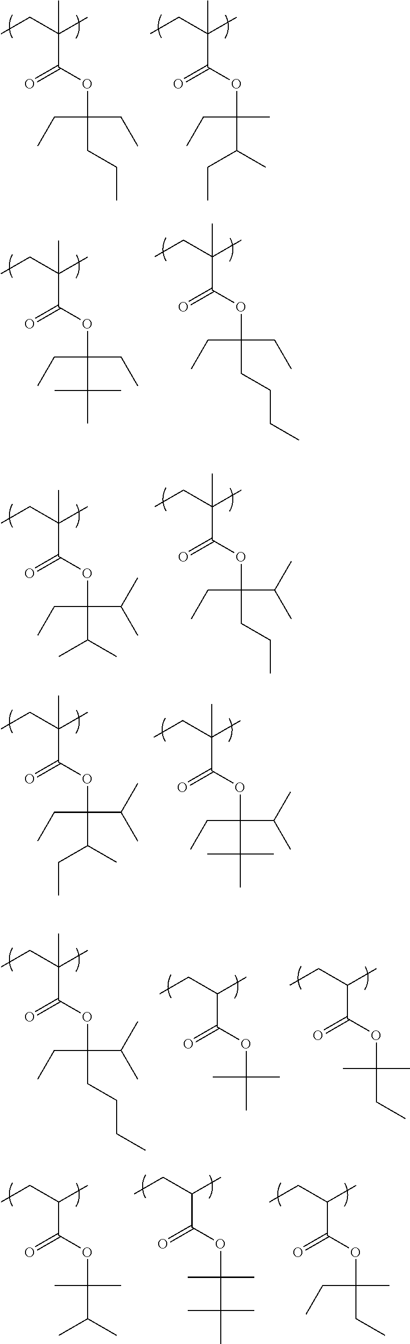

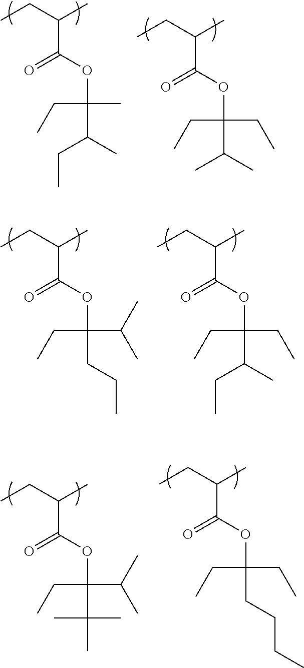

In the case where the resin (A) contains a repeating unit represented by formula (I) as the repeating unit having an acid-decomposable group, the repeating unit having an acid group is preferably consisting of only at least one repeating unit represented by formula (I).

Further, the repeating unit having the acid-decomposable group is preferably a repeating unit represented by the following Formula (IB), which decomposes by the action of an acid to generate a carboxyl group, and accordingly, a pattern forming method that is excellent in roughness performance such as line width roughness, uniformity of a local pattern dimension and exposure latitude, and may further suppress reduction in film thickness of a pattern portion formed by development, so-called film reduction may be provided.

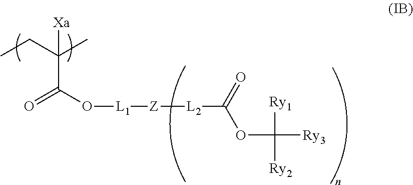

In the Formula, Xa represents a hydrogen atom, an alkyl group, a cyano group or a halogen atom.

Each of Ry₁ to Ry₃ independently represents an alkyl group or a cycloalkyl group. Two of Ry₁ to Ry₃ may be linked to each other to form a ring.

Z represents a linking group having a polycyclic hydrocarbon structure that may have a heteroatom as a (n+1)-valent cyclic member.

Each of L₁ and L₂ independently represents a single bond or a divalent linking group. n represents an integer of 1 to 3.

When n is 2 or 3, each of L₂, Ry₁, Ry₂ and Ry₃ may be the same as or different from every other of L₂, Ry₁, Ry₂ and Ry₃.

The alkyl group of Xa may have a substituent, and examples of the substituent include a hydroxyl group and a halogen atom (preferably a fluorine atom).

The alkyl group of Xa is preferably an alkyl group having 1 to 4 carbon atoms, and examples thereof include a methyl group, an ethyl group, a propyl group, a hydroxymethyl group, a trifluoromethyl group or the like, but a methyl group is preferred.

Xa is preferably a hydrogen atom or a methyl group.

The alkyl group of Ry₁ to Ry₃ may be chained or branched, and is preferably a methyl group, an ethyl group, an n-propyl group, an isopropyl group, an n-butyl group, an isobutyl group, a t-butyl group or the like having 1 to 4 carbon atoms.

The cycloalkyl group of Ry₁ to Ry₃ is preferably a monocyclic cycloalkyl group such as a cyclopentyl group, a cyclohexyl group and the like, and a polycyclic cycloalkyl group such as a norbornyl group, a tetracyclodecanyl group, a tetracyclododecanyl group and an adamantyl group.

The ring that two of Ry₁ to Ry₃ forms by combining with each other is preferably a monocyclic hydrocarbon ring such as a cyclopentane ring, a cyclohexane ring and the like, and a polycyclic hydrocarbon ring such as a norbornane ring, a tetracyclodecane ring, a tetracyclododecane ring, an adamantane ring and the like. A monocyclic hydrocarbon group having 5 or 6 carbon atoms is particularly preferred.

Each of Ry₁ to Ry₃ is independently an alkyl group, and more preferably a chained or branched alkyl group having 1 to 4 carbon atoms. Further, the sum of carbon atoms of the chained or branched alkyl group as Ry₁ to Ry₃ is preferably 5 or less.

Ry₁ to Ry₃ may further have a substituent, and examples of the substituent include an alkyl group (having 1 to 4 carbon atoms), a cycloalkyl group (having 3 to 8 carbon atoms), a halogen atom, an alkoxy group (having 1 to 4 carbon atoms), a carboxyl group, an alkoxycarbonyl group (having 2 to 6 carbon atoms) and the like, and a group having 8 or less carbon atoms is preferred. Among them, from the viewpoint of further improving the dissolution contrast in a developer containing an organic solvent before and after the acid decomposition, the substituent is more preferably a substituent that does not have a heteroatom such as an oxygen atom, a nitrogen atom and a sulfur atom (for example, it is more preferred that the substituent is not an alkyl group substituted with a hydroxyl group, and the like), more preferably a group consisting only of a hydrogen atom and a carbon atom, and particularly preferably a straight chained or branched alkyl group and a cycloalkyl group.

The linking group having a polycyclic hydrocarbon structure of Z includes a ring assembly hydrocarbon ring group and a crosslinked cyclic hydrocarbon ring group, and examples thereof include a group obtained by removing arbitrary (n+1) hydrogen atoms from a ring assembly hydrocarbon ring and a group obtained by removing arbitrary (n+1) hydrogen atoms from a crosslinked cyclic hydrocarbon ring, respectively.

Examples of the ring assembly hydrocarbon ring group include a bicyclohexane ring group, a perhydronaphthalene ring group and the like. Examples of the crosslinked cyclic hydrocarbon ring group include a bicyclic hydrocarbon ring group such as a pinane ring group, a bornane ring group, a norpinane ring group, a norbornane ring group and a bicyclooctane ring group (a bicyclo[2.2.2]octane ring group, a bicyclo[3.2.1]octane ring group and the like), a tricyclic hydrocarbon ring group such as a homobledane ring group, an adamantane ring group, a tricyclo[5.2.1.0^{2,6}]decane ring group and a tricyclo[4.3.1.1^{2,5}]undecane ring group, a tetracyclic hydrocarbon ring group such as a tetracyclo[4.4.0.1^{2,5}0.1^{7,10}]dodecane ring group and a perhydro-1,4-methano 5,8-methanonaphthalene ring group, and the like. Further, the crosslinked cyclic hydrocarbon ring group also includes a condensed cyclic hydrocarbon ring group, for example, a condensed ring group obtained by condensing a plurality of 5- to 8-membered cycloalkane ring groups, such as a perhydronaphthalene (decalin) ring group, a perhydroanthracene ring group, a perhydrophenanthrene ring group, a perhydroacenaphthene ring group, a perhydrofluorene ring group, a perhydroindene ring group and a perhydrophenalene ring group.

Preferred examples of the crosslinked cyclic hydrocarbon ring group include a norbornane ring group, an adamantane ring group, a bicyclooctane ring group, a tricyclo[5,2,1,0^{2,6}]decane ring group and the like.

Examples of the more preferred crosslinked cyclic hydrocarbon ring group include a norbornane ring group and an adamantane ring group.

The linking group having a polycyclic hydrocarbon structure represented in Z may have a substituent. Examples of the substituent that Z may have include a substituent such as an alkyl group, a hydroxyl group, a cyano group, a keto group (═O), an acyloxy group, —COR, —COOR, —CON(R)₂, —SO₂R, —SO₃R and —SO₂N(R)₂. Here, R represents a hydrogen atom, an alkyl group, a cycloalkyl group or an aryl group.

An alkyl group, an alkylcarbonyl group, an acyloxy group, —COR, —COOR, —CON(R)₂, —SO₂R, —SO₃R and —SO₂N(R)₂ as the substituent that Z may have may further have a substituent, and examples of the substituent includes a halogen atom (preferably, fluorine atom).

In the linking group having a polycyclic hydrocarbon structure represented by Z, the carbon constituting the polycyclic ring (the carbon contributing to ring formation) may be carbonyl carbon. In addition, as described above, the polycyclic ring may have, as a ring member, a heteroatom such as an oxygen atom and a sulfur atom.

Examples of the linking group represented by L₁ and L₂ include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), a linking group formed by combining a plurality of these members and the like, and a linking group having a total carbon number of 12 or less is preferred.

L₁ is preferably a single bond, an alkylene group, —COO—, —OCO—, —CONH—, —NHCO—, -an alkylene group-COO—, -an alkylene group-OCO—, -an alkylene group-CONH—, -an alkylene group-NHCO—, —CO—, —O—, —SO₂— and -an alkylene group-O—, and more preferably a single bond, an alkylene group, -an alkylene group-COO— or -an alkylene group-O—.

L₂ is preferably a single bond, an alkylene group, —COO—, —OCO—, —CONH—, —NHCO—, —COO-an alkylene group-, —OCO-an alkylene group-, —CONH-an alkylene group-, —NHCO-an alkylene group-, —CO—, —O—, —SO₂—, —O-an alkylene group- and —O-a cycloalkylene group-, and more preferably a single bond, an alkylene group, —COO-an alkylene group-, —O-an alkylene group- or —O-a cycloalkylene group-.

In the above-described description method, the bonding hand “—” at the left end means to be connecting the ester bond on the main chain side in L₁ and connecting Z in L₂, and the bonding hand “—” at the right end means to be binding to Z in L₁ and binding to the ester bond bonded to the group represented by (Ry₁)(Ry₂)(Ry₃)C— in L₂.

In addition, L₁ and L₂ may be bonded to the same atom constituting the polycyclic ring in Z.

n is preferably 1 or 2, and more preferably 1.

Hereinafter, specific examples of the repeating unit represented by Formula (IB) will be described below, but the present invention is not limited thereto. In the following specific example, Xa represents a hydrogen atom, an alkyl group, a cyano group or a halogen atom.

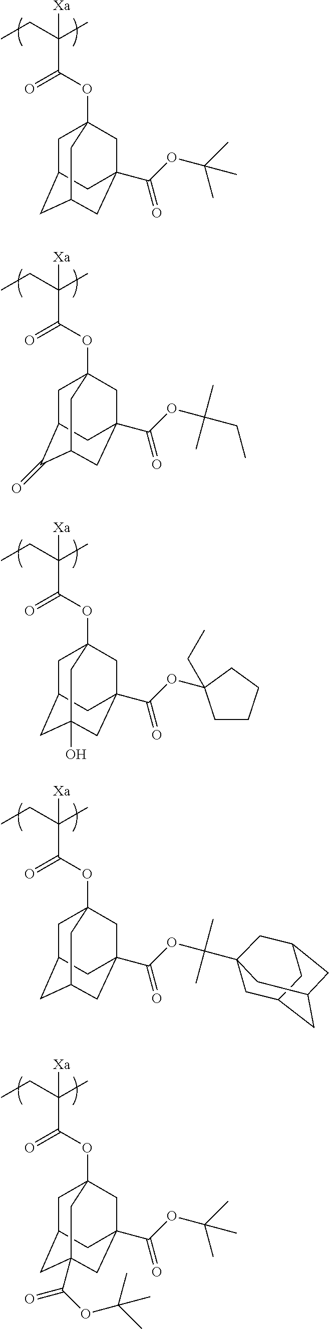

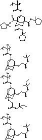

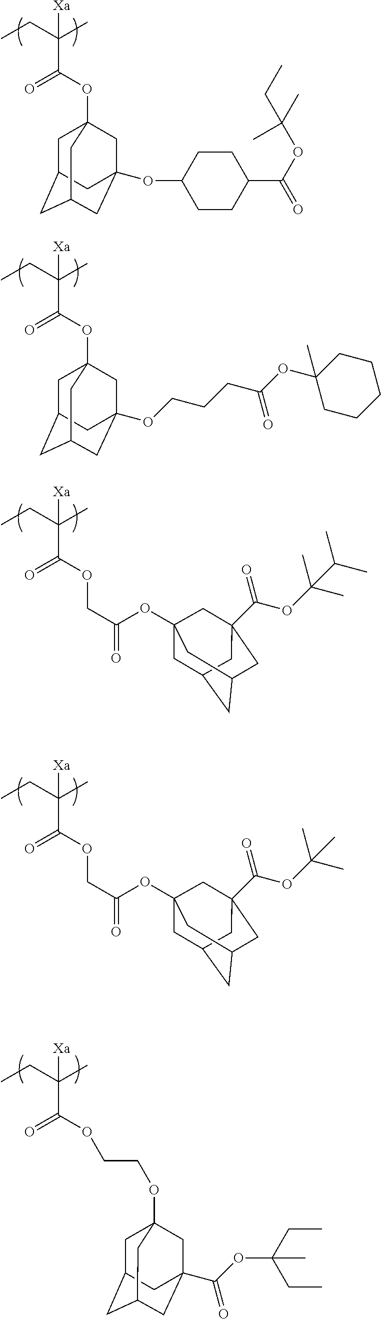

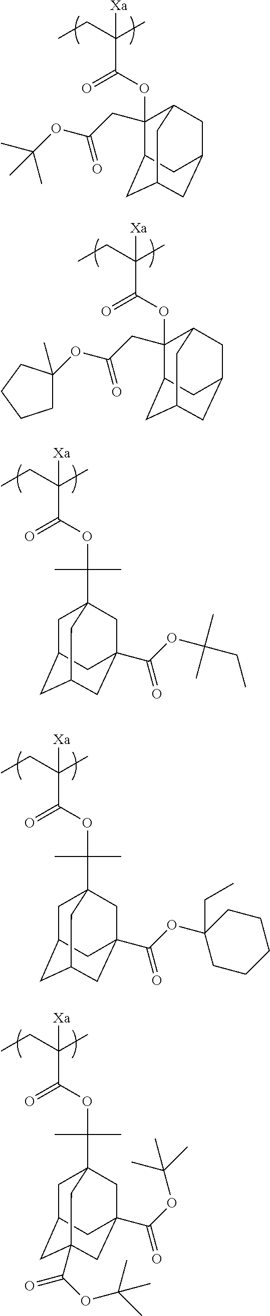

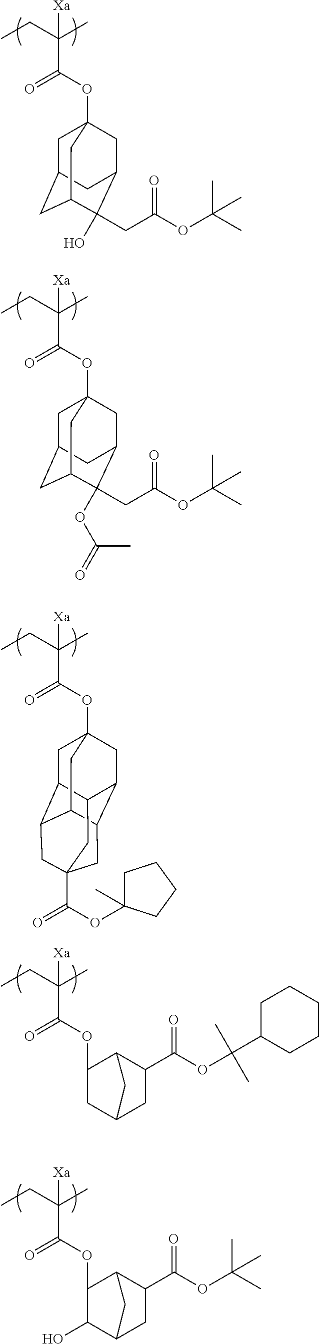

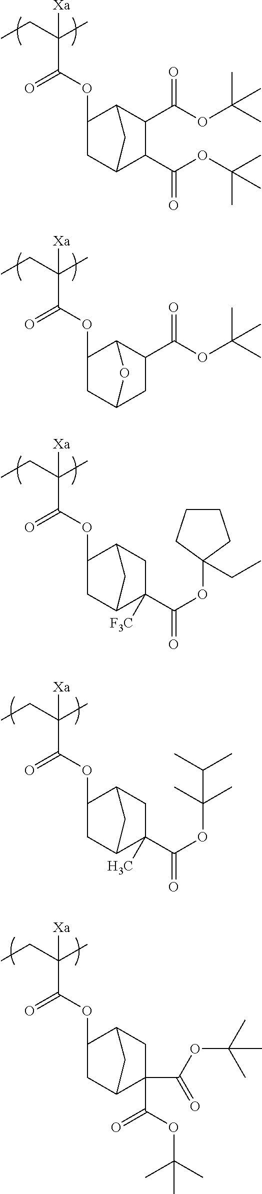

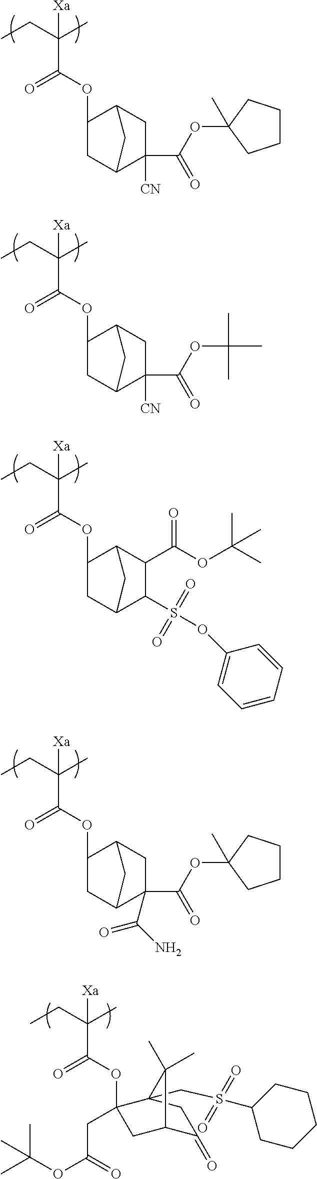

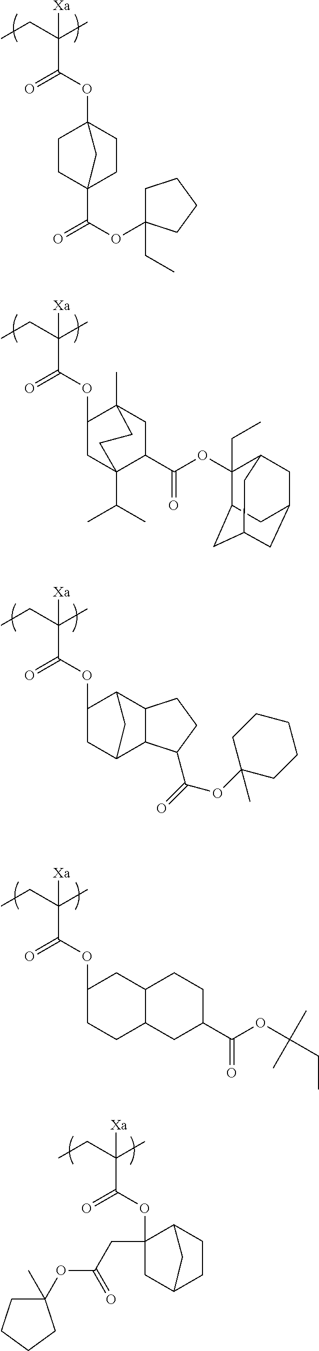

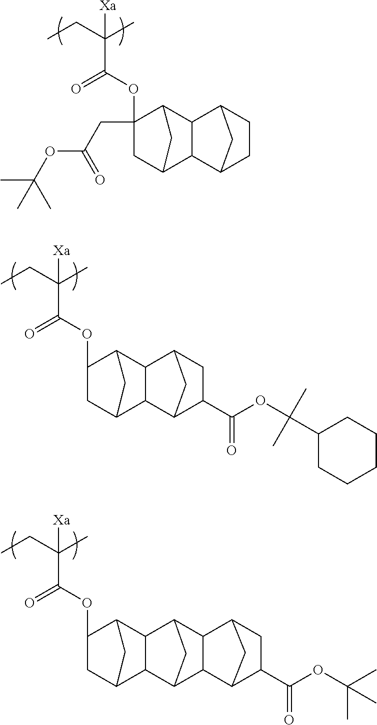

Also, the resin (A) may contain, as the repeating unit having an acid-decomposable group, a repeating unit having in the side chain thereof a structure capable of decomposing by the action of an acid to produce an alcoholic hydroxy group (hereinafter, sometimes referred to as “OH protection structure”).

The OH protection structure is preferably a structure represented by at least one formula selected from the group consisting of the following formulae (II-1) to (II-4).

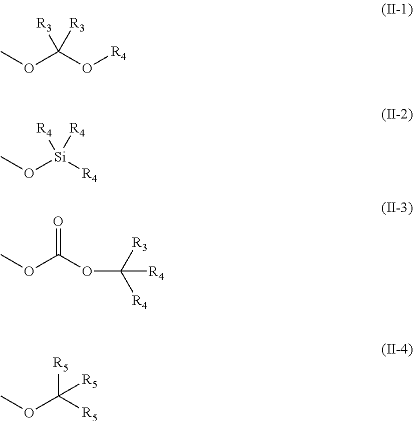

In the formulae, each R₃ independently represents a hydrogen atom or a monovalent organic group. R₄s may combine with each other to form a ring.

Each R₄ independently represents a monovalent organic group. R₄s may combine with each other to form a ring. R₃ and R₄ may combine with each other to form a ring.

Each R₅ independently represents a hydrogen atom, an alkyl group, a cycloalkyl group, an aryl group, an alkenyl group or an alkynyl group. At least two R₅s may combine with each other to form a ring, provided that when one or two members out of three R₅s are a hydrogen atom, at least one of the remaining R₅s represents an aryl group, an alkenyl group or an alkynyl group.

As the OH protection structure, at least one structure selected from the group consisting of the following formulae (II-5) to (II-9) is also a preferred embodiment.

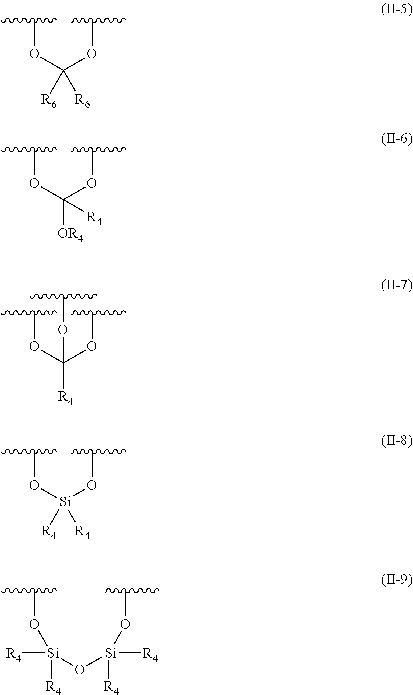

In the formulae, R₄ has the same meaning as in formulae (II-1) to (II-3).

Each R₆ independently represents a hydrogen atom or a monovalent organic group. R₆s may combine with each other to form a ring.

The group capable of decomposing by the action of an acid to produce an alcoholic hydroxy group is more preferably represented by at least one formula selected from formulae (II-1) to (II-3), still more preferably represented by formula (II-1) or (II-3), yet still more preferably represented by formula (II-1).

R₃ represents a hydrogen atom or a monovalent organic group as described above. R₃ is preferably a hydrogen atom, an alkyl group or a cycloalkyl group, more preferably a hydrogen atom or an alkyl group.

The alkyl group of R₃ may be a linear or branched-chain alkyl group. The carbon number of the alkyl group of R₃ is preferably from 1 to 10, more preferably from 1 to 3. Examples of the alkyl group of R₃ include a methyl group, an ethyl group, an n-propyl group, an isopropyl group, and an n-butyl group.

The cycloalkyl group of R₃ may be monocyclic or polycyclic. The carbon number of the cycloalkyl group of R₃ is preferably from 3 to 10, more preferably from 4 to 8. Examples of the cycloalkyl group of R₃ include a cyclopropyl group, a cyclobutyl group, a cyclopentyl group, a cyclohexyl group, a norbornyl group, and an adamantyl group.

R₄ represents a monovalent organic group. R₄ is preferably an alkyl group or a cycloalkyl group, more preferably an alkyl group. These alkyl group and cycloalkyl group may have a substituent.

The alkyl group of R₄ preferably has no substituent or has one or more aryl groups and/or one or more silyl groups as the substituent. The carbon number of the unsubstituted alkyl group is preferably from 1 to 20. The carbon number of the alkyl group moiety in the alkyl group substituted with one or more aryl groups is preferably from 1 to 25. The carbon number of the alkyl group moiety in the alkyl group substituted with one or more silyl groups is preferably from 1 to 30. Also, in the case where the cycloalkyl group of R₄ does not have a substituent, the carbon number thereof is preferably from 3 to 20.

R₅ represents a hydrogen atom, an alkyl group, a cycloalkyl group, an aryl group, an alkenyl group or an alkynyl group. However, when one or two members out of three R₅s are a hydrogen atom, at least one of the remaining R₅s represents an aryl group, an alkenyl group or an alkynyl group. R₅ is preferably a hydrogen atom or an alkyl group. The alkyl group may or may not have a substituent. In the case where the alkyl group does not have a substituent, the carbon number thereof is preferably from 1 to 6, more preferably from 1 to 3.

R₆ represents a hydrogen atom or a monovalent organic group as described above. R₆ is preferably a hydrogen atom, an alkyl group or a cycloalkyl group, more preferably a hydrogen atom or an alkyl group, still more preferably a hydrogen atom or an alkyl group having no substituent. R₆ is preferably a hydrogen atom or an alkyl group having a carbon number of 1 to 10, more preferably a hydrogen atom or an alkyl group having a carbon number of 1 to 10 and having no substituent.

Examples of the alkyl group and cycloalkyl group of R₄, R₅ and R₆ are the same as those described for R₃ above.

Specific examples of the repeating unit having an OH protection structure in the side chain include the following specific examples and those derived from monomers exemplified in paragraph [0025] of U.S. Patent Application Publication 2012/0064456A, but the present invention is not limited thereto.

(In the following specific examples, Xa₁ represents a hydrogen atom, CH₃, CF₃ of CH₂OH.)

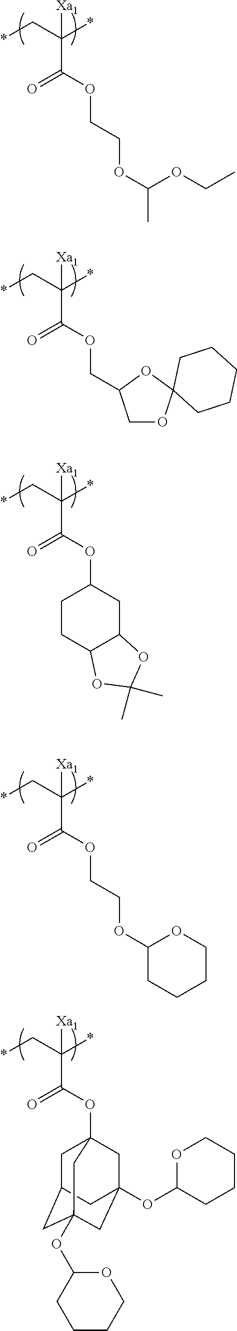

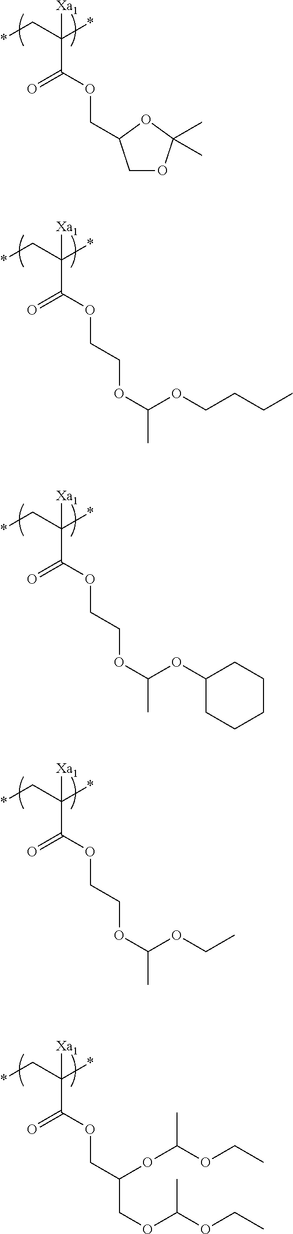

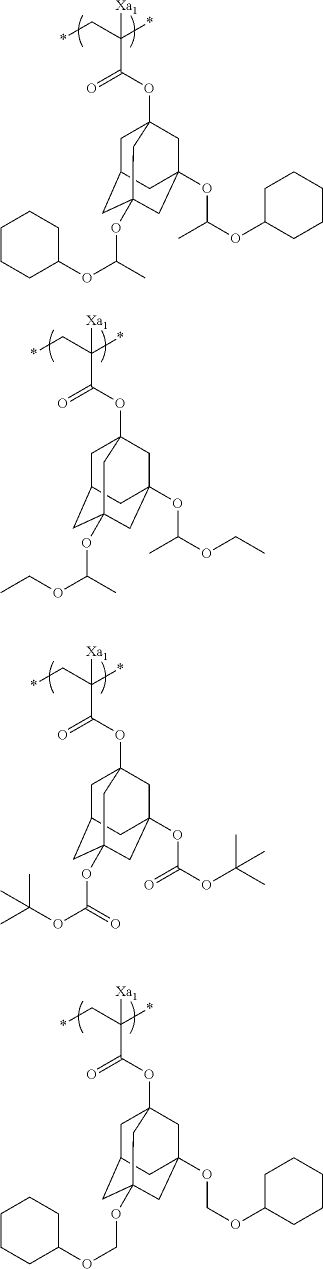

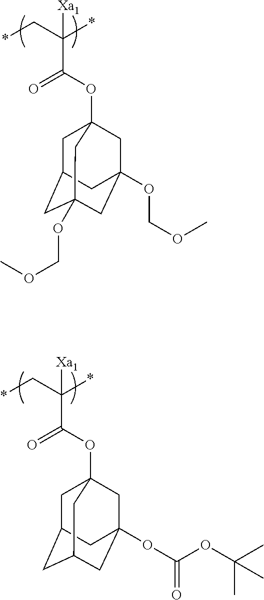

The repeating unit having an acid-decomposable group of the resin (A) may be used either alone or in combination of two or more thereof

In the present invention, it is preferred that when a dissociated substance produced by decomposing a group (acid-decomposable group) capable of decomposing by the action of an acid to produce a polar group has a molecular weight (when plural kinds of dissociated substances are produced, a weighted molecular weight of the molecular weight by a mole fraction (hereinafter also referred to as the molar average value)) of 140 or less, the resin (A) has 50 mol % or more of a repeating unit having the acid-decomposable group based on all the repeating groups in the resin. Accordingly, when a negative type image is formed, an exposed portion remains as a pattern, and thus the film thickness of the pattern portion may be prevented from being reduced by decreasing the molecular weight of the dissociated substance.

In the present invention, the term “the dissociated substance produced by decomposing the acid-decomposable group” refers to a substance obtained by decomposing and leaving by the action of an acid, which corresponds to the group capable of decomposing and leaving by the action of an acid. For example, in the case of a repeating unit (a) (a repeating unit at the upperleft part in the example described below) described below, the term refers to alkene (H₂C═C(CH₃)₂) produced by decomposing a t-butyl moiety.

In the present invention, the molecular weight (molar average value when plural kinds of dissociated substances are produced) of the dissociated substance produced by decomposing the acid-decomposable group is more preferably 100 or less from the viewpoint of preventing the film thickness of the pattern portion from being decreased.

Further, the lower limit of the molecular weight (the average value thereof when plural kinds of dissociated substances are produced) of the dissociated substance produced by decomposing the acid-decomposable group is not particularly limited, but is preferably 45 and more preferably 55 from the viewpoint that the acid-decomposable group exhibits the function thereof

In the present invention, from the viewpoint of maintaining the film thickness of the pattern portion which is the exposed portion more definitely, when the molecular weight of the dissociated substance produced by decomposing the acid-decomposable group is 140 or less, the repeating unit having the acid-decomposable group (the sum thereof in the case of containing plural kinds thereof) is present in an amount of more preferably 60 mol % or more, more preferably 65 mol % or more and still more preferably 70 mol % or more, based on all the repeating units in the resin. Further, the upper limit is not particularly limited, but is preferably 90 mol % and more preferably 85 mol %.

The content ratio as the sum of the repeating unit having the acid-decomposable group is preferably 20 mol % or more, more preferably 30 mol % or more, still more preferably 45 mol % or more and particularly preferably 50 mol % or more, based on all the repeating units in the resin (A).

Further, the content ratio as the sum of the repeating unit having the acid-decomposable group is preferably 90 mol % or less and more preferably 85 mol % or less, based on all the repeating units in the resin (A).

The resin (A) may contain a repeating unit further having a lactone structure or a sultone structure.

As the lactone structure or the sultone structure, anything may be used as long as the structure has a lactone structure or a sultone structure, but a 5- to 7-membered ring lactone structure is preferred, and a 5- to 7-membered ring lactone structure to which another ring structure is condensed to form a bicyclo or Spiro structure is preferred. It is more preferred that the structure has a repeating unit having a lactone structure represented by any one of the following Formulas (LC1-1) to (LC1-17) or a sultone structure represented by any one of the following Formulas (SL1-1) to (SL1-3). Further, the lactone structure or the sultone structure may be bonded directly to the main chain. A preferred lactone structure is (LC1-1), (LC1-4), (LC1-5), (LC1-6), (LC1-13), (LC1-14) and (LC1-17), and a particularly preferred lactone structure is (LC1-4). By using such a specific lactone structure, LWR and development defects are improved.

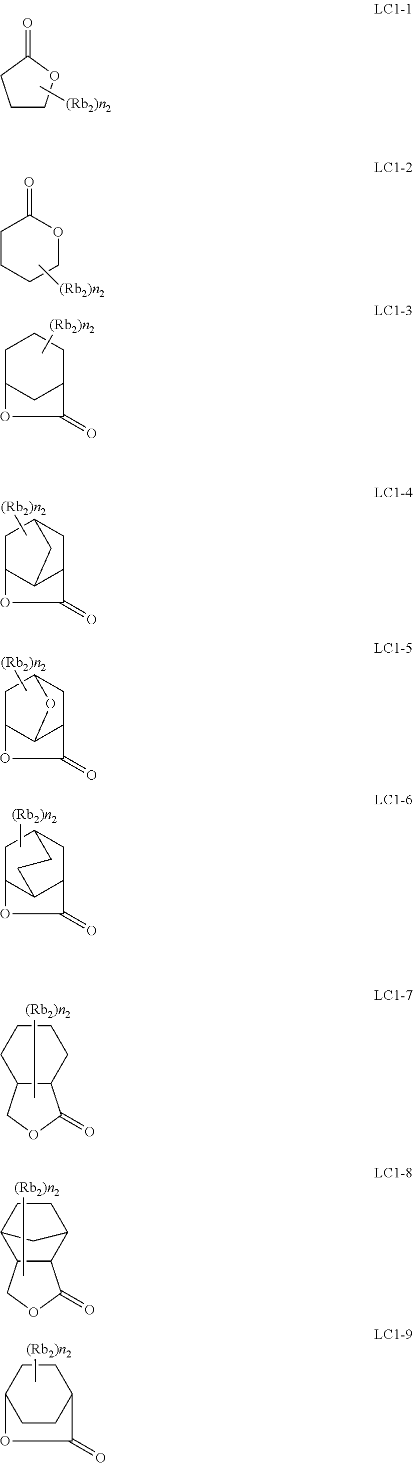

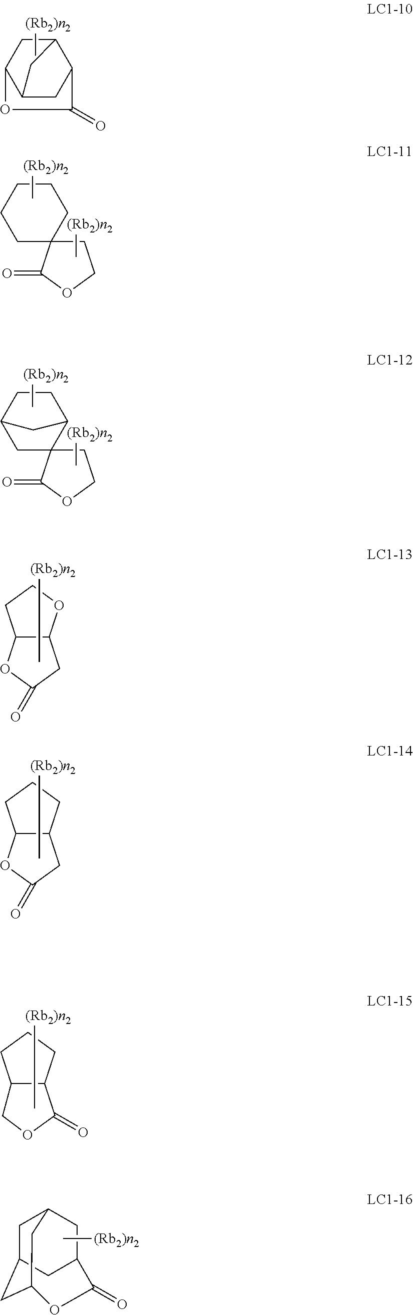

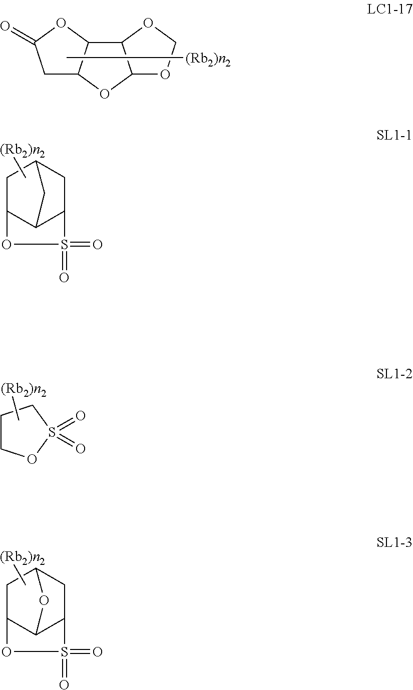

The lactone structure or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group and the like. An alkyl group having 1 to 4 carbon atoms, a cyano group and an acid-decomposable group are more preferred. n₂ represents an integer of 0 to 4. When n₂ is 2 or more, each substituent (Rb₂) may be the same as or different from every other substituent (Rb₂). In addition, a plurality of substituents (Rb₂) may be bonded to each other to form a ring.

The repeating unit having a lactone group or a sultone structure usually has an optical isomer, but any optical isomer may be used. Further, a kind of optical isomer may be used alone, or a plurality of optical isomers may be mixed and the mixture may be used. When a kind of optical isomer is mainly used, the optical purity (ee) thereof is preferably 90% or more, and more preferably 95% or more.

The repeating unit having a lactone structure or a sultone structure is preferably a repeating unit represented by the following Formula (AII).

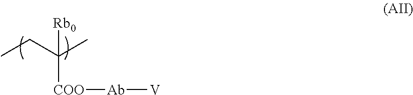

In Formula (AII),

Rb₀ represents a hydrogen atom, a halogen atom or an alkyl group (preferably having 1 to 4 carbon atoms) that may have a substituent.

Examples of a preferred substituent that an alkyl group of Rb₀ may have include a hydroxyl group and a halogen atom. Examples of the halogen atom of Rb₀ include a fluorine atom, a chlorine atom, a bromine atom and an iodine atom. Rb₀ is preferably a hydrogen atom, a methyl group, a hydroxymethyl group and a trifluoromethyl group, and particularly preferably a hydrogen atom and a methyl group.

Ab represents a single bond, an alkylene group, a divalent linking group having a monocyclic or polycyclic cycloalkyl structure, an ether bond, an ester bond, a carbonyl group or a divalent linking group obtained by combining thereof. Ab is preferably a single bond and a divalent linking group represented by -Ab₁-CO₂—.

Ab₁ is a straight chained or branched alkylene group and a monocyclic or polycyclic cycloalkylene group, and preferably a methylene group, an ethylene group, a cyclohexylene group, an adamantylene group and a norbornylene group.

V represents a group having a lactone structure or a sultone structure. Specifically, V represents a group having a structure represented by any one of for example, Formula (LC1-1) to (LC1-17) and (SL1-1) to (SL1-3).

When the resin (A) contains a repeating unit having a lactone structure or a sultone structure, the content of the repeating unit having a lactone structure or a sultone structure is preferably in a range of 0.5 mol % to 80 mol %, more preferably in a range of 1 mol % to 65 mol %, still more preferably in a range of 5 mol % to 60 mol %, particularly preferably in a range of 3 mol % to 50 mol % and most preferably in a range of 10 mol % to 50 mol %, based on all the repeating units of the resin (A).

The repeating unit having a lactone structure or a sultone structure may be used either alone or in combination of two or more thereof.

Hereinafter, specific examples of the repeating unit having a lactone structure or a sultone structure will be described, but the present is not limited thereto.

(In the formula, Rx represents H, CH₃, CH₂OH or CF₃)

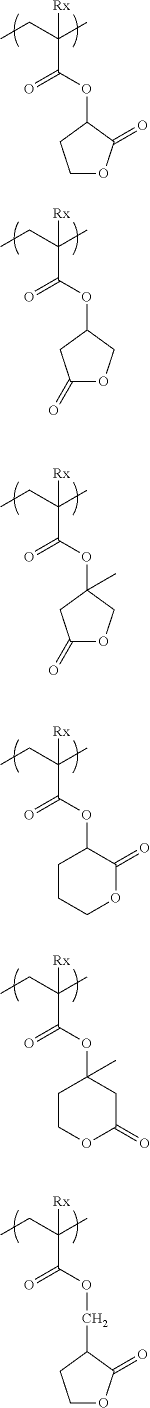

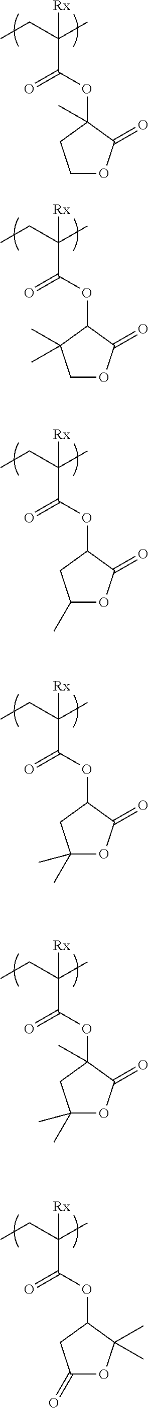

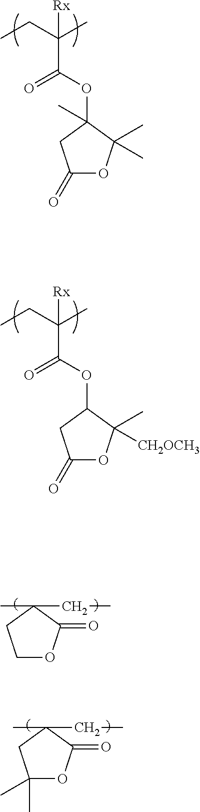

On the formula, Rx represents H, CH₃, CH₂OH or CF₃)

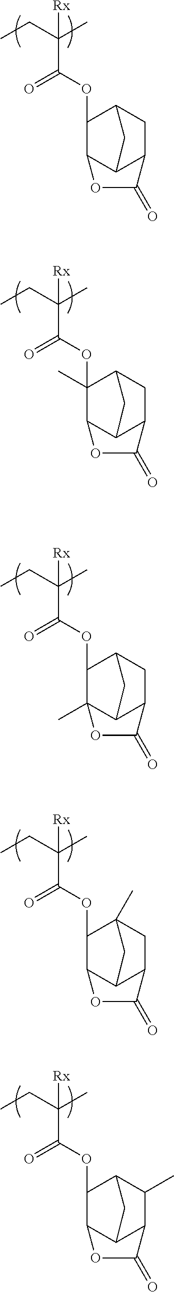

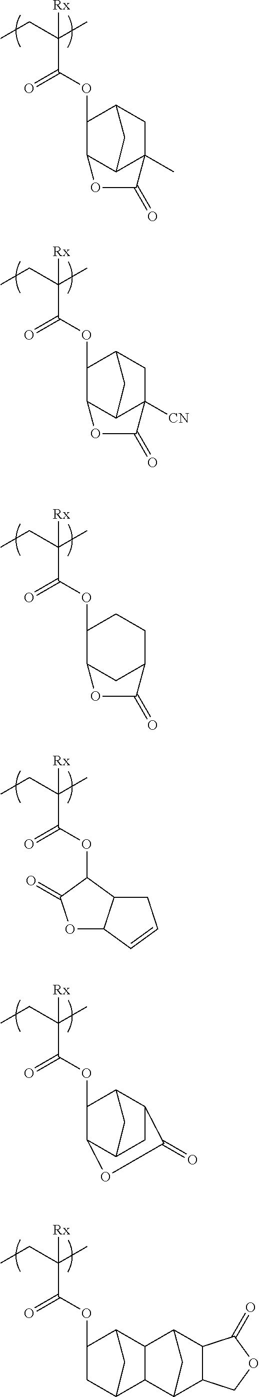

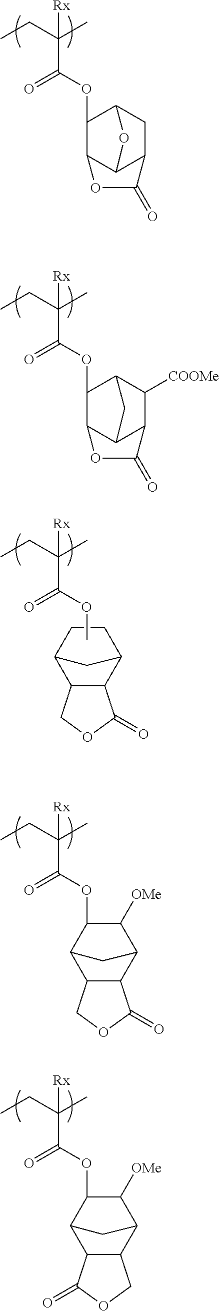

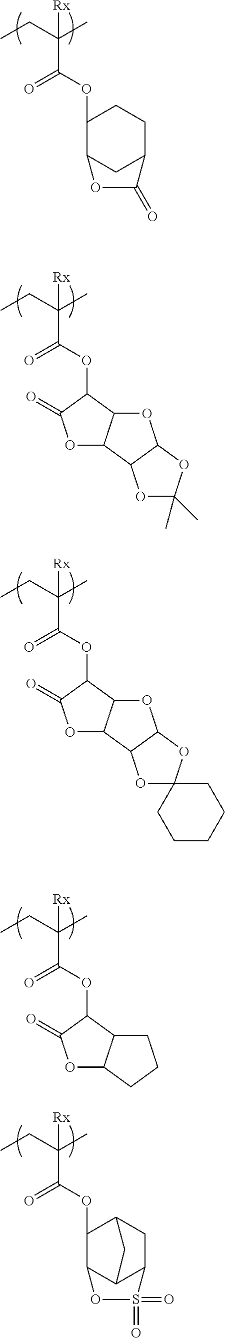

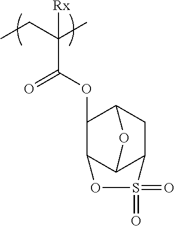

(In the formula, Rx represents H, CH₂OH or CF₃)

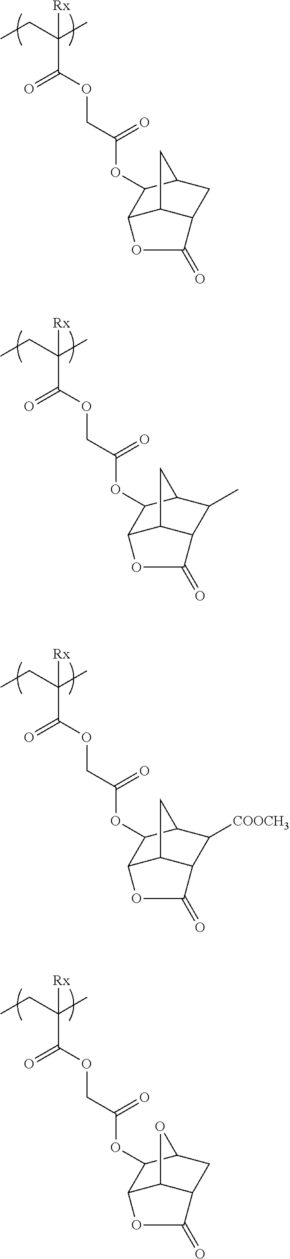

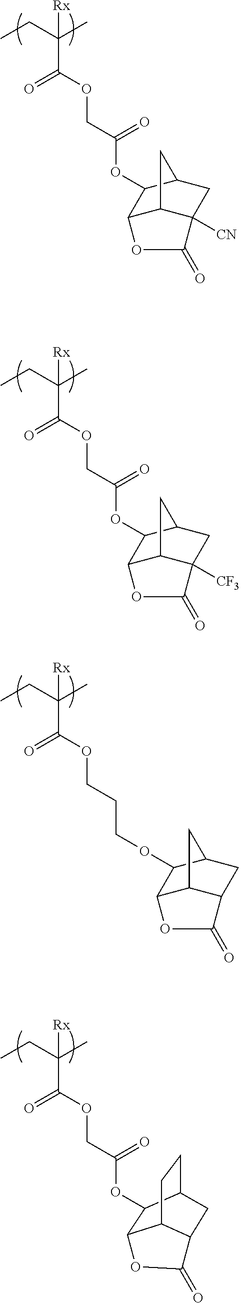

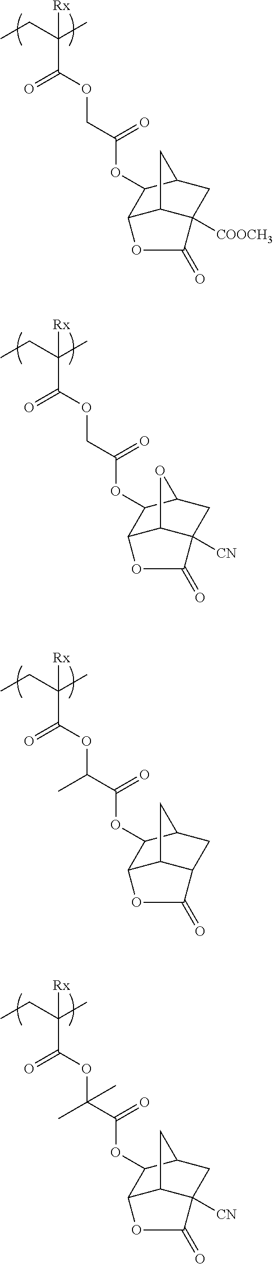

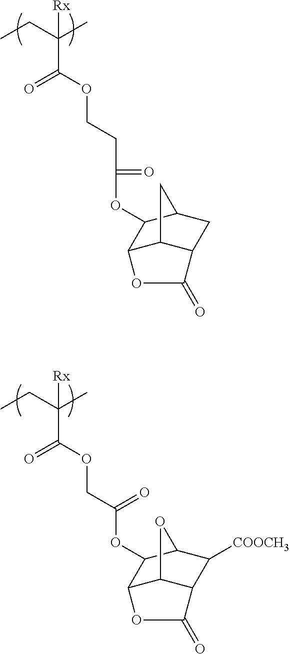

(In the formula, Rx represents H, CH₃, CH₂OH or CF₃)

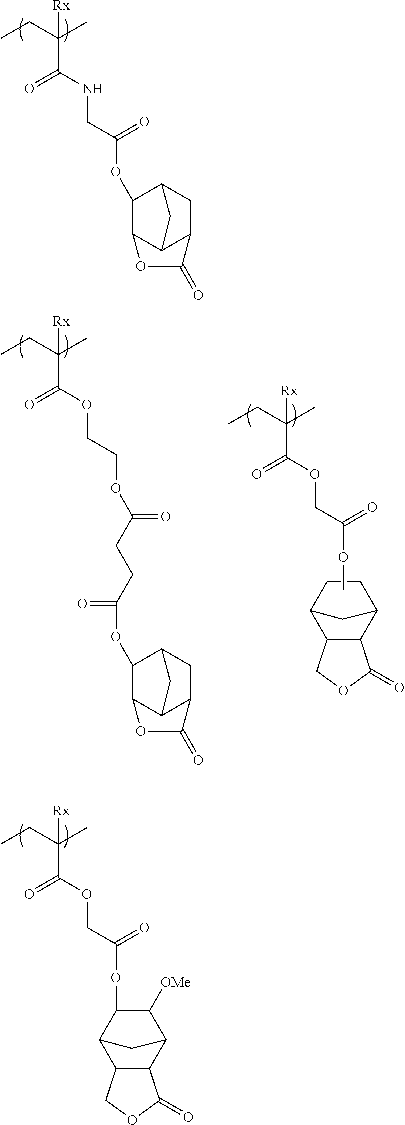

The resin (A) may have a repeating unit having a hydroxyl group or a cyano group. Accordingly, adhesion to substrate and affinity for developer are improved. The repeating unit having a hydroxyl group or a cyano group is preferably a repeating unit having an alicyclic hydrocarbon structure substituted with a hydroxyl group or a cyano group and preferably has no acid-decomposable group.

Further, it is preferred that the repeating unit having the alicyclic hydrocarbon structure substituted with a hydroxyl group or a cyano group is different from the repeating unit represented by Formula (AII).

In the alicyclic hydrocarbon structure in the alicyclic hydrocarbon structure substituted with a hydroxyl group or a cyano group, the alicyclic hydrocarbon structure is preferably an adamantyl group, a diamantyl group and a norbornane group. A preferred alicyclic hydrocarbon structure substituted with a hydroxyl group or a cyano group is preferably a partial structure represented by the following Formulas (VIIa) to (VIId).

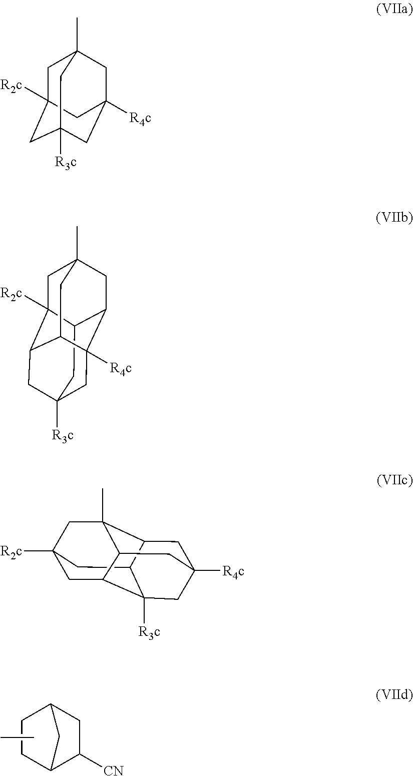

In Formulas (VIIa) to (VIIc),

each of R_{2c} to R_{4c} independently represents a hydrogen atom, a hydroxyl group or a cyano group. However, at least one of R_{2c} to R_{4c} represents a hydroxyl group or a cyano group. It is preferred that one or two of R_{2c} to R_{4c} are a hydroxyl group with the remaining being a hydrogen atom. In Formula (VIIa), it is more preferred that two of R_{2c} to R_{4c} are a hydroxyl group with the remaining being a hydrogen atom.

Examples of the repeating unit having a partial structure represented by Formulas (VIIa) to (VIId) include a repeating unit represented by the following Formulas (AIIa) to (AIId).

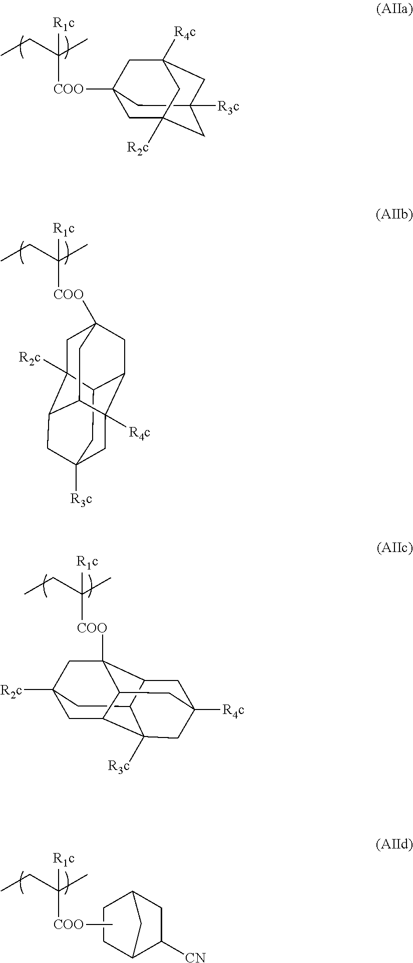

In Formulas (AIIa) to (AIId),

R_{1c} represents a hydrogen atom, a methyl group, a trifluoromethyl group or a hydroxymethyl group.

R_{2c} to R_{4c} have the same meaning as R_{2c} to R_{4c} in Formulas (VIIa) to (VIIc).

The resin (A) may or may not contain a repeating unit having a hydroxyl group or a cyano group, but when the resin (A) contains a repeating having a hydroxyl group or a cyano group, the content of the repeating unit having a hydroxyl group or a cyano group is preferably 1 mol % to 40 mol %, more preferably 3 mol % to 30 mol %, and still more preferably 5 mol % to 25 mol %, based on all the repeating units in the resin (A).

Specific examples of the repeating unit having a hydroxyl group or a cyano group will be described below, but the present invention is not limited thereto.

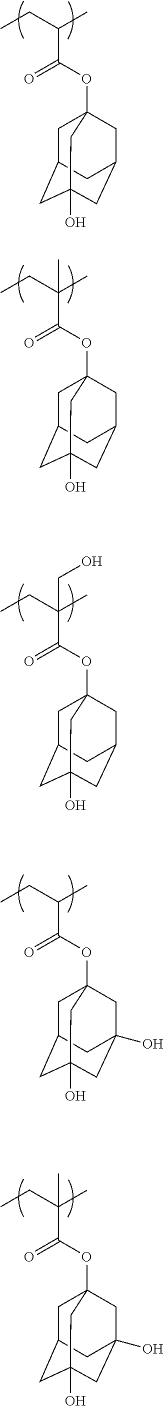

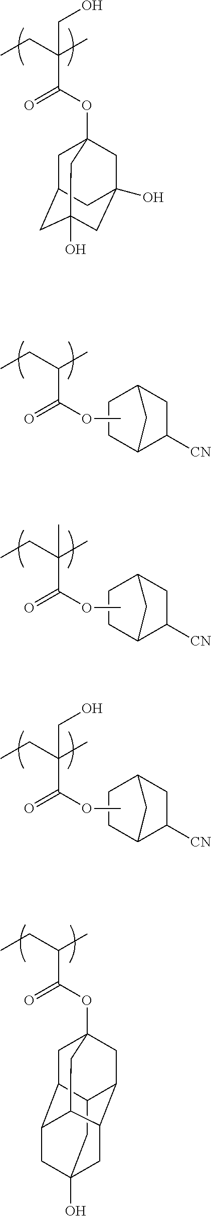

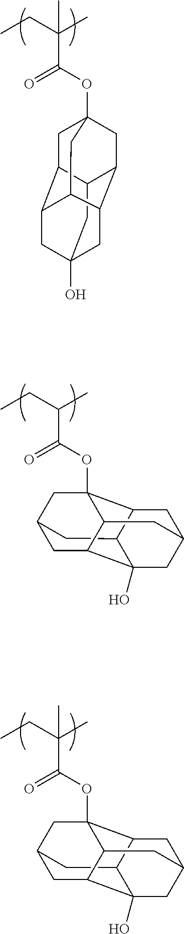

The resin (A) may have a repeating unit having an acid group. Examples of the acid group includes a carboxyl group, a sulfonamide group, a sulfonylimide group, a bissulfonylimide group, and an aliphatic alcohol (for example, a hexafluoroisopropanol group) in which an α-position is substituted with an electron-withdrawing group (for example, a hexafluoroisopropanol group), and it is more preferred that the resin has a repeating unit having a carboxyl group. By containing a repeating unit having an acid group, the resolution increases in the usage of contact holes. As for the repeating unit having an acid group, a repeating unit in which the acid group is directly bonded to the main chain of the resin, such as repeating unit by an acrylic acid or a methacrylic acid or a repeating unit in which the acid group is bonded to the main chain of the resin through a linking group, and a repeating unit in which the acid group is introduced into the terminal of the polymer chain by using a polymerization initiator having an acid group or a chain transfer agent at the time of polymerization are all preferred, and the linking group may have a monocyclic or polycyclic cyclic hydrocarbon structure. A repeating unit by an acrylic acid or a methacrylic acid is particularly preferred.

The resin (A) may or may not contain a repeating unit having an acid group, but in the case of containing a repeating unit having an acid group, the content ratio of the repeating unit having an acid group is preferably 15 mol % or less, and more preferably 10 mol % or less, based on all the repeating units in the resin (A). When the resin (A) contains a repeating unit having an acid group, the content of the repeating unit having an acid group in the resin (A) is usually 1 mol % or more.

Specific examples of the repeating unit having an acid group will be described below, but the present invention is not limited thereto.

In the specific examples, Rx represents H, CH₃, CH₂OH or CF₃.

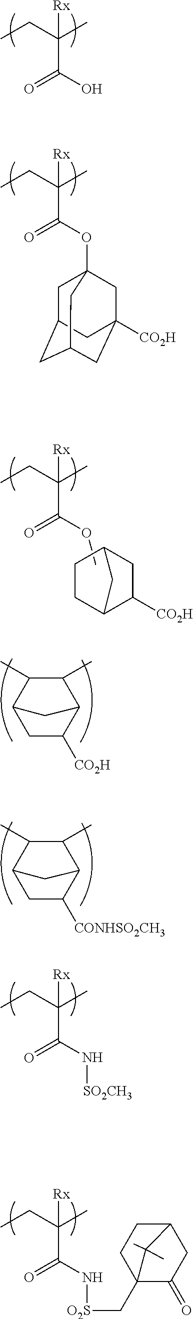

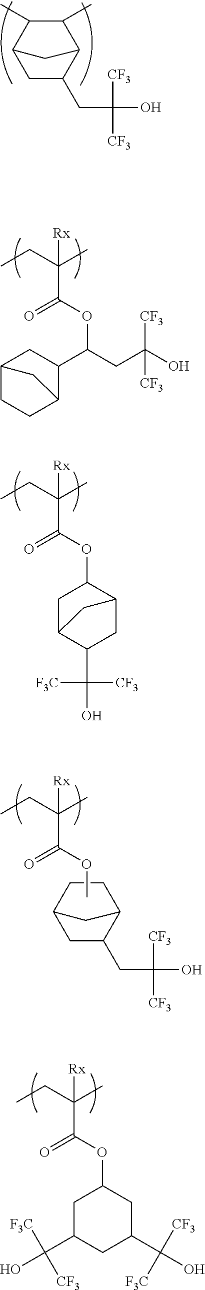

The resin (A) of the present invention may have a repeating unit having an alicyclic hydrocarbon structure having no polar group (for example, the acid group, the hydroxyl group and the cyano group) and not exhibiting acid decomposability. Accordingly, elution of low molecular components from the resist film into the immersion liquid at the time of immersion exposure may be reduced, and further, the solubility of the resin at the time of the development using an organic solvent-containing developer may be appropriately adjusted. Examples of the repeating unit include a repeating unit represented by Formula (IV).

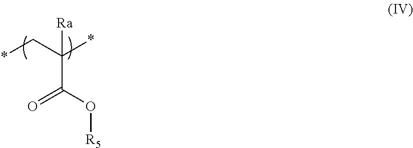

In Formula (IV), R₅ represents a hydrocarbon group having at least one cyclic structure and having no polar group.

Ra represents a hydrogen atom, an alkyl group or a —CH₂—O—Ra₂ group. In the formula, Ra₂ represents a hydrogen atom, an alkyl group or an acyl group. Ra is preferably a hydrogen atom, a methyl group, a hydroxymethyl group and a trifluoromethyl group, and particularly preferably a hydrogen atom and a methyl group.

The cyclic structure that R₅ has includes a monocyclic hydrocarbon group and a polycyclic hydrocarbon group. Examples of the monocyclic hydrocarbon group include a cycloalkyl group having 3 to 12 carbon atoms, such as a cyclopentyl group, a cyclohexyl group, a cycloheptyl group and a cyclooctyl group, and a cycloalkenyl group having 3 to 12 carbon atoms, such as a cyclohexenyl group. The monocyclic hydrocarbon group is preferably a monocyclic hydrocarbon group having 3 to 7 carbon atoms, and more preferably a cyclopentyl group or a cyclohexyl group.

The polycyclic hydrocarbon group includes a ring assembly hydrocarbon group and a crosslinked cyclic hydrocarbon group, and examples of the ring assembly hydrocarbon group include a bicyclohexyl group, a perhydronaphthalenyl group and the like. Examples of the crosslinked cyclic hydrocarbon ring include a bicyclic hydrocarbon ring such as a pinane ring, a bornane ring, a norpinane ring, a norbornane ring and a bicyclooctane ring (a bicyclo[2.2.2]octane ring, a bicyclo[3.2.1]octane ring and the like), a tricyclic hydrocarbon ring such as a homobledane ring, an adamantine ring, a tricyclo[5.2.1.0^{2,6}]decane ring and a tricyclo[4.3.1.1^{2,5}]undecane ring, a tetracyclic hydrocarbon ring such as tetracyclo[4.4.0.1^{2,5}0.1^{7,10}]dodecane ring and a perhydro-1,4-methano-5,8-methanonaphthalene ring, and the like. Further, the crosslinked cyclic hydrocarbon ring also includes a condensed cyclic hydrocarbon ring, for example, a condensed ring obtained by condensing a plurality of 5- to 8-membered cycloalkane rings, such as a perhydronaphthalene (decalin) ring, a perhydroanthracene ring, a perhydrophenanthrene ring, a perhydroacenaphthene ring, a perhydrofluorene ring, a perhydroindene ring and a perhydrophenalene ring.

Preferred examples of the crosslinked cyclic hydrocarbon ring include a norbornyl group, an adamantyl group and a bicyclooctanyl group a tricyclo[5,2,1,0^{2,6}]decanyl group. More preferred examples of the crosslinked cyclic hydrocarbon ring include a norbornyl group and an adamantyl group.

The alicyclic hydrocarbon groups may have a substituent, and preferred examples of the substituent include a halogen atom, an alkyl group, a hydroxyl group with a hydrogen atom being substituted, an amino group with a hydrogen atom being substituted and the like. Preferred examples of the halogen atom include a bromine atom, a chlorine atom and a fluorine atom, and preferred examples of the alkyl group include a methyl group, an ethyl group, a butyl group or a t-butyl group. The above-described alkyl group may further have a substituent, and examples of the substituent which the alkyl group may further have include a halogen atom, an alkyl group, a hydroxyl group with a hydrogen atom being substituted, and an amino group with a hydrogen atom being substituted.

Examples of the substituent for hydrogen atom include an alkyl group, a cycloalkyl group, an aralkyl group, a substituted methyl group, a substituted ethyl group, an alkoxycarbonyl group and an aralkyloxycarbonyl group. Preferred examples of the alkyl group include an alkyl group having 1 to 4 carbon atoms, preferred examples of the substituted methyl group include a methoxymethyl group, a methoxythiomethyl group, a benzyloxymethyl group, a t-butoxymethyl group and a 2-methoxyethoxymethyl group, examples of the substituted ethyl group include a 1-ethoxy ethyl group and a 1-methyl-1-methoxyethyl group, preferred examples of the acyl group include an aliphatic acyl group having 1 to 6 carbon atoms, such as a formyl group, an acetyl group, a propionyl group, a butyryl group, an isobutyryl group and a valeryl group a pivaloyl group, and examples of the alkoxycarbonyl group includes an alkoxycarbonyl group having 1 to 4 carbon atoms and the like.

The resin (A) may or may not contain a repeating unit having a polar group-free alicyclic hydrocarbon structure and not exhibiting acid decomposability, but in the case of containing the repeating unit, the content ratio of the repeating unit is preferably 1 mol % to 40 mol %, and more preferably 1 mol % to 20 mol %, based on all the repeating units in the resin (A).

Specific examples of the repeating unit having a polar group-free alicyclic hydrocarbon structure and not exhibiting acid decomposability will be described below, but the present invention is not limited thereto. In the formulas, Ra represents H, CH₃, CH₂OH or CF₃.

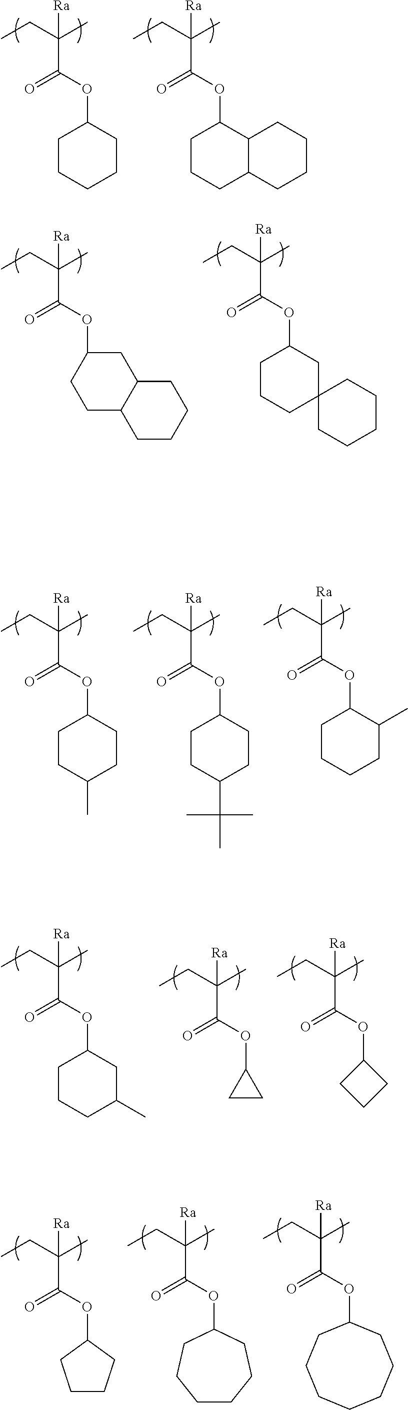

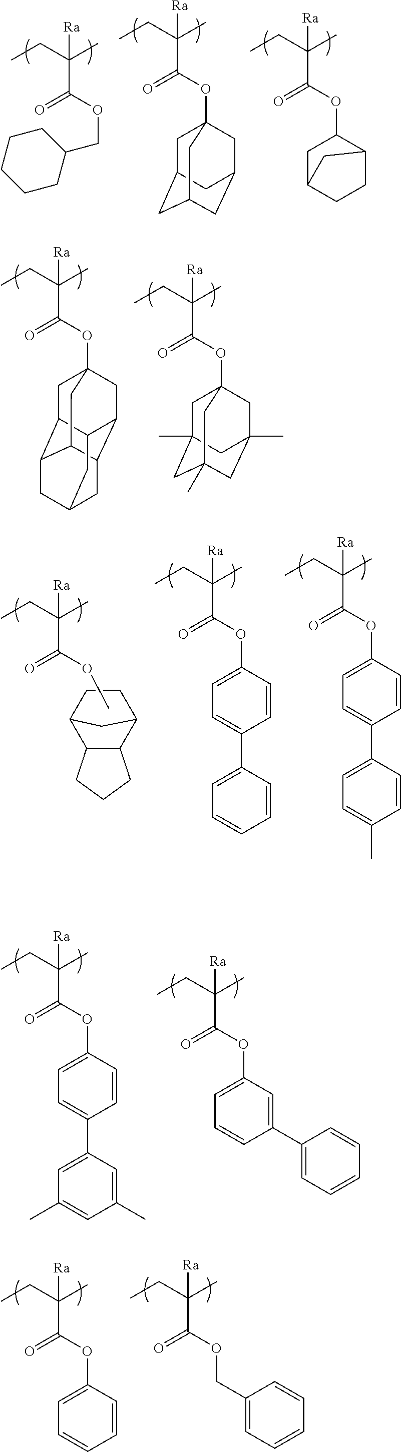

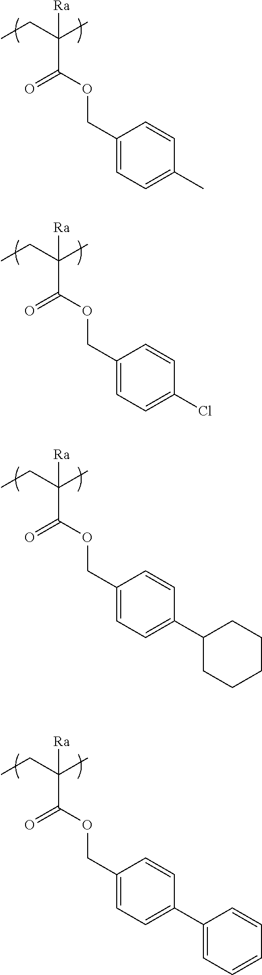

The resin (A) used in the composition of the present invention may have, in addition to the above-described repeating structural units, various repeating structural units for the purpose of controlling the dry etching resistance, suitability for a standard developer, adhesion to a substrate, and resist profile, and further resolution, heat resistance, sensitivity and the like, which are properties generally required for a resist.

Examples of the repeating structural units include repeating structural units corresponding to the monomers described below, but are not limited thereto.

Accordingly, it is possible to minutely adjust the performance required for the resin used in the composition of the present invention, particularly

(1) solubility in a coating solvent,

(2) film-forming property (glass transition temperature),

(3) alkali developability,

(4) film reduction (selection of a hydrophilic, hydrophobic or alkali-soluble group),

(5) adhesion of an unexposed portion to substrate,

(6) dry etching resistance,

and the like.

Examples of the monomer include a compound having one addition-polymerizable unsaturated bond selected from acrylic acid esters, methacrylic acid esters, acrylamides, methacrylamides, allyl compounds, vinyl ethers, vinyl esters and the like.

Other than these, an addition-polymerizable unsaturated compound that is copolymerizable with the monomers corresponding to the above-described various repeating structural units may be copolymerized.

In the resin (A) used in the composition of the present invention, the molar ratio of respective repeating structural units contained is appropriately set in order to control dry etching resistance of the resist, suitability for a standard developer, adhesion to a substrate and resist profile and further resolution, heat resistance, sensitivity and the like which are performances generally required for the resist.

The form of the resin (A) in the present invention may be any form of a random type, a block type, a comb type and a star type. The resin (A) may be synthesized, for example, by polymerization of radicals, cations, or anions of an unsaturated monomer, corresponding to each structure. In addition, it is possible to obtain a target resin by using an unsaturated monomer corresponding to a precursor of each structure to perform polymerization, and then performing a polymer reaction.

When the composition of the present invention is for ArF exposure, from the viewpoint of transparency to ArF light, the resin (A) used in the composition of the present invention preferably has substantially no aromatic ring (specifically, the ratio of a repeating unit having an aromatic group in the resin is preferably 5 mol % or less, more preferably 3 mol % or less, and ideally 0 mol %, that is, the resin does not have an aromatic group), and the resin (A) preferably has a monocyclic or polycyclic alicyclic hydrocarbon structure.

Further, a C Log P value of the resin (A) is not particularly limited, but is preferably 0 to 6, more preferably 1 to 5, and still more preferably 1 to 4, from the viewpoint of sufficiently expressing an effect by (D) a resin described below.

The absolute value of the difference between the C Log P value of the resin (A) and the C Log P value of the resin (D) is preferably larger than 0, more preferably 1 or more, and still more preferably 2 or more.

When the absolute value of the difference between the C Log P value of the resin (A) and the C Log P value of the resin (D) is large, at the time of the formation of a resist film, the resin (D) may be easily segregated on the surface of the resist film and the effects (uniformity of the film thickness and reduction in bridge defects and watermark defects) of the present invention may be increased.

Here, as for a method for calculating the C Log P value of the resin (A), please refer to a description on a calculation method in (D) a resin described below.

Further, from the viewpoint different from the point, when the composition of the present invention includes (E) a resin described below, the resin (A) preferably contains no fluorine atom and no silicon atom from the viewpoint of compatibility with the resin (E).

The resin (A) used in the composition of the present invention is preferably a resin in which all the repeating units consist of a (meth)acrylate-based repeating unit. In this case, all repeating units may be used as any of a methacrylate-based repeating unit, an acrylate-based repeating unit, or a methacrylate-based repeating unit and an acrylate-based repeating unit, but the acrylate-based repeating unit is present in an amount of preferably 50 mol % or less based on all the repeating units. In addition, a copolymerizable polymer including 20 mol % to 50 mol % of a (meth)acrylate-based repeating unit having an acid-decomposable group, 20 mol % to 50 mol % of a (meth)acrylate-based repeating unit having a lactone group, 5 mol % to 30 mol % of a (meth)acrylate-based repeating unit having an alicyclic hydrocarbon structure substituted with a hydroxyl group or a cyano group, and 0 mol % to 20 mol % of other (meth)acrylate-based repeating units is also preferred.

When KrF excimer laser light, electron beam, X-ray or high-energy beam having a wavelength of 50 nm or less (EUV and the like) is irradiated on the composition of the present invention, the resin (A) preferably further has a hydroxystyrene-based repeating unit. The resin (A) has more preferably a hydroxystyrene-based repeating unit and an acid-decomposable repeating unit such as a hydroxystyrene-based repeating unit protected by an acid-decomposable group, (meth)acrylic acid tertiary alkyl ester and the like.

Preferred examples of the hydroxystyrene-based repeating unit having an acid-decomposable group include repeating units consisting of t-butoxycarbonyloxystyrene, 1-alkoxyethoxystyrene, (meth)acrylic acid tertiary alkyl ester and the like, and repeating units consisting of 2-alkyl-2-adamantyl(meth)acrylate and dialkyl(1-adamantyl)methyl (meth)acrylate are more preferred.

The resin (A) of the present invention may be synthesized by a typical method (for example, radical polymerization). Examples of a general synthesis method include a batch polymerization method of dissolving monomer species and an initiator in a solvent and heating the solution to perform the polymerization, a dropping polymerization method of adding dropwise a solution containing monomer species and an initiator to a heated solvent over 1 to 10 hours, and the like, and a dropping polymerization method is preferred. Examples of a reaction solvent include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and a solvent capable of dissolving the composition of the present invention described below, such as propylene glycol monomethyl ether acetate, propylene glycol monomethyl ether and cyclohexanone. The polymerization is more preferably performed by using the same solvent as the solvent used in the photosensitive composition of the present invention. Accordingly, generation of particles during storage may be suppressed.

The polymerization reaction is preferably performed under an inert gas atmosphere such as nitrogen or argon. As for the polymerization initiator, the polymerization is initiated by using a commercially available radical initiator (azo-based initiator, peroxide and the like). The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile, dimethyl 2,2′-azobis(2-methylpropionate) and the like. The initiator is added additionally or in parts, if desired, and after the completion of reaction, the reaction product is poured in a solvent, and a desired polymer is recovered by a powder or solid recovery method, or the like. The reaction concentration is 5% by mass to 50% by mass, and preferably 10% by mass to 30% by mass.

The reaction temperature is usually 10° C. to 150° C., preferably 30° C. to 120° C., and more preferably 60° C. to 100° C.

After the completion of reaction, the reaction solution is allowed to cool to room temperature and purified. The purification may be performed by a typical method, such as a liquid-liquid extraction method of applying water-washing or combining water-washing with an appropriate solvent to remove residual monomers or oligomer components, a purification method in a solution state, such as ultrafiltration of removing only polymers having a molecular weight not more than a specific molecular weight by virtue of extraction, a reprecipitation method of adding dropwise a resin solution in a poor solvent to solidify the resin in the poor solvent thereby removing residual monomers and the like, a purification method in a solid state, such as washing of the resin slurry separated by filtration with a poor solvent, and the like. For example, the resin is precipitated as a solid by contacting the reaction solution with a solvent (poor solvent) in which the resin is sparingly soluble or insoluble, in a volumetric amount of 10 times or less and preferably 10 to 5 times the reaction solution.

The solvent used at the time of operation of precipitation or reprecipitation from the polymer solution (precipitation or reprecipitation solvent) may be sufficient if the solvent is a poor solvent for the polymer, and the solvent may be appropriately selected from a hydrocarbon, a halogenated hydrocarbon, a nitro compound, ether, ketone, ester, carbonate, alcohol, carboxylic acid, water, and a mixed solvent including these solvents, according to the kind of the polymer, and may be used. Among these solvents, a solvent including at least alcohol (particularly, methanol or the like) or water is preferred as the precipitation or reprecipitation solvent.

The amount of the precipitation or reprecipitation solvent used may be appropriately selected by considering the efficiency, yield and the like, but in general, the amount is 100 parts by mass to 10,000 parts by mass, preferably 200 by parts by mass to 2,000 parts by mass, and more preferably 300 parts by mass to 1,000 parts by mass, based on 100 parts by mass of the polymer solution.

The temperature at the time of precipitation or reprecipitation may be appropriately selected by considering the efficiency or operability but is usually in the order from 0 to 50° C., and preferably in the vicinity of room temperature (for example, approximately from 20° C. to 35° C.). The precipitation or reprecipitation operation may be performed by a known method such as batch system and continuous system using a commonly employed mixing vessel such as a stirring tank.

The precipitated or reprecipitated polymer is usually subjected to commonly employed solid-liquid separation such as filtration and centrifugation, then dried and used. The filtration is performed by using a solvent-resistant filter element, and preferably under pressure. The drying is performed under atmospheric pressure or reduced pressure (preferably under reduced pressure) at a temperature of approximately from 30° C. to 100° C., and preferably at a temperature of approximately from 30° C. to 50° C.

Further, after the resin is once precipitated and separated, the resin may be dissolved in a solvent again and then brought into contact with a solvent in which the resin is sparingly soluble or insoluble. That is, there may be used a method including, after the completion of radical polymerization reaction, bringing the polymer into contact with a solvent in which the polymer is sparingly soluble or insoluble, to precipitate a resin (step a), separating the resin from the solution (step b), dissolving the resin in a solvent to prepare a resin solution A (step c), and then bringing the resin solution A into contact with a solvent in which the resin is sparingly soluble or insoluble and which is in a volumetric amount of less than 10 times (volumetric amount of preferably 5 times or less) the resin solution A, to precipitate a resin solid (step d), and separating the precipitated resin (step e).

Further, for suppressing the resin after preparation of the composition from aggregation or the like, as described, for example, in Japanese Patent Application Laid-Open No. 2009-037108, a step of dissolving the synthesized resin in a solvent to prepare a solution, and heating the solution at approximately from 30° C. to 90° C. for approximately from 30 minutes to 4 hours may be added.

The weight average molecular weight of the resin (A) used in the composition of the present invention is preferably 1,000 to 200,000, more preferably 2,000 to 100,000, still more preferably 3,000 to 70,000, and particularly preferably 5,000 to 50,000, in terms of polystyrene by the GPC method. By setting the weight average molecular weight within 1,000 to 200,000, it is possible to prevent deterioration in the heat resistance or dry etching resistance may be prevented and prevent the film-forming property from deteriorating due to impaired developability or increased viscosity.

The polydispersity (molecular weight distribution) is usually in a range of 1.0 to 3.0. The polydispersity is preferably is in a range of 1.0 to 2.6, more preferably in a range of 1.1 to 2.5, still more preferably in a range of 1.4 to 2.4, particularly preferably in a range of 1.3 to 2.2, and particularly preferably in a range of 1.4 to 2.0. When the molecular weight distribution satisfies the range, the resolution and resist shape are excellent, the side wall of the resist pattern is smoother, and roughness is excellent.

In the actinic ray-sensitive or radiation-sensitive resin composition of the present invention, the blending ratio of the resin (A) in the entire composition is preferably 30% by mass to 99% by mass, and more preferably 60% by mass to 95% by mass, based on the total solid content of the composition of the resin (A).

Further, the resin (A) of the present invention may be used either alone or in combination of a plurality thereof.

[2] (B) Compound Capable of Generating Acid Upon Irradiation with an Actinic Ray or Radiation

The composition in the present invention contains (B) a compound capable of generating an acid upon irradiation with an actinic ray or radiation (hereinafter also referred to as an “acid generator”). The compound (B) capable of generating an acid upon irradiation with an actinic ray or radiation is preferably a compound capable of generating an organic acid upon irradiation with an actinic ray or radiation.

The acid generator may be appropriately selected from a photo-initiator for cationic photopolymerization, a photo-initiator for radical photopolymerization, a photodecoloring agent for dyes, a photodiscoloring agent, a known compound capable of generating an acid upon irradiation with an actinic ray or radiation, which is used for microresist or the like, and a mixture thereof, and be used.

Examples thereof include a diazonium salt, a phosphonium salt, a sulfonium salt, an iodonium salt, imidosulfonate, oxime sulfonate, diazodisulfone, disulfone and o-nitrobenzyl sulfonate.

Among the acid generators, preferred compounds include compounds represented by the following Formulas (ZI), (ZII) and (ZIII).

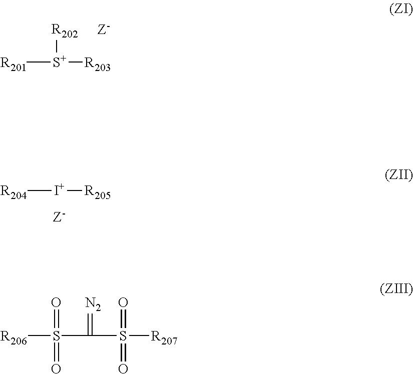

In Formula (ZI),

each of R₂₀₁, R₂₀₂ and R₂₀₃ independently represents an organic group.

The carbon number of the organic group as R₂₀₁, R₂₀₂ and R₂₀₃ is generally 1 to 30, and preferably 1 to 20.

In addition, two of R₂₀₁ to R₂₀₃ may be bonded to each other to form a ring structure, and the ring may include an oxygen atom, a sulfur atom, an ester bond, an amide bond or a carbonyl group therein. Examples of the group formed by combining two of R₂₀₁ to R₂₀₃ include an alkylene group (for example, a butylene group and a pentylene group).

Z⁻ represents a non-nucleophilic anion.

Examples of the non-nucleophilic anion as Z⁻ include sulfonate anion, carboxylate anion, sulfonylimide anion, bis(alkylsulfonyl)imide anion, tris(alkylsulfonyl)methyl anion and the like.

The non-nucleophilic anion is an anion having an extremely low ability of causing a nucleophilic reaction and capable of suppressing the decomposition with time due to intramolecular nucleophilic reaction. Accordingly, the stability of the actinic ray-sensitive or radiation-sensitive resin composition with time is improved.

Examples of the sulfonate anion include an aliphatic sulfonate anion, an aromatic sulfonate anion, a camphorsulfonate anion and the like.

Examples of the carboxylate anion include an aliphatic carboxylate anion, an aromatic carboxylate anion, an aralkylcarboxylate anion and the like.

The aliphatic moiety in the aliphatic sulfonate anion and the aliphatic carboxylate anion may be an alkyl group or a cycloalkyl group and is preferably an alkyl group having 1 to 30 carbon atoms and a cycloalkyl group having 3 to 30 carbon atoms, and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group and the like.

The aromatic group in the aromatic sulfonate anion and the aromatic carboxylate anion is preferably an aryl group having 6 to 14 carbon atoms, and examples thereof include a phenyl group, a tolyl group, a naphthyl group and the like.

The alkyl group, the cycloalkyl group and the aryl group in the aliphatic sulfonate anion and the aromatic sulfonate anion may have a substituent. Examples of the substituent of the alkyl group, the cycloalkyl group and the aryl group in the aliphatic sulfonate anion and the aromatic sulfonate anion include a nitro group, a halogen atom (a fluorine atom, a chlorine atom, a bromine atom and an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) and the like. The aryl group and ring structure that each group has may further have, as the substituent, an alkyl group (preferably having 1 to 15 carbon atoms) or a cycloalkyl group (preferably having 3 to 15 carbon atoms).

The aralkyl group in the aralkylcarboxylate anion is preferably an aralkyl group having 7 to 12 carbon atoms, and examples thereof include a benzyl group, a phenethyl group, a naphthylmethyl group, a naphthylethyl group, a naphthylbutyl group and the like.

The alkyl group, the cycloalkyl group, the aryl group and the aralkyl group in the aliphatic carboxylate anion, the aromatic carboxylate anion and the aralkylcarboxylate anion may have a substituent. Examples of the substituent include the same halogen atom, alkyl group, cycloalkyl group, alkoxy group, alkylthio group and the like as those in the aromatic sulfonate anion.

Examples of the sulfonylimide anion include saccharin anion.

The alkyl group in the bis(alkylsulfonyl)imide anion and the tris(alkylsulfonyl)methide anion is preferably an alkyl group having 1 to 5 carbon atoms, and examples thereof include a methyl group, an ethyl group, a propyl group, an isopropyl group, an n-butyl group, an isobutyl group, a sec-butyl group, a pentyl group, a neopentyl group and the like. Examples of the substituent of the alkyl group include a halogen atom, an alkyl group substituted with a halogen atom, an alkoxy group, an alkylthio group, an alkyloxysulfonyl group, an aryloxysulfonyl group, a cycloalkylaryloxysulfonyl group and the like, and an alkyl group substituted with a fluorine atom is preferred.

Examples of other non-nucleophilic anions include fluorinated phosphate (for example, PF₆⁻), fluorinated boron (for example, BF₄⁻), fluorinated antimony (for example, SbF₆⁻) and the like.

The non-nucleophilic anion of Z⁻ is preferably an aliphatic sulfonate anion in which an α-position of sulfonic acid is substituted with a fluorine atom, an aromatic sulfonate anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having 4 to 8 carbon atoms and a benzenesulfonate anion having a fluorine atom, and more preferably a nonafluorobutanesulfonate anion, a perfluorooctanesulfonate anion, a pentafluorobenzenesulfonate anion and a 3,5-bis(trifluoromethyl)benzenesulfonate anion.

The acid generator is preferably a compound capable of generating an acid represented by the following Formula (III) or (IV) upon irradiation with an actinic ray or radiation. By the compound capable of generating an acid represented by the following Formula (III) or (IV), the compound has a cyclic organic group, and thus the resolution and roughness performance may be excellent.

The non-nucleophilic anion may be an anion capable of producing an organic acid represented by the following Formula (III) or (IV).

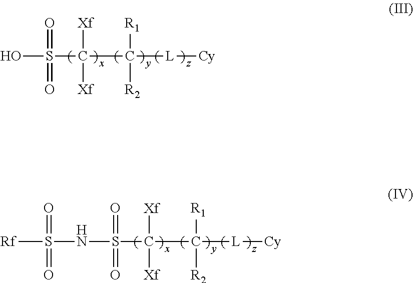

In the formula,

each Xf independently represents a fluorine atom or an alkyl group substituted with at least one fluorine atom.

Each of R₁ and R₂ independently represents a hydrogen atom, a fluorine atom or an alkyl group.

Each L independently represents a divalent linking group.

Cy represents a cyclic organic group.

Rf is a group including a fluorine atom.

x represents an integer of 1 to 20.

y represents an integer of 0 to 10.

z represents an integer of 0 to 10.

Xf represents a fluorine atom or an alkyl group substituted with at least one fluorine atom. The carbon number of the alkyl group is preferably 1 to 10, and more preferably 1 to 4. In addition, the alkyl group substituted with at least one fluorine atom is preferably a perfluoroalkyl group.

Xf is preferably a fluorine atom or a perfluoroalkyl group having 1 to 4 carbon atoms. More specifically, Xf is preferably a fluorine atom, CF₃, C₂F₅, C₃F₇, C₄F₉, C₅F₁₁, C₆F₁₃, C₇F₁₅, C₃F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉, and more preferably a fluorine atom or CF₃. In particular, it is preferred that both Xf's are a fluorine atom.

Each of R₁ and R₂ independently represents a hydrogen atom, a fluorine atom or an alkyl group. The alkyl group may have a substituent (preferably fluorine atom) and preferably has from 1 to 4 carbon atoms. The alkyl group is more preferably a perfluoroalkyl group having 1 to 4 carbon atoms. Specific examples of the alkyl group having a substituent of R₁ and R₂ include CF₃, C₂F₅, C₃F₇, C₄F₉, C₅F₁₁, C₆F₁₃, C₇F₁₅, C₃F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, and among them, CF₃ is preferred.

L represents a divalent linking group. Examples of the divalent linking group include —COO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), a divalent linking group formed by combining a plurality of these members, and the like. Among them, —COO—, —CONH—, —NHCO—, —CO—, —O—, —SO₂—, —COO-an alkylene group-, —OCO-an alkylene group-, —CONH-an alkylene group- or —NHCO-an alkylene group- is preferred, and alkylene group- or —OCO-an alkylene group- is more preferred.

Cy represents a cyclic organic group. Examples of the cyclic organic group include an alicyclic group, an aryl group and a heterocyclic group.

The alicyclic group may be monocyclic or polycyclic. Examples of the monocyclic alicyclic group include a monocyclic cycloalkyl group such as a cyclopentyl group, a cylohexyl group and a cyclooctyl group. Examples of the polycyclic alicyclic group include a polycyclic cycloalkyl group such as a norbornyl group, a tricyclodecanyl group, a tetracyclodecanyl group, a tetracyclododecanyl group, an adamantyl group, and a group having a steroid skeleton. Among them, an alicyclic group having a bulky structure with 7 or more carbon atoms, such as a norbornyl group, a tricyclodecanyl group, a tetracyclodecanyl group, a tetracyclododecanyl group, an adamantyl group, and a steroid skeleton, is preferred from the viewpoint of restraining diffusion in film during a PEB (post-exposure baking) step and improving the MEEF (mask error enhancement factor).

The steroid skeleton typically includes a structure where a substituent such as carbonyl group and hydroxy group is arbitrarily substituted on the carbon skeleton shown below, and examples of the anion capable of producing an organic acid represented by formula (III) or (IV), where Cy represents a group having a steroid skeleton, upon irradiation with an actinic ray or radiation include anion structures contained in four compounds exemplified in paragraph [0036] of U.S. Patent Application Publication 2011/0250537A1.

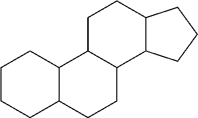 [SMILES: C1CCC2C(C1)CCC1C3CCCC3CCC21]

The aryl group may be monocyclic or polycyclic. Examples of the aryl group include a phenyl group, a naphthyl group, a phenanthryl group and an anthryl group. Among them, a naphthyl group having relatively low light absorbance at 193 nm is preferred.

The heterocyclic group may be monocyclic or polycyclic, but a polycyclic heterocyclic group may suppress the diffusion of an acid more efficiently. Further, the heterocyclic group may have aromaticity or may not have aromaticity. Examples of the heterocyclic ring having aromaticity include a furan ring, a thiophene ring, a benzofuran ring, a benzothiophene ring, a dibenzofuran ring, a dibenzothiophene ring and a pyridine ring. Examples of the heterocyclic ring having no aromaticity include a tetrahydropyran ring, a lactone ring, a sultone ring and a decahydroisoquinoline ring. The heterocyclic ring in the heterocyclic group is particularly preferably a furan ring, a thiophene ring, a pyridine ring or a decahydroisoquinoline ring. In addition, examples of the lactone ring and the sultone ring include a lactone structure and a sultone structure exemplified in the above-described resin (A).

The cyclic organic group may have a substituent. Examples of the substituent include an alkyl group (may be straight chained or branched, and preferably having 1 to 12 carbon atoms), a cycloalkyl group (may be monocyclic, polycyclic or spirocyclic, and preferably 3 to 20 carbon atoms), an aryl group (preferably having 6 to 14 carbon atoms), a hydroxyl group, an alkoxy group, an ester group, an amide group, a urethane group, a ureido group, a thioether group, a sulfonamide group and a sulfonic acid ester group. Further, the carbon constituting the cyclic organic group (the carbon contributing to ring formation) may be carbonyl carbon.

x is preferably 1 to 8, and among them, more preferably 1 to 4, and particularly preferably 1. y is preferably 0 to 4, and more preferably 0. z is preferably 0 to 8, and among them, preferably 0 to 4.

Examples of the group having a fluorine atom represented by Rf include an alkyl group having at least one fluorine atom, a cycloalkyl group having at least one fluorine atom, and an aryl group having at least one fluorine atom.

The alkyl group, the cycloalkyl group and the aryl group may be substituted with a fluorine atom, or may be substituted with another substituent including a fluorine atom. When Rf is a cycloalkyl group having at least one fluorine atom or an aryl group having at least one fluorine atom, examples of the another substituent including a fluorine atom include an alkyl group substituted with at least one fluorine atom.

Further, the alkyl group, the cycloalkyl group and the aryl group may also be substituted with a substituent including no fluorine atom. Examples of the substituent include those including no fluorine atom among those for Cy described above.

Examples of the alkyl group having at least one fluorine atom represented by Rf include the same as those described above as the alkyl group substituted with at least one fluorine atom represented by Xf. Examples of the cycloalkyl group having at least one fluorine atom represented by Rf include a perfluorocyclopentyl group and a perfluorocyclohexyl group. Examples of the aryl group having at least one fluorine atom represented by Rf include a perfluorophenyl group.

As the non-nucleophilic anion, a sulfonate anion represented by the following formula (B-1) is also preferred.

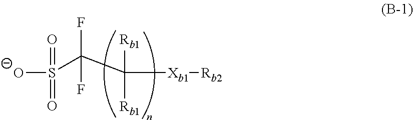

In formula (B-1), each R_{b1} independently represents a hydrogen atom, a fluorine atom or a trifluoromethyl group (CF₃).

n represents an integer of 0 to 4.

n is preferably an integer of 0 to 3, more preferably 0 or 1.

X_{b1} represents a single bond, an alkylene group, an ether bond, an ester bond (—OCO— or —COO—), a sulfonic acid ester bond (—OSO₂— or —SO₃—) or a combination thereof.

X_{b1} is preferably an ester bond (—OCO— or —COO—) or a sulfonic acid ester bond (—OSO₂— or —SO₃—), more preferably an ester bond (—OCO— or —COO—).

R_{b2} represents an organic group having a carbon number of 6 or more.

The organic group having a carbon number of 6 or more for R_{b2} is preferably a bulky group, and examples thereof include an alkyl group, an alicyclic group, an aryl group, and a heterocyclic group each having a carbon number of 6 or more.

The alkyl group having a carbon number of 6 or more for R_{b2} may be linear or branched and is preferably a linear or branched alkyl group having a carbon number of 6 to 20, and examples thereof include a linear or branched hexyl group, a linear or branched heptyl group, and a linear or branched octyl group. In view of bulkiness, a branched alkyl group is preferred.

The alicyclic group having a carbon number of 6 or more for R_{b2} may be monocyclic or polycyclic. The monocyclic alicyclic group includes, for example, a monocyclic cycloalkyl group such as cyclohexyl group and cyclooctyl group. The polycyclic alicyclic group includes, for example, a polycyclic cycloalkyl group such as norbornyl group, tricyclodecanyl group, tetracyclodecanyl group, tetracyclododecanyl group and adamantyl group. Above all, an alicyclic group having a bulky structure with a carbon number of 7 or more, such as norbornyl group, tricyclodecanyl group, tetracyclodecanyl group, tetracyclododecanyl group and adamantyl group, is preferred from the standpoint of suppressing diffusion in film during a PEB (post-exposure baking) step and improving MEEF (Mask Error Enhancement Factor).

The aryl group having a carbon number of 6 or more for R_{b2} may be monocyclic or polycyclic. Examples of this aryl group include a phenyl group, a naphthyl group, a phenanthryl group, and an anthryl group. Among these, a naphthyl group having a relatively low light absorbance at 193 nm is preferred.

The heterocyclic group having a carbon number of 6 or more for R_{b2} may be monocyclic or polycyclic, but with a polycyclic heterocyclic group, diffusion of an acid can be more suppressed. The heterocyclic group may have aromaticity or may not have aromaticity. Examples of the heterocyclic ring having aromaticity include a benzofuran ring, a benzothiophene ring, a dibenzofuran ring, and a dibenzothiophene ring. Examples of the heterocyclic ring not having aromaticity include a tetrahydropyran ring, a lactone ring, a sultone ring, and a decahydroisoquinoline ring.

The above-described substituent having a carbon number of 6 or more for R_{b2} may further have a substituent. Examples of the further substituent include an alkyl group (may be linear or branched, preferably having a carbon number of 1 to 12), a cycloalkyl group (may be monocyclic, polycyclic or spirocyclic, preferably having a carbon number of 3 to 20), an aryl group (preferably having a carbon number of 6 to 14), a hydroxy group, an alkoxy group, an ester group, an amido group, a urethane group, a ureido group, a thioether group, a sulfonamido group, and a sulfonic acid ester group. Incidentally, the carbon constituting the alicyclic group, aryl group or heterocyclic group (the carbon contributing to ring formation) may be a carbonyl carbon.

Specific examples of the sulfonate anion structure represented by formula (B-1) are illustrated below, but the present invention is not limited thereto.

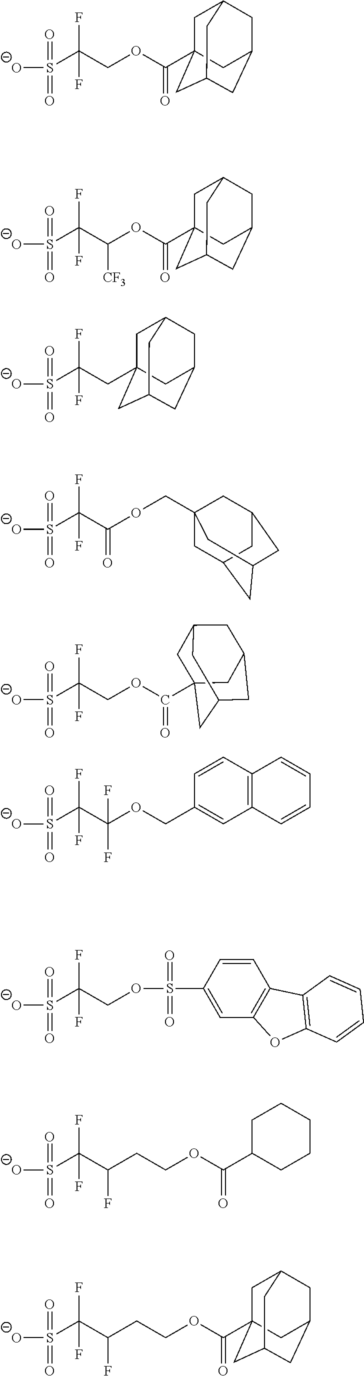

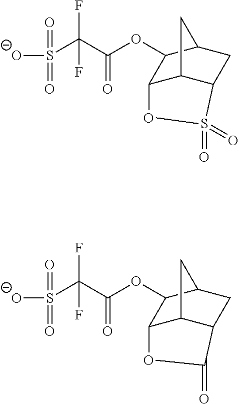 [SMILES: O=C(OC1C2CC3C1OS(=O)(=O)C3C2)C(F)(F)S(=O)(=O)[O-] ; O=C1OC2C3CC(CC13)C2OC(=O)C(F)(F)S(=O)(=O)[O-]]

Examples of the organic group represented by R₂₀₁, R₂₀₂ and R₂₀₃ include corresponding groups in the compounds (ZI-1), (ZI-2), (ZI-3) and (ZI-4) described below.

Further, a compound having a plurality of structures represented by Formula (ZI) may be used. For example, it is possible to use a compound having a structure in which at least one of R₂₀₁ to R₂₀₃ in a compound represented by Formula (ZI) is bonded to at least one of R₂₀₁ to R₂₀₃ in another compound represented by Formula (ZI) through a single bond or a linking group.

Examples of a more preferred (ZI) component include compounds (ZI-1), (ZI-2), (ZI-3) and (ZI-4) described below.

The compound (ZI-1) is an arylsulfonium compound in which at least one of R₂₀₁ to R₂₀₃ in Formula (ZI) is an aryl group, that is, a compound having arylsulfonium as a cation.

In the arylsulfonium compound, all of R₂₀₁ to R₂₀₃ may be an aryl group or a part of R₂₀₁ to R₂₀₃ may be an aryl group, with the remaining being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound and an aryldicycloalkylsulfonium compound.

The aryl group in the arylsulfonium compound is preferably a phenyl group and a naphthyl group, and more preferably a phenyl group. The aryl group may be an aryl group having a heterocyclic structure having an oxygen atom, a nitrogen atom, a sulfur atom or the like. Examples of the heterocyclic structure include a pyrrole residue, a furan residue, a thiophene residue, an indole residue, a benzofuran residue, a benzothiophene residue and the like. When the arylsulfonium compound has two or more aryl groups, each aryl group may be the same as or different from each other aryl group.

The alkyl group or the cycloalkyl group, which the arylsulfonium compound has, if necessary, is preferably a straight chained or branched alkyl group having 1 to 15 carbon atoms and a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, a cyclohexyl group and the like.

The aryl group, the alkyl group and the cycloalkyl group of R₂₀₁ to R₂₀₃ may have, as a substituent, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group or a phenylthio group. The substituent is preferably a straight chained or branched alkyl group having 1 to 12 carbon atoms, a cycloalkyl group having 3 to 12 carbon atoms, and a straight chained, branched or cyclic alkoxy group having 1 to 12 carbon atoms, and more preferably an alkyl group having 1 to 4 carbon atoms and an alkoxy group having 1 to 4 carbon atoms. The substituent may be substituted with any one of three R₂₀₁ to R₂₀₃ or may be substituted with all of the three. Further, when R₂₀₁ to R₂₀₃ are an aryl group, the substituent is preferably substituted at the p-position of the aryl group.

Next, the compound (ZI-2) will be described below.

The compound (ZI-2) is a compound in which each of R₂₀₁ to R₂₀₃ in Formula (ZI) independently represents an organic group having no aromatic ring. Here, the aromatic ring also includes an aromatic ring containing a heteroatom.

The organic group containing no aromatic ring as R₂₀₁ to R₂₀₃ has generally 1 to 30 carbon atoms, and preferably 1 to 20 carbon atoms.

Each of R₂₀₁ to R₂₀₃ independently represents preferably an alkyl group, a cycloalkyl group, an allyl group or a vinyl group, more preferably a straight chained or branched 2-oxoalkyl group, a 2-oxocycloalkyl group and an alkoxycarbonylmethyl group, and particularly preferably a straight chained or branched 2-oxoalkyl group.

The alkyl group and the cycloalkyl group of R₂₀₁ to R₂₀₃ are preferably a straight chained or branched alkyl group having 1 to 10 carbon atoms (for example, a methyl group, an ethyl group, a propyl group, a butyl group and a pentyl group) and a cycloalkyl group having 3 to 10 carbon atoms (a cyclopentyl group, a cyclohexyl group and a norbornyl group). The alkyl group is more preferably a 2-oxoalkyl group and an alkoxycarbonylmethyl group. The cycloalkyl group is more preferably a 2-oxocycloalkyl group.

The 2-oxoalkyl group may be either straight chained or branched and is preferably a group having >C═O at the 2-position of the above-described alkyl group.

The 2-oxocycloalkyl group is preferably a group having >C═O at the 2-position of the above-described cycloalkyl group.

The alkoxy group in the alkoxycarbonylmethyl group is preferably an alkoxy group having 1 to 5 carbon atoms (a methoxy group, an ethoxy group, a propoxy group, a butoxy group and a pentoxy group).

R₂₀₁ to R₂₀₃ may be further substituted with a halogen atom, an alkoxy group (for example, having 1 to 5 carbon atoms), a hydroxyl group, a cyano group or a nitro group.

Next, the compound (ZI-3) will be described.

The compound (ZI-3) is a compound represented by the following Formula (ZI-3), and a compound having a phenacylsulfonium salt structure.

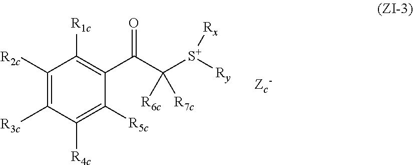

In Formula (ZI-3),

each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Each of R_{6c} and R_{7c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more of R_{1c} to R_{5c}, R_{5c} and R_{6c}, R_{6c} and R_{7c}, R_{5c} and Rₓ, and Rₓ and R_{y} may be bonded to each other to form a ring structure, and the ring structure may include an oxygen atom, a sulfur atom, a ketone group, an ester bond or an amide bond.

Examples of the ring structure includes an aromatic or non-aromatic hydrocarbon ring, an aromatic or non-aromatic heterocyclic ring, and a polycyclic condensed ring formed by combining two or more of these rings. The ring structure includes a 3- to 10-membered ring and is preferably a 4- to 8-membered ring, and more preferably a 5- or 6-membered ring.

Examples of the group formed by combining any two or more of R_{1c} to R_{5c}, R_{6c} and R_{7c}, and Rₓ and R_{y} include a butylene group, a pentylene group and the like.

The group formed by combining R_{5c} and R_{6c} and R_{5c} and Rₓ is preferably a single bond or an alkylene group, and examples of the alkylene group include a methylene group, an ethylene group and the like.

Zc⁻ represents a non-nucleophilic anion, and examples thereof include the same as those of the non-nucleophilic anion as Z⁻ in Formula (ZI).

The alkyl group as R_{1c} to R_{7c} may be either straight chained or branched and examples thereof include an alkyl group having 1 to 20 carbon atoms, and preferably a straight chained or branched alkyl group having 1 to 12 carbon atoms (for example, a methyl group, an ethyl group, a straight chained or branched propyl group, a straight chained or branched butyl group, and a straight chained or branched pentyl group), and examples of the cycloalkyl group include a cycloalkyl group having 3 to 10 carbon atoms (for example, a cyclopentyl group and a cyclohexyl group).

The aryl group as R_{1c} to R_{5c} preferably has from 5 to 15 carbon atoms, and examples thereof include a phenyl group and a naphthyl group.

The alkoxy group as R_{1c} to R_{5c} may be straight chained, branched or cyclic and examples thereof include an alkoxy group having 1 to 10 carbon atoms, preferably a straight chained or branched alkoxy group having 1 to 5 carbon atoms (for example, a methoxy group, an ethoxy group, a straight chained or branched propoxy group, a straight chained or branched butoxy group, and a straight chained or branched pentoxy group), and a cyclic alkoxy group having 3 to 10 carbon atoms (for example, a cyclopentyloxy group and a cyclohexyloxy group).

Specific examples of the alkoxy group in the alkoxycarbonyl group as R_{1c} to R_{5c} are the same as the specific examples of the alkoxy group as R_{1c} to R_{5c}.

Specific examples of the alkyl group in the alkylcarbonyloxy group and the alkylthio group as R_{1c} to R_{5c} are the same as the specific examples of the alkyl group as R_{1c} to R_{5c}.

Specific examples of the cycloalkyl group in the cycloalkylcarbonyloxy group as R_{1c} to R_{5c} are the same as the specific examples of the cycloalkyl group as R_{1c} to R_{5c}.

Specific examples of the aryl group in the aryloxy group and the arylthio group as R_{1c} to R_{5c} are the same as the specific examples of the aryl group as R_{1c} to R_{5c}.

Any one of R_{1c} to R_{5c} is preferably a straight chained or branched alkyl group, a cycloalkyl group, or a straight chained, branched or cyclic alkoxy group, and the sum of carbon numbers of R_{1c} to R_{5c} is more preferably 2 to 15 is more preferred. Accordingly, the solvent solubility is further improved, and thus, generation of particles during storage is suppressed.

Examples of the ring structure which may be formed by combining any two or more of R_{1c} to R_{5c} with each other include preferably a 5- or 6-membered ring, and more preferably a 6-membered ring (for example, a phenyl ring).

Examples of the ring structure which may be formed by combining R_{5c} and R_{6c} with each other include a 4-membered or greater membered ring (particularly preferably a 5- or 6-membered ring) formed together with the carbonyl carbon atom and the carbon atom in Formula (I) by combining R_{5c} and R_{6c} with each other to constitute a single bond or an alkylene group (such as a methylene group or an ethylene group).

The aryl group as R_{6c} to R_{7c} preferably has from 5 to 15 carbon atoms, and examples thereof include a phenyl group and a naphthyl group.

An aspect in which both R_{6c} and R_{7c} are an alkyl group is preferred. In particular, an aspect in which each of R_{6c} and R_{7c} is a straight chained or branched alkyl group having 1 to 4 carbon atoms is preferred, and an aspect in which both are a methyl group is particularly preferred.

Further, when R_{6c} and R_{7c} are combined with each other to form a ring, the group formed by combining R_{6c} and R_{7c} is preferably an alkylene group having 2 to 10 carbon atoms, and examples thereof include an ethylene group, a propylene group, a butylene group, a pentylene group, a hexylene group and the like. In addition, the ring formed by combining R_{6c} and R_{7c} may have a heteroatom such as an oxygen atom in the ring.

Examples of the alkyl group and the cycloalkyl group as Rₓ and R_{y} are the same as those of the alkyl group and the cycloalkyl group in R_{1c} to R_{7c}.

Examples of the 2-oxoalkyl group and the 2-oxocycloalkyl group as Rₓ and R_{y} include a group having >C═O at the 2-position of the alkyl group and the cycloalkyl group as R_{1c} to R_{7c}.

Examples of the alkoxy group in the alkoxycarbonylalkyl group as Rₓ and R_{y} are the same as those of the alkoxy group in R_{1c} to R_{5c}, and examples of the alkyl group include an alkyl group having 1 to 12 carbon atoms, and preferably a straight chained alkyl group having 1 to 5 carbon atoms (for example, a methyl group and an ethyl group).

The allyl group as Rₓ and R_{y} is not particularly limited, but is preferably an unsubstituted allyl group, or an allyl group substituted with a monocyclic or polycyclic cycloalkyl group (preferably a cycloalkyl group having 3 to 10 carbon atoms).

The vinyl group as Rₓ and R_{y} is not particularly limited, but is preferably an unsubstituted vinyl group, or a vinyl group substituted with a monocyclic or polycyclic cycloalkyl group (preferably a cycloalkyl group having 3 to 10 carbon atoms).

Examples of the ring structure which may be formed by combining R_{5c} and Rₓ with each other include a 5-membered or greater membered ring (particularly preferably a 5-membered ring) formed together with a sulfur atom and a carbonyl carbon atom in Formula (I) by combining R_{5c} and Rₓ with each other to constitute a single bond or an alkylene group (a methylene group, an ethylene group or the like).

Examples of the ring structure which may be formed by combining Rₓ and R_{y} with each other include a 5- or 6-membered ring, particularly preferably a 5-membered ring (that is, a tetrahydrothiophene ring), formed together with a sulfur atom in Formula (ZI-3) by divalent Rₓ and R_{y} (for example, a methylene group, an ethylene group, a propylene group and the like).

Each of Rₓ and R_{y} is preferably an alkyl group or a cycloalkyl group having 4 or more carbon atoms, more preferably 6 or more carbon atoms, and still more preferably 8 or more carbon atoms.

Each of R_{1c} to R_{7c} and Rₓ and R_{y} may further have a substituent, and examples of the substituent include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group and the like.

In Formula (ZI-3), it is more preferred that each of R_{1c}, R_{2c}, R_{4c} and R_{5c} independently represents a hydrogen atom and R_{3c} represents a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Examples of a cation in the compound (ZI-2) or (ZI-3) in the present invention include cations described in Paragraph Nos. [0130] to [0134] of Japanese Patent Application Laid-Open No. 2010-256842, Paragraph Nos. [0136] to [0140] of Japanese Patent Application Laid-Open No. 2011-76056, and the like.

Next, the compound (ZI-4) will be described.

The compound (ZI-4) is represented by the following Formula (ZI-4).

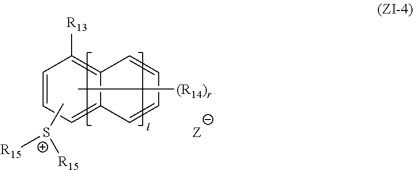

In Formula (ZI-4),

R₁₃ represents a hydrogen atom, a fluorine atom, a hydroxyl group, an alkyl group, a cycloalkyl group, an alkoxy group, an alkoxycarbonyl group or a group having a cycloalkyl group. These groups may have a substituent.

When a plurality of R₁₄ is present, each R₁₄ independently represents a hydroxyl group, an alkyl group, a cycloalkyl group, an alkoxy group, an alkoxycarbonyl group, an alkylcarbonyl group, an alkylsulfonyl group, a cycloalkylsulfonyl group or a group having a cycloalkyl group. These groups may have a substituent.

Each R₁₅ independently represents an alkyl group, a cycloalkyl group or a naphthyl group. Two of R₁₅ may be bonded to each other to form a ring. These groups may have a substituent.

l represents an integer of 0 to 2.

r represents an integer of 0 to 8.

Z⁻ represents a non-nucleophilic anion, and examples thereof are the same as those of the non-nucleophilic anion of Z⁻ in Formula (ZI).

In Formula (ZI-4), the alkyl group of R₁₃, R₁₄ and R₁₅ is preferably a straight chained or branched alkyl group having 1 to 10 carbon atoms, and preferred examples thereof include a methyl group, an ethyl group, an n-butyl group, a t-butyl group and the like.

Examples of the cycloalkyl group of R₁₃, R₁₄ and R₁₅ include a monocyclic or polycyclic cycloalkyl group (preferably a cycloalkyl group having 3 to 20 carbon atoms), and cyclopropyl, cyclopentyl, cyclohexyl, cycloheptyl and cyclooctyl are particularly preferred.

The alkoxy group of R₁₃ and R₁₄ is preferably a straight chained or branched alkoxy group having 1 to 10 carbon atoms, and preferred examples thereof include a methoxy group, an ethoxy group, an n-propoxy group, an n-butoxy group and the like.

The alkoxycarbonyl group of R₁₃ and R₁₄ is preferably a straight chained or branched alkoxycarbonyl group having 2 to 11 carbon atoms, and preferred examples thereof include a methoxycarbonyl group, an ethoxycarbonyl group, an n-butoxycarbonyl group and the like.

Examples of the group having a cycloalkyl group of R₁₃ and R₁₄ include a monocyclic or polycyclic cycloalkyl group (preferably a cycloalkyl group having 3 to 20 carbon atoms), and examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ has a total carbon number of preferably 7 or more, and more preferably 7 to 15, and preferably has a monocyclic cycloalkyl group. The monocyclic cycloalkyloxy group having a total carbon number of 7 or more represents a monocyclic cycloalkyloxy group in which a cycloalkyloxy group such as a cyclopropyloxy group, a cyclobutyloxy group, a cyclopentyloxy group, a cyclohexyloxy group, a cycloheptyloxy group, a cyclooctyloxy group and a cyclododecanyloxy group arbitrarily has a substituent such as an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group and an iso-amyl group, a hydroxyl group, halogen atom (fluorine, chlorine, bromine and iodine), a nitro group, a cyano group, an amide group, a sulfonamide group, alkoxy group such as a methoxy group, an ethoxy group, a hydroxyethoxy group, a propoxy group, a hydroxypropoxy group and a butoxy group, an alkoxycarbonyl group such as a methoxycarbonyl group and an ethoxycarbonyl group, an acyl group such as a formyl group, an acetyl group and a benzoyl group, an acyloxy group such as an acetoxy group and a butyryloxy group, a carboxyl group, and the like, and in which the total carbon number inclusive of the carbon number of an arbitrary substituent on the cycloalkyl group is 7 or more.

Further, examples of the polycyclic cycloalkyloxy group having a total carbon number of 7 or more include a norbornyloxy group, a tricyclodecanyloxy group, a tetracyclodecanyloxy group, an adamantyloxy group and the like.

The alkoxy group having a monocyclic or polycyclic cycloalkyl group of R₁₃ and R₁₄ has preferably a total carbon number of 7 or more, and more preferably a total carbon number ranging from 7 to 15, and is preferably an alkoxy group having a monocyclic cycloalkyl group. The alkoxy group having a total carbon number of 7 or more and having a monocyclic cycloalkyl group represents an alkoxy group in which an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy and iso-amyloxy is substituted with the above-described monocyclic cycloalkyl group which may have a substituent, and where the total carbon number inclusive of the carbon number of the substituent is 7 or more. Examples thereof include a cyclohexylmethoxy group, a cyclopentylethoxy group, a cyclohexylethoxy group and the like, and a cyclohexylmethoxy group is preferred.

Further, examples of the alkoxy group having a total carbon number of 7 or more and having a polycyclic cycloalkyl group include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group and the like, and a norbornylmethoxy group, a norbornylethoxy group and the like are preferred.

Specific examples of the alkyl group in the alkylcarbonyl group of R₁₄ are the same as those of the above-described alkyl group as R₁₃ to R₁₅.

The alkylsulfonyl group and cycloalkylsulfonyl group of R₁₄ are preferably a straight chained, branched or cyclic alkylsulfonyl group having 1 to 10 carbon atoms, and preferred examples thereof include a methanesulfonyl group, an ethanesulfonyl group, an n-propanesulfonyl group, an n-butanesulfonyl group, a cyclopentanesulfonyl group, a cyclohexanesulfonyl group and the like.

Examples of the substituent which each of the groups may have include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group and the like.

Examples of the alkoxy group include a straight chained, branched or cyclic alkoxy group having 1 to 20 carbon atoms, and the like, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group and a cyclohexyloxy group.

Examples of the alkoxyalkyl group include a straight chained, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group and a 2-ethoxyethyl group.

Examples of the alkoxycarbonyl group include a straight chained, branched or cyclic alkoxycarbonyl group having 2 to 21 carbon atoms and the like, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group and a cyclohexyloxycarbonyl group.

Examples of the alkoxycarbonyloxy group include a straight chained, branched or cyclic alkoxycarbonyloxy group having 2 to 21 carbon atoms, and the like, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group and a cyclohexyloxycarbonyloxy group.

Examples of the ring structure which may be formed by combining two R₁₅ with each other include a 5- or 6-membered ring formed together with the sulfur atom in Formula (ZI-4) by two R₁₅, and particularly preferably a 5-membered ring (that is, a tetrahydrothiophene ring), and may be condensed with an aryl group or a cycloalkyl group. The divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group and the like. As for the substituent on the ring structure, a plurality of substituents may be present, and the substituents may be bonded to each other to form a ring (an aromatic or non-aromatic hydrocarbon ring, an aromatic or non-aromatic heterocyclic ring, a polycyclic condensed ring formed by combining two or more of these rings or the like).

In Formula (ZI-4), R₁₅ is preferably a methyl group, an ethyl group, a naphthyl group, a divalent group capable of forming a tetrahydrothiophene ring structure together with the sulfur atom by combining two R₁₅ with each other, and the like.

The substituent that R₁₃ and R₁₄ may have is preferably a hydroxyl group, an alkoxy group, an alkoxycarbonyl group or a halogen atom (particularly a fluorine atom).

l is preferably 0 or 1, and more preferably 1.

r is preferably 0 to 2.

Examples of the cation in the compound represented by Formula (ZI-4) in the present invention include the cations described in the Paragraph Nos. [0121], [0123] and [0124] of Japanese Patent Application Laid-Open No. 2010-256842, Paragraph Nos. [0127], [0129] and [0130] of Japanese Patent Application Laid-Open No. 2011-76056, and the like.

One preferred embodiment of the compound (ZI-4) includes a compound represented by the following formula (ZI-4′).

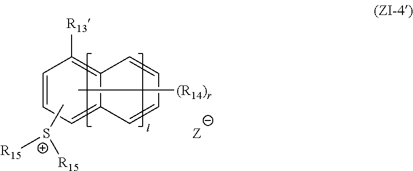

In formula (ZI-4′), R₁₃′ represents a branched alkyl group.

R₁₄ represents, when a plurality of R₁₄s are present, each independently represents, a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group.

Each R₁₅ independently represents an alkyl group, a cycloalkyl group or a naphthyl group, and two R₁₅s combine with each other to form a ring.

l represents an integer of 0 to 2.

r represents an integer of 0 to 8.

Z⁻ represents a non-nucleophilic anion.

Examples of the branched alkyl group of R₁₃′ include an isopropyl group and a tert-butyl group, with a tert-butyl group being preferred.

In formula (ZI-4′), specific examples and preferred examples of the group of each of R₁₄ and R₁₅, the ring structure formed by combining two R₁₅s with each other, and Z⁻ are the same as those described in formula (ZI-4).

Preferred ranges of 1 and r are also the same as those described in formula (ZI-4).

Next, Formulas (ZII) and (ZIII) will be described.

In Formulas (ZII) and (ZIII),

each of R₂₀₄ to R₂₀₇ independently represents an aryl group, an alkyl group or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure having an oxygen atom, a nitrogen atom, a sulfur atom or the like. Examples of the structure of the aryl group having a heterocyclic structure include pyrrole, furan, thiophene, indole, benzofuran, benzothiophene and the like.

The alkyl group or the cycloalkyl group in R₂₀₄ to R₂₀₇ is preferably a straight chained or branched alkyl group having 1 to 10 carbon atoms (for example, a methyl group, an ethyl group, a propyl group, a butyl group and a pentyl group) and a cycloalkyl group having 3 to 10 carbon atoms (a cyclopentyl group, a cyclohexyl group and a norbornyl group).

The aryl group, the alkyl group and the cycloalkyl group of R₂₀₄ to R₂₀₇ may have a substituent. Examples of the substituent that the aryl group, the alkyl group and the cycloalkyl group of R₂₀₄ to R₂₀₇ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, a phenylthio group and the like.

Z⁻ represents a non-nucleophilic anion, and examples thereof are the same as those of the non-nucleophilic anion of Z⁻ in Formula (ZI).

Examples of the acid generator further include compounds represented by the following Formulas (ZIV), (ZV) and (ZVI).

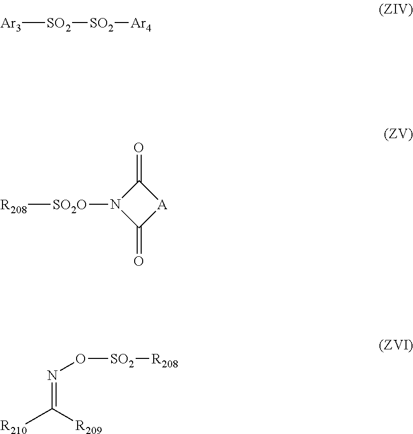

In Formulas (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as specific examples of the aryl group as R₂₀₁, R₂₀₂ and R₂₀₃ in Formula (ZI-1).

Specific examples of the alkyl group and the cycloalkyl group of R₂₀₈, R₂₀₉ and R₂₁₀ are the same as specific examples of the alkyl group and the cycloalkyl group as R₂₀₁, R₂₀₂ and R₂₀₃ in Formula (ZI-2).

Examples of the alkylene group of A include an alkylene group having 1 to 12 carbon atoms (for example, a methylene group, an ethylene group, a propylene group, an isopropylene group, a butylene group, an isobutylene group and the like), examples of the alkenylene group of A include an alkenylene group having 2 to 12 carbon atoms (for example, an ethenylene group, a propenylene group, a butenylene group and the like), and examples of the arylene group of A includes an arylene group having 6 to 10 carbon atoms (for example, a phenylene group, a tolylene group, a naphthylene group and the like).

Among the acid generators, the compounds represented by Formulas (ZI) to (ZIII) are more preferred.

In addition, the acid generator is preferably a compound capable of generating an acid having either a sulfonic acid group or an imide group, more preferably a compound capable of generating a monovalent perfluoroalkanesulfonic acid, a compound capable of generating an aromatic sulfonic acid substituted with a monovalent fluorine atom or a fluorine atom-containing group, or a compound capable of generating an imide acid substituted with a monovalent fluorine atom or a fluorine atom-containing group, and still more preferably a sulfonium salt of fluoro-substituted alkanesulfonic acid, fluorine-substituted benzenesulfonic acid, fluorine-substituted imide acid or fluorine-substituted methide acid. The acid generator which may be used is particularly preferably a fluoro-substituted alkanesulfonic acid, a fluoro-substituted benzenesulfonic acid or a fluoro-substituted imide acid, in which pKa of the acid generated is −1 or less, and the sensitivity is enhanced.

Among the acid generators, particularly preferred examples will be described below.

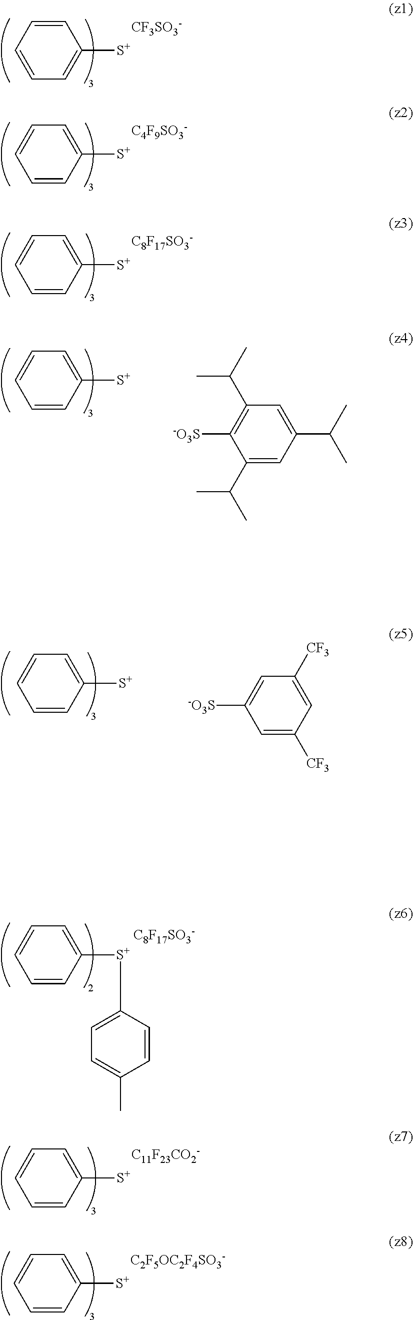

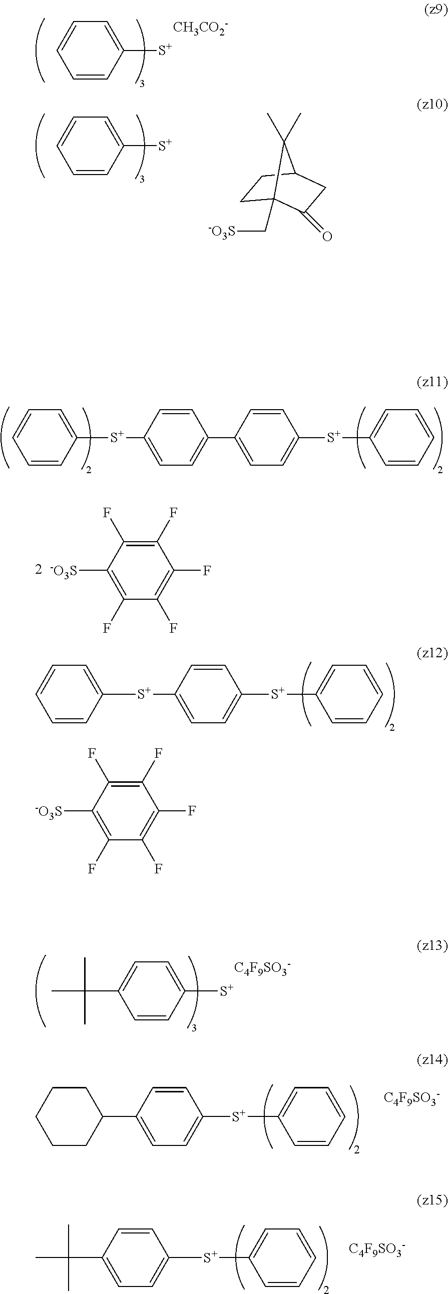

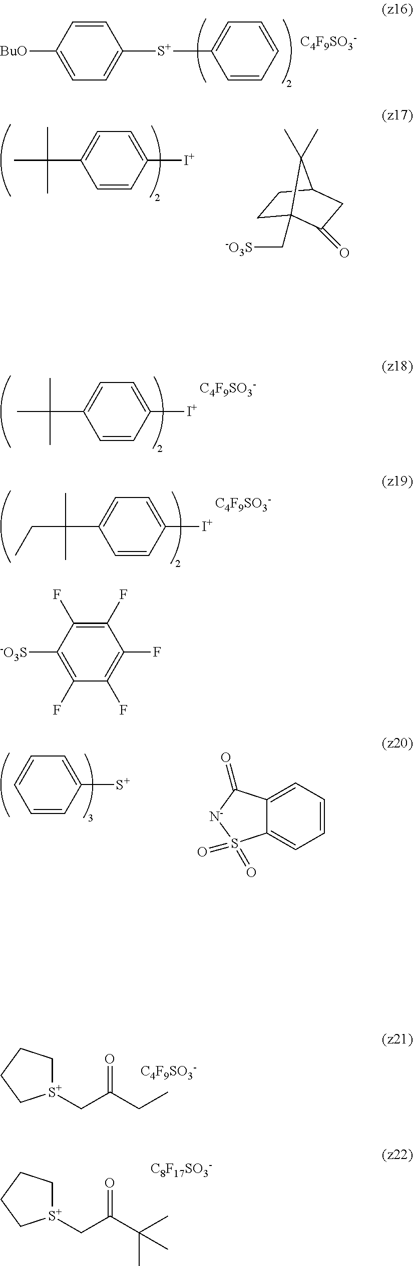

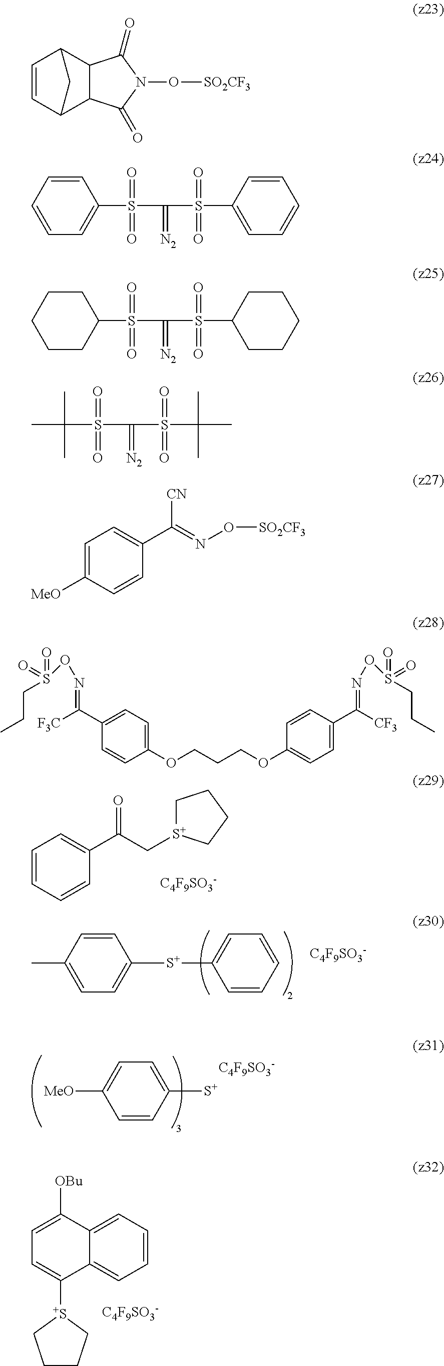

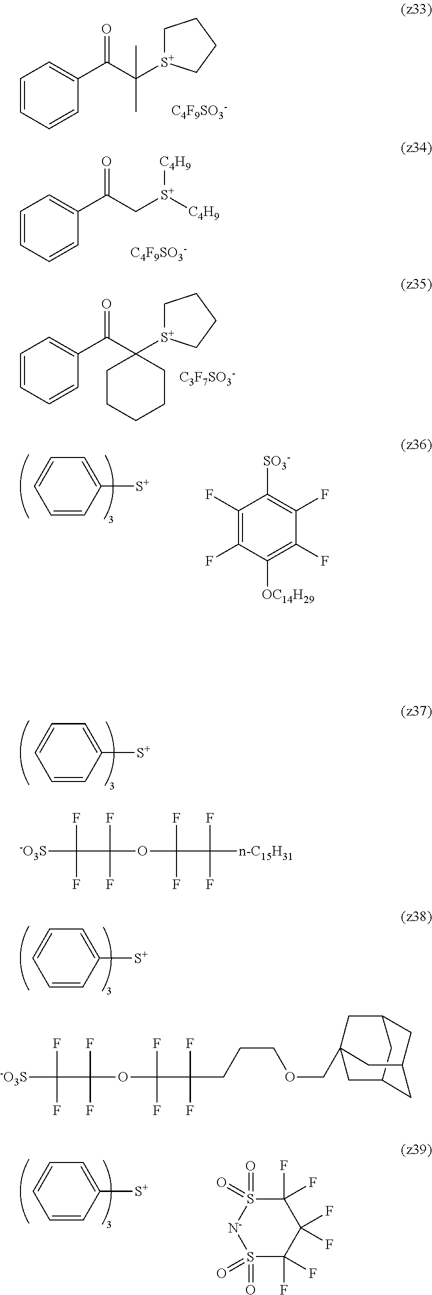

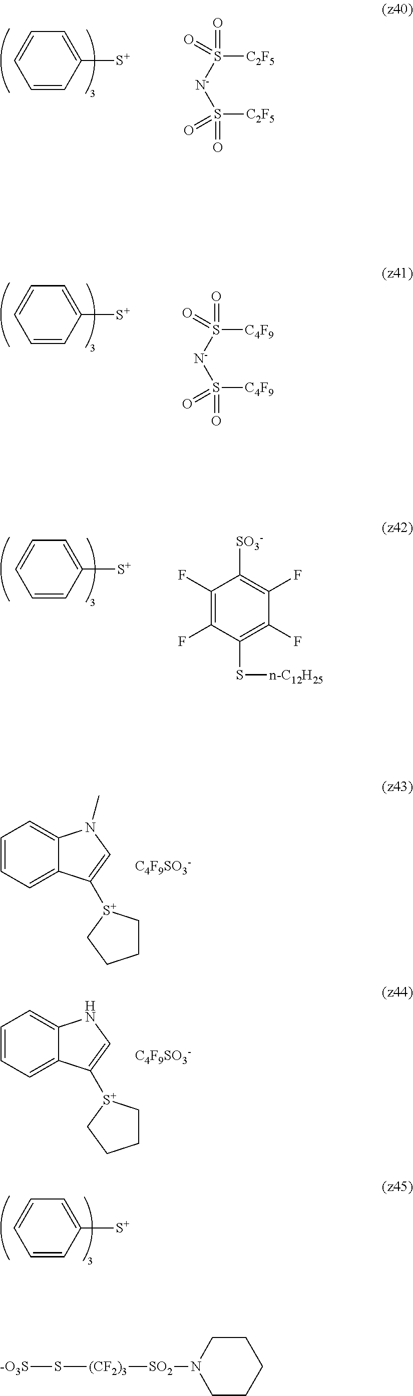

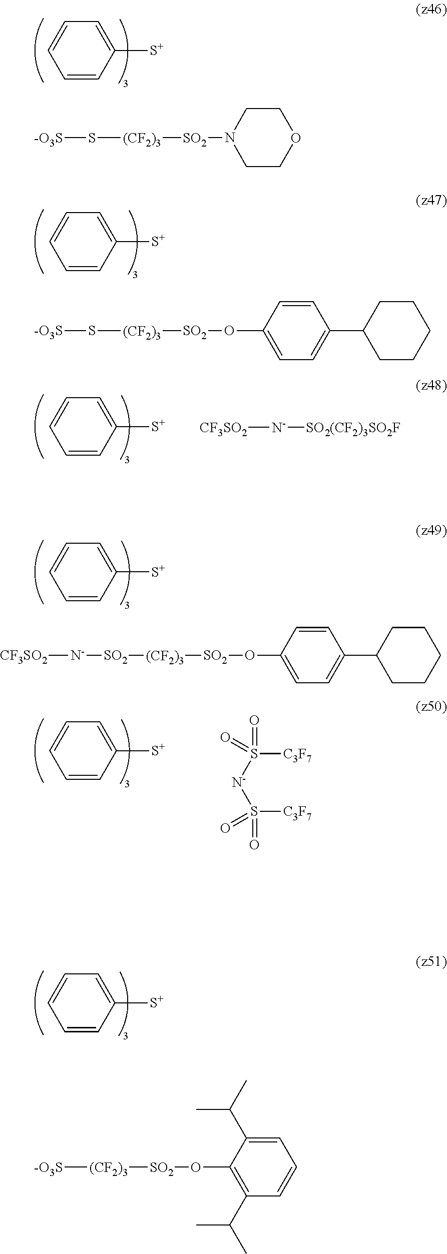

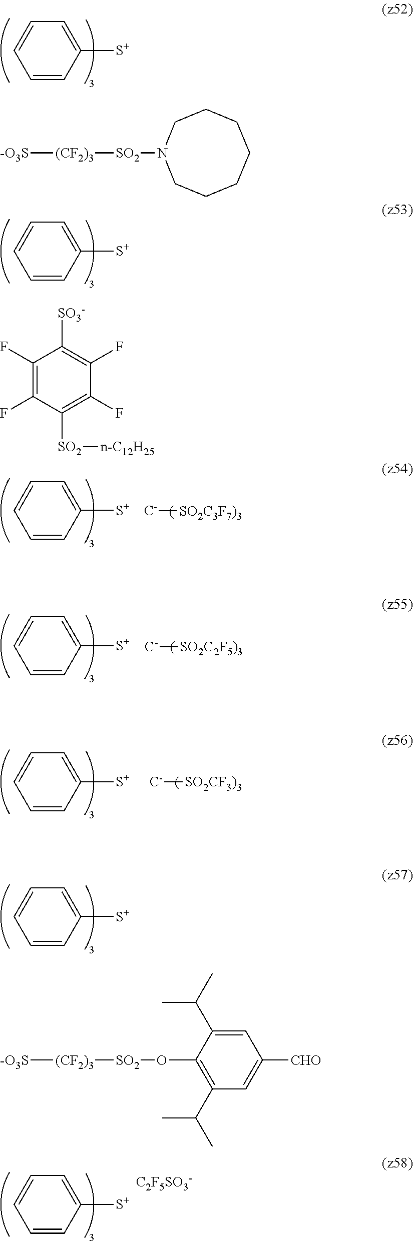

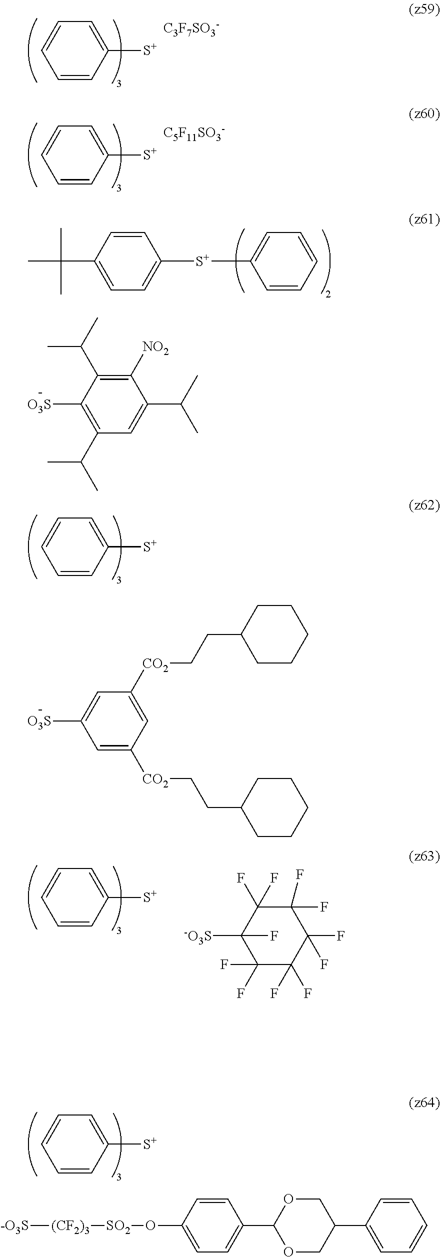

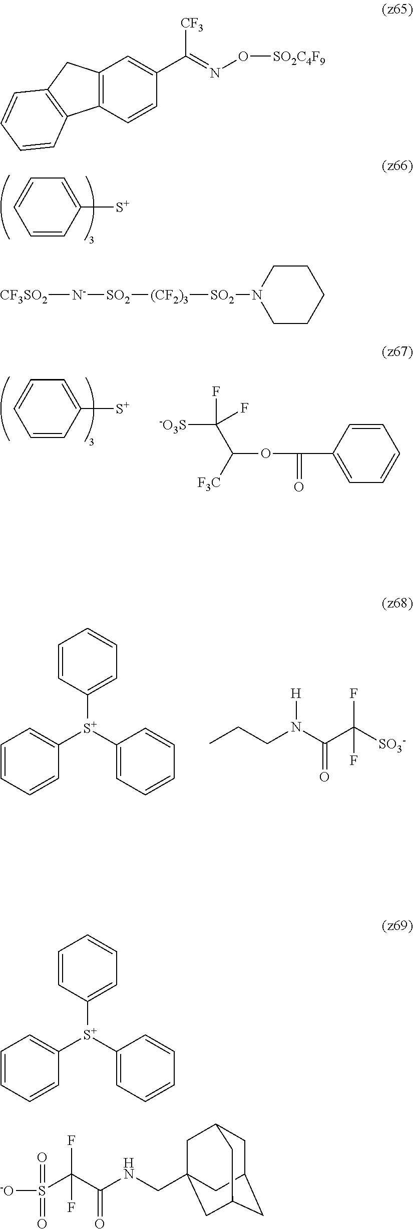

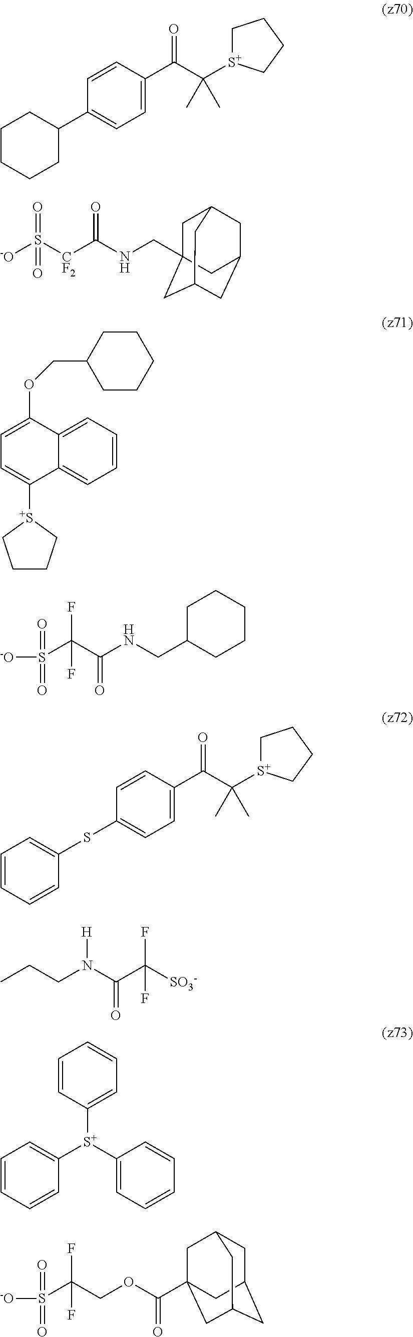

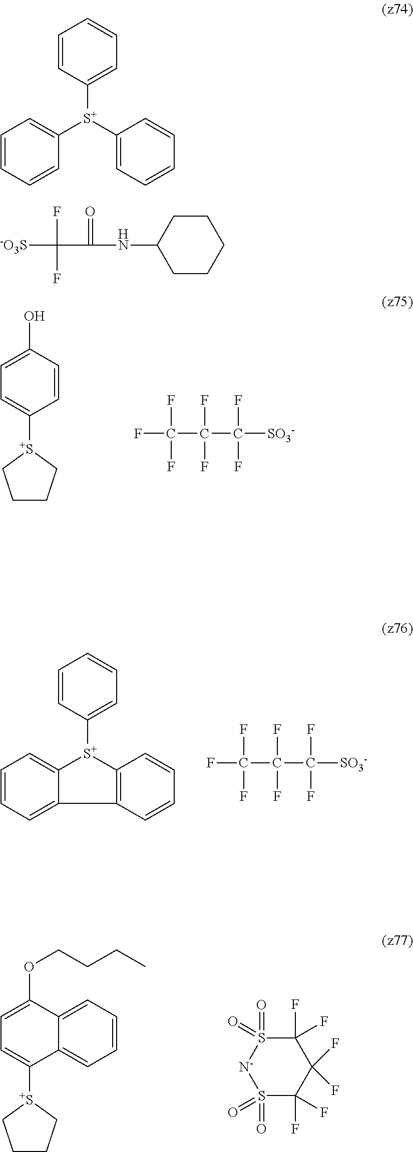

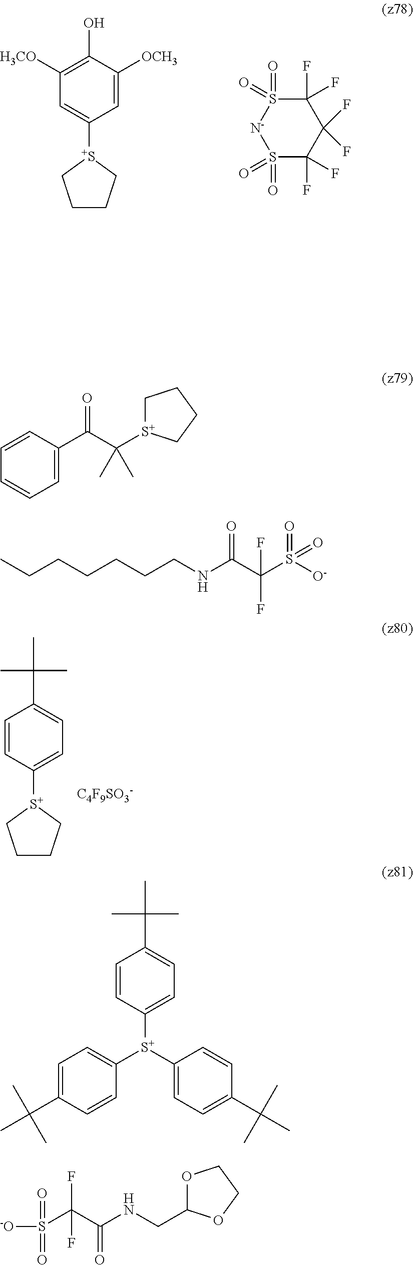

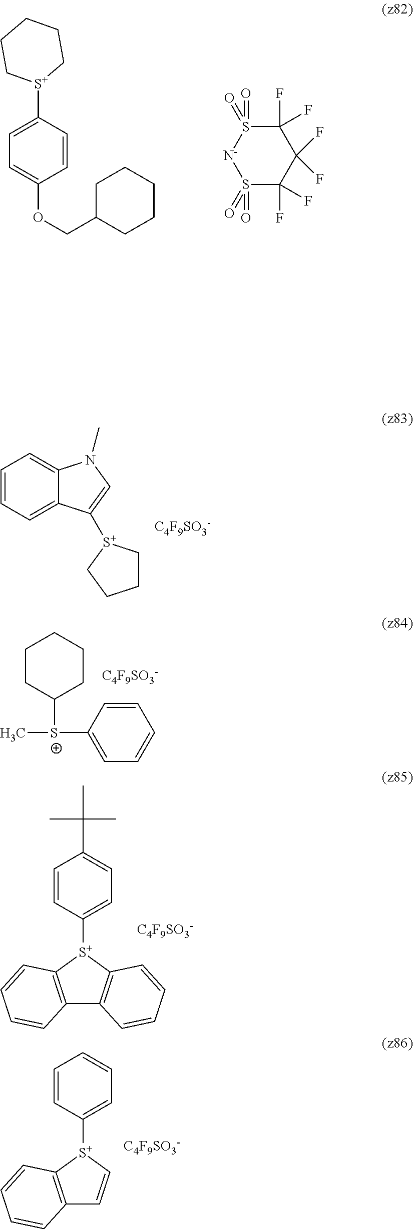

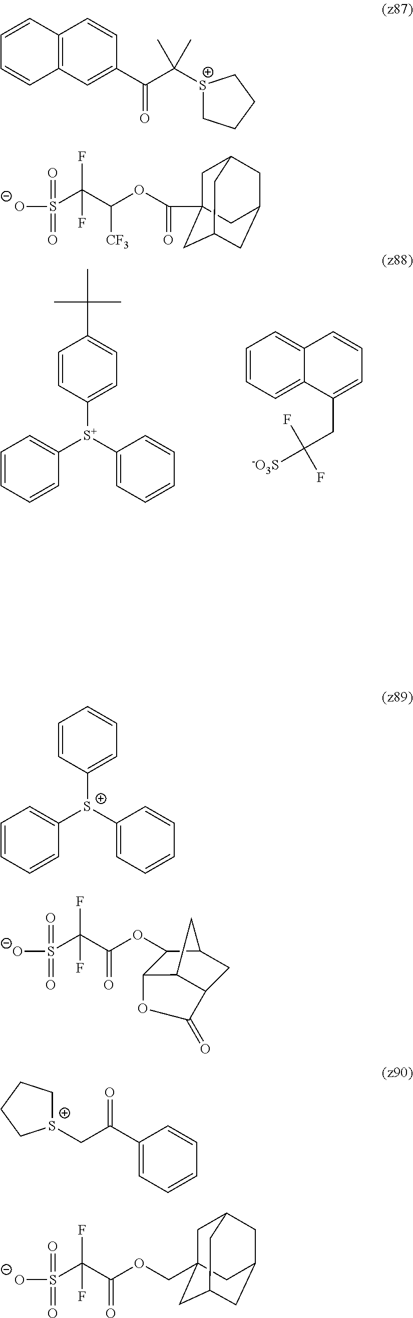

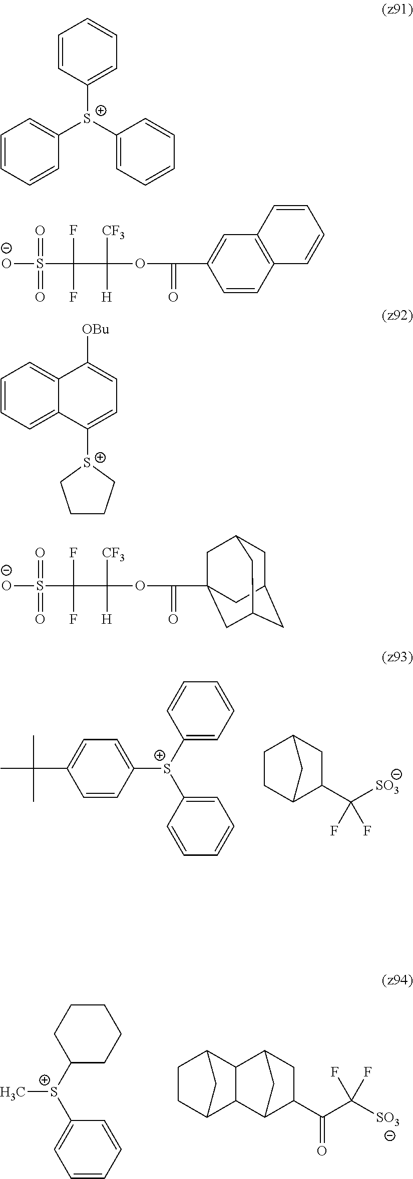

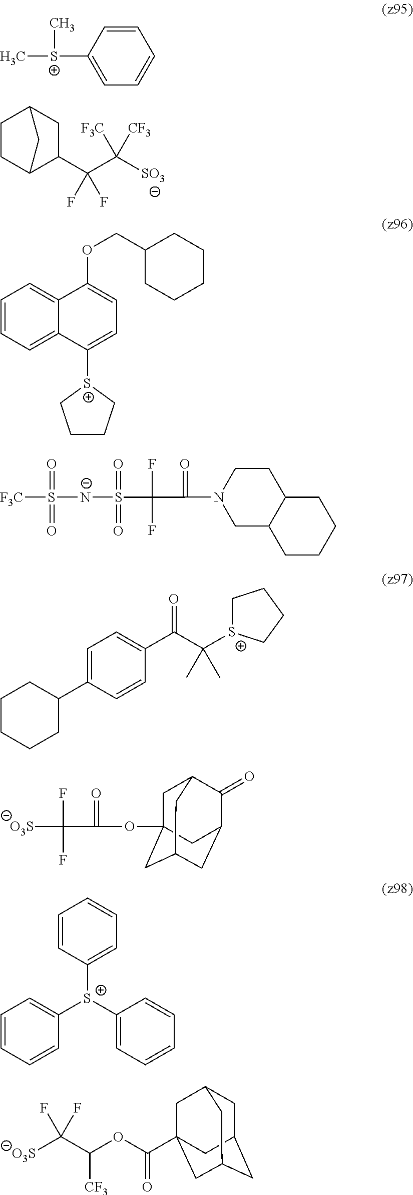

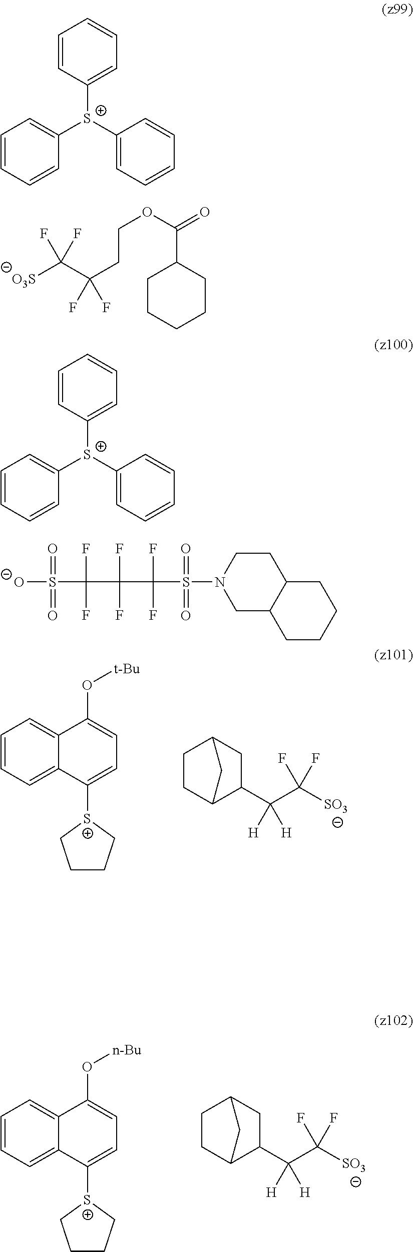

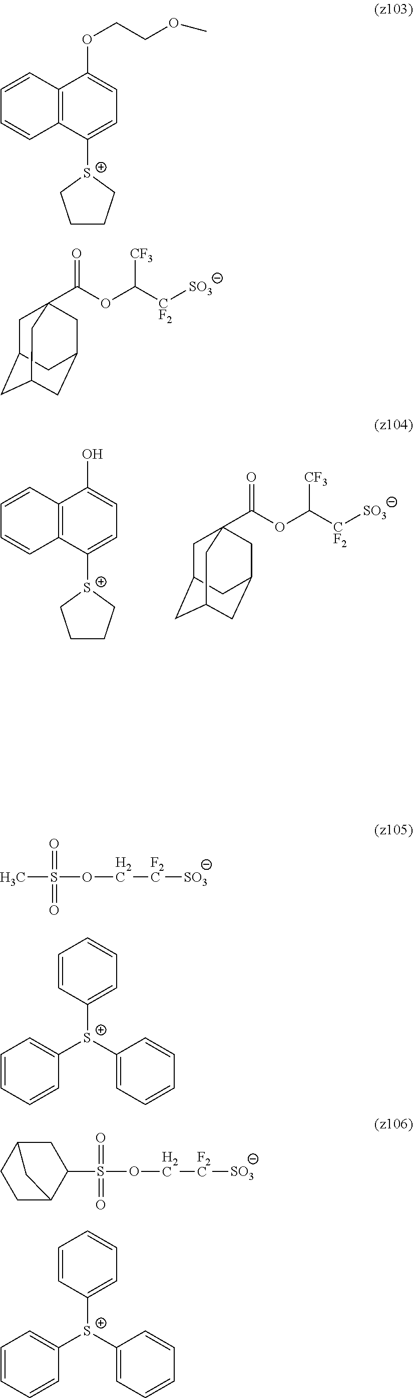

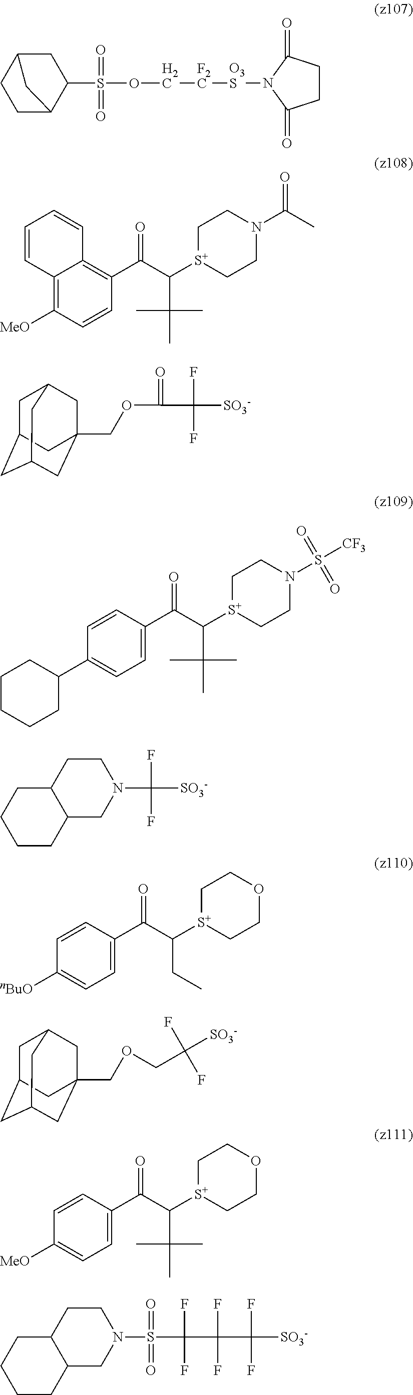

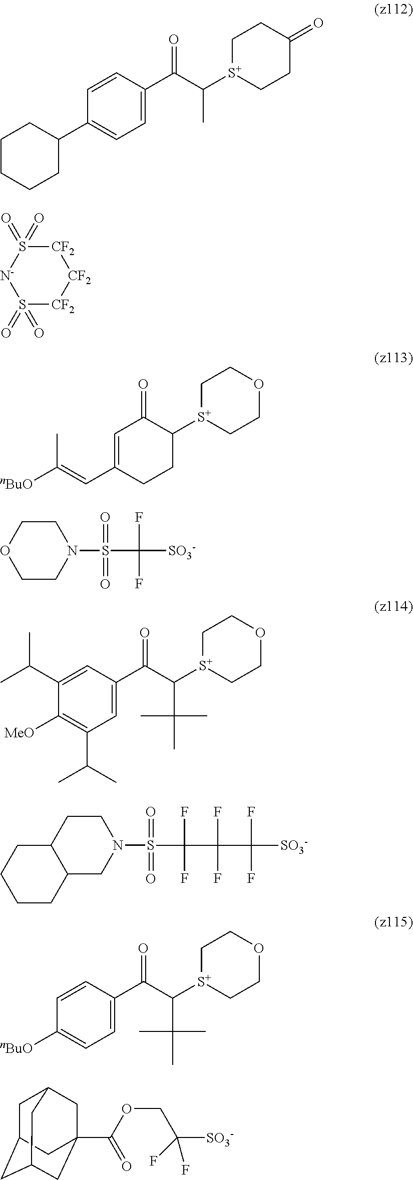

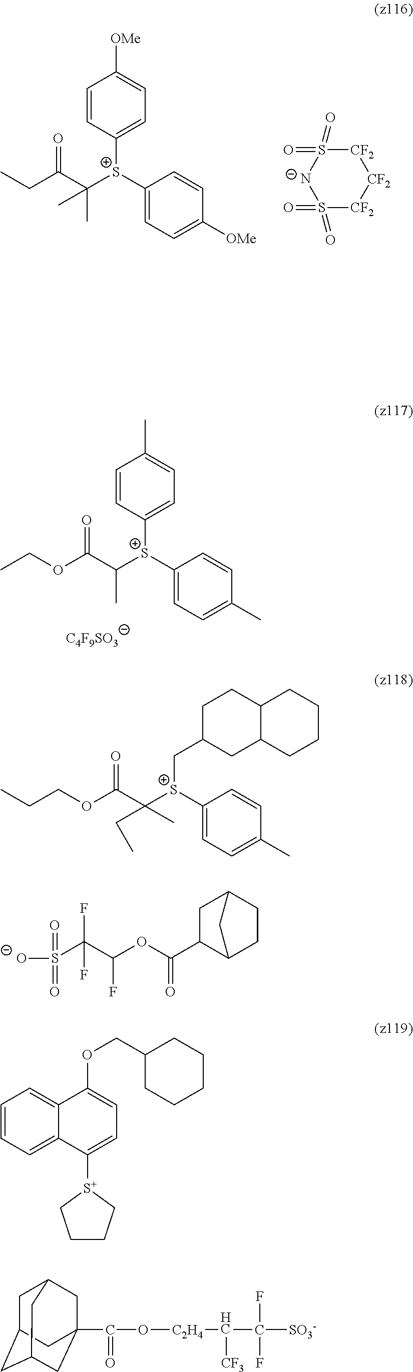

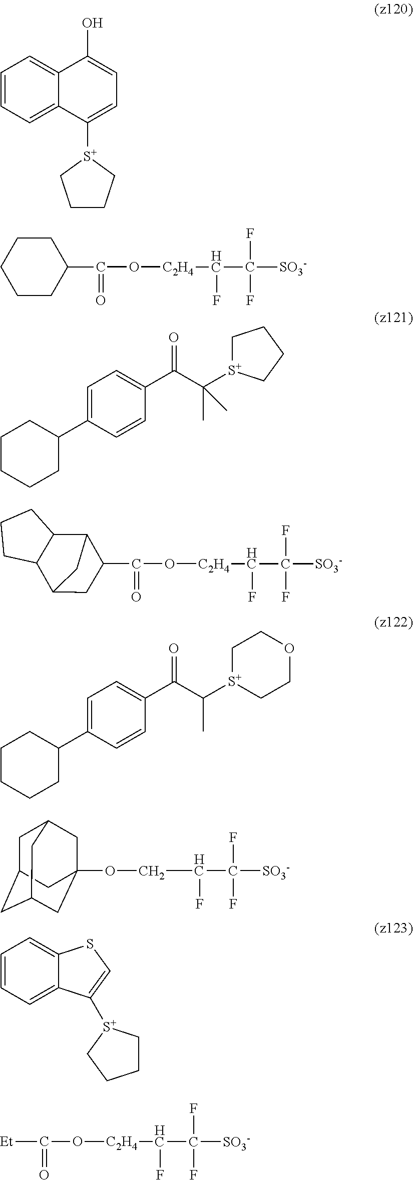

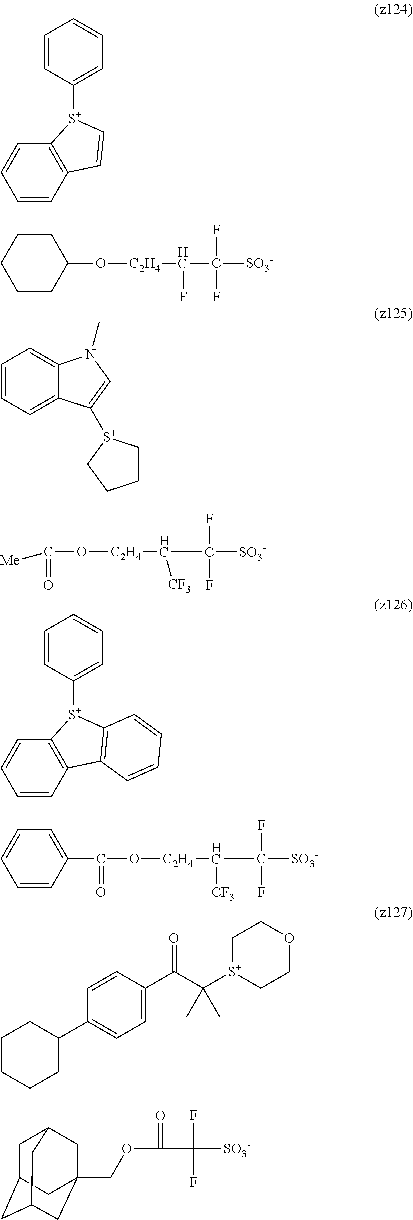

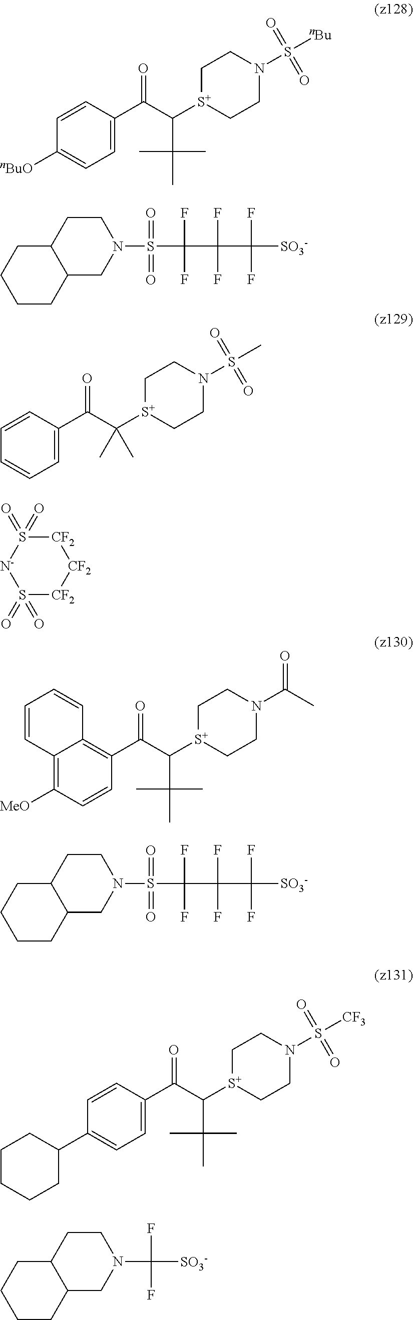

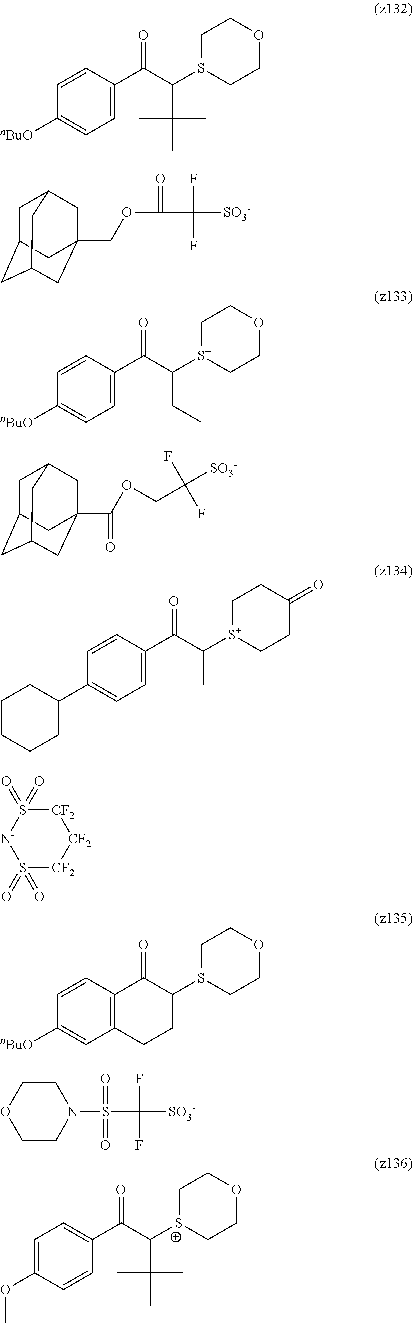

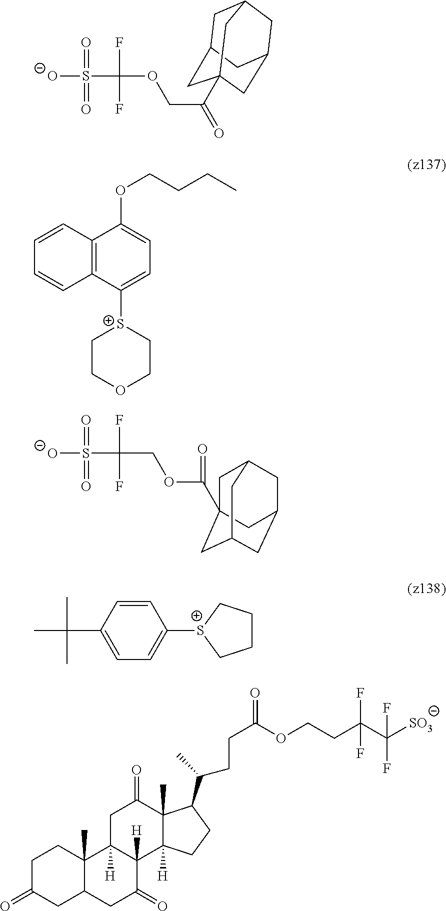

The acid generator may be synthesized by a known method, and may be synthesized in accordance with the method described in, for example, Japanese Patent Application Laid-Open No. 2007-161707.

The acid generator may be used either alone or in combination of two or more thereof.

The content of the compound capable of generating an acid upon irradiation with an actinic ray or radiation in the composition is preferably 0.1% by mass to 30% by mass, more preferably 0.5% by mass to 25% by mass, still more preferably 3% by mass to 20% by mass, and particularly preferably 3% by mass to 15% by mass, based on the total solid content of the actinic ray-sensitive or radiation-sensitive resin composition.

Further, when the acid generator is represented by Formula (ZI-3) or (ZI-4), the content thereof is preferably 5% by mass to 35% by mass, more preferably 8% by mass to 30% by mass, still more preferably 9% by mass to 30% by mass, and particularly preferably 9% by mass to 25% by mass, based on the total solid content of the composition.

[3] (D) Resin Different from Resin (A) and Containing Substantially No Fluorine Atom and Silicon Atom

The actinic ray-sensitive or radiation-sensitive resin composition according to the present invention contains a resin (D) (hereinafter simply referred to as “resin (D)” in some cases) which is different from the resin (A) and contains substantially no fluorine atom and silicon atom. Accordingly, a receding contact angle of water on a resist film formed in the step (a) may be further improved, and excellent uniformity of the film thickness and reduction in bridge defects and watermark defects may be achieved.

Here, the resin (D) contains substantially no fluorine atom and silicon atom, but specifically, the content of the repeating unit having a fluorine atom or a silicon atom is preferably 5 mol % or less, more preferably 3 mol % or less, and still more preferably 1 mol % or less, based on all the repeating units in the resin (D), and is ideally 0 mol %, that is, contains no fluorine atom and silicon atom. Further, it is preferred that the resin (D) substantially consists only of a repeating unit consisting only of an atom selected from a carbon atom, an oxygen atom, a hydrogen atom, a nitrogen atom and a sulfur atom. More specifically, the repeating unit composed only of an atom selected from a carbon atom, an oxygen atom, a hydrogen atom, a nitrogen atom and a sulfur atom is present in an amount of preferably 95 mol % or more, more preferably 97 mol % or more, still more preferably 99 mol % or more, and ideally 100 mol %, based on all the repeating units in the resin (D).

From the viewpoint of unevenly distributing the resin (D) in the top layer portion of the resist film to achieve excellent uniformity of the film thickness and reduction in bridge defects and watermark defects, the content of the resin (D) in the present invention in the composition is preferably 0.1% by mass to 10% by mass, more preferably 0.2% by mass to 8% by mass, still more preferably 0.3% by mass to 6% by mass, and particularly preferably 0.5% by mass to 5% by mass, based on the total solid content in the actinic ray-sensitive or radiation-sensitive resin composition.

In the present invention, it is preferred that the C Log P value of the resin (D) is high.

The higher the C Log P value of the resin (D) is, the higher the hydrophobicity of the resin (D) becomes and the receding contact angle of water on the resist film formed in the step (a) may be further improved, and thus, watermark defects in the immersion exposure may be further suppressed.

Further, the higher the C Log P value of the resin (D) is, the better the solubility in a solvent is, and thus the uniformity of the film thickness of the resist film may be further improved, and bridge defects may be reduced.

Here, the C Log P value refers to a common logarithmic value of a 1-octanol/water partition coefficient P, which represents a ratio of an equilibrium concentration of a compound (resin (D)) in 1-octanol to an equilibrium concentration of the resin (D) in water.

From the above-described viewpoint, the C Log P value of the resin (D) is preferably 1.5 or more, more preferably 2.5 or more, further preferably 2.8 or more, and particularly preferably 3.5 or more.

In addition, the upper limit of the C Log P value of the resin (D) is not particularly limited, but is preferably 10.0 or less, and more preferably 8.0 or less.

In the present invention, the C Log P value of the resin (D) may be calculated as follows.

When the resin (D) is composed of the repeating units D1, D2, Dx, . . . , and Dn, each of the C Log P values of the monomers corresponding to the repeating units D1, D2, . . . , Dx, . . . , and Dn is defined as C log P1, C log P2, . . . , C log Px, . . . , and C log Pn, and each of the molar ratios of the repeating units D1, D2, . . . , Dx, . . . , and Dn in the resin (D) is defined as ω1, ω2, . . . , ωx, . . . , and ωn, the C Log P value of the resin (D) may be calculated by the following equation.

The C Log P value of the resin (D)=Σ[(ω1×C log P1)+(ω2×C log P2)++(ωx×C log Px+ . . . +(ωn×C log Pn)]

Further, the C Log P values (C log P1, C log P2, C log Px, . . . , and C log Pn) of the monomers corresponding to the repeating units D1, D2, Dx, . . . , and Dn may be calculated by using ChemDraw Ultra ver. 8.0 manufactured by Cambridgesoft Corp.

From the viewpoint of enhancing C log P value of the resin (D), the resin (D) preferably contains a repeating unit corresponding to a monomer having C log P value of 2.5 or more, more preferably a repeating unit corresponding to a monomer having C log P value of 2.8 or more, and further preferably a repeating unit corresponding to a monomer having C log P value of 3.5 or more.

The upper limit of C log P value of the monomer corresponding to the repeating unit contained in the resin (D) is not particularly limited, but is preferably 10.0 or less, and more preferably 8.0 or less.

Specific examples of each repeating unit that may be composed in the resin (D) and specific examples of the C Log P values of the monomers corresponding to the repeating units will be described below, but the present invention is not limited thereto.

| Structure | |
|---|---|
| of | |
| repeating | ClogP of |
| unit | monomer |
| 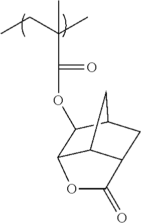 | 0.6201 |
| 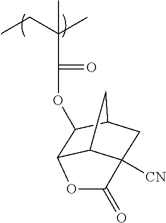 | −0.1857 |
| 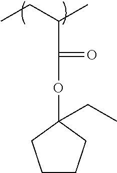 | 3.317 |
| 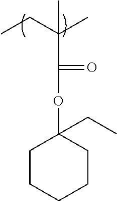 | 4.185 |
| 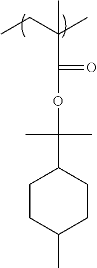 | 4.983 |
| 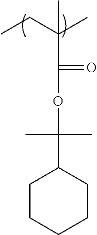 | 4.464 |
| 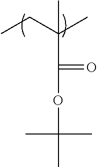 | 2.343 |
| 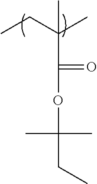 | 2.872 |
| 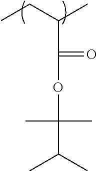 | 2.962 |
| 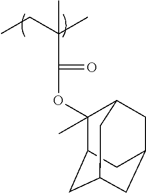 | 4.284 |
| 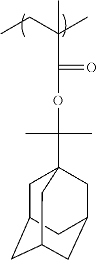 | 6.132 |
| 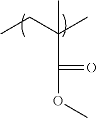 | 1.106 |
| 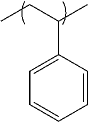 | 2.866 |
| 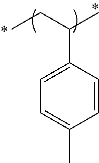 | 3.365 |
| 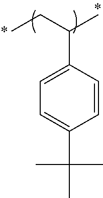 | 4.692 |
| 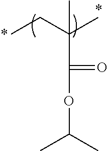 | 1.944 |
| 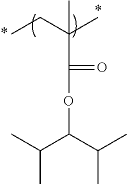 | 3.8 |
| 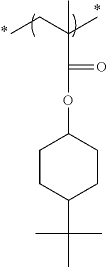 | 4.983 |
| 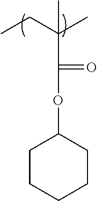 | 3.137 |
| 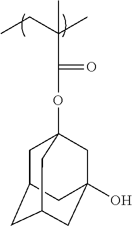 | 2.182 |

Specific examples of the resin (D) and specific examples of the C Log P value thereof will be described below, but the present invention is not limited thereto.

| | Compo- | ClogP |
|---|---|---|
| | sition | of |
| | ratio | Resin |
| Structure of Resin (D) | (mol %) | (D) |
| 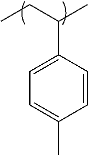 | 100 | 3.37 |
| 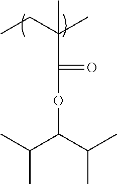 | 100 | 3.80 |
| 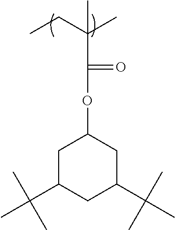 | 100 | 6.83 |
| 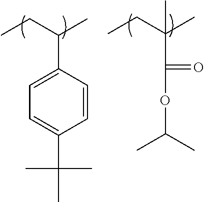 | 40/60 | 3.04 |
| 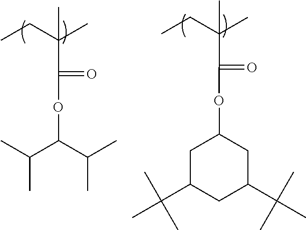 | 70/30 | 4.71 |
| 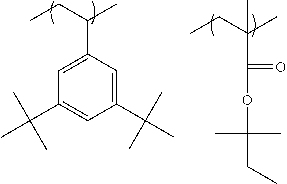 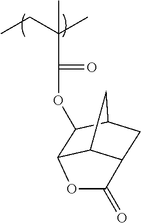 | 40/50/10 | 4.11 |
| 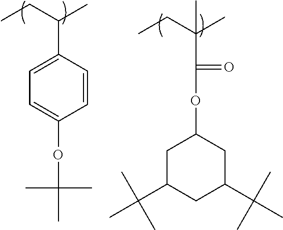 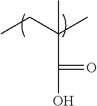 | 15/75/10 | 5.79 |
| 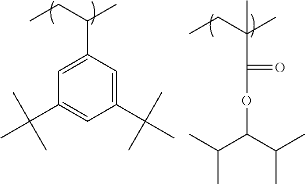 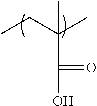 | 20/75/5 | 4.19 |
| 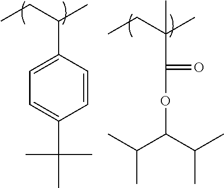 | 20/80 | 3.98 |
| 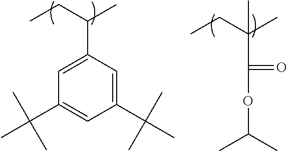 | 10/90 | 2.40 |
| 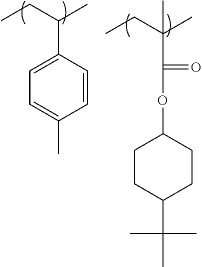 | 30/70 | 4.50 |
| 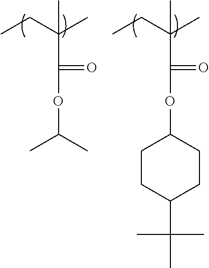 | 40/60 | 3.77 |
| 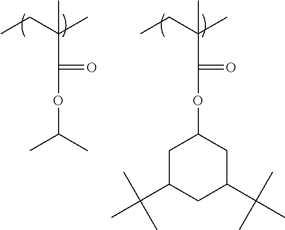 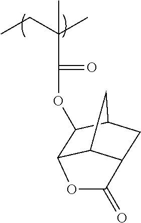 | 35/60/5 | 4.81 |
| 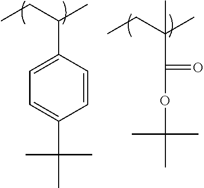 | 10/90 | 2.58 |
| 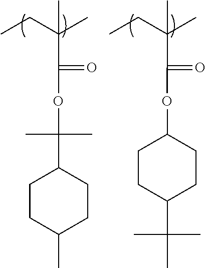 | 40/60 | 4.98 |
| 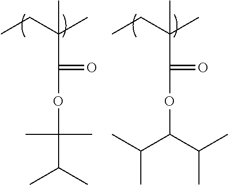 | 50/50 | 3.38 |

Further, the mass content ratio of the CH₃ partial structure, that the side chain moiety in the resin (D) has, in the resin (D) is preferably 12.0% or more, and more preferably 18.0% or more. Accordingly, a low surface free energy may be achieved and the uneven distribution of the resin (D) in the top layer portion of the resist film may be further improved, and as a result, the uniformity of the film thickness may be improved, and reduction in bridge defects and watermark defects in the immersion exposure may be achieved.

In addition, the upper limit of the mass content ratio of the CH3 partial structure that the side chain moiety in the resin (D) has is preferably 50% or less, and more preferably 40% or less.

Here, a methyl group (for example, an α-methyl group of the repeating unit having a methacrylic acid structure) directly bonded to the main chain of the resin (D) slightly contributes to the surface uneven distribution of the resin (D) due to the effects of the main chain and thus is not included in the CH₃ partial structure in the present invention and is not counted. More specifically, when the resin (D) includes a repeating unit derived from a monomer having a polymerizable moiety having a carbon-carbon double bond, such as, for example, a repeating unit represented by the following Formula (M) and when R₁₁ to R₁₄ are a CH₃ “as it is”, the CH₃ is not included (not counted) in the CH₃ partial structure in the present invention that the side chain moiety has.

Meanwhile, the CH₃ partial structure present through any atom from the C—C main chain is counted as a CH₃ partial structure. For example, when R₁₁ is an ethyl group (CH₂CH₃), R₁₁ is counted to have “one” of the CH₃ partial structure in the present invention.

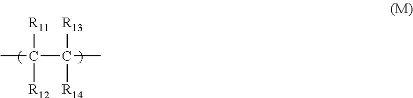

In Formula (M),

each of R₁₁ to R₁₄ independently represents a side chain moiety.

Examples of R₁₁ to R₁₄ in the side chain moiety include a hydrogen atom, a monovalent organic group and the like.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group and the like.

The monovalent organic group may further have a substituent, and examples of the substituent are the same as specific examples described below as a substituent that an aromatic group Ar₂₁ in Formula (II) may have and preferred examples thereof.

In the present invention, the CH₃ partial structure (hereinafter simply referred to as a “side chain CH₃ partial structure” in some cases) that the side chain moiety in the resin (D) has includes a CH₃ partial structure that an ethyl group, a propyl group and the like have.

Hereinafter, the mass content ratio (hereinafter simply referred to as a “mass content ratio of the side chain CH3 partial structure in the resin (D)” in some cases) of the CH₃ partial structure, that the side chain moiety in the resin (D) has, in the resin (D) will be described.

Here, the mass content ratio of the side chain CH₃ partial structure in the resin (D) will be described by exemplifying the case in which the resin (D) is composed of the repeating units D1, D2, . . . , Dx, . . . , and Dn, and each of the molar ratios of the repeating units D1, D2, . . . , Dx, . . . , and Dn in the resin (D) is ω1, ω2, . . . , ωx, . . . , and ωn.

(1) First, the mass content ratio (MCx) of the side chain CH₃ partial structure of the repeating unit Dx may be calculated by an equation of “100×15.03×(the number of CH₃ partial structures in the side chain moiety in the repeating unit Dx)/molecular weight (Mx) of the repeating unit Dx”.

Here, the number of CH₃ partial structures in the side chain moiety in the repeating unit Dx does not include the number of methyl groups directly bonded to the main chain thereof.

(2) Next, the mass content ratio of the side chain CH₃ partial structure in the resin (D) may be calculated by the following equation by using the mass content ratio of the side chain CH₃ partial structure calculated for each repeating unit.

Mass content ratio of the side chain CH3 partial structure in the resin (D):

DMC=Σ[(ω1×MC1)+(ω2×MC2)+ . . . +(ωx×MCx)+ . . . +(ωn×MCn)]

The resin (D) contains a repeating unit preferably containing 2 or more CH₃ partial structures at a side chain thereof, more preferably 3 or more CH₃ partial structures at a side chain thereof, further preferably 3 to 10 CH₃ partial structures at a side chain thereof, and particularly preferably 3 to 8 CH₃ partial structures at a side chain thereof.

Due to such a configuration, the mass content of the CH3 partial structure at a side chain of the resin (D) is increased, and a surface free energy of the resin (D) becomes lower than that of the resin (A). By this, it can be expected to enhance localization of the resin (D) at the surface part of the resist film. And then, improvement of the uniformity of the resist thickness, reduction of bridge defects, and reduction of watermark defects in an immersion exposure.

From the viewpoint of better improving a receding contact angle of water on a resist film formed in the step (a) and achieving excellent uniformity of the film thickness and reduction in bridge defects and watermark defects more securely, it is preferred that the resin (D) has at least one of the repeating units represented by the following Formula (II) or (III), and it is more preferred that the resin (D) consists only of at least one of the repeating units represented by the following Formula (II) or (III).

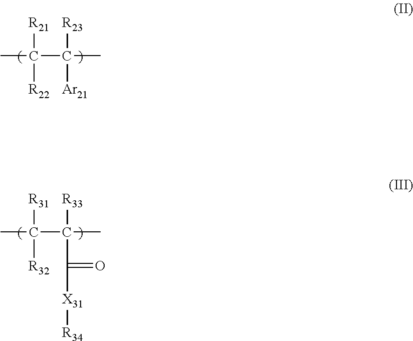

In Formula (II),

each of R₂₁ to R₂₃ independently represents a hydrogen atom or an alkyl group.

Ar₂₁ represents an aromatic group. R₂₂ and Ar₂₁ may form a ring, and in that case, R₂₂ represents an alkylene group.

In Formula (III),

each of R₃₁ to R₃₃ independently represents a hydrogen atom or an alkyl group.

X₃₁ represents —O— or —NR₃₅—. R₃₅ represents a hydrogen atom or an alkyl group.

R₃₄ represents an alkyl group or a cycloalkyl group.

In Formula (II), the alkyl group of R₂₁ to R₂₃ is preferably an alkyl group (a methyl group, an ethyl group, a propyl group and a butyl group) having 1 to 4 carbon atoms, more preferably a methyl group or an ethyl group, and particularly preferably a methyl group.

When R₂₂ and Ar₂₁ form a ring, examples of the alkylene group include a methylene group, an ethylene group and the like.

R₂₁ to R₂₃ in Formula (II) are particularly preferably a hydrogen atom or a methyl group.

The aromatic group of Ar₂₁ in Formula (II) may have a substituent, and examples thereof include an aryl group having 6 to 14 carbon atoms, such as a phenyl group and a naphthyl group, or an aromatic group including a hetero ring such as thiophene, furan, pyrrole, benzothiophene, benzofuran, benzopyrrole, triazine, imidazole, benzimidazole, triazole, thiadiazole and thiazole, but an aryl group that may have a substituent having 6 to 14 carbon atoms, such as a phenyl group and a naphthyl group is preferred.

Examples of the substituent that the aromatic group Ar₂₁ may have include an alkyl group, an alkoxy group, an aryl group and the like, but from the viewpoint of improving the C Log P value and hydrophobicity of the resin (D) to improve the receding contact angle, an alkyl group and an alkoxyl group are preferred, an alkyl group having 1 to 4 carbon atoms and an alkoxyl group are more preferred, and a methyl group, an isopropyl group, a t-butyl group and a t-butoxy group are particularly preferred.

Further, the aromatic group for Ar₂₁ may have two or more substituents.

In Formula (III), the alkyl group of R₃₁ to R₃₃ and R₃₅ is preferably an alkyl group (a methyl group, an ethyl group, a propyl group and a butyl group) having 1 to 4 carbon atoms, more preferably a methyl group and an ethyl group, and particularly preferably a methyl group. Each of R₃₁ to R₃₃ in Formula (III) is independently particularly preferably a hydrogen atom and a methyl group.

X₃₁ in Formula (III) is preferably —O— and —NH— (that is, when R₃₅ in —NR₃₅— is a hydrogen atom), and particularly preferably —O—.

In Formula (III), the alkyl group for R₃₄ may be either chained or branched, and examples thereof include a chained alkyl group (for example, a methyl group, an n-propyl group, an n-butyl group, an n-hexyl group, an n-octyl group, an n-dodecyl and the like), a branched alkyl group (for example, an isopropyl group, an isobutyl group, a t-butyl group, a methylbutyl group, a dimethylpentyl group and the like), but from the viewpoint of improving the C Log P value and hydrophobicity of the resin (D) to improve the receding contact angle, a branched alkyl group is preferred, a branched alkyl group having 3 to 10 carbon atoms are more preferred, and a branched alkyl group having 3 to 8 carbon atoms are particularly preferred.

In Formula (III), the cycloalkyl group for R34 may have a substituent, and examples thereof include a monocyclic cycloalkyl group, such as a cyclobutyl group, a cyclopentyl group and a cycicohexyl group, and a polycyclic cycloalkyl group, such as a norbornyl group, a tetracyclodecanyl group and an adamantly group, but a monocyclic cycloalkyl group is preferred, a monocyclo cycloalkyl group having 5 to 6 carbon atoms is more preferred, and a cyclohexyl group is particularly preferred.

Examples of the substituent that R₃₄ may have include an alkyl group, an alkoxy group, an aryl group and the like, but from the viewpoint of improving the C Log P value and hydrophobicity of the resin (D) to improve the receding contact angle, an alkyl group and an alkoxyl group are preferred, an alkyl group having 1 to 4 carbon atoms and an alkoxyl group are more preferred, and a methyl group, an isopropyl group, a t-butyl group and a t-butoxy group are particularly preferred.

Further, the alkyl group and the cycloalkyl group for R₃₄ may have two or more substituents.

It is preferred that R₃₄ is not a group capable of decomposing and leaving by the action of an acid, that is, the repeating unit represented by Formula (III) is not a repeating unit having an acid-decomposable group.

In Formula (III), R₃₄ is most preferably a cyclohexyl group substituted with a branched alkyl group having 3 to 8 carbon atoms, an alkyl group having 1 to 4 carbon atoms and an alkoxyl group.

In Formulae (II) and (III), as mentioned the above, from the viewpoint of enhancement of the mass content of the CH3 partial structure at a side chain of the resin (D), the resin (D) contains a repeating unit preferably containing 2 or more CH₃ partial structures at a side chain thereof, more preferably 3 or more CH₃ partial structures at a side chain thereof, further preferably 3 to 10 CH₃ partial structures at a side chain thereof, and particularly preferably 3 to 8 CH₃ partial structures at a side chain thereof.

Specific examples of the repeating unit represented by Formula (II) or (III) will be described below, but the present invention is not limited thereto.

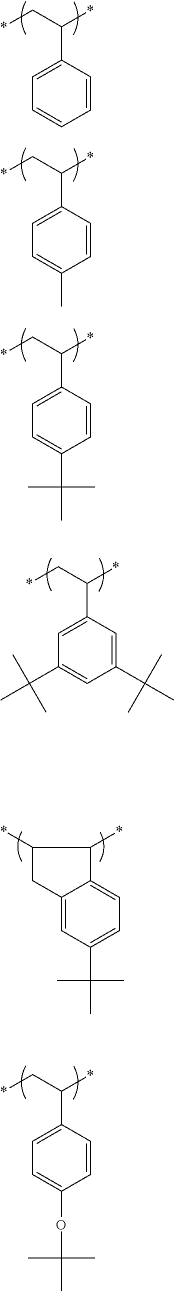

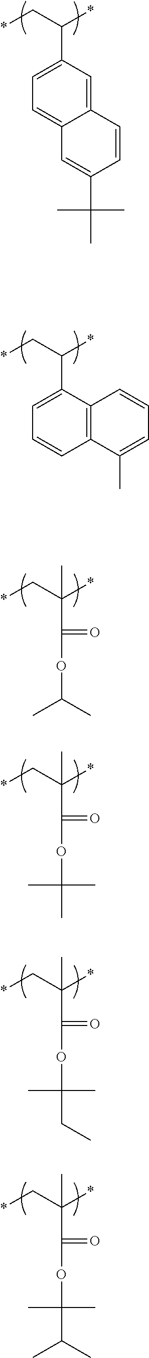

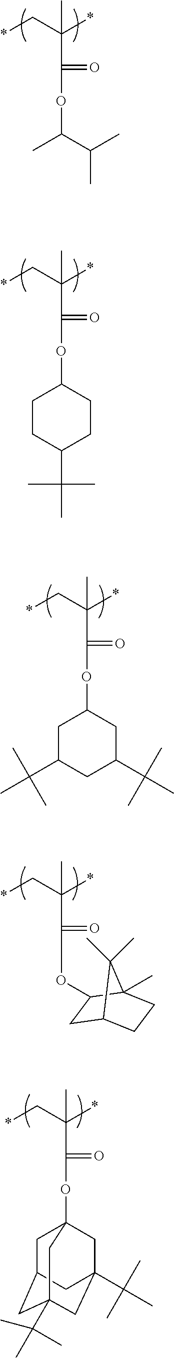

When the resin (D) has the repeating unit represented by Formula (II) or (III), the content of the repeating unit represented by Formula (II) or (III) is preferably in a range of 50 mol % to 100 mol %, more preferably in a range of 65 mol % to 100 mol %, and particularly preferably in a range of 80 mol % to 100 mol %, based on all the repeating units in the resin (D), from the viewpoint of improving the C Log P value and hydrophobicity of the resin (D) to improve the receding contact angle, thereby achieving the effects of the present invention.

The resin (D) may further have appropriately a repeating unit having an acid-decomposable group, a repeating unit having a lactone structure, a repeating unit having a hydroxyl group or a cyano group, a repeating unit having an acid group (an alkali-soluble group), and a repeating unit having an alicyclic hydrocarbon structure having no polar group and not exhibiting acid decomposability, which are the same as described above for the resin (A).

Specific examples and preferred examples of each repeating unit that the resin (D) may have are the same as the specific examples and preferred examples of each repeating unit described above for the resin (A).

However, from the viewpoint of achieving the effects of the present invention more securely, it is more preferred that the resin (D) does not have a repeating unit having an acid-decomposable group, an alkali-soluble repeating unit and a repeating unit having a lactone structure.

The weight average molecular weight of the resin (D) related to the present invention is not particularly limited, but the weight average molecular weight is preferably in a range of 3,000 to 100,000, more preferably in a range of 6,000 to 70,000, and particularly preferably in a range of 10,000 to 40,000. In particular, by adjusting the weight average molecular weight in a range of 10,000 to 40,000, uniformity of the film thickness is excellent in forming a fine pattern, and defect reduction performance is excellent in the immersion exposure. Here, the weight average molecular weight of the resin represents the molecular weight in terms of polystyrene measured by GPC (carrier: THF or N-methyl-2-pyrrolidone (NMP)).

In addition, the polydispersity (Mw/Mn) is preferably 1.00 to 5.00, more preferably 1.03 to 3.50 and still more preferably 1.05 to 2.50. The smaller the molecular weight distribution is, the better the resolution and resist pattern shape are.

The resin (D) according to present invention may be used either alone or in combination of two or more thereof.

As for the resin (D), various commercially available products may be used, and the resin (D) may be synthesized by a typical method (for example, radical polymerization). Examples of a general synthesis method include a batch polymerization method of dissolving monomer species and an initiator in a solvent and heating the solution, thereby performing the polymerization, a dropping polymerization method of adding dropwise a solution containing monomer species and an initiator to a heated solvent over 1 to 10 hours, and the like, and a dropping polymerization method is preferred.

The reaction solvent, polymerization initiator, reaction conditions (temperature, concentration and the like) and purification method after reaction are the same as those described in the resin (A), but in the synthesis of the resin (D), the reaction concentration is preferably 10% by mass to 50% by mass.

Specific examples of the resin (D) will be described below, but the present invention is not limited thereto.

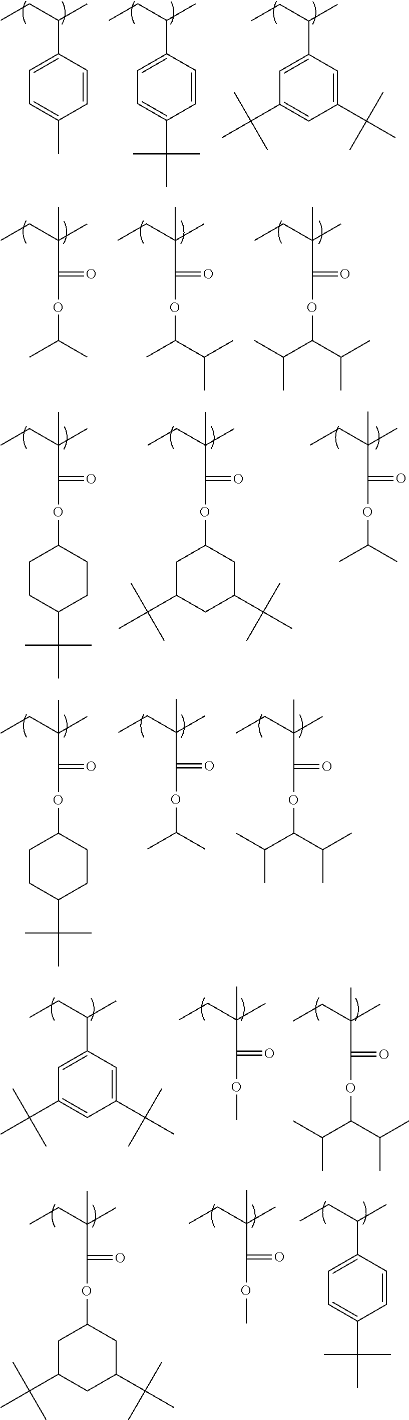

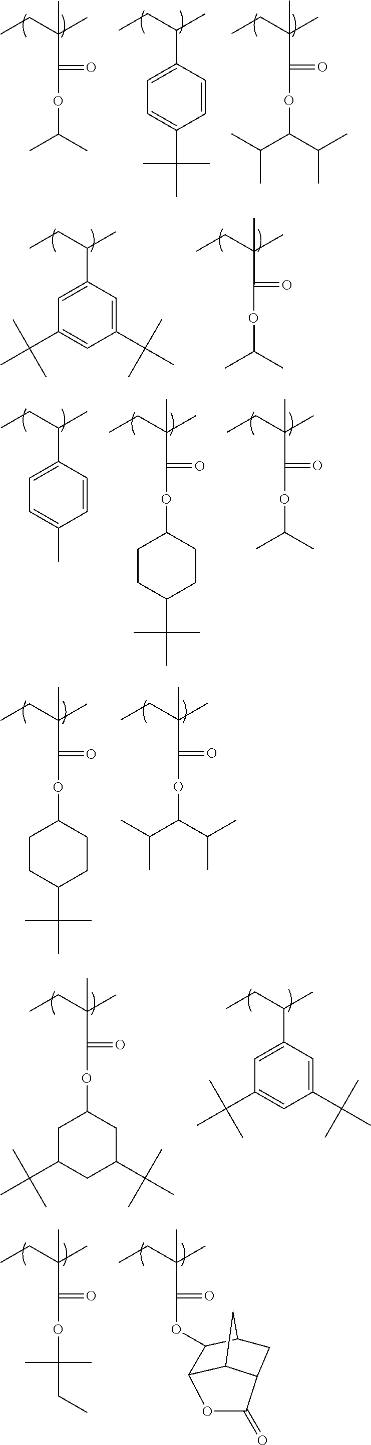

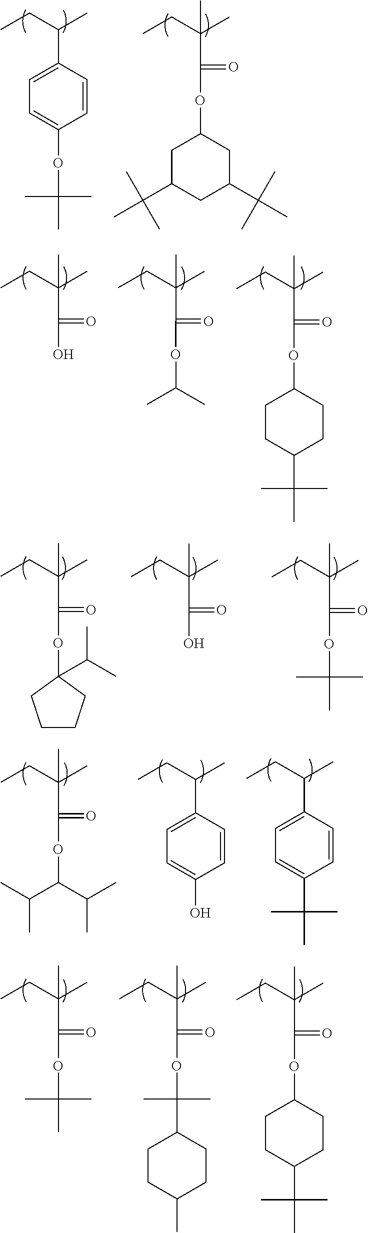

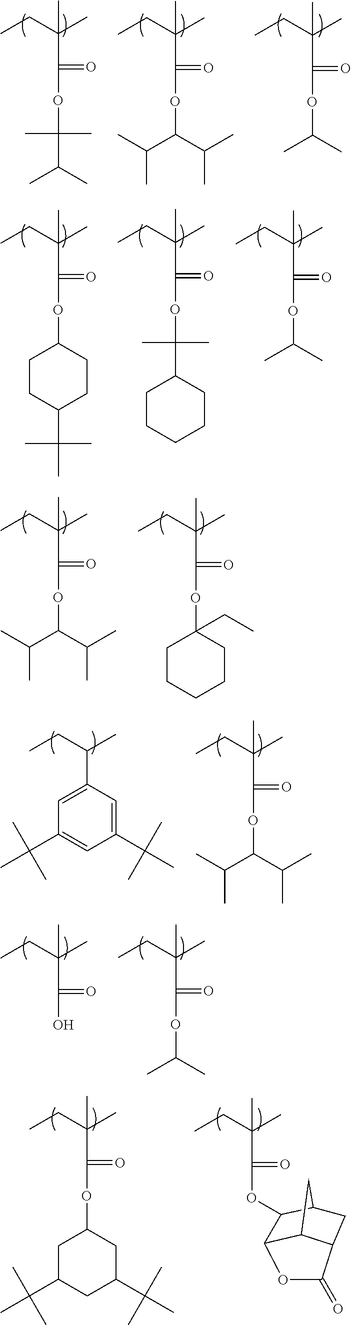

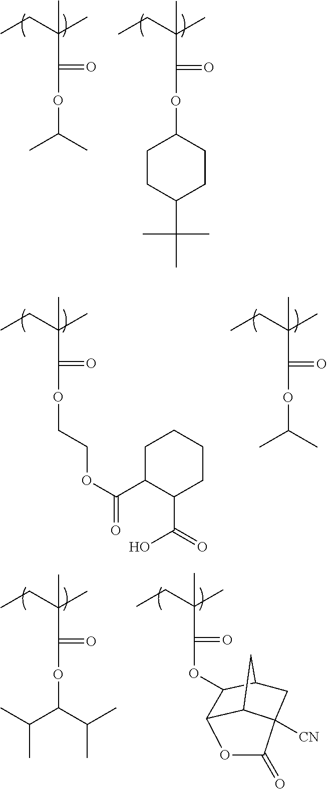

[4] (E) Combined Hydrophobic Resin Having at Least One of Fluorine Atom and Silicon Atom and Different from Resin (A) and Resin (D)

The actinic ray-sensitive or radiation-sensitive resin composition according to the present invention may contain a hydrophobic resin (hereinafter referred to as the “combined hydrophobic resin (E)” or simply referred to as a “resin (E)” in some cases) having at least one of a fluorine atom and a silicon atom and being different from the resin (A) and the resin (D), particularly when applied to immersion exposure. Accordingly, when the combined hydrophobic resin (E) is unevenly distributed in the film top layer and the immersion medium is water, the static/dynamic contact angle of water on the resist film surface may be improved, thereby improving an immersion liquid follow-up property.

It is preferred that the combined hydrophobic resin (E) is designed to be unevenly distributed at the interface as described above, but unlike a surfactant, the combined hydrophobic resin (E) does not necessarily have a hydrophilic group in the molecule thereof, and may not contribute to the mixing of polar/non-polar materials homogeneously.

The combined hydrophobic resin (E) includes a fluorine atom and/or a silicon atom. The fluorine atom and/or the silicon atom in the combined hydrophobic resin (E) may be included in the main chain of the resin, and may be included in the side chain thereof

When the combined hydrophobic resin (E) includes a fluorine atom, a resin having an alkyl group having a fluorine atom, a cycloalkyl group having a fluorine atom, or an aryl group having a fluorine atom is preferred as a partial structure having a fluorine atom.

The alkyl group (having preferably 1 to 10 carbon atoms, and more preferably 1 to 4 carbon atoms) having a fluorine atom is a straight chained or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom and may further have a substituent other than a fluorine atom.

The aryl group having a fluorine atom is an aryl group in which at least one hydrogen atom in an aryl group such as a phenyl group and a naphthyl group is substituted with a fluorine atom and may further have a substituent other than a fluorine atom.

Preferred examples of the alkyl group having a fluorine atom, the cycloalkyl group having a fluorine atom and the aryl group having a fluorine atom include groups represented by the following Formulas (F2) to (F4), but the present invention is not limited thereto.

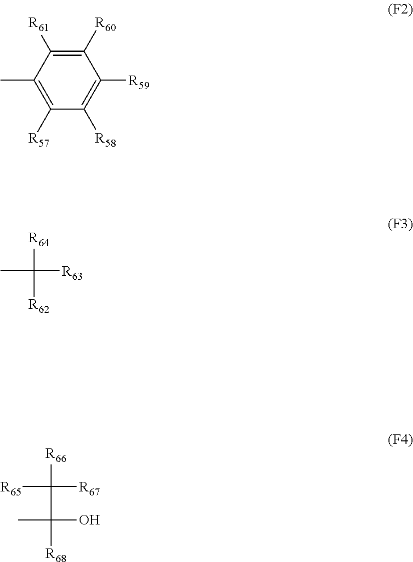

In Formulas (F2) to (F4),

each of R₅₇ to R₆₈ independently represents a hydrogen atom, a fluorine atom or an alkyl group (straight chained or branched). However, each of at least one of R₅₇ to R₆₁, at least one of R₆₂ to R₆₄ and at least one of R₆₅ to R₆₈ independently represents a fluorine atom or an alkyl group (preferably having 1 to 4 carbon atoms) in which at least one hydrogen atom is substituted with a fluorine atom.

All of R₅₇ to R₆₁ and R₆₅ to R₆₇ are preferably a fluorine atom. R₆₂, R₆₃ and R₆₈ are preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be bonded to each other to form a ring.

Specific examples of the group represented by Formula (F2) include a p-fluorophenyl group, a pentafluorophenyl group, a 3,5-di(trifluoromethyl)phenyl group and the like.

Specific examples of the group represented by Formula (F3) include a trifluoromethyl group, a pentafluoropropyl group, a pentafiuoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. A hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred, and a hexafluoroisopropyl group and a heptafluoroisopropyl group are more preferred.

Specific examples of the group represented by Formula (F4) include —C(CF₃)₂OH, —C(C₂F₅)₂OH, —C(CF₃)(CH₃)OH, —CH(CF₃)OH and the like, and —C(CF₃)₂OH is preferred.

The partial structure including a fluorine atom may be bonded directly to the main chain or may be further bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more of these groups.

Hereinafter, specific examples of the repeating unit having a fluorine atom will be described, but the present invention is not limited thereto.

In the specific examples, X₁ represents a hydrogen atom, —CH₃, —F or —CF₃. X₂ represents —F or —CF₃.

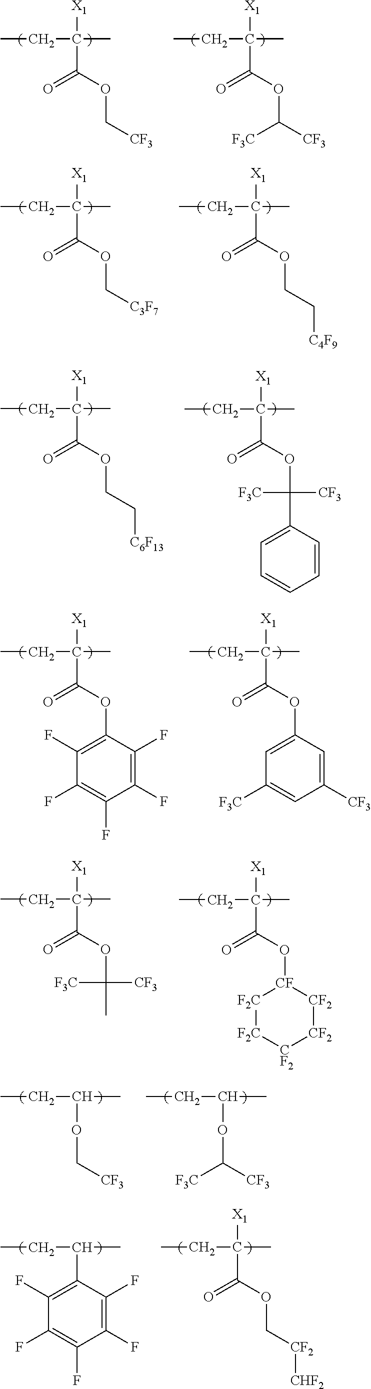

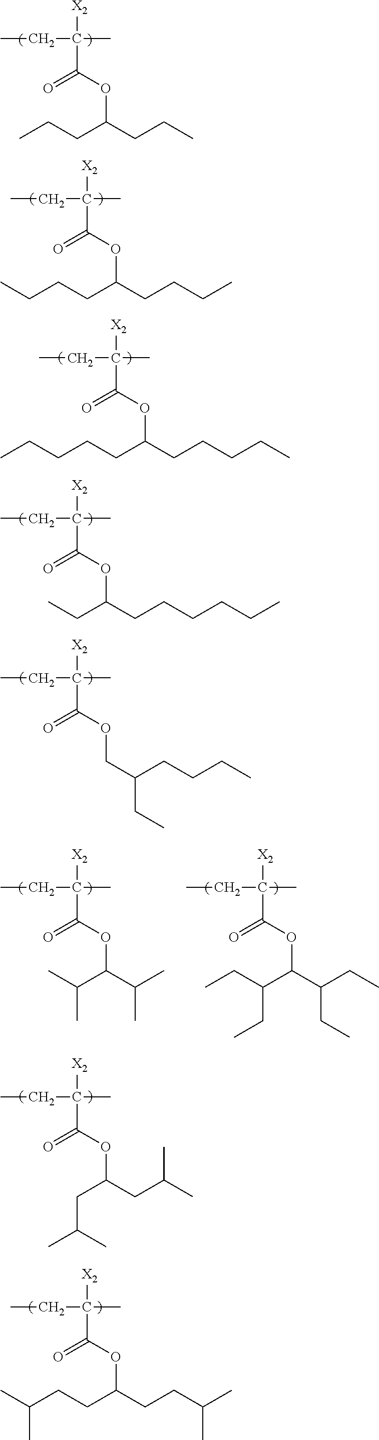

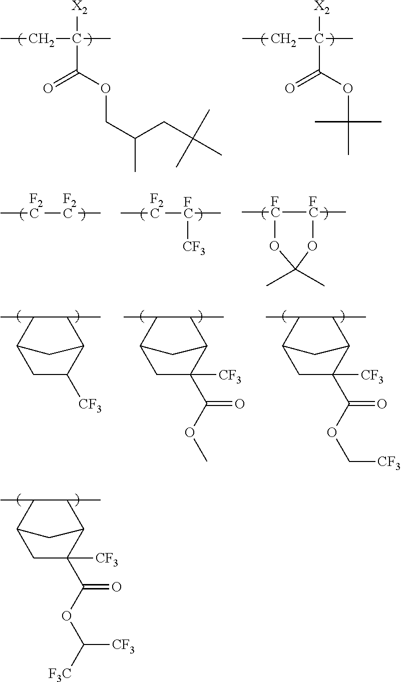

The combined hydrophobic resin (E) may contain a silicon atom. As a partial structure having a silicon atom, a resin having an alkylsilyl structure (preferably a trialkylsilyl group) or a cyclic siloxane structure is preferred.

Specific examples of the alkylsilyl structure or the cyclic siloxane structure include groups represented by the following Formulas (CS-1) to (CS-3), and the like.

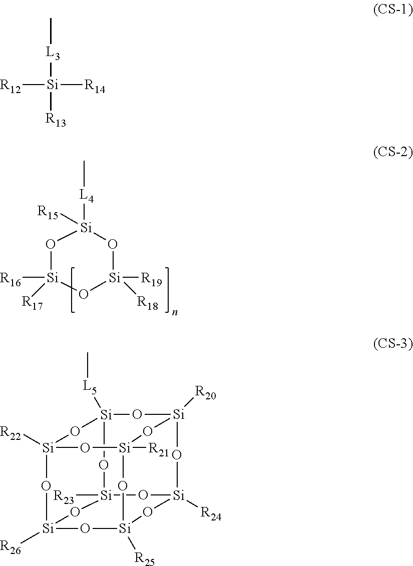

In Formulas (CS-1) to (CS-3),

each of R₁₂ to R₂₆ independently represents a straight chained or branched alkyl group (preferably having 1 to 20 carbon atoms) or a cycloalkyl group (preferably having 3 to 20 carbon atoms).

Each of L₃ to L₅ represents a single bond or a divalent linking group. Examples of the divalent linking group include a sole member or a combination of two or more members (preferably having a total carbon number of 12 or less), selected from the group consisting of an alkylene group, a phenylene group, an ether bond, a thioether bond, a carbonyl group, an ester bond, an amide bond, a urethane bond and a urea bond.

n represents an integer of 1 to 5. n is preferably an integer of 2 to 4.

Hereinafter, specific examples of the repeating unit having a group represented by Formulas (CS-1) to (CS-3) will be described, but the present invention is not limited thereto. Also, in the specific examples, X₁ represents a hydrogen atom, —CH₃, —F or —CF₃.

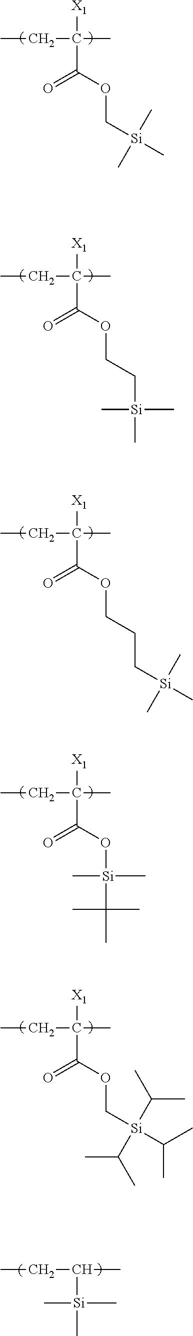

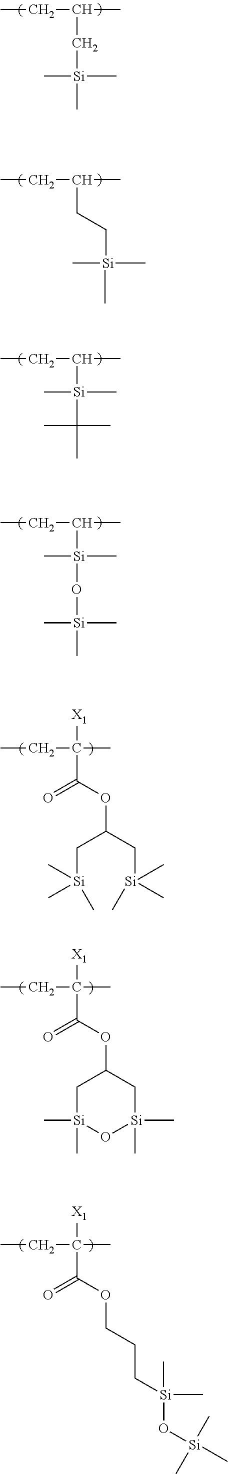

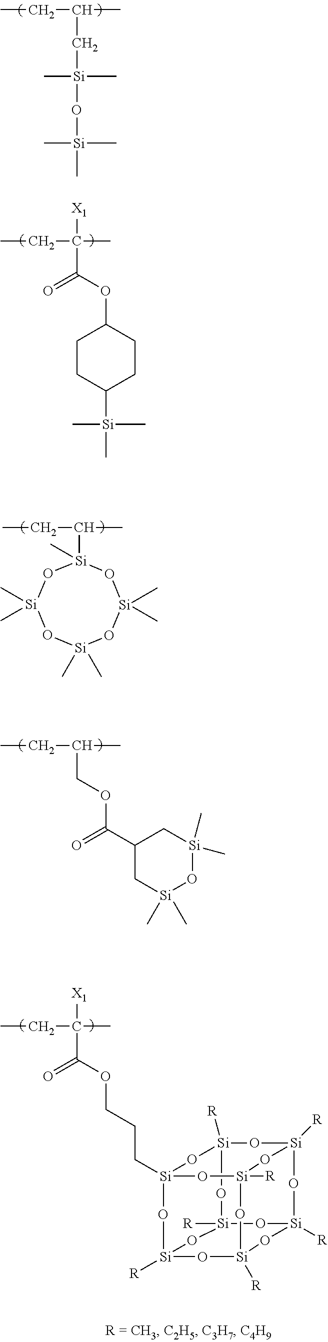

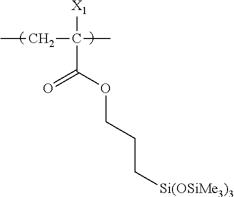

Further, the combined hydrophobic resin (E) may have at least one group selected from the group of the following (x) to (z).

(x) an acid group

(y) a group having a lactone structure, an acid anhydride group or an acid imide group, and

(z) a group capable of decomposing by the action of an acid

Examples of the acid group (x) include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group and the like.

Preferred examples of the acid group include a fluorinated alcohol group (preferably hexafluoroisopropanol), a sulfonimide group and a bis(alkylcarbonyl)methylene group.

Examples of the repeating unit having the acid group (x) include a repeating unit, in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the terminal of the polymer chain by using a polymerization initiator having an acid group or a chain transfer agent at the time of polymerization, and thus all of these cases are preferred. The repeating unit having the acid group (x) may have at least one of a fluorine atom and a silicon atom.

The content of the repeating unit having the acid group (x) is preferably 1 mol % to 50 mol %, more preferably 3 mol % to 35 mol %, and still more preferably 5 mol % to 20 mol %, based on all the repeating units in the combined hydrophobic resin (E).

Specific examples of the repeating unit having the acid group (x) will be described below, but the present invention is not limited thereto. In the formulas, Rx represents a hydrogen atom, CH₃, CF₃ or CH₂OH.

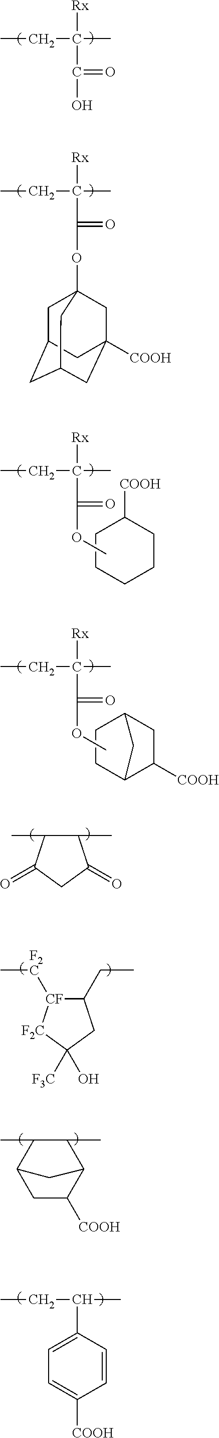

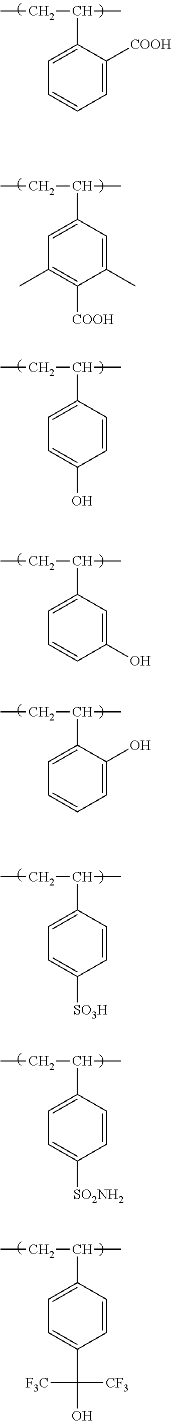

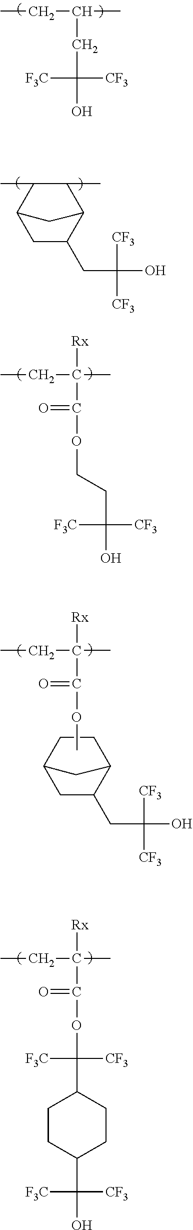

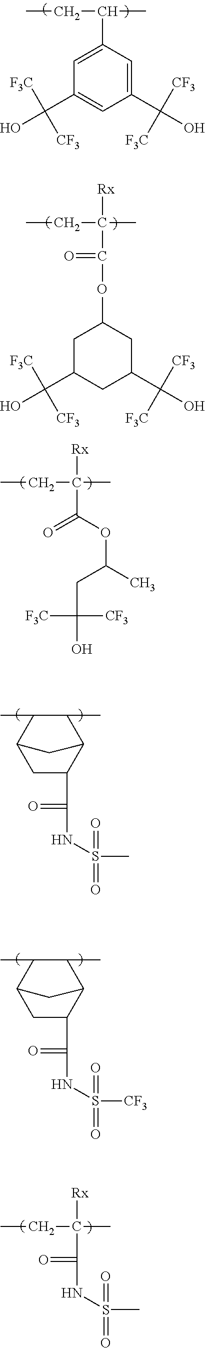

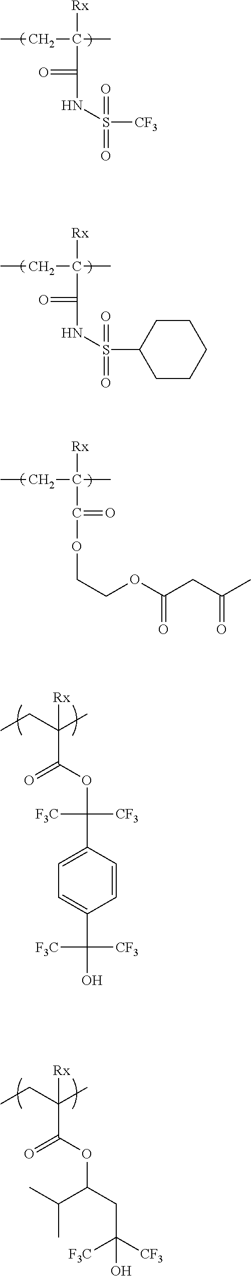

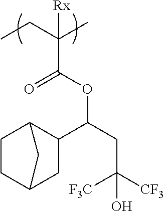

As (y) the group having a lactone structure, the acid anhydride group or the acid imide group, a group having a lactone structure is particularly preferred.

Examples of the repeating unit including these groups include a repeating unit in which the group is directly bonded to the main chain of the resin, such as a repeating unit by an acrylic acid ester or a methacrylic acid ester. Further, the repeating unit may be a repeating unit in which the group is bonded to the main chain of the resin through a linking group. In addition, the repeating unit may be introduced into the terminal of the resin by using a polymerization initiator or a chain transfer agent having the group at the time of polymerization.

Examples of the repeating unit having a group having a lactone structure are the same as those of the repeating unit having a lactone structure described in the paragraph of acid-decomposable resin (A).

The content of the repeating unit having a group having a lactone structure, an acid anhydride group or an acid imide group is preferably 1 mol % to 100 mol %, more preferably 3 mol % to 98 mol %, and still more preferably 5 mol % to 95 mol %, based on all the repeating units in the combined hydrophobic resin (E).

Examples of the repeating unit having (z) a group capable of decomposing by the action of an acid in the combined hydrophobic resin (E) are the same as those of the repeating unit having an acid-decomposable group exemplified in the resin (A). The repeating unit having (z) a group capable of decomposing by the action of an acid may have at least one of a fluorine atom and a silicon atom. In the hydrophobic resin (E), the content of the repeating unit having (z) a group capable of decomposing by the action of an acid is preferably 1 mol % to 80 mol %, more preferably 10 mol % to 80 mol %, and still more preferably 20 mol % to 60 mol %, based on all the repeating units in the resin (E).

The combined hydrophobic resin (E) may further have a repeating unit represented by the following Formula (III).

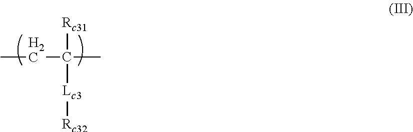

In Formula (III),

Rc₃₁ represents a hydrogen atom, an alkyl group (which may be substituted with a fluorine atom or the like), a cyano group or a —CH₂—O-Rac₂ group. In the formula, Rac₂ represents a hydrogen atom, an alkyl group or an acyl group. Rc₃₁ is preferably a hydrogen atom, a methyl group, a hydroxymethyl group and a trifluoromethyl group, and particularly preferably a hydrogen atom and a methyl group.

Rc₃₂ represents a group having an alkyl group, a cycloalkyl group, an alkenyl group, a cycloalkenyl group or an aryl group. These groups may be substituted with a fluorine atom or a group including a silicon atom.

Lc₃ represents a single bond or a divalent linking group.

In Formula (III), the alkyl group of R_{c32} is preferably a straight chained or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group, and these groups may have a substituent.

Rc₃₂ is preferably an unsubstituted alkyl group or a alkyl group substituted with a fluorine atom.

The divalent linking group of Lc₃ is preferably an alkylene group (preferably having 1 to 5 carbon atoms), an ether bond, a phenylene group or an ester bond (a group represented by —COO—).

The content of the repeating unit represented by Formula (III) is preferably 1 mol % to 100 mol %, more preferably 10 mol % to 90 mol %, and still more preferably 30 mol % to 70 mol %, based on all the repeating units in the hydrophobic resin.

It is also preferred that the combined hydrophobic resin (E) further has a repeating unit represented by the following Formula (CII-AB).

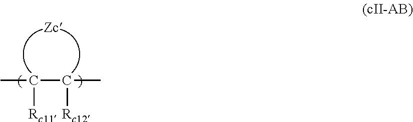

In Formula (CII-AB),

each of R_{c11}′ and R_{c12}′ independently represents a hydrogen atom, a cyano group, a halogen atom or an alkyl group.

Z_{c}′ represents an atomic group for forming an alicyclic structure including two carbon atoms (C—C) to which Z_{c}′ is bonded.

The content of the repeating unit represented by Formula (CII-AB) is preferably 1 mol % to 100 mol %, more preferably 10 mol % to 90 mol %, and still more preferably 30 mol % to 70 mol %, based on all the repeating units in the hydrophobic resin.

Hereinafter, specific examples of the repeating units represented by Formulas (III) and (CII-AB) will be described below, but the present invention is not limited thereto. In the formulas. Ra represents H, CH₃, CH₂OH, CF₃ or CN.

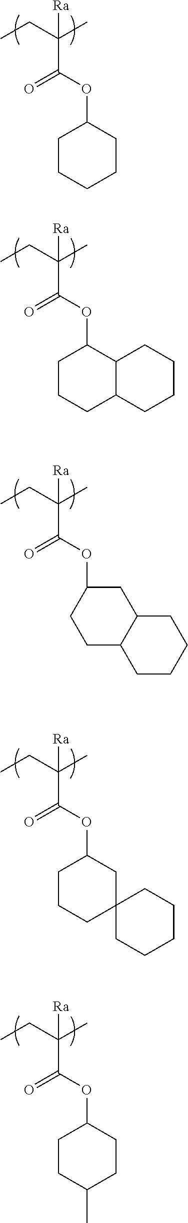

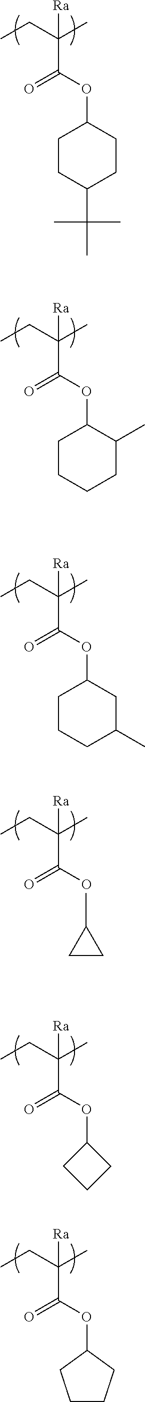

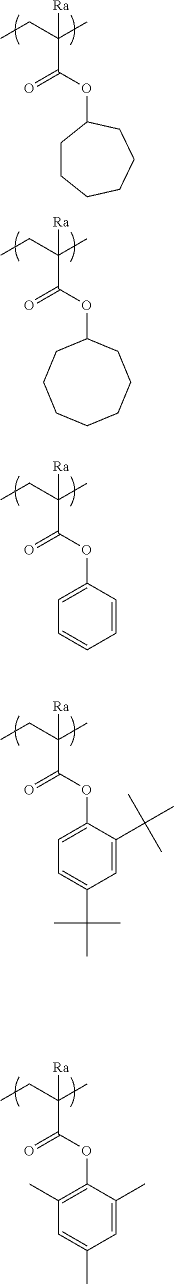

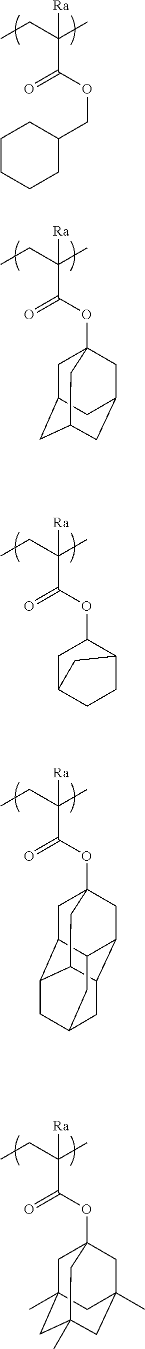

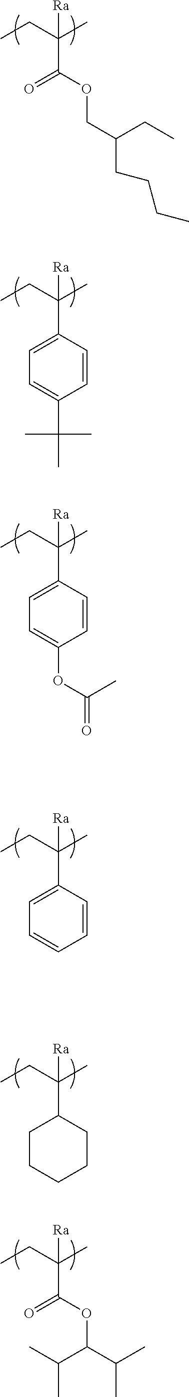

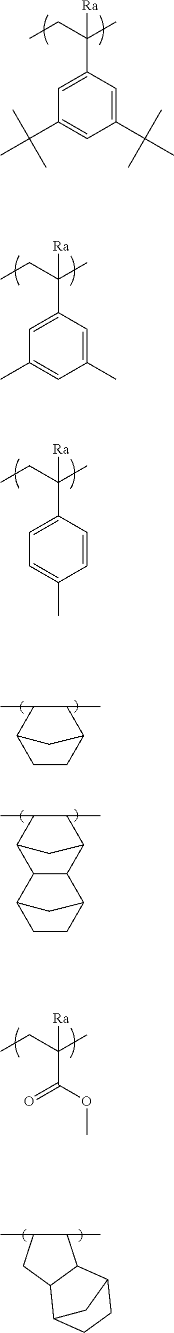

When the combined hydrophobic resin (E) has a fluorine atom, the content of the fluorine atom is preferably 5% by mass to 80% by mass, and more preferably 10% by mass to 80% by mass, based on the weight average molecular weight of the combined hydrophobic resin (E). Further, the repeating unit including a fluorine atom is preferably 10 mol % to 100 mol %, and more preferably 30 mol % to 100 mol %, based on all the repeating units included in the combined hydrophobic resin (E).

When the combined hydrophobic resin (E) has a silicon atom, the content of the silicon atom is preferably 2% by mass to 50% by mass, and more preferably 2% by mass to 30% by mass, based on the weight average molecular weight of the combined hydrophobic resin (E). Further, the repeating unit including a silicon atom is preferably 10 mol % to 100 mol %, and more preferably 20 mol % to 100 mol %, based on all the repeating units included in the combined hydrophobic resin (E).

The standard polystyrene-equivalent weight average molecular weight of the combined hydrophobic resin (E) is preferably 1,000 to 100,000, more preferably 1,000 to 50,000, and still more preferably 2,000 to 15,000.

In addition, the combined hydrophobic resin (B) may be used either alone or in combination of a plurality thereof

The content of the combined hydrophobic resin (E) in the composition is preferably 0.01% by mass to 10% by mass, more preferably 0.05% by mass to 8% by mass, and still more preferably 0.1% by mass to 5% by mass, based on the total solid content in the composition of the present invention.

In the combined hydrophobic resin (E), similarly to the resin (A), it is natural that the content of impurities such as metal is small, but the content of residual monomers or oligomer components is preferably 0.01% by mass to 5% by mass, more preferably 0.01% by mass to 3% by mass, and still more preferably 0.05% by mass to 1% by mass. Accordingly, it is possible to obtain an actinic ray-sensitive or radiation-sensitive resin composition free from extraneous substances in liquid and change in sensitivity and the like with time. In addition, in view of resolution, resist shape, side wall of resist pattern, roughness and the like, the molecular weight distribution (Mw/Mn, also referred to as polydispersity) is in a range of preferably 1 to 5, more preferably 1 to 3, and still more preferably 1 to 2.

As for the combined hydrophobic resin (E), various commercially available products may be used, and the resin (E) may be synthesized by a typical method (for example, radical polymerization). Examples of a general synthesis method include a batch polymerization method of dissolving monomer species and an initiator in a solvent and heating the solution to perform the polymerization, a dropping polymerization method of adding dropwise a solution containing monomer species and an initiator to a heated solvent over 1 to 10 hours, and the like, and a dropping polymerization method is preferred.

The reaction solvent, polymerization initiator, reaction conditions (temperature, concentration and the like) and purification method after reaction are the same as those described in the resin (A), but in the synthesis of the combined hydrophobic resin (E), the reaction concentration is preferably 30% by mass to 50% by mass.

Specific examples of the combined hydrophobic resin (E) will be described below. Further, the molar ratio of repeating units (corresponding to repeating units starting from the left), weight average molecular weight and polydispersity of each resin are shown in the following Tables 1 and 2.

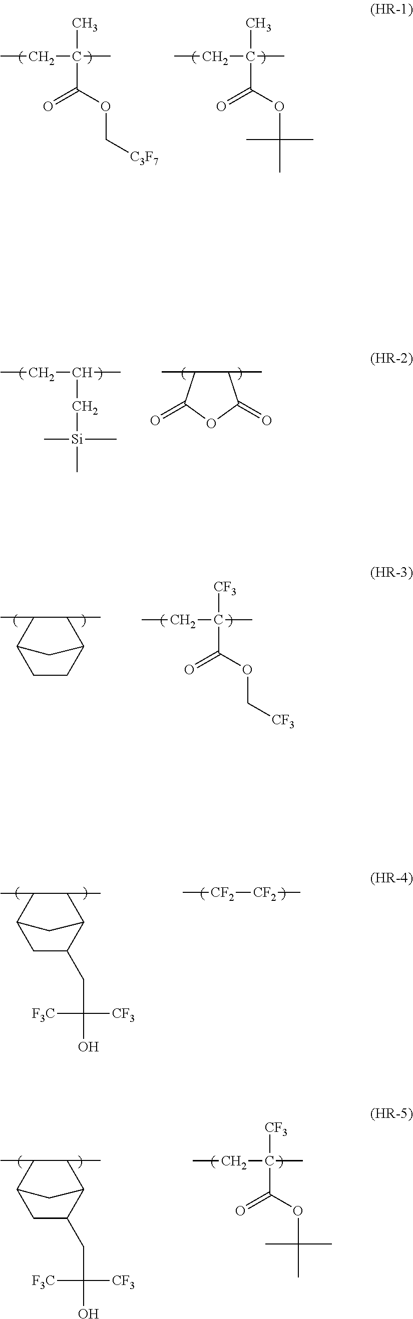

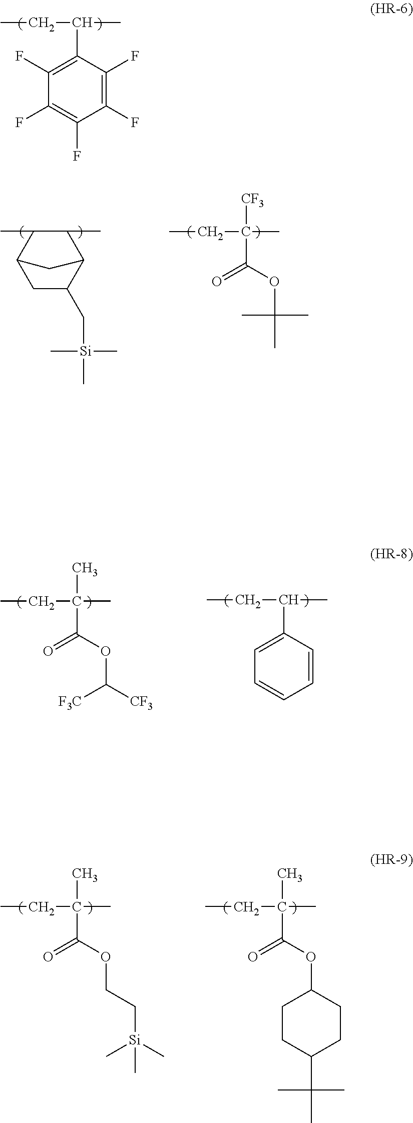

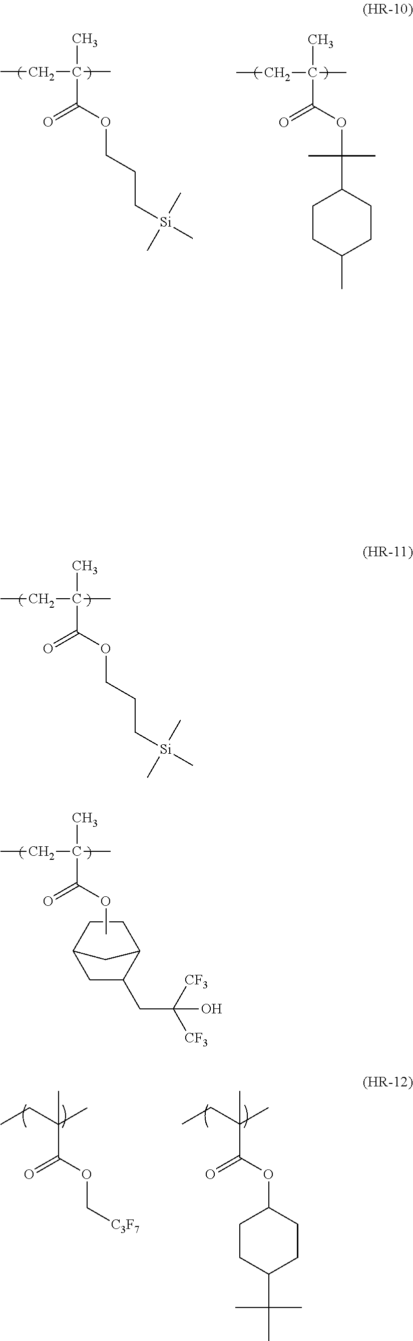

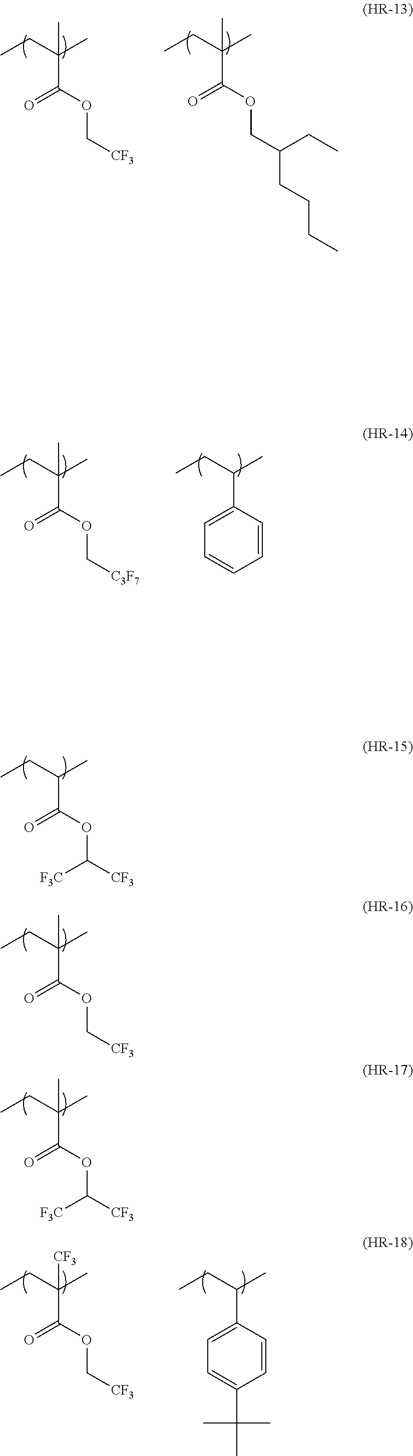

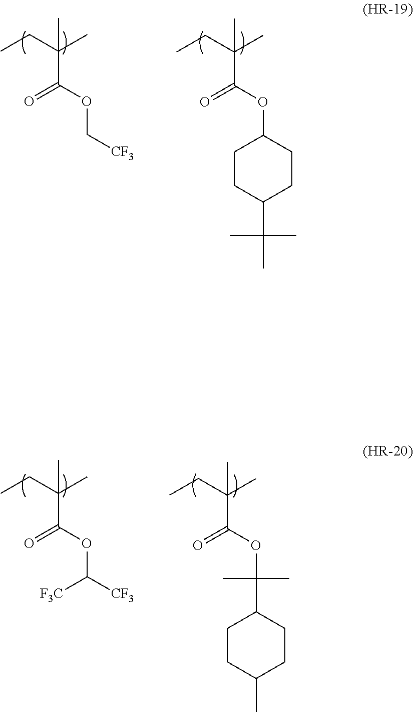

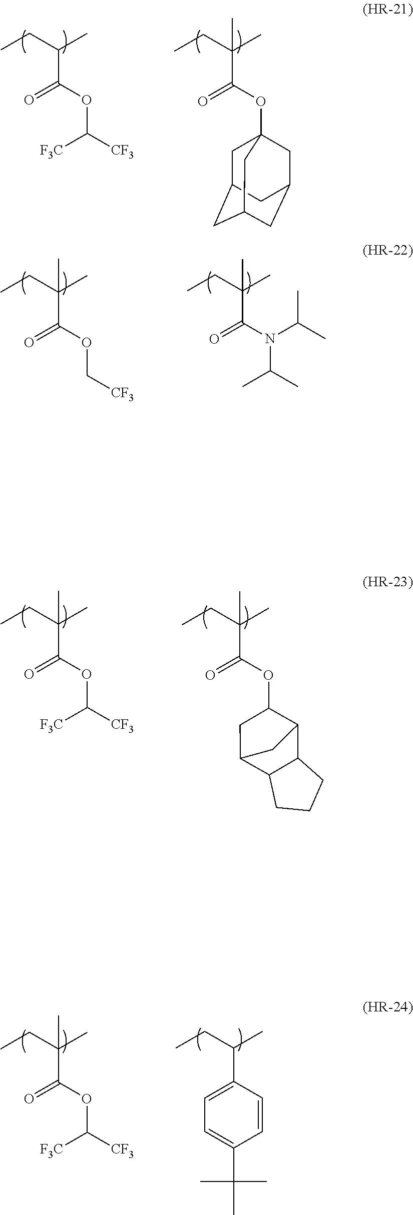

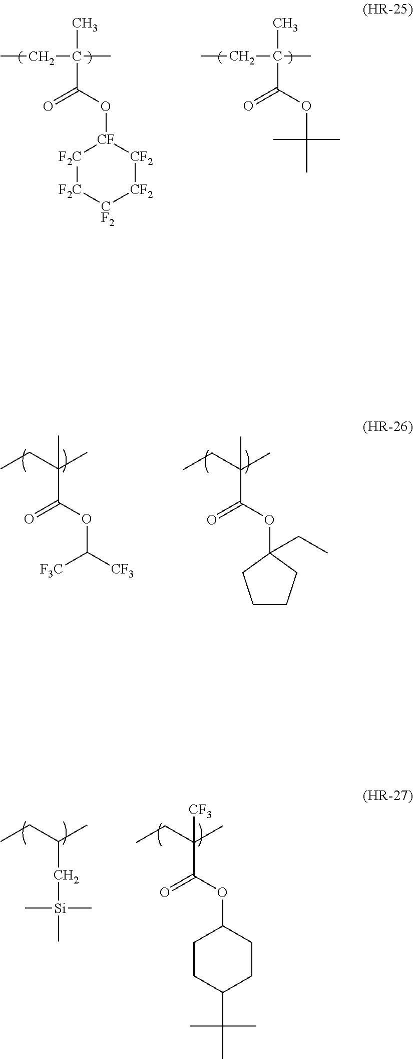

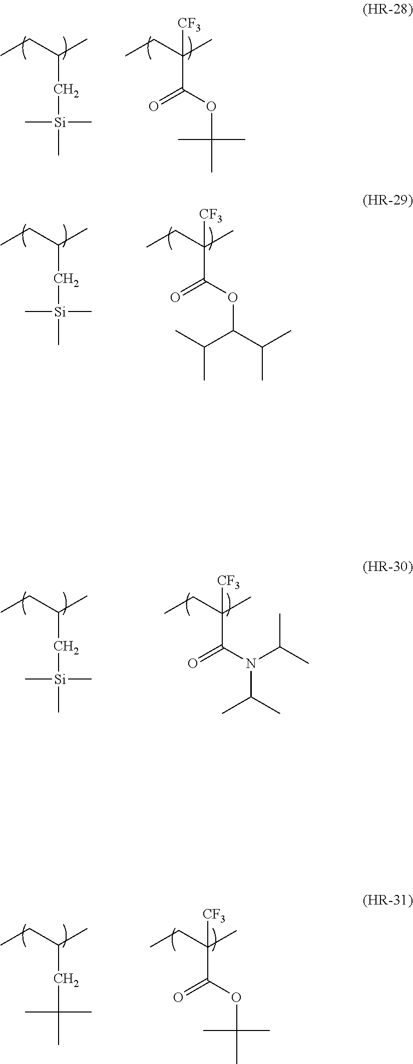

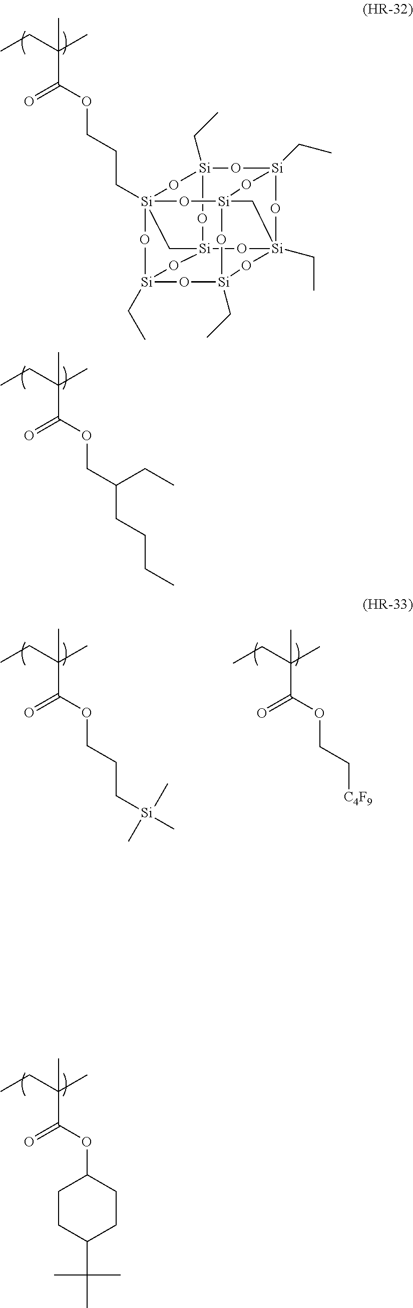

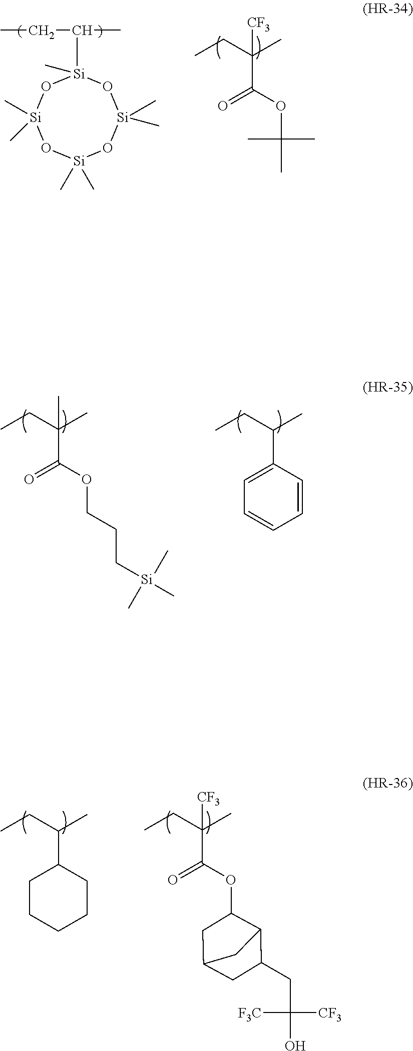

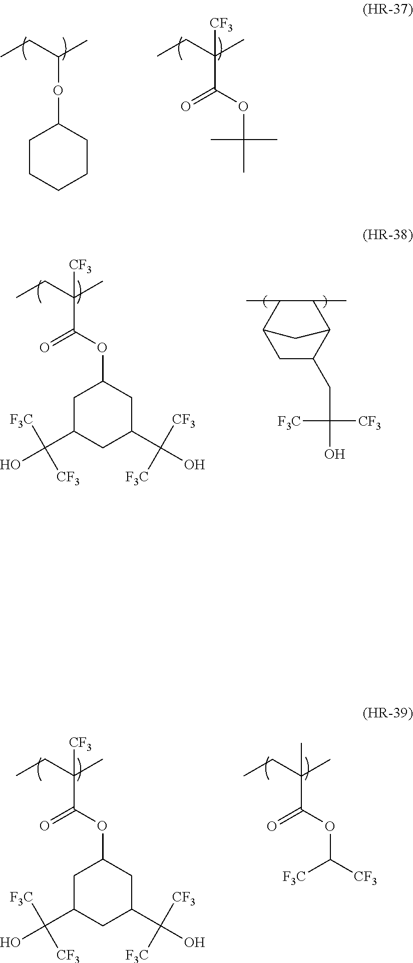

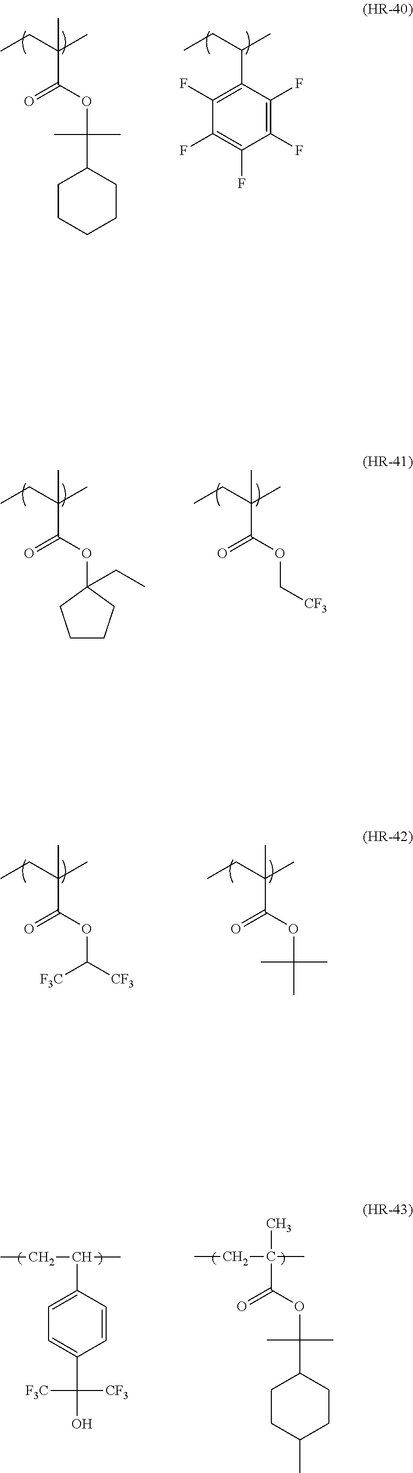

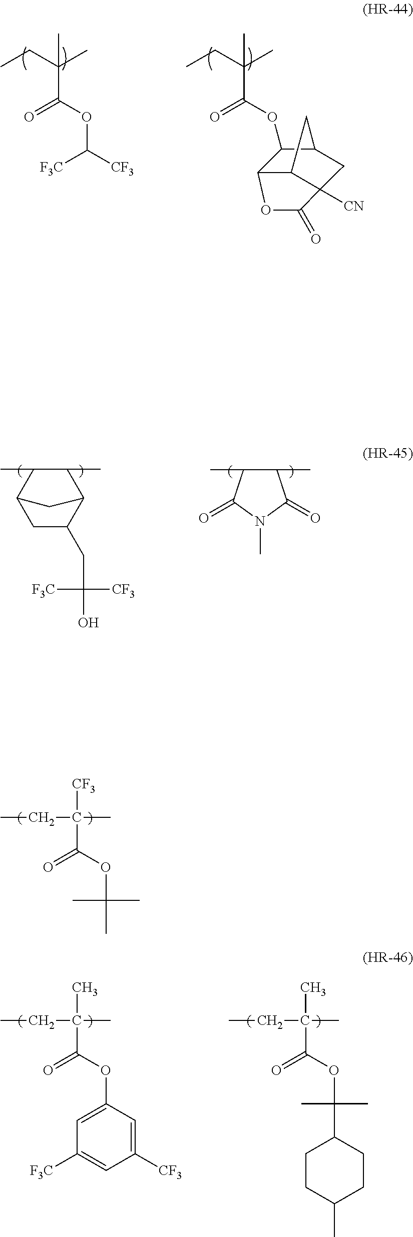

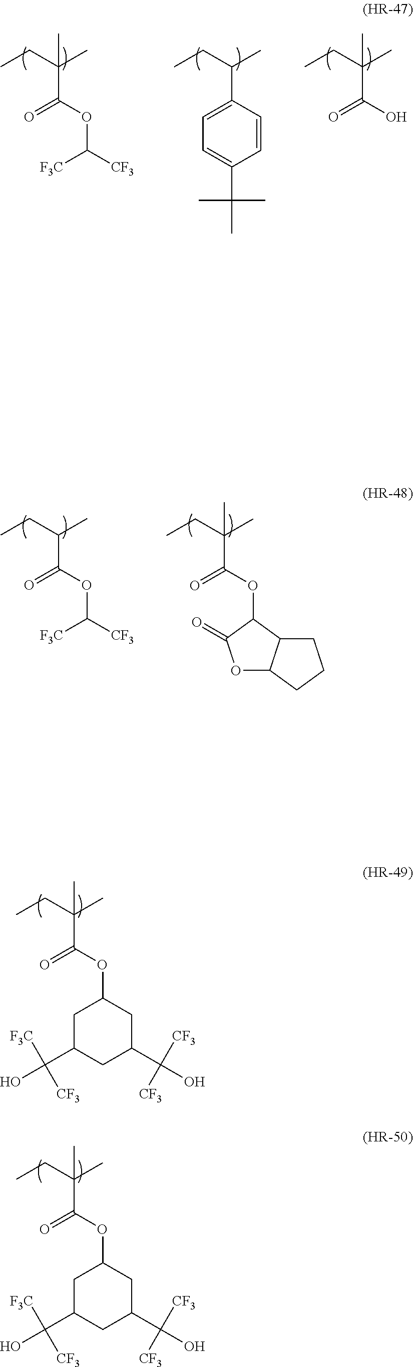

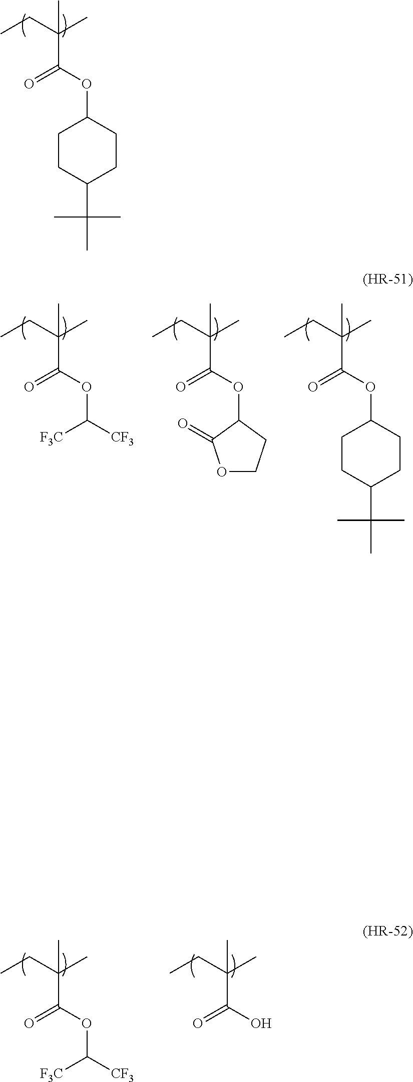

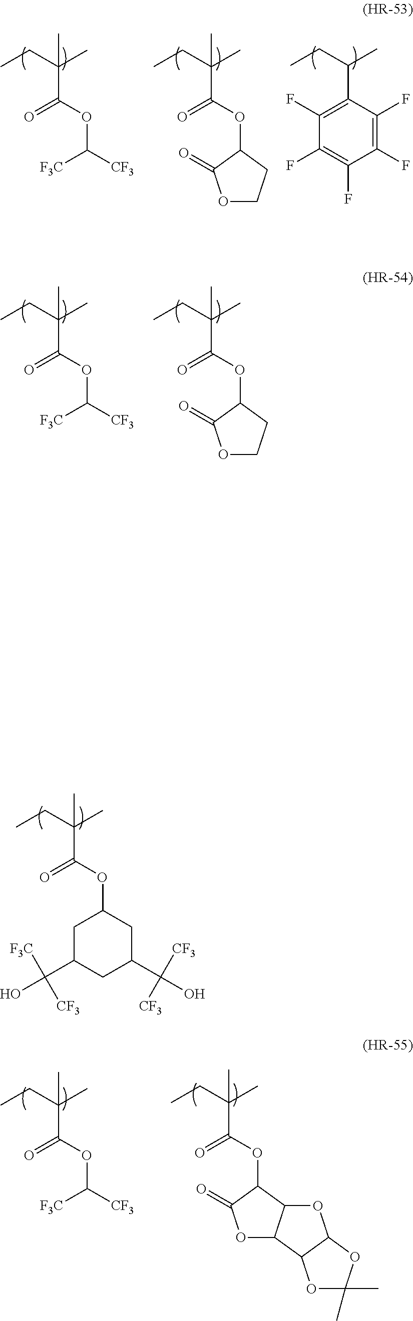

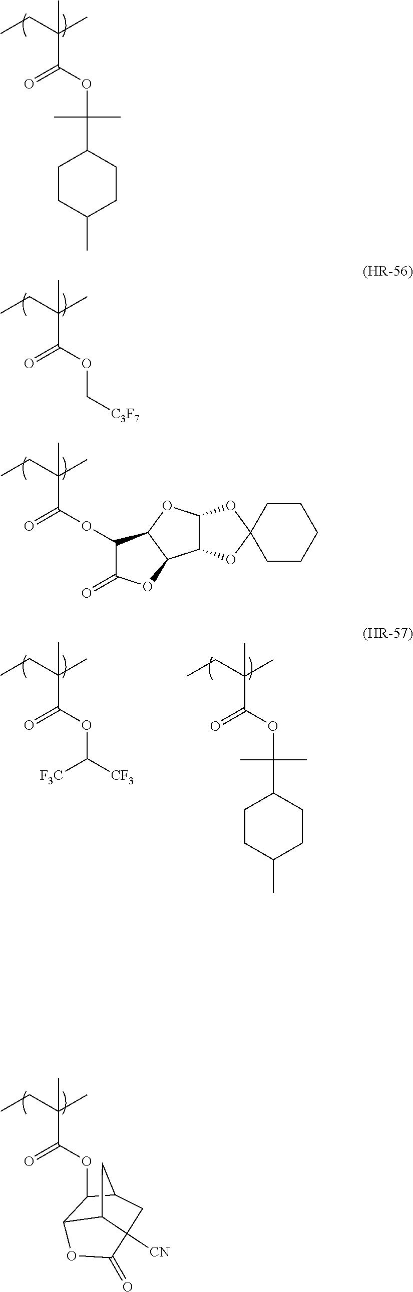

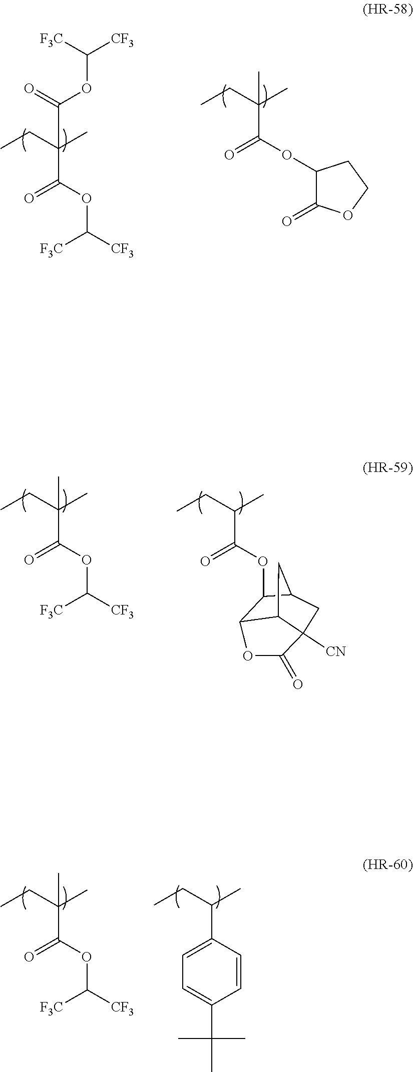

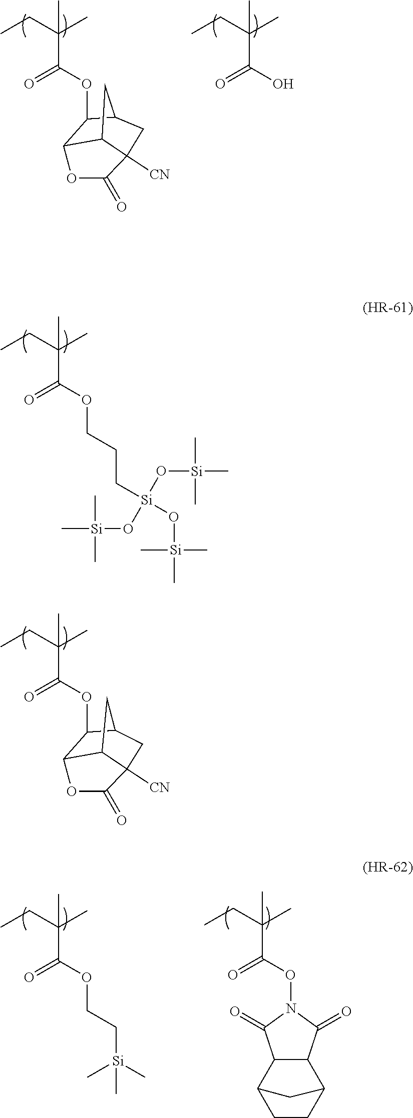

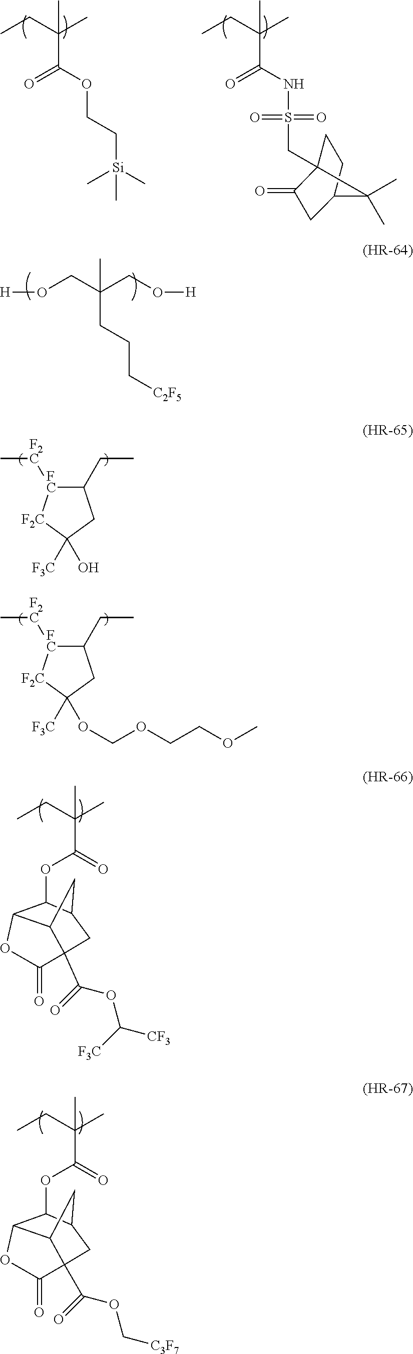

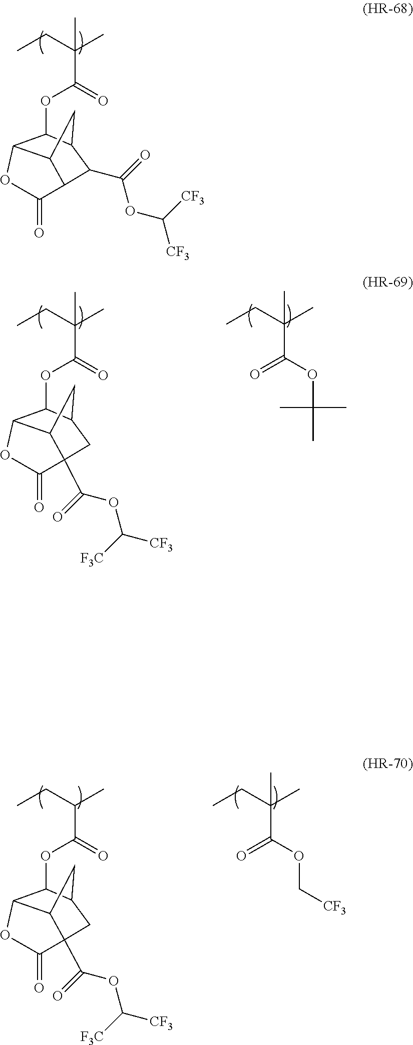

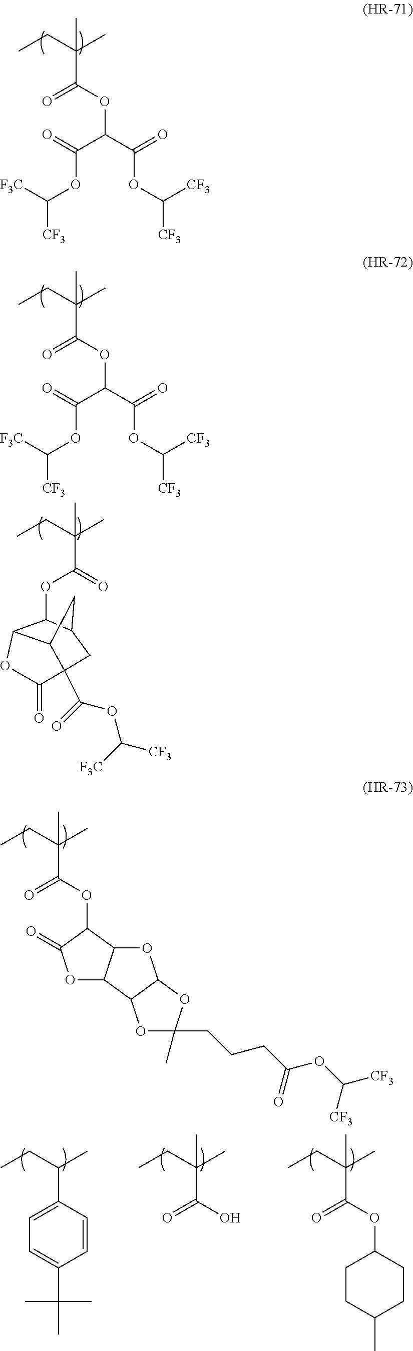

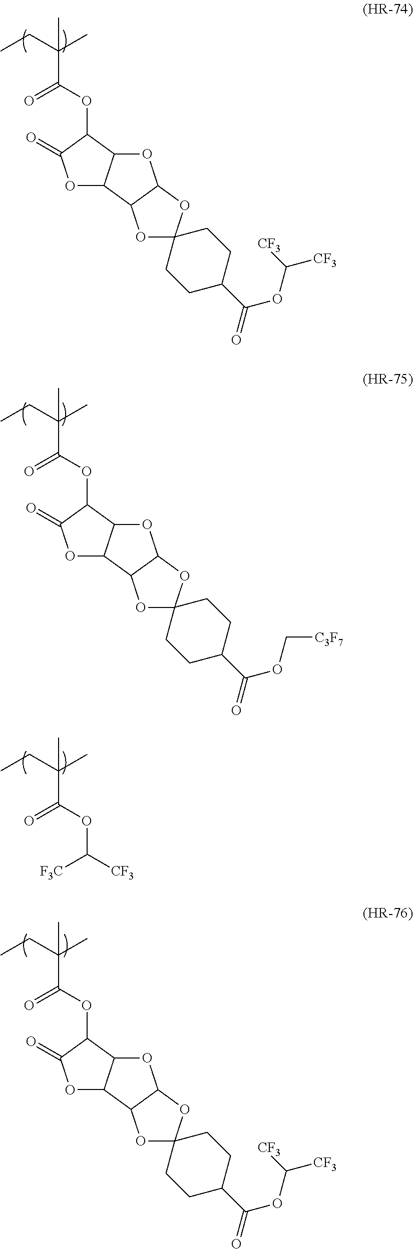

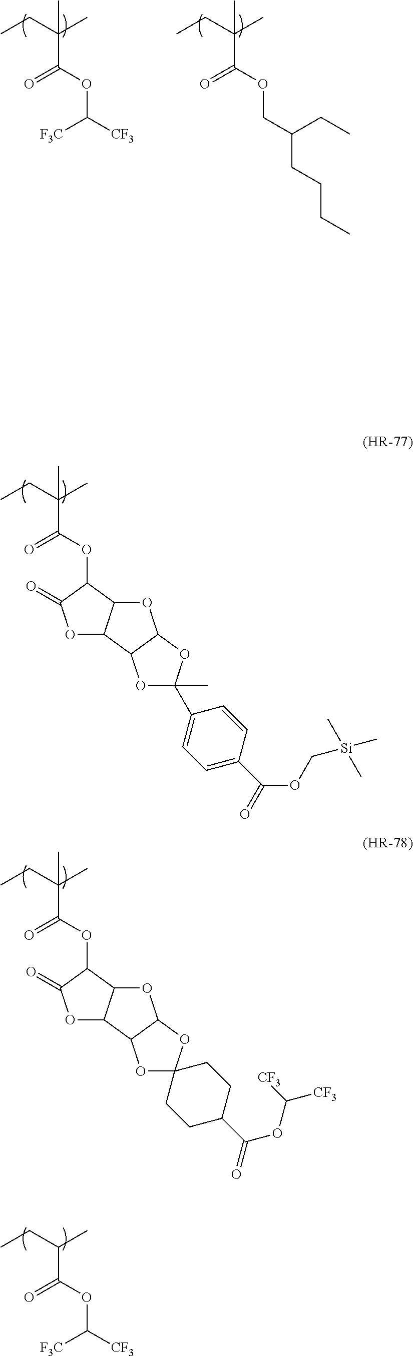

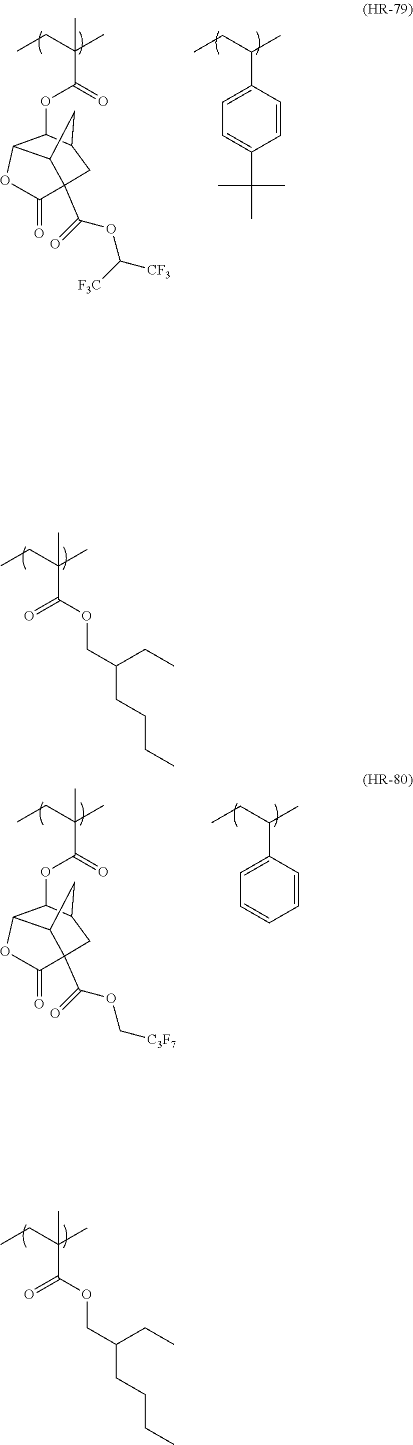

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

TABLE 2

| Resin | Composition | Mw | Mw/Mn |
|---|---|---|---|
| HR-66 | 100 | 6000 | 1.5 |
| HR-67 | 100 | 6000 | 1.4 |
| HR-68 | 1000 | 9000 | 1.5 |
| HR-69 | 60/40 | 8000 | 1.3 |
| HR-70 | 80/20 | 5000 | 1.4 |
| HR-71 | 100 | 9500 | 1.5 |
| HR-72 | 40/60 | 8000 | 1.4 |
| HR-73 | 55/30/5/10 | 8000 | 1.3 |
| HR-74 | 100 | 13000 | 1.4 |
| HR-75 | 70/30 | 8000 | 1.3 |
| HR-76 | 50/40/10 | 9500 | 1.5 |
| HR-77 | 100 | 9000 | 1.6 |
| HR-78 | 80/20 | 3500 | 1.4 |
| HR-79 | 90/8/2 | 13000 | 1.5 |
| HR-80 | 85/10/5 | 5000 | 1.5 |

[5] Solvent (C)

Examples of the solvent which may be used at the time of preparing the actinic ray-sensitive or radiation-sensitive resin composition in the present invention include an organic solvent such as alkylene glycol monoalkyl ether carboxylate, alkylene glycol monoalkyl ether, alkyl ester lactate, alkyl alkoxypropionate, cyclic lactone (preferably having 4 to 10 carbon atoms), a monoketone compound (preferably having 4 to 10 carbon atoms) which may have a ring, alkylene carbonate, alkyl alkoxyacetate and alkyl pyruvate.

Specific examples of these solvents include those described in [0441] to [0455] of U.S. Patent Application Publication No. 2008/0187860.

It is preferred that the actinic ray-sensitive or radiation-sensitive resin composition in the present invention contains a mixed solvent composed of two or more solvents containing at least one solvent having a standard boiling point (hereinafter simply referred to as the “boiling point” in some cases) at 200° C. or more from the viewpoint of reduction in bridge defects and watermark defects in an immersion exposure.

As mentioned above, it is presumed that a factor of the bridge defects may be a resin component sparingly soluble in an organic solvent-containing developer at the surface of the resist film.

It is also presumed that a component having lower surface free energy in the actinic ray-sensitive or radiation-sensitive resin composition further tends to localize at the surface of the resist film, by using a mixed solvent containing a solvent having high boiling point (e.g., boiling point of 200° C. or more).

The resin (D) in the present invention tends to be excellent in the solubility in an organic solvent and have low surface free energy.

Therefore, it is presumed that by using the mixed solvent containing a solvent having high boiling point, a content of the resin (D) at the surface part of the resist film is increased, the solubility of the surface of the resist pattern in an organic solvent-containing developer, and thereby the component sparingly soluble in an organic solvent-containing developer, which may be a factor of the bridge defects can be dissolved and removed.

Also, by using the above mixed solvent, the resist film surface uneven distribution of the resin (D) is improved, and thereby a receding contact angle may be improved. As a result, watermark defects may be reduced at the time of immersion exposure.

The content of the solvent having a standard boiling point of 200° C. or more in the mixed solvent is preferably 1% by mass or more, more preferably 3% by mass or more, and still more preferably 5% by mass. Further, the content thereof is 100% by mass or less, preferably 50% by mass or less, and still more preferably 20% by mass or less. By adjusting the content in the range, bridge defects and watermark defects may be further reduced.

The solvent having a standard boiling point of 200° C. or more is preferably represented by any one of the following Formulas (S1) to (S3).

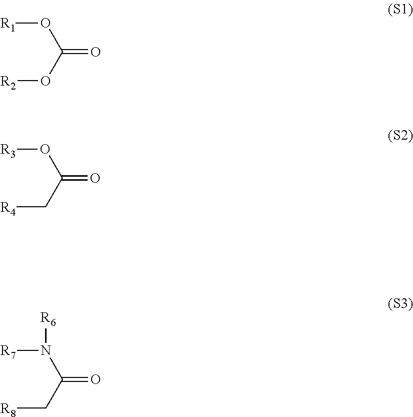

In Formulas (S1) to (S3),

each of R₁ to R₄ and R₆ to R₈ independently represents an alkyl group, a cycloalkyl group or an aryl group. R₁ and R₂, R₃ and R₄, or R₇ and R₈ may be linked to each other to form a ring.

It is preferred that R₁ to R₄ and R₆ to R₈ in Formulas (S1) to (S3) are an alkyl group, and it is more preferred that R₁ and R₂, R₃ and R₄, and R₇ and R₈ are linked to each other to form a ring, respectively.

Further, the solvent having a structure represented by Formulas (S1) to (S3) is more preferably a solvent represented by Formula (S1) or (S2), and most preferably a solvent represented by Formula (S1).

Preferred examples of the solvent having a structure represented by Formulas (S1) to (S3) include a solvent having a lactone structure, such as γ-butyrolactone (standard boiling point: 203° C.), a solvent having an alkylene carbonate structure, such as ethylene carbonate (standard boiling point: 244° C.), propylene carbonate (standard boiling point: 242° C.) and butylene carbonate (standard boiling point: 251° C.), N-methylpyrrolidone (standard boiling point: 203° C.) and the like. Among them, the solvent is still more preferably a solvent having a lactone structure and a solvent having an alkylene carbonate structure, particularly preferably γ-butyrolactone and propylene carbonate, and most preferably propylene carbonate.

In the present invention, the solvent having a standard boiling point at less than 200° C., which the solvent (C) may contain, is not particularly limited, but examples thereof include the following solvent containing a hydroxyl group, a solvent containing no hydroxyl group, and the like.

Examples of the solvent containing a hydroxyl group include alkylene glycol monoalkyl ether, alkyl lactate and the like, and for example, ethylene glycol, ethylene glycol monomethyl ether, ethylene glycol monoethyl ether, propylene glycol, propylene glycol monomethyl ether (PGME, another name 1-methoxy-2-propanol), propylene glycol monoethyl ether, ethyl lactate and the like are preferred, and among them, propylene glycol monomethyl ether and ethyl acetate are particularly preferred.

Examples of the solvent containing no hydroxyl group include alkylene glycol monoalkyl ether acetate, alkyl alkoxypropionate, a monoketone compound which may contain a ring, a cyclic lactone, alkyl acetate and the like, and for example, propylene glycol monomethyl ether acetate (PGMEA, another name 1-methoxy-2-acetoxypropane), ethyl ethoxypropionate, 2-heptanone, cyclohexanone, butyl acetate, N,N-dimethylacetamide, dimethyl sulfoxide and the like are preferred, and among them, propylene glycol monomethyl ether acetate, ethylethoxy propionate, 2-heptanone, cyclohexanone and butyl acetate are particularly preferred, and propylene glycol monomethyl ether acetate, ethylethoxy propionate, 2-heptanone and cyclohexanone are most preferred.

The mixing ratio (by mass) of the solvent containing a hydroxyl group to the solvent containing no hydroxyl group is 1/99 to 99/1, preferably 10/90 to 90/10, and more preferably 20/80 to 60/40. A mixed solvent in which the solvent containing no hydroxyl group is contained in an amount of 50% by mass or more is particularly preferred in view of coating uniformity.

The solvent (C) preferably contains propylene glycol monomethyl ether acetate. The solvent (C) is more preferably a mixed solvent including a solvent having a standard boiling point of 200° C. or more, a solvent containing a hydroxyl group, and a solvent containing no hydroxyl group, and still more preferably a mixed solvent including a solvent having a standard boiling point of 200° C. or more, alkylene glycol monoalkyl ether acetate and alkylene glycol monoalkyl ether.

[6-1] (N) Basic Compound or Ammonium Salt Compound Whose Basicity Decreases Upon Irradiation with Actinic Ray or Radiation

The actinic ray-sensitive or radiation-sensitive resin composition in the present invention preferably contains a basic compound or an ammonium salt compound (hereinafter also referred to as a “compound (N)”) whose basicity decreases upon irradiation with an actinic ray or radiation.

The compound (N) is preferably a compound (N-1) having a basic functional group or an ammonium group and a group capable of generating an acidic functional group upon irradiation with an actinic ray or radiation. That is, the compound (N) is preferably a basic compound having a basic functional group and a group capable of generating an acidic functional group upon irradiation with an actinic ray or radiation, or an ammonium salt compound having an ammonium group and a group capable of generating an acidic functional group upon irradiation with an actinic ray or radiation.

Specifically, examples thereof include a compound in which a salt is formed by an anion resulting from elimination of a proton from an acidic functional group of a compound having a basic functional group or an ammonium group and the acidic functional group, and an onium cation, and the like.

Here, examples of the basic functional group include an atomic group including structures such as a crown ether, a primary to tertiary amine and a nitrogen-containing heterocyclic ring (pyridine, imidazole, pyrazine and the like). Further, examples of the preferred structure of an ammonium group include an atomic group including a primary to tertiary ammonium structure, a pyridinium structure, an imidazolinium structure, a pyrazinium structure and the like. In addition, the basic functional group is preferably a functional group having a nitrogen atom, and more preferably a structure having a primary to tertiary amino group, or a nitrogen-containing heterocyclic structure. In these structures, from the viewpoint of improving the basicity, it is preferred that all atoms adjacent to a nitrogen atom included in the structure are a carbon atom or a hydrogen atom. Further, from the viewpoint of improving the basicity, it is preferred that an electron-withdrawing functional group (a carbonyl group, a sulfonyl group, a cyano group, a halogen atom and the like) is not directly linked to the nitrogen atom.

Examples of the acidic functional group include a carboxylic acid group, a sulfonic acid group, a group having a —X—NH—X—(X═CO or SO₂) structure, and the like.

Examples of the onium cation include a sulfonium cation, an iodonium cation and the like. More specific examples thereof include those described as a cation moiety of Formulas (ZI) and (ZII) of the acid generator (B), and the like.

More specific examples of the compounds generated by decomposing the compound (N) or (N-1) upon irradiation with an actinic ray or radiation and whose basicity is reduced include compounds represented by the following Formulas (PA-1), (PA-II) or (PA-III), and from the viewpoint of enhancing excellent effects relating to LWR, uniformity of a local pattern dimension and DOF to a high level, the compounds represented by Formula (PA-II) or (PA-III) are particularly preferred.

First, the compounds represented by Formula (PA-I) will be described.

Q-A₁-(X)ₙ—B—R (PA-I)

In Formula (PA-I),

A₁ represents a single bond or a divalent linking group.

Q represents —SO₃H, or —CO₂H. Q corresponds to an acidic functional group generated upon irradiation with an actinic ray or radiation.

X represents —SO₂—, or —CO—.

n represents 0 or 1.

B represents a single bond, an oxygen atom, or —N(Rx)-.

Rx represents a hydrogen atom, or a monovalent organic group.

R represents a monovalent organic group having a basic functional group or a monovalent organic group having an ammonium group.

The divalent linking group in A₁ is preferably a divalent linking group having 2 to 12 carbon atoms, and examples thereof include an alkylene group, a phenylene group and the like. An alkylene group having at least one fluorine atom is more preferred, and the carbon number thereof is preferably 2 to 6, and more preferably 2 to 4. The alkylene chain may have a linking group such as an oxygen atom and sulfur atom. The alkylene group is preferably an alkylene group in which 30% to 100% of the number of the hydrogen atom is substituted with a fluorine atom, and more preferably an alkylene group in which the carbon atom bonded to the Q site has a fluorine atom. In addition, a perfluoroalkylene group is preferred, and a perfluoroethylene group, a perfluoropropylene group and a perfluorobutylene group are more preferred.

The monovalent organic group in Rx preferably has from 4 to 30 carbon atoms, and examples thereof include an alkyl group, a cycloalkyl group, an aryl group, an aralkyl group, an alkenyl group and the like.

The alkyl group in Rx may have a substituent and is preferably a straight chained or branched alkyl group having 1 to 20 carbon atoms, and the alkyl chain may have an oxygen atom, a sulfur atom or a nitrogen atom.

Further, examples of the alkyl group having a substituent particularly include a group in which a straight chained or branched alkyl group is substituted with a cycloalkyl group (for example, an adamantylmethyl group, an adamantylethyl group, a cyclohexylethyl group, a camphor residue and the like).

The cycloalkyl group in Rx may have a substituent, and is preferably a cycloalkyl group having 3 to 20 carbon atoms, and may have an oxygen atom in the ring.

The aryl group in Rx may have a substituent, and is preferably an aryl group having 6 to 14 carbon atoms.

The aralkyl group in Rx may have a substituent and is preferably an aralkyl group having 7 to 20 carbon atoms.

The alkenyl group in Rx may have a substituent, and examples thereof include a group having a double bond at an arbitrary position of the alkyl group exemplified as Rx.

Examples of a preferred partial structure of the basic functional group include a structure such as crown ether, a primary to tertiary amine, and a nitrogen-containing heterocyclic ring (pyridine, imidazole, pyrazine and the like).

Examples of the preferred partial structure of an ammonium group include a primary to tertiary ammonium structure, a pyridinium structure, an imidazolinium structure, a pyrazinium structure and the like.

Further, the basic functional group is preferably a functional group having a nitrogen atom, and more preferably a structure having a primary to tertiary amino group, or a nitrogen-containing heterocyclic structure. In these structures, from the viewpoint of improving the basicity, it is preferred that all atoms adjacent to a nitrogen atom included in the structure are a carbon atom or a hydrogen atom. In addition, from the viewpoint of improving the basicity, it is preferred that an electron-withdrawing functional group (a carbonyl group, a sulfonyl group, a cyano group, a halogen atom and the like) is not directly linked to the nitrogen atom.

The monovalent organic group in the monovalent organic group (group R) including the structure preferably has from 4 to 30 carbon atoms, examples thereof include an alkyl group, a cycloalkyl group, an aryl group, an aralkyl group, an alkenyl group and the like, and each group may have a substituent.

The alkyl group, the cycloalkyl group, the aryl group, the aralkyl group, the alkenyl group in the alkyl group, the cycloalkyl group, the aryl group, the aralkyl group and the alkenyl group including a basic functional group or an ammonium group in R are the same as the alkyl group, the cycloalkyl group, the aryl group, the aralkyl group and the alkenyl group exemplified as Rx.

Examples of the substituent which each group may have include a halogen atom, a hydroxyl group, a nitro group, a cyano group, a carboxyl group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 20 carbon atoms) and the like. The cyclic structure in the aryl group, the cycloalkyl group and the like may further have an alkyl group (preferably having 1 to 20 carbon atoms) as the substituent. The aminoacyl group may further have one or two alkyl groups (preferably having 1 to 20 carbon atoms) as the substituent.

When B is —N(Rx)-, R and Rx are preferably bonded to each other to form a ring. By forming a ring structure, the stability is improved, and storage stability of the composition using the same is improved. The number of carbon atoms forming the ring is preferably 4 to 20, and the ring may be monocyclic or polycyclic and may include an oxygen atom, a sulfur atom or a nitrogen atom in the ring. Examples of the monocyclic structure include a 4- to 8-membered ring including a nitrogen atom. Examples of the polycyclic structure include a structure composed of a combination of two monocyclic structures or three or more monocyclic structures.

The monocyclic structure and polycyclic structure may have a substituent, and preferred examples of the substituent include a halogen atom, a hydroxyl group, a cyano group, a carboxyl group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 15 carbon atoms), an acyloxy group (preferably having 2 to 15 carbon atoms), an alkoxycarbonyl group (preferably having 2 to 15 carbon atoms), an aminoacyl group (preferably having 2 to 20 carbon atoms) and the like. The cyclic structure in the aryl group, the cycloalkyl group and the like may further have an alkyl group (preferably having 1 to 15 carbon atoms) as the substituent. The aminoacyl group may further have one or two alkyl groups (preferably having 1 to 15 carbon atoms) as the substituent.

Among the compounds represented by Formula (PA-I), a compound where the Q site is a sulfonic acid may be synthesized by using a general sulfonamidation reaction. For example, the compound may be obtained by a method of selectively reacting one sulfonyl halide moiety of a bis-sulfonyl halide compound with an amine compound to form a sulfonamide bond and then hydrolyzing the other sulfonyl halide moiety, or a method of ring-opening a cyclic sulfonic anhydride through reaction with an amine compound.

Next, compounds represented by Formula (PA-II) will be described.

Q₁-X₁—NH—X₂-Q₂ (PA-II)

In Formula (PA-II),

each of Q₁ and Q₂ independently represents a monovalent organic group. However, either Q₁ or Q₂ has a basic functional group. Q₁ and Q₂ may be bonded to each other to form a ring, and the ring formed may have a basic functional group.

Each of X₁ and X₂ independently represents —CO— or —SO₂—.

In addition, —NH— corresponds to an acidic functional group generated upon irradiation with an actinic ray or radiation.

The monovalent organic group as Q₁ and Q₂ in Formula (PA-II) preferably has from 1 to 40 carbon atoms, and examples thereof include an alkyl group, a cycloalkyl group, an aryl group, an aralkyl group, an alkenyl group and the like.

The alkyl group in Q₁ and Q₂ may have a substituent and is preferably a straight chained or branched alkyl group having 1 to 30 carbon atoms, and the alkyl chain may have an oxygen atom, a sulfur atom or a nitrogen atom.

The cycloalkyl group in Q₁ and Q₂ may have a substituent, is preferably a cycloalkyl group having 3 to 20 carbon atoms, and may have an oxygen atom and a nitrogen atom in the ring.

The aryl group in Q₁ and Q₂ may have a substituent, and is preferably an aryl group having 6 to 14 carbon atoms.

The aralkyl group in Q₁ and Q₂ may have a substituent and is preferably an aralkyl group having 7 to 20 carbon atoms.

The alkenyl group in Q₁ and Q₂ may have a substituent, and examples thereof include a group having a double bond at an arbitrary position of the alkyl group.

Examples of the substituent which each group may have include a halogen atom, a hydroxyl group, a nitro group, a cyano group, a carboxyl group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 10 carbon atoms) and the like. The cyclic structure in the aryl group, the cycloalkyl group and the like may further have an alkyl group (preferably having 1 to 10 carbon atoms) as the substituent. The aminoacyl group may further have an alkyl group (preferably having 1 to 10 carbon atoms) as the substituent. Examples of the alkyl group having a substituent include a perfluoroalkyl group such as a perfluoromethyl group, a perfluoroethyl group, a perfluoropropyl group and a perfluorobutyl group.

Preferred partial structures of the basic functional group that at least one of Q₁ and Q₂ has are the same as those described as the basic functional group that R of Formula (PA-I) has.

Examples of the structure in which Q₁ and Q₂ are bonded to each other to form a ring and the ring formed has a basic functional group include a structure in which the organic groups of Q₁ and Q₂ are further bonded through an alkylene group, an oxy group, an imino group or the like.

In Formula (PA-II), at least one of X₁ and X₂ is preferably —SO₂—.

Next, compounds represented by Formula (PA-III) will be described.

Q₁-X₁—NH—X₂-A₂-(X₃)ₘ—B-Q₃ (PA-III)

In Formula (PA-III),

each of Q₁ and Q₃ independently represents a monovalent organic group. However, either Q₁ or Q₃ has a basic functional group. Q₁ and Q₃ may be bonded to each other to form a ring, and the ring formed may have a basic functional group.

Each of X₁, X₂ and X₃ independently represents —CO— or —SO₂—.

A₂ represents a divalent linking group.

B represents a single bond, an oxygen atom, or —N(Qx)-.

Qx represents a hydrogen atom, or a monovalent organic group.

When B is —N(Qx)-, Q₃ and Qx may be bonded to each other to form a ring. m represents 0 or 1.

Further, —NH— corresponds to an acidic functional group generated upon irradiation with an actinic ray or radiation.

Q₁ has the same meaning as Q₁ in Formula (PA-II).

Examples of the organic group of Q₃ are the same as those of the organic groups of Q₁ and Q₂ in Formula (PA-II).

Further, examples of the structure in which Q₁ and Q₃ are bonded to each other to form a ring and the ring formed has a basic functional group include a structure in which the organic groups of Q₁ and Q₃ are further bonded through an alkylene group, an oxy group, an imino group or the like.

The divalent linking group in A₂ is preferably a divalent linking group having 1 to 8 carbon atoms and having a fluorine atom, and examples thereof include a alkylene group having 1 to 8 carbon atoms and having a fluorine atom, a phenylene group having a fluorine atom and the like. An alkylene group having a fluorine atom is more preferred, and the number of carbon atoms is preferably 2 to 6, and more preferably 2 to 4. The alkylene chain may have a linking group such as an oxygen atom and a sulfur atom. The alkylene group is preferably an alkylene group in which 30% to 100% of the number of the hydrogen atom is substituted with a fluorine atom, preferably a perfluoroalkylene group, and particularly preferably a perfluoroalkylene group having 2 to 4 carbon atoms.

The monovalent organic group in Qx is preferably an organic group having 4 to 30 carbon atoms, and examples thereof include an alkyl group, a cycloalkyl group, an aryl group, an aralkyl group, an alkenyl group and the like. Examples of the alkyl group, cycloalkyl group, aryl group, aralkyl group and alkenyl group are the same as those for Rx in Formula (PA-I).

In Formula (PA-III), X₁, X₂ and X₃ are preferably —SO₂—.

The compound (N) is preferably a sulfonium salt compound of the compound represented by Formula (PA-I), (PA-II) or (PA-III), or an iodonium salt compound of the compound represented by Formula (PA-I), (PA-II) or (PA-III), and more preferably a compound represented by the following Formula (PA1) or (PA2).

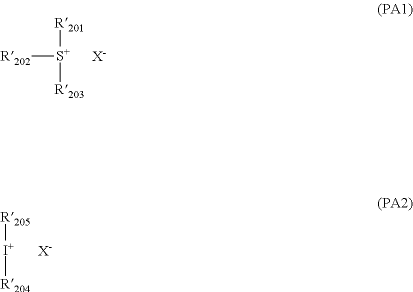

In Formula (PA1),

each of R′₂₀₁, R′₂₀₂ and R′₂₀₃ independently represents an organic group, and specific examples thereof are the same as those for R₂₀₁, R₂₀₂ and R₂₀₃ of Formula ZI in the component (B).

X⁻ represents a sulfonate anion or a carboxylate anion resulting from elimination of a hydrogen atom in the —SO₃H moiety or —COOH moiety of the compound represented by Formula (PA-I), or an anion resulting from elimination of a hydrogen atom from the —NH— moiety of the compound represented by Formula (PA-II) or (PA-III).

In Formula (PA2),

each of R₂₀₄ and R′₂₀₅ independently represents an aryl group, an alkyl group or a cycloalkyl group, and specific examples thereof are the same as those for R₂₀₄ and R₂₀₅ of Formula ZII in the component (B).

X⁻ represents a sulfonate anion or a carboxylate anion resulting from elimination of a hydrogen atom in the —SO₃H moiety or —COOH moiety of the compound represented by Formula (PA-I), or an anion resulting from elimination of a hydrogen atom from the —NH— moiety of the compound represented by Formula (PA-II) or (PA-III).

The compound (N) decomposes upon irradiation with an actinic ray or radiation to generate, for example, a compound represented by Formula (PA-I), (PA-II) or (PA-III).

The compound represented by Formula (PA-I) is a compound having a sulfonic acid group or a carboxylic acid group together with a basic functional group or an ammonium group and thereby being reduced in or deprived of the basicity or changed from basic to acidic as compared to the compound (N).

The compound represented by Formula (PA-II) or (PA-III) is a compound having an organic sulfonylimino group or an organic carbonylimino group together with a basic functional group and thereby being reduced in or deprived of the basicity or changed from basic to acidic as compared to the compound (N).

In the present invention, reduction in the basicity upon irradiation with an actinic ray or radiation means that the acceptor property for a proton (an acid generated upon irradiation with an actinic ray or radiation) of the compound (N) decreases upon the irradiation with an actinic ray or radiation. The decrease in the acceptor property means that when an equilibrium reaction of producing a noncovalent bond complex as a proton adduct from a basic functional group-containing compound and a proton takes place or when an equilibrium reaction of letting the counter cation of the ammonium group-containing compound be exchanged with a proton takes place, the equilibrium constant in the chemical equilibrium decreases.

In this manner, the compound (N) whose basicity decreases upon irradiation with an actinic ray or radiation is contained in the resist film, so that in the unexposed portion, the acceptor property of the compound (N) may be sufficiently expressed and an unintended reaction of an acid diffused from the exposed portion or the like with the resin (A) may be suppressed, whereas in the exposed portion, the acceptor property of the compound (N) decreases, and thus the intended reaction of an acid with the resin (A) more certainly occurs, and in the degree of contribution of the operation mechanism, it is assumed to be able to obtain a pattern excellent in terms of line width variation (LWR), uniformity of local pattern dimension, focus latitude (DOF) and pattern shape.

Further, the basicity may be confirmed by measuring the pH, or a calculated value may be calculated by a commercially available software.

Hereinafter, specific examples of the compound (N) capable of generating a compound represented by Formula (PA-I) upon irradiation with an actinic ray or radiation will be described, but the present invention is not limited thereto.

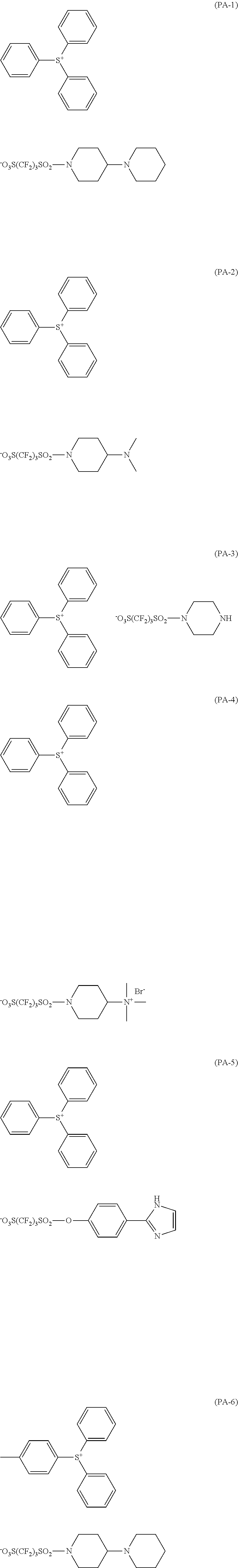

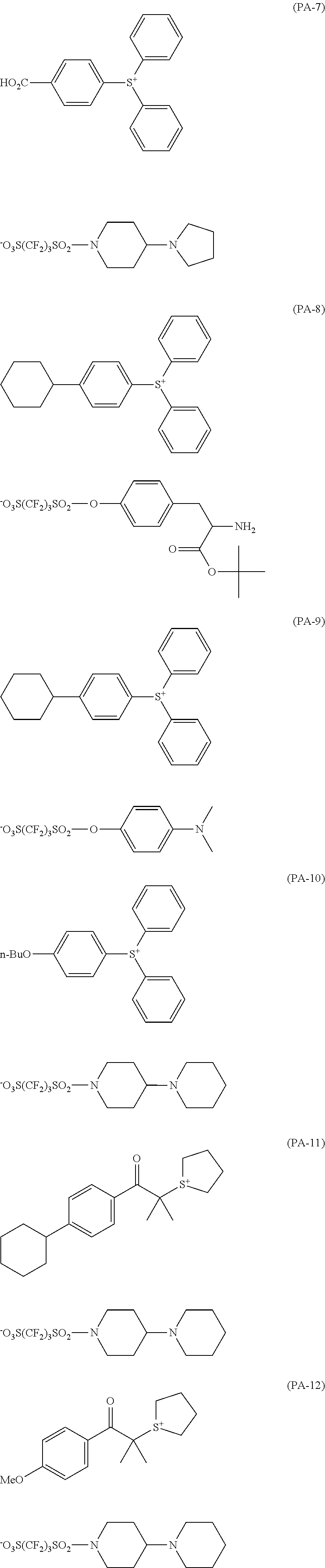

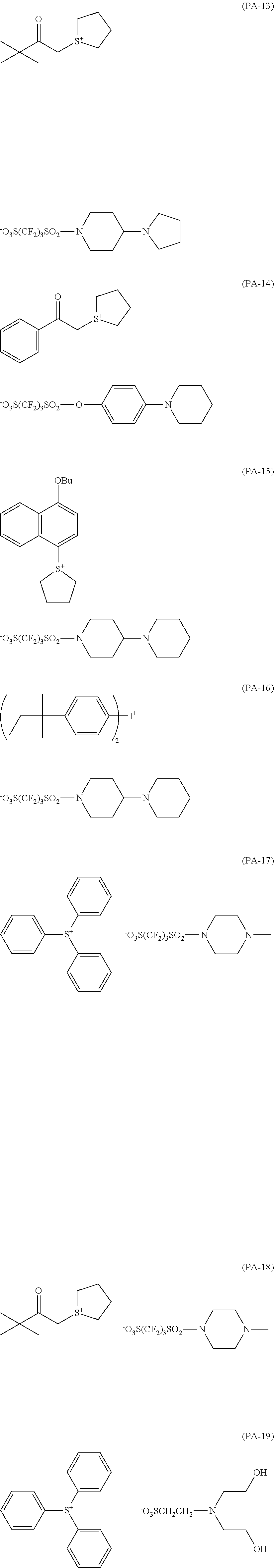

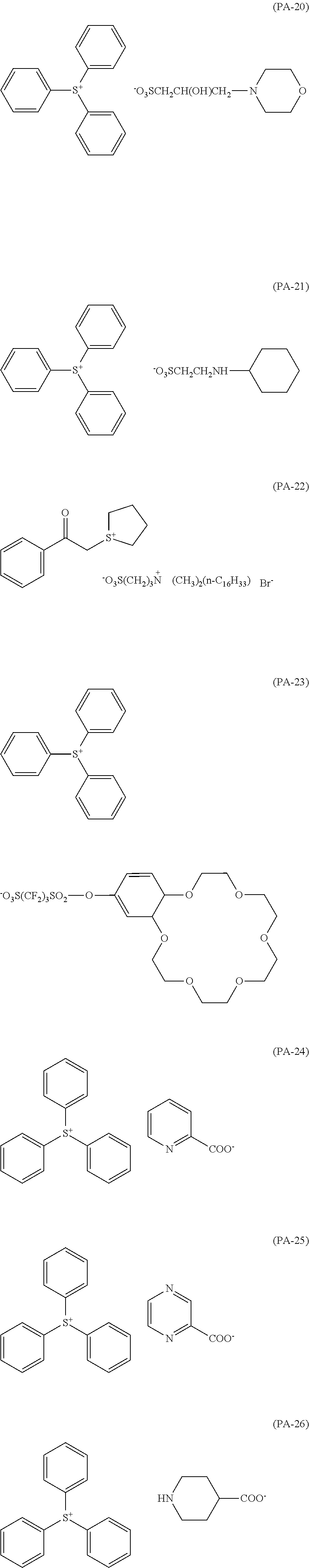

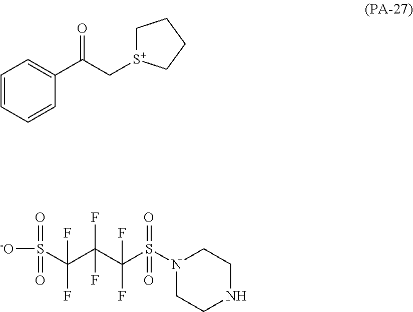

These compounds may be easily synthesized from a compound represented by Formula (PA-I) or a lithium, sodium or potassium salt thereof and a hydroxide, bromide, chloride or the like of iodonium or sulfonium, by using the salt exchange method described in Japanese National Publication of International Patent Application No. H11-501909 or Japanese Patent Application Laid-Open No. 2003-246786. Further, the synthesis may also be performed in accordance with the synthesis method described in Japanese Patent Application Laid-Open No. H7-333851.

Hereinafter, specific examples of the compound (N) capable of generating a compound represented by Formula (PA-II) or (PA-III) upon irradiation with an actinic ray or radiation will be described, but the present invention is not limited thereto.

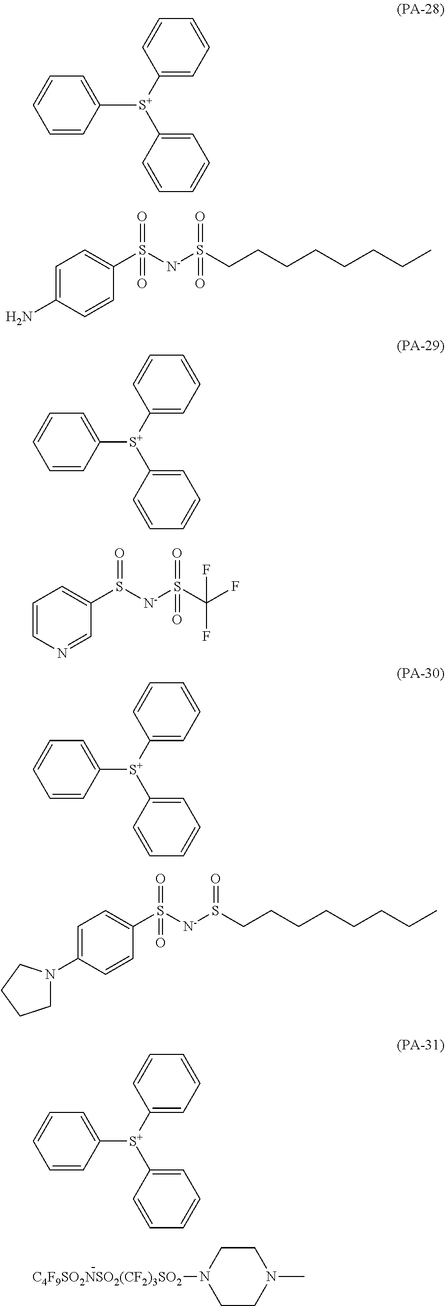

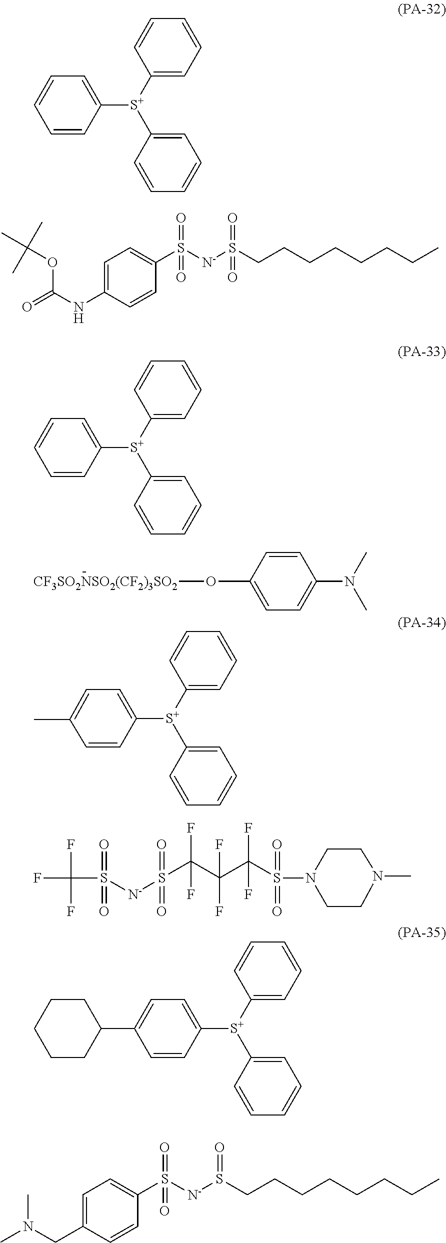

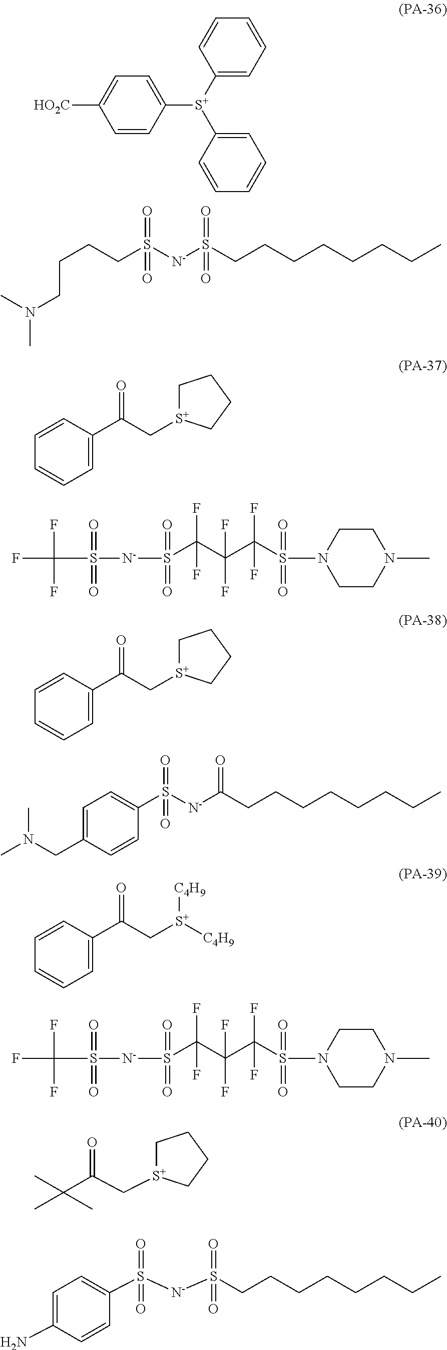

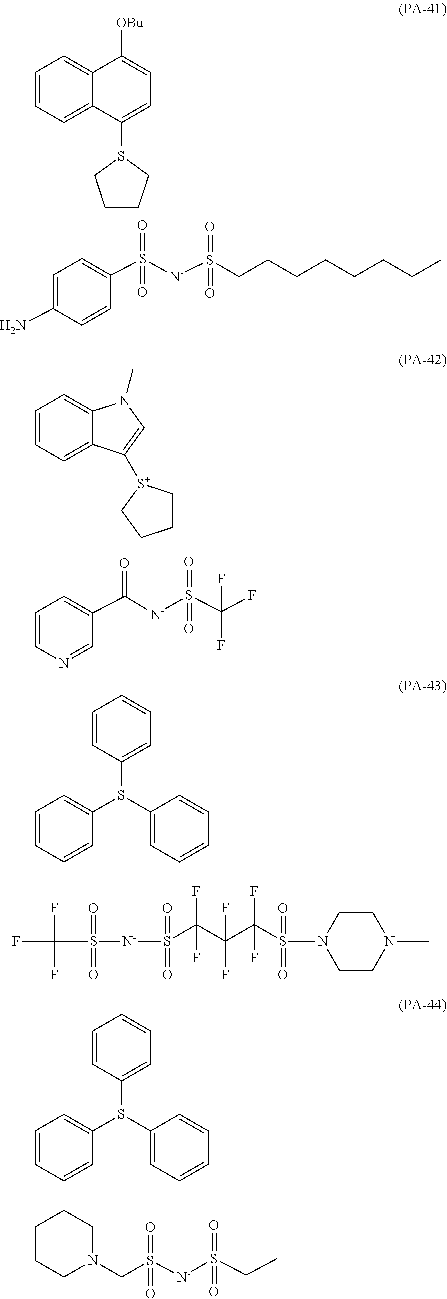

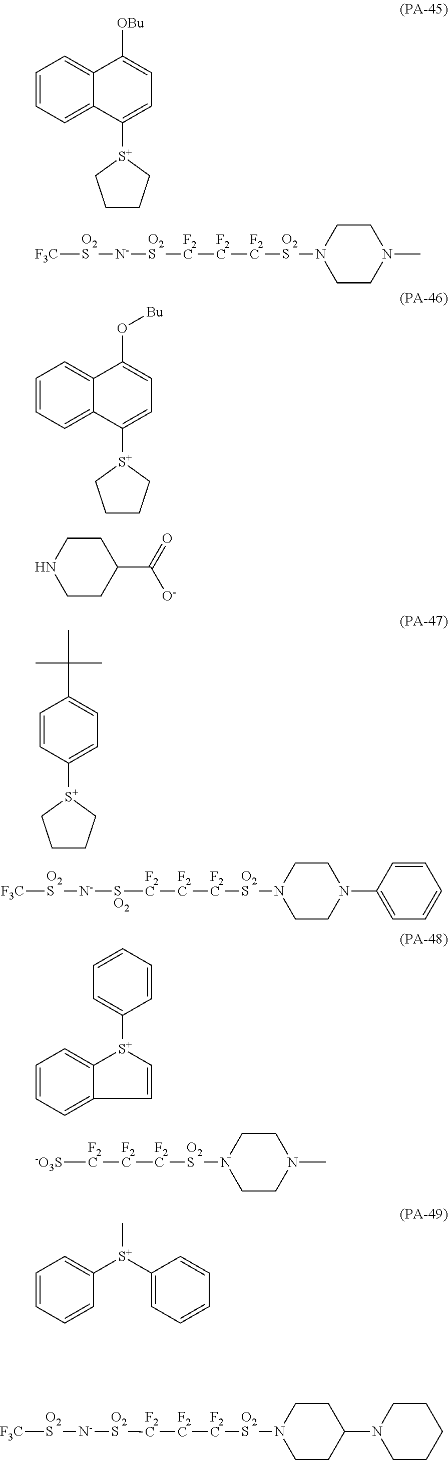

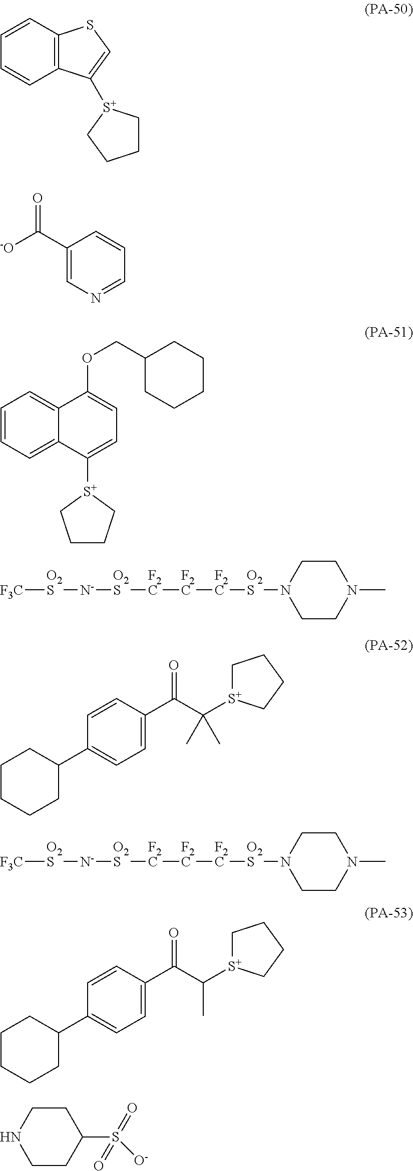

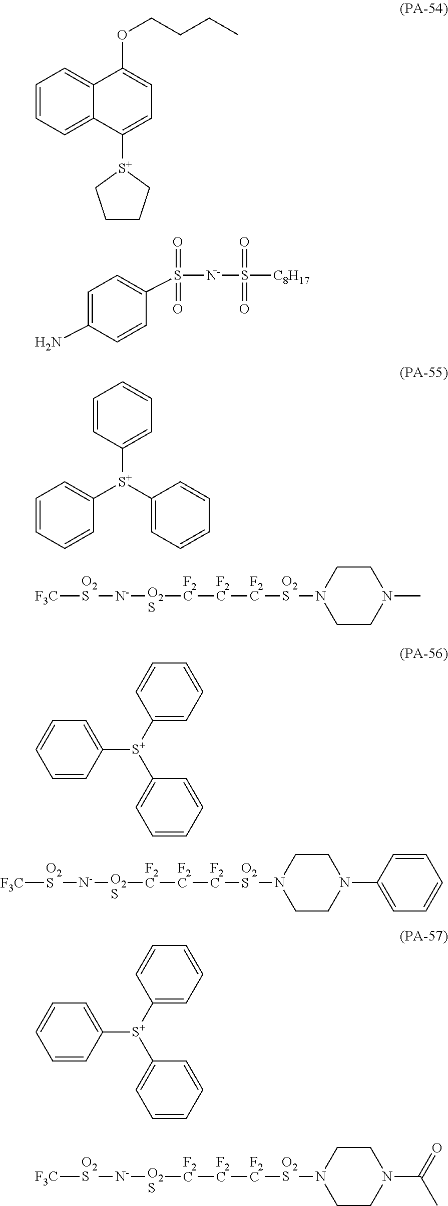

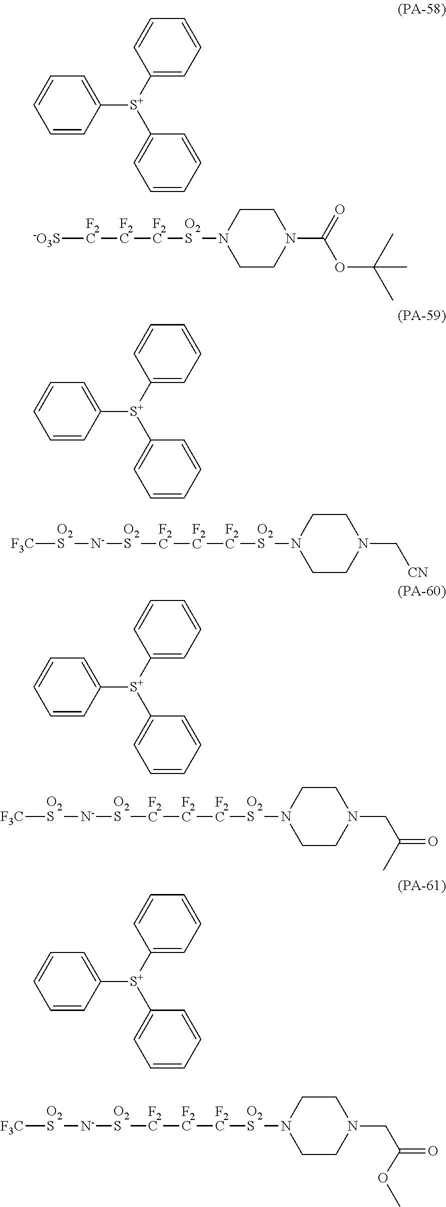

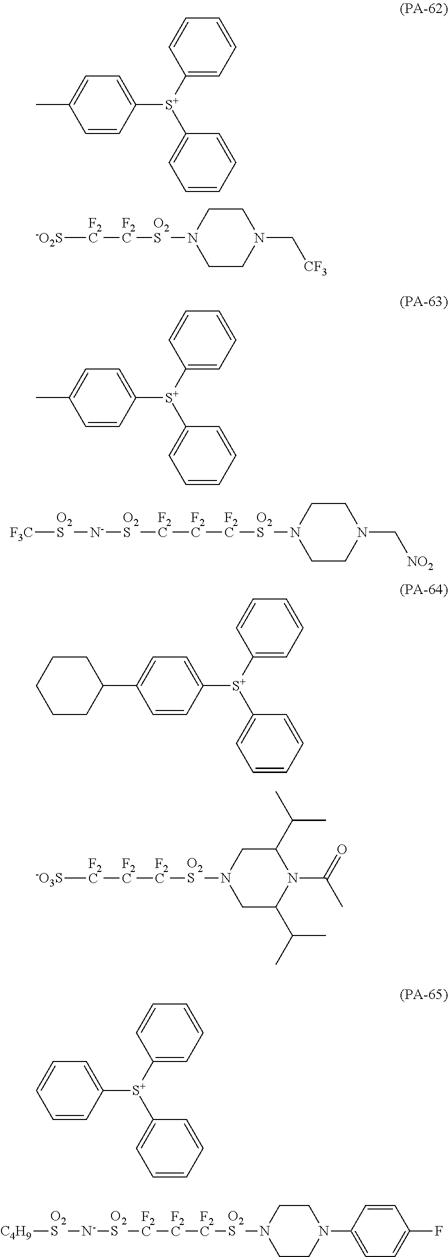

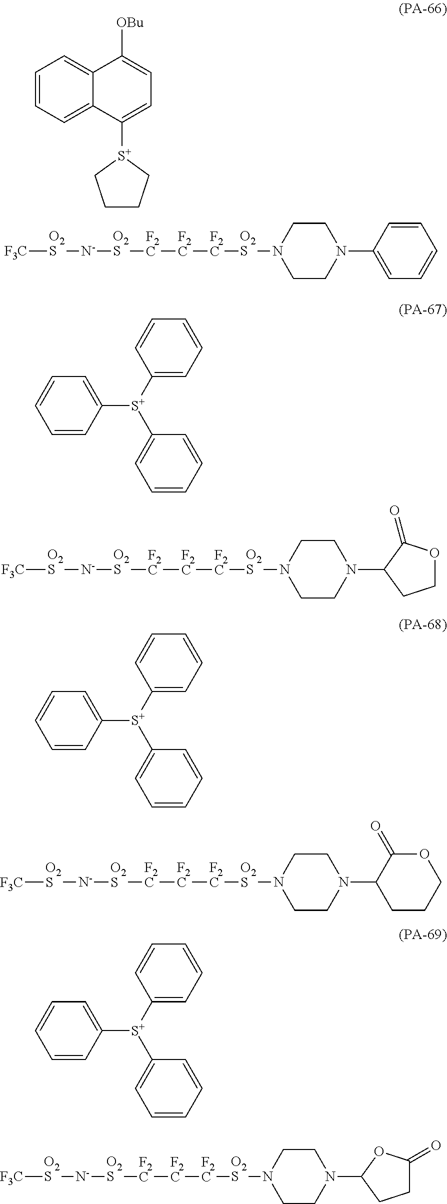

These compounds may be easily synthesized by using a general sulfonic acid esterification reaction or sulfonamidation reaction. For example, the compound may be obtained by a method of selectively reacting one sulfonyl halide moiety of a bis-sulfonyl halide compound with an amine, alcohol or the like including a partial structure represented by Formula (PA-II) or (PA-III) to form a sulfonamide bond or a sulfonic acid ester bond and then hydrolyzing the other sulfonyl halide moiety, or a method of ring-opening a cyclic sulfonic anhydride by an amine or alcohol including a partial structure represented by Formula (PA-II). The amine or alcohol including a partial structure represented by Formula (PA-II) or (PA-III) may be synthesized by reacting an amine or an alcohol with an anhydride such as (R′O₂C)₂O and (R′SO₂)₂O or an acid chloride compound such as R′O₂CCl, R′SO₂Cl (R′ is a methyl group, an n-octyl group or a trifluoromethyl group) under basic conditions. In particular, the synthesis may be performed in accordance with synthesis examples and the like in Japanese Patent Application Laid-Open No. 2006-330098.

The molecular weight of the compound (N) is preferably 500 to 1,000.

The actinic ray-sensitive or radiation-sensitive resin composition in the present invention may or may not contain the compound (N), but in the case of containing the compound (N), the content of the compound (N) is preferably 0.1% by mass to 20% by mass, and more preferably 0.1% by mass to 10% by mass, based on the solid content of the actinic ray-sensitive or radiation-sensitive resin composition.

[6-2] Basic Compound (N′)

The actinic ray-sensitive or radiation-sensitive resin composition in the present invention may contain a basic compound (N′) in order to reduce the change in performance with time from exposure to heating.

Preferred examples of the basic compounds include compounds having a structure represented by the following Formulae (A) to (E).

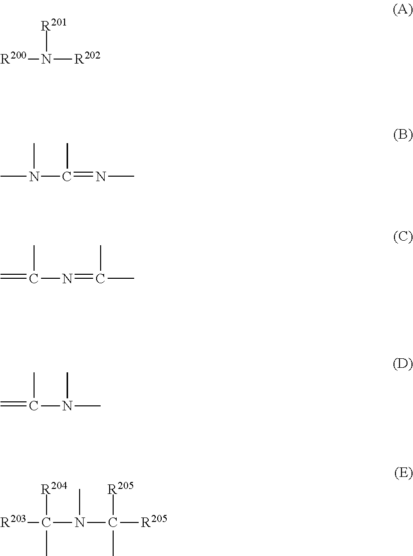

In Formulas (A) to (E),

each of R²⁰⁰, R²⁰¹ and R²⁰² may be the same as or different from each other of R²⁰⁰, R²⁰¹ and R²⁰² and represents a hydrogen atom, an alkyl group (preferably having 1 to 20 carbon atoms), a cycloalkyl group (preferably having 3 to 20 carbon atoms) or an aryl group (having 6 to 20 carbon), and R²⁰¹ and R²⁰² may be bonded to each other to form a ring. Each of R²⁰³, R²⁰⁴, R²⁰⁵ and R²⁰⁶ may be the same as or different from each other of R²⁰³, R²⁰⁴, R²⁰⁵ and R²⁰⁶ and represents an alkyl group having 1 to 20 carbon atoms.

As for the alkyl group, the alkyl group having a substituent is preferably an aminoalkyl group having 1 to 20 carbon atoms, a hydroxyalkyl group having 1 to 20 carbon atoms or a cyanoalkyl group having 1 to 20 carbon atoms.

The alkyl group in Formulas (A) to (E) is more preferably unsubstituted.

Preferred examples of the compound include guanidine, aminopyrrolidine, pyrazole, pyrazoline, piperazine, aminomorpholine, aminoalkylmorpholine, piperidine and the like, and more preferred examples of the compound include a compound having an imidazole structure, a diazabicyclo structure, an onium hydroxide structure, an onium carboxylate structure, a trialkylamine structure, an aniline structure or a pyridine structure, an alkylamine derivative having a hydroxyl group and/or an ether bond, an aniline derivative having a hydroxyl group and/or an ether bond and the like.

Examples of the compound having an imidazole structure include imidazole, 2,4,5-triphenylimidazole, benzimidazole and the like. Examples of the compound having a diazabicyclo structure include 1,4-diazabicyclo[2,2,2]octane, 1,5-diazabicyclo[4,3,0]non-5-ene and 1,8-diazabicyclo[5,4,0]undec-7-ene. Examples of the compound having an onium hydroxide structure include triarylsulfonium hydroxide, phenacylsulfonium hydroxide, a sulfonium hydroxide having a 2-oxoalkyl group, specifically, triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. Examples of the compound having an onium carboxylate structure include a compound, in which the anion moiety of a compound having an onium hydroxide structure has been converted into carboxylate, such as acetate, adamantane-1-carboxylate and perfluoroalkylcarboxylate. Examples of the compound having a trialkylamine structure include tri(n-butyl)amine, tri(n-octyl)amine and the like. Examples of the compound having an aniline structure include 2,6-diisopropylaniline, N,N-dimethylaniline, N,N-dibutylaniline, N,N-dihexylaniline and the like. Examples of the alkylamine derivative having a hydroxyl group and/or an ether bond include ethanolamine, diethanolamine, triethanolamine, tris(methoxyethoxyethyl)amine and the like. Examples of the aniline derivative having a hydroxyl group and/or an ether bond include N,N-bis(hydroxyethyl)aniline and the like.

Examples of the preferred basic compound further include an amine compound having a phenoxy group, an ammonium salt compound having a phenoxy group, an amine compound having a sulfonic acid ester group, and an ammonium salt compound having a sulfonic acid ester group.

It is preferred that the amine compound having a phenoxy group, the ammonium salt compound having a phenoxy group, the amine compound having a sulfonic acid ester group, and the ammonium salt compound having a sulfonic acid ester group have at least one alkyl group bonded to a nitrogen atom. Further, it is preferred that the alkyl chain has an oxygen atom therein to form an oxyalkylene group. The number of the oxyalkylene groups is one or more, preferably 3 to 9, and more preferably 4 to 6, in the molecule. Among the oxyalkylene groups, the structures of —CH₂CH₂O—, CH(CH₃)CH₂O— or —CH₂CH₂CH₂O— are preferred.

Specific examples of the amine compound having a phenoxy group, the ammonium salt compound having a phenoxy group, the amine compound having a sulfonic acid ester group, and the ammonium salt compound having a sulfonic acid ester group include compounds (C1-1) to (C3-3) as exemplified in [0066] of US Patent Application Publication No. 2007/0224539, but are not limited thereto.

Examples of a basic compound may also include N-alkylcaprolactam. As N-alkylcaprolactam, for example, N-methylcaprolactam may be preferably exemplified.

Further, a nitrogen-containing organic compound having a group capable of leaving by the action of an acid may also be used as a kind of basic compound. Examples of the compound include a compound represented by the following Formula (F). In addition, the compound represented by the following Formula (F) exhibits an effective basicity in the system as a result of elimination of the group capable of leaving by the action of an acid.

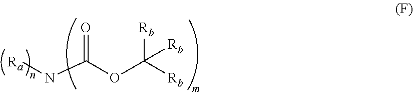

In Formula (F), each Ra independently represents a hydrogen atom, an alkyl group, a cycloalkyl group, an aryl group or an aralkyl group. Further, when n=2, each of two Ra's may be the same as or different from each other of Ra's, and two Ra's may be bonded to each other to form a divalent heterocyclic hydrocarbon group (preferably having 20 or less carbon atoms) or a derivative thereof.

Each Rb independently represents a hydrogen atom, an alkyl group, a cycloalkyl group, an aryl group or an aralkyl group. However, in —C(R_{b})(R_{b})(R_{b}), when one or more R_{b} are a hydrogen atom, at least one of the remaining R_{b} is a cyclopropyl group or a 1-alkoxy alkyl group.

At least two R_{b} may be bonded to each other to form an alicyclic hydrocarbon group, an aromatic hydrocarbon group, a heterocyclic hydrocarbon group or a derivative thereof.

n represents an integer of 0 to 2, m represents an integer of 1 to 3, and n+m=3.

In Formula (F), each of the alkyl group, the cycloalkyl group, the aryl group and the aralkyl group represented by Rₐ and R_{b} may be substituted with a functional group such as a hydroxyl group, a cyano group, an amino group, a pyrrolidino group, a piperidino group, a morpholino group and an oxo group, an alkoxy group or a halogen atom.

Examples of the alkyl group, the cycloalkyl group, the aryl group or the aralkyl group (each of the alkyl group, the cycloalkyl group, the aryl group and the aralkyl group may be substituted with the functional group, an alkoxy group or a halogen atom) of the R include a group derived from a straight chained or branched alkane such as methane, ethane, propane, butane, pentane, hexane, heptane, octane, nonane, decane, undecane and dodecane, a group in which the group derived from the alkane is substituted with one or more kinds of or one or more groups of cycloalkyl groups such as, for example, a cyclobutyl group, a cyclopentyl group and a cyclohexyl group,

a group derived from a cycloalkane such as cyclobutane, cyclopentane, cyclohexane, cycloheptane, cyclooctane, norbornane, adamantane and noradamantane, a group where the group derived from the cycloalkane is substituted with one or more kinds of or one or more groups of straight chained or branched alkyl groups such as, for example, a methyl group, an ethyl group, an n-propyl group, an i-propyl group, an n-butyl group, a 2-methylpropyl group, a 1-methylpropyl group and a t-butyl group,

a group derived from an aromatic compound such as benzene, naphthalene and anthracene, a group in which the group derived from the aromatic compound is substituted with one or more kinds of or one or more groups of straight chained or branched alkyl groups such as, for example, a methyl group, an ethyl group, an n-propyl group, an i-propyl group, an n-butyl group, a 2-methylpropyl group, a 1-methylpropyl group and a t-butyl group, and

a group derived from a heterocyclic compound such as pyrrolidine, piperidine, morpholine, tetrahydrofuran, tetrahydropyran, indole, indoline, quinoline, perhydroquinoline, indazole and benzimidazole, a group in which the group derived from the heterocyclic compound is substituted with one or more kinds of or one or more groups of straight chained or branched alkyl groups or groups derived from aromatic compounds, a group in which the group derived from a straight chained or branched alkane or the group derived from a cycloalkane is substituted with one or more kinds of or one or more groups of groups derived from aromatic compounds, such as a phenyl group, a naphthyl group and an anthracenyl group, a group in which the above-described substituent is substituted with a functional group such as a hydroxyl group, a cyano group, an amino group, a pyrrolidino group, a piperidino group, a morpholino group and an oxo group, and the like.

Further, examples of the divalent heterocyclic hydrocarbon group (preferably having 1 to 20 carbon atoms) formed by combining Rₐ with each other or a derivative thereof include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydro quinoxaline, perhydroquinoline and 1,5,9-triazacyclododecane, a group in which the group derived from the heterocyclic compound is substituted with one or more kinds of or one or more groups of straight chained or branched groups derived from alkane, groups derived from cycloalkane, groups derived from aromatic compounds, groups derived from heterocyclic compounds and functional groups such as a hydroxyl group, a cyano group, an amino group, a pyrrolidino group, a piperidino group, a morpholino group and an oxo group, and the like.

The nitrogen-containing organic compound having a particularly preferred group capable of leaving by the action of an acid in the present invention will be described in detail, but the present invention is not limited thereto.

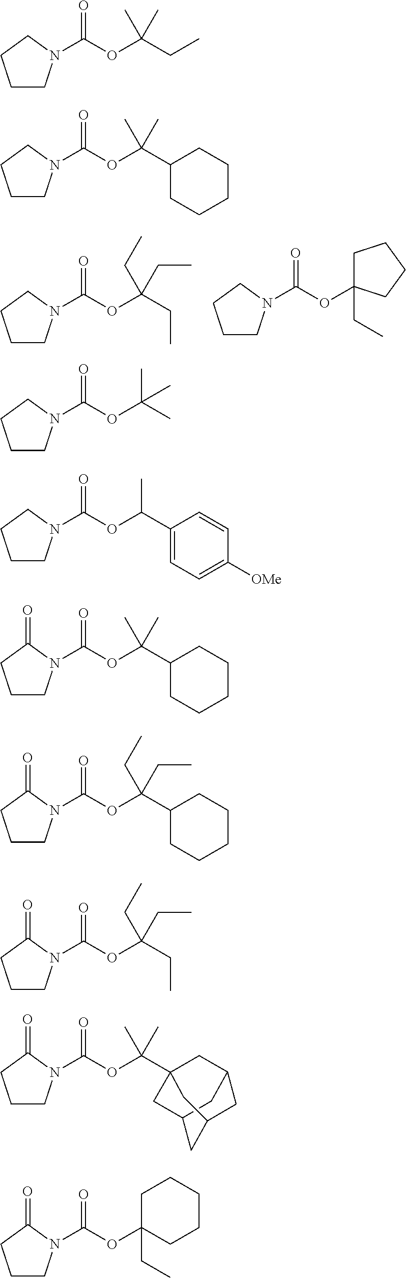

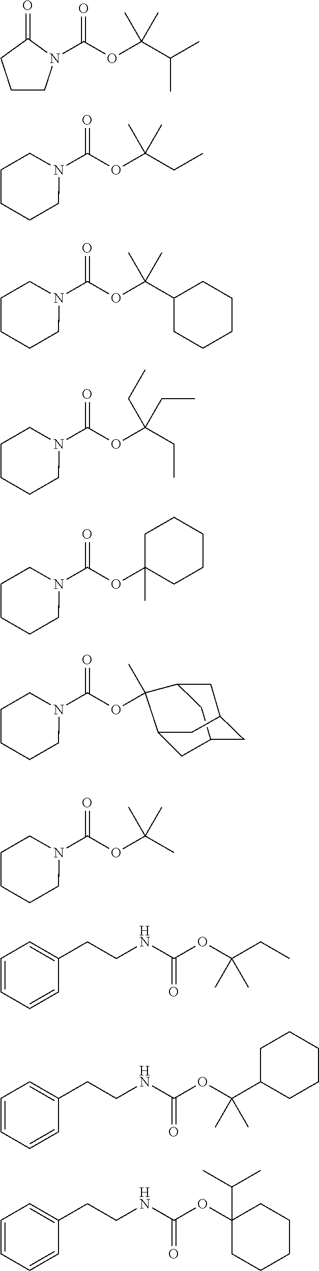

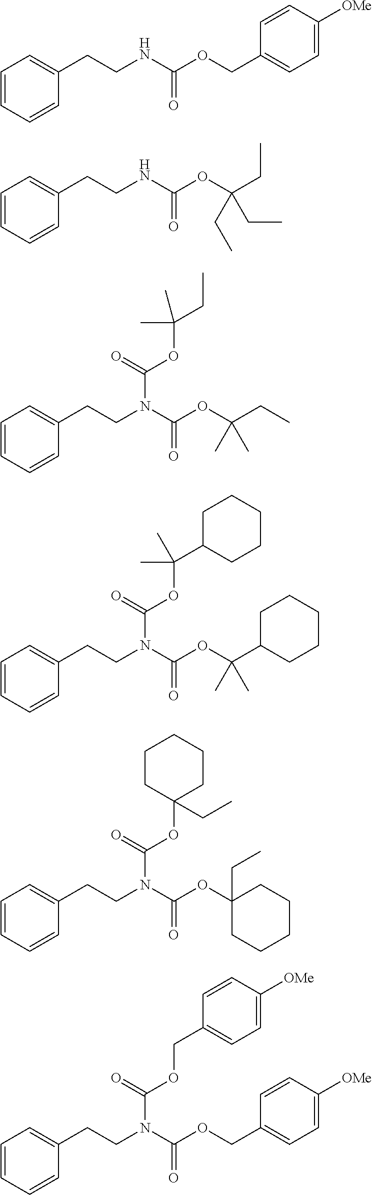

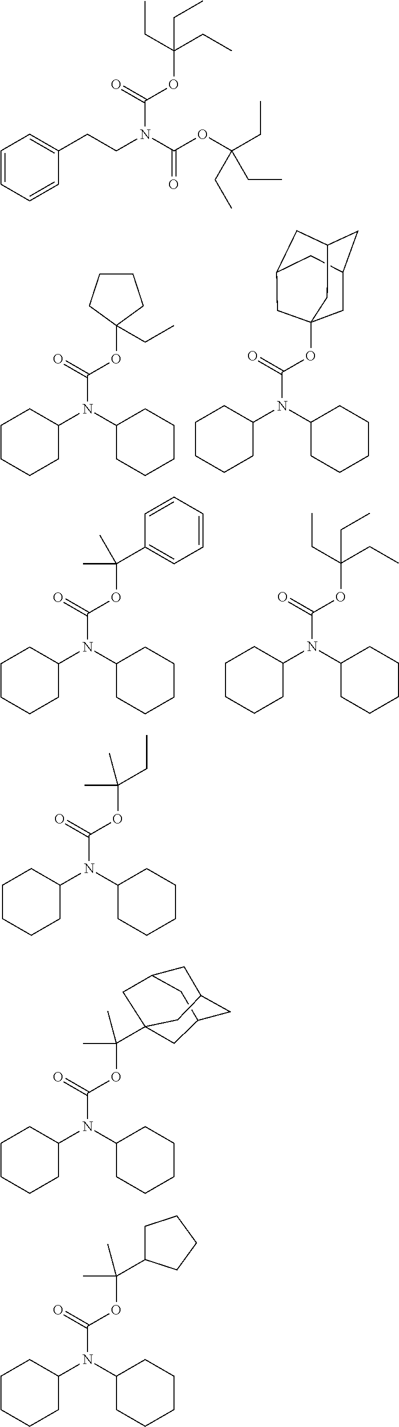

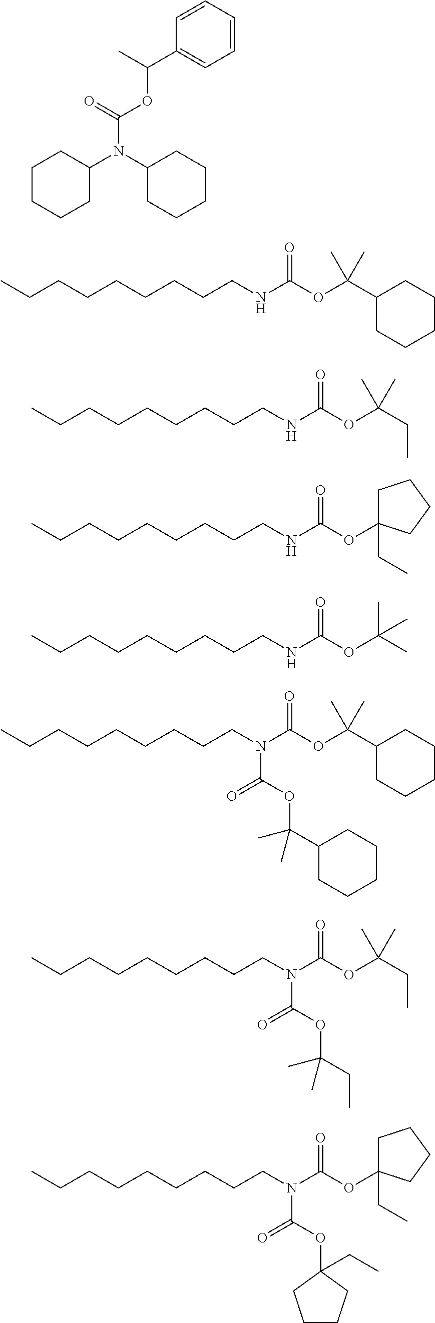

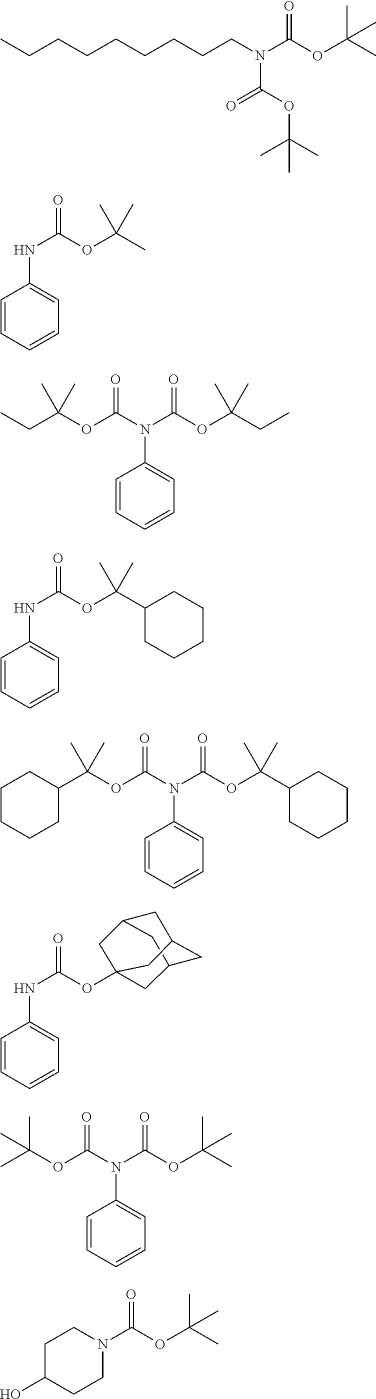

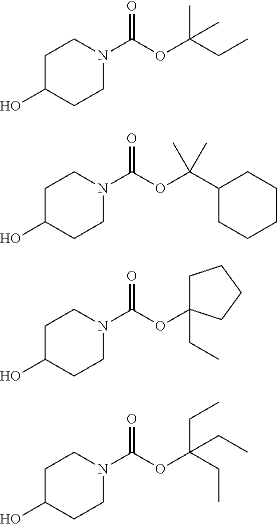

As for the compound represented by Formula (F), even though a commercially available product is used, the compound may be synthesized from a commercially available amine by the method described in Protective Groups in Organic Synthesis, 4th edition and the like. The compound may be synthesized in accordance with the method described, for example, in Japanese Patent Application Laid-Open No. 2009-199021, as the most general method.

Further, as the basic compound, a compound having a fluorine atom or a silicon atom and having basicity or capable of increasing the basicity by the action of an acid, as described in Japanese Patent Application Laid-Open No. 2011-141494 may be used. Specific examples thereof include compounds (B-7) to (B-18) used in the Examples of the patent document and the like.

The molecular weight of the basic compound is preferably 250 to 2,000, and more preferably 400 to 1,000. From the viewpoint of more reduction in LWR and uniformity of local pattern dimension, the molecular weight of the basic compound is preferably 400 or more, more preferably 500 or more, and still more preferably 600 or more.

These basic compounds may be used in combination with the compound (N), and are used either alone or in combination of two or more thereof.

The actinic ray-sensitive or radiation-sensitive resin composition in the present invention may or may not contain a basic compound, but in the case of containing a basic compound, the amount of the basic compound used is usually 0.001% by mass to 10% by mass, and preferably 0.01% by mass to 5% by mass, based on the solid content of the actinic ray-sensitive or radiation-sensitive resin composition.

The ratio of the acid generator and the basic compound used in the composition is preferably acid generator/basic compound (molar ratio)=from 2.5 to 300. That is, the molar ratio is preferably 2.5 or more in view of sensitivity, resolution and the like, and is preferably 300 or less from the viewpoint of suppressing the reduction in resolution caused by thickness of the resist pattern with time after exposure until heat treatment. The acid generator/basic compound (molar ratio) is more preferably 5.0 to 200, and still more preferably 7.0 to 150.

[7] Surfactant (F)

The actinic ray-sensitive or radiation-sensitive resin composition in the present invention may or may not further contain a surfactant, but in the case of containing a surfactant, it is more preferred that the composition contains any one of fluorine and/or silicon-based surfactants (a fluorine-based surfactant, a silicon-based surfactant and a surfactant having both a fluorine atom and a silicon atom), or two or more thereof.

The actinic ray-sensitive or radiation-sensitive resin composition in the present invention contains a surfactant, thereby imparting a resist pattern with adhesion and reduced development defect due to improved sensitivity and resolution when using an exposure light source with a wavelength of 250 nm or less, particularly 220 nm or less.

Examples of the fluorine-based and/or silicon-based surfactants include surfactants described in [0276] of U.S. Patent Application Publication No. 2008/0248425, such as EFtop EF301 and EF303 (manufactured by Shin-Akita Kasei Co., Ltd.), Florad FC430, 431 and 4430 (manufactured by Sumitomo 3M Inc.), Megaface F171, F173, F176, F189, F113, F110, F177, F120 and R08 (manufactured by DIC Corporation), Surflon S-382, SC101, 102, 103, 104, 105 and 106 and KH-20 (manufactured by Asahi Glass Co., Ltd.), Troysol S-366 (manufactured by Troy Chemical Corp.), GF-300 and GF-150 (manufactured by Toagosei Chemical Industry Co., Ltd.), Surflon S-393 (manufactured by Seimi Chemical Co., Ltd.), EFtop EF121, EF122A, EF122B, RF122C, EF125M, EF135M, EF351, EF352, EF801, EF802 and EF601 (manufactured by JEMCO Co., Ltd.), PF636, PF656, PF6320 and PF6520 (manufactured by OMNOVA Solutions, Inc.), and FTX-204G, 208G, 218G, 230G, 204D, 208D, 212D, 218D and 222D (manufactured by NEOS Co., Ltd.). Further, polysiloxane polymer KP-341 (manufactured by Shin-Etsu Chemical Co., Ltd.) may also be used as the silicon-based surfactant.

Further, other than those known surfactants described above, it is possible to use a surfactant using a polymer having a fluoro-aliphatic group derived from a fluoro-aliphatic compound which is prepared by a telomerization method (also referred to as a telomer method) or an oligomerization method (also referred to as an oligomer method) as the surfactant. The fluoro-aliphatic compound may be synthesized by the method described in Japanese Patent Application Laid-Open No. 2002-90991.

Examples of a surfactant corresponding to the above-described surfactant include Megaface F178, F-470, F-473, F-475, F-476 and F-472 (manufactured by DIC Corporation), a copolymer of an acrylate having a C₆Fi₃ group (or methacrylate) with a (poly(oxyalkylene))acrylate (or methacrylate), a copolymer of an acrylate having a C₃F₇ group (or methacrylate) with a (poly(oxyethylene))acrylate (or methacrylate) and a (poly(oxypropylene))acrylate (or methacrylate), and the like.

Further, in the present invention, it is also possible to use a surfactant other than the fluorine-based and/or silicon-based surfactant, described in [0280] of U.S. Patent Application Publication No. 2008/0248425.

These surfactants may be used either alone or in combination of several thereof

When the actinic ray-sensitive or radiation-sensitive resin composition contains a surfactant, the amount of the surfactant used is preferably 0.0001% by mass to 2% by mass, and more preferably 0.0005 mol % to 1 mol %, based on the total amount of the actinic ray-sensitive or radiation-sensitive resin composition (excluding the solvent).

On one hand, by adjusting the amount of the surfactant added to 10 ppm or less based on the total amount of the actinic ray-sensitive or radiation-sensitive resin composition (excluding the solvent), the surface uneven distribution of the resin D relating to the present invention is increased, and accordingly, the surface of the resist film may be made to be more hydrophobic, thereby improving the water follow-up property at the of immersion exposure.

[8] Other Additives (G)

The actinic ray-sensitive or radiation-sensitive resin composition in the present invention may or may not contain a carboxylic acid onium salt. Examples of the carboxylic acid onium salt include those described in [0605] to [0606] of U.S. Patent Application Publication No. 2008/0187860.

The carboxylic acid onium salt may be synthesized by reacting sulfonium hydroxide, iodonium hydroxide, ammonium hydroxide and carboxylic acid with silver oxide in an appropriate solvent.

When the actinic ray-sensitive or radiation-sensitive resin composition contains a carboxylic acid onium salt, the content thereof is generally 0.1% by mass to 20% by mass, preferably 0.5% by mass to 10% by mass, and more preferably 1% by mass to 7% by mass, based on the total solid content of the composition.

The actinic ray-sensitive or radiation-sensitive resin composition of the present invention may further contain a dye, a plasticizer, a photosensitizer, a light absorber, an alkali-soluble resin, a dissolution inhibitor, a compound for accelerating solubility in a developer (for example, a phenol compound having a molecular weight of 1,000 or less, or an alicyclic or aliphatic compound having carboxyl group) and the like, if necessary.

The phenol compound having a molecular weight of 1,000 or less may be easily synthesized by a person skilled in the art by referring to the methods described in, for example, Japanese Patent Application Laid-Open No. H4-122938, Japanese Patent Application Laid-Open No. H2-28531, U.S. Pat. No. 4,916,210, European Patent No. 219294 and the like.

Specific examples of the alicyclic or aliphatic compound having a carboxylic acid include a carboxylic acid derivative having a steroid structure, such as cholic acid, deoxycholic acid and lithocholic acid, an adamantanecarboxylic acid derivative, adamantanedicarboxylic acid, cyclohexanecarboxylic acid, cyclohexanedicarboxylic acid and the like, but are not limited thereto.

From the viewpoint of improving the resolution, the actinic ray-sensitive or radiation-sensitive resin composition in the present invention is preferably used in a film thickness from 30 nm to 250 nm, and more preferably in a film thickness from 30 nm to 200 nm. Such a film thickness may be achieved by setting a solid concentration in the composition to an adequate range to have an appropriate viscosity, thereby improving coatability and film-formation property.

The solid content concentration of the actinic ray-sensitive or radiation-sensitive resin composition in the present invention is usually 1.0% by mass to 10% by mass, preferably 2.0% by mass to 5.7% by mass, and more preferably 2.0% by mass to 5.3% by mass. By setting the solid content concentration to the above-described range, the resist solution may be uniformly applied on a substrate and a resist pattern which is excellent in line width roughness may be formed. The reason is not clear, but it is thought that by setting the solid content concentration to 10% by mass or less, preferably 5.7% by mass or less, aggregation of materials, particularly, a photo-acid generator, in the resist solution is suppressed, and as a result, a uniform resist film may be formed.

The solid content concentration is a weight percentage of the weight of other resist components excluding the solvent, based on the total weight of the actinic ray-sensitive or radiation-sensitive resin composition.

The actinic ray-sensitive or radiation-sensitive resin composition in the present invention is used by dissolving the above-described components in a predetermined organic solvent, preferably in the mixed solvent, filtering the solution through a filter, and then applying the filtered solution on a predetermined support (substrate). The filter used for filtration is preferably a polytetrafluoroethylene-, polyethylene- or nylon-made filter having a pore size of 0.1 μm or less, more preferably 0.05 μm or less, and still more preferably 0.03 μm or less. In the filtration through a filter, as described in, for example, Japanese Patent Application Laid-Open No. 2002-62667, circulating filtration may be performed, or the filtration may be performed by connecting a plurality of kinds of filters in series or in parallel. Further, the composition may be filtered a plurality of times. In addition, a deaeration treatment or the like may be applied to the composition before or after filtration.

[9] Pattern Forming Method

The pattern forming method (negative type pattern forming method) of the present invention at least includes

(a) forming a film (resist film) by the actinic ray-sensitive or radiation-sensitive resin composition of the present invention,

(b) exposing the film, and

(c) performing development using a developer.

The exposure in the step (b) may be immersion exposure.

It is preferred that the pattern forming method of the present invention has a heating step (d) after the exposure step (b).

The pattern forming method of the present invention may further have (e) a step of performing development using an alkali developer.

The pattern forming method of the present invention may have several times of the exposure step (b).

The pattern forming method of the present invention may have several times of the heating step (e).

The resist film of the present invention is formed from the above-described actinic ray-sensitive or radiation-sensitive resin composition of the present invention, and more specifically, is preferably a film formed by applying the actinic ray-sensitive or radiation-sensitive resin composition on a substrate. In the pattern forming method of the present invention, the step of forming a film by an actinic ray-sensitive or radiation-sensitive resin composition on a substrate, the step of exposing the film, and the step of performing development may be performed by a generally known method.

It is also preferred that the method includes, after film formation, a pre-baking step (PB) before the exposure step.

Further, it is also preferred that the method includes a post-exposure baking step (PEB) after the exposure step but before the development step.

As for the heating temperature, both PB and PEB are performed preferably at from 70° C. to 130° C., and more preferably at from 80° C. to 120° C.

The heating time is preferably 30 to 300 seconds, more preferably 30 to 180 seconds, and still more preferably 30 to 90 seconds.

The heating may be performed using a means equipped with a typical exposure/developing machine or may be performed using a hot plate or the like.

By means of baking, the reaction in the exposed portion is accelerated, and thus the sensitivity or pattern profile is improved.

The light source wavelength used in the exposure apparatus in the present invention is not limited, but examples thereof include an infrared light, visible light, ultraviolet light, far ultraviolet light, an extreme-ultraviolet light, X-ray, an electron beam and the like, but are preferably far ultraviolet light at a wavelength of preferably 250 nm or less, more preferably 220 nm or less, and particularly preferably 1 nm to 200 nm. Specific examples thereof include a KrF excimer laser (248 nm), an ArF excimer laser (193 nm), a F₂ excimer laser (157 nm), an X-ray, an EUV (13 nm), an electron beam and the like, and a KrF excimer laser, an ArF excimer laser, an EUV or an electron beam is preferred, and an ArF excimer laser is more preferred.

Further, in the step of performing exposure of the present invention, an immersion exposure method may be applied.

The immersion exposure method is, as the technique to increase the resolution, a technique of performing the exposure by filling a high refractive-index liquid (hereinafter, also referred to as an “immersion liquid”) between a projection lens and a sample.

As described above, for the “effect of immersion”, assuming that λ₀ is the wavelength of exposure light in air, n is the refractive index of the immersion liquid for air, 0 is the convergence half-angle of beam and NAₒ=sin θ, the resolution and the depth of focus in immersion may be expressed by the following equations. Here, k₁ and k₂ are coefficients related to the step.

(Resolution)=k₁(λ₀/n)/NA₀

(Depth of focus)=±k₂·(λ₀/n)/NA₀²

That is, the effect of immersion is equal to the use of an exposure wavelength having a wavelength of 1/n. In other words, in the case of a projection optical system having the same NA, the depth of focus may be made n times larger by the immersion. This is effective for all pattern shapes and may be combined with the super-resolution technology that is being now currently studied, such as a phase-shift method and a modified illumination method.

In the case of performing immersion exposure, a step of washing the surface of the film with an aqueous chemical solution may be performed (1) after forming the film on a substrate and before the step of performing exposure and/or (2) after the step of exposing the film through an immersion liquid but before the step of heating the film.

The immersion liquid is preferably a liquid which is transparent to light at the exposure wavelength and has a temperature coefficient of refractive index as small as possible in order to minimize the distortion of an optical image projected on the film, but particularly, when the exposure light source is an ArF excimer laser (wavelength; 193 nm), water is preferably used from the viewpoint of easy availability and easy handleability in addition to the above-described viewpoint.

When water is used, an additive (liquid) capable of decreasing the surface tension of water and increasing the interfacial activity may be added in a small ratio. It is preferred that the additive does not dissolve the resist layer on the wafer and has only a negligible effect on the optical coat at the undersurface of the lens element.

Such an additive is preferably an aliphatic alcohol having a refractive index almost equal to that of, for example, water, and specific examples thereof include methyl alcohol, ethyl alcohol, isopropyl alcohol and the like. By adding an alcohol having a refractive index almost equal to that of water, even when the alcohol component in water is evaporated and the content concentration thereof is changed, it is possible to obtain an advantage in that the change in the refractive index of the liquid as a whole may be made very small.

On one hand, when a substance opaque to light at 193 nm or an impurity greatly differing from water in the refractive index is incorporated, the incorporation incurs distortion of the optical image projected on the resist, and thus, the water used is preferably distilled water. Further, pure water filtered through an ion exchange filter or the like may also be used.

The electrical resistance of water used as the immersion liquid is preferably 18.3 MQcm or more, and TOC (organic concentration) is preferably 20 ppb or less and the water is preferably subjected to deaeration treatment.

Further, the lithography performance may be enhanced by raising the refractive index of the immersion liquid. From the viewpoint, an additive for raising the refractive index may be added to water, or heavy water (D₂O) may be used in place of water.

The receding contact angle of water on the resist film formed by using the actinic ray-sensitive or radiation-sensitive resin composition in the present invention is 70° or more at a temperature of 23±3° C. and a humidity of 45±5%, is appropriate in the case of performing exposure through an immersion medium, and is preferably 75° or more, and more preferably 75° to 85°.

When the receding contact angle is extremely small, the receding contact angle may not be appropriately used in the case of performing exposure through an immersion medium, and an effect of reducing watermark defects may not be sufficiently exhibited.

The resin (D) substantially contains no fluorine atom and silicon atom, and thus the receding contact angle of water on the resist film surface may be improved by containing the resin (D) in the actinic ray-sensitive or radiation-sensitive resin composition in the present invention.

From the viewpoint of improving the receding contact angle, the resin (D) preferably has at least one of the repeating unit represented by Formula (II) or (III) as described above. In addition, from the viewpoint of improving the receding contact angle, the C Log P value of the resin (D) is preferably 1.5 or more as described above. Further, from the viewpoint of improving the receding contact angle, the mass content ratio of the CH3 partial structure, that the side chain moiety in the resin (D) has, in the resin (D) is preferably 12.0% or more, as described above.

In the immersion exposure step, the immersion liquid needs to move on a wafer following the movement of an exposure head that scans the wafer at a high speed and forms an exposure pattern, and thus the contact angle of the immersion liquid for the resist film in a dynamic state is important, and it is possible to obtain from the resist a performance of allowing the immersion liquid to follow the high-speed scanning of the exposure head while a liquid droplet no longer remains.

In the present invention, the substrate on which the film is formed is not particularly limited, and it is possible to use an inorganic substrate such as silicon, SiN, SiO₂ or SiN, a coating-type inorganic substrate such as SOG, or a substrate generally used in the process of manufacturing a semiconductor such as IC or manufacturing a liquid crystal device or a circuit board such as a thermal head or in the lithography process of other photo-fabrication processes. Further, if necessary, an organic antireflection film may be formed between the film and the substrate.

When the pattern forming method of the present invention further includes performing development using an alkali developer, it is possible to use an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, cyclic amines such as pyrrole and piperidine, and the like, as the alkali developer.

Further, alcohols and a surfactant may be added to the alkaline aqueous solution each in an appropriate amount and the mixture may be used.

The alkali concentration of the alkali developer is usually 0.1% by mass to 20% by mass.

The pH of the alkali developer is usually 10.0 to 15.0.

In particular, an aqueous solution of 2.38% by mass of tetramethylammonium hydroxide is preferred.

As for the rinsing solution in the rinsing treatment performed after the alkali development, pure water is used, and an appropriate amount of a surfactant may be added thereto to use the mixture.

Further, after the development treatment or rinsing treatment, a treatment of removing the developer or rinsing solution adhering on the pattern by a supercritical fluid may be performed.

As the developer (hereinafter, also referred to as an “organic-based developer”) in the step of performing developing using a developer containing an organic solvent in the pattern forming method of the present invention, a polar solvent such as a ketone-based solvent, an ester-based solvent, an alcohol-based solvent, an amide-based solvent and an ether-based solvent, and a hydrocarbon-based solvent may be used.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate and the like.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate and the like.

Examples of the alcohol-based solvent include an alcohol such as methyl alcohol, ethyl alcohol, n-propyl alcohol, isopropyl alcohol, n-butyl alcohol, sec-butyl alcohol, t-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol, and the like.

Examples of the ether-based solvent include, in addition to the glycol ether-based solvents, dioxane, tetrahydrofuran and the like.

As the amide-based solvent, it is possible to use, for example, N-methyl-2-pyrrolidone, N,N-dimethylacetamide, N,N-dimethylformamide, hexamethylphosphoric triamide, 1,3-dimethyl-2-imidazolidinone and the like.

Examples of the hydrocarbon-based solvent include an aromatic hydrocarbon-based solvent such as toluene and xylene, and an aliphatic hydrocarbon-based solvent such as pentane, hexane, octane and decane.

A plurality of the above-described solvents may be mixed, or the solvents may be used by being mixing with a solvent other than those described above or with water. However, in order to sufficiently exhibit the effects of the present invention, the water content ratio of the entire developer is preferably less than 10% by mass, and it is more preferred that the developer contains substantially no moisture.

That is, the amount of the organic solvent used in the organic-based developer is preferably 90% by mass to 100% by mass, and more preferably 95% by mass to 100% by mass, based on the total amount of the developer.

In particular, the organic-based developer is preferably a developer containing at least one of organic solvents selected from the group consisting of a ketone-based solvent, an ester-based solvent, an alcohol-based solvent, an amide-based solvent and an ether-based solvent.

The vapor pressure of the organic-based developer is preferably 5 kPa or less, more preferably 3 kPa or less, and particularly preferably 2 kPa or less, at 20° C. By adjusting the vapor pressure of the organic-based developer to 5 kPa or less, evaporation of the developer on a substrate or in a development cup is suppressed so that the temperature uniformity in the wafer plane is improved, and as a result, the dimensional uniformity in the wafer plane is improved.

Specific examples of the solvent having a vapor pressure of 5 kPa or less include a ketone-based solvent such as 1-octanone, 2-octanone, 1-nonanone, 2-nonanone, 2-heptanone (methyl amyl ketone), 4-heptanone, 2-hexanone, diisobutyl ketone, cyclohexanone, methylcyclohexanone, phenylacetone and methyl isobutyl ketone, an ester-based solvent such as butyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate and propyl lactate, an alcohol-based solvent such as n-propyl alcohol, isopropyl alcohol, n-butyl alcohol, sec-butyl alcohol, t-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol, an ether-based solvent such as tetrahydrofuran, an amide-based solvent such as N-methyl-2-pyrrolidone, N,N-dimethylacetamide and N,N-dimethylformamide, an aromatic hydrocarbon-based solvent such as toluene and xylene, and an aliphatic hydrocarbon-based solvent such as octane and decane.

Specific examples of the solvent having a vapor pressure of 2 kPa or less that is in a particularly preferred range include a ketone-based solvent such as 1-octanone, 2-octanone, 1-nonanone, 2-nonanone, 4-heptanone, 2-hexanone, diisobutyl ketone, cyclohexanone, methylcyclohexanone and phenylacetone, an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate and propyl lactate, an alcohol-based solvent such as n-butyl alcohol, sec-butyl alcohol, t-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol, an amide-based solvent such as N-methyl-2-pyrrolidone, N,N-dimethylacetamide and N,N-dimethylformamide, an aromatic hydrocarbon-based solvent such as xylene, and an aliphatic hydrocarbon-based solvent such as octane and decane, and the like.

In the organic developer, a surfactant may be added in an appropriate amount, if necessary.

The surfactant is not particularly limited but, for example, ionic or nonionic fluorine-based and/or silicon-based surfactant and the like may be used. Examples of the fluorine and/or silicon-based surfactants include surfactants described in Japanese Patent Application Laid-Open Nos. S62-36663, S61-226746, S61-226745, S62-170950, S63-34540, H7-230165, H8-62834, H9-54432 and H9-5988, and U.S. Pat. Nos. 5,405,720, 5,360,692, 5,529,881, 5,296,330, 5,436,098, 5,576,143, 5,294,511 and 5,824,451, and a nonionic surfactant is preferred. The nonionic surfactant is not particularly limited, but a fluorine-based surfactant or a silicon-based surfactant is more preferably used.

The amount of the surfactant used is usually 0.001% by mass to 5% by mass, preferably 0.005% by mass to 2% by mass, and more preferably 0.01% by mass to 0.5% by mass, based on the total amount of the developer.

As for the developing method, it is possible to apply, for example, a method of dipping a substrate in a bath filled with a developer for a fixed time (dipping method), a method of raising a developer on a substrate surface sufficiently by the effect of a surface tension and keeping the substrate still for a fixed time, thereby performing development (puddle method), a method of spraying a developer on a substrate surface (spraying method), a method of continuously ejecting a developer on a substrate spinning at a constant speed while scanning a developer ejecting nozzle at a constant rate (dynamic dispense method) and the like.

When the above-described various developing methods include ejecting a developer toward a resist film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, and still more preferably 1 mL/sec/mm² or less. The flow velocity has no particular lower limit, but is preferably 0.2 mL/sec/mm² or more in consideration of throughput.

By setting the ejection pressure of the ejected developer to the above-described range, pattern defects resulting from the resist scum after development may be significantly reduced. Details on the mechanism are not clear, but it is thought that by setting the ejection pressure in the above-described range, the pressure imposed on the resist film by the developer is decreased and the resist film or resist pattern is suppressed from being inadvertently cut or collapsing.

Further, the ejection pressure (mL/sec/mm²) of the developer is the value at the outlet of the development nozzle in the developing apparatus.

Examples of the method for adjusting the ejection pressure of the developer include a method of adjusting the ejection pressure by a pump or the like, a method of supplying a developer from a pressurized tank and adjusting the pressure to change the ejection pressure and the like.

Further, after the step of performing development using a developer including an organic solvent, a step of stopping the development while replacing the solvent with another solvent may be performed.

A step of rinsing a film using a rinsing solution is preferably included after the step of performing development using a developer including an organic solvent.

The rinsing solution used in the rinsing step after the step of performing development using an developer including an organic solvent is not particularly limited as long as the rinsing solution does not dissolve the resist pattern, and a solution including a general organic solvent may be used. As for the rinsing solution, a rinsing solution containing at least one of organic solvents selected from the group consisting of a hydrocarbon-based solvent, a ketone-based solvent, an ester-based solvent, an alcohol-based solvent, an amide-based solvent and an ether-based solvent is preferably used.

Specific examples of the hydrocarbon-based solvent, the ketone-based solvent, the ester-based solvent, the alcohol-based solvent, the amide-based solvent and the ether-based solvent are the same as those described above for the developer including an organic solvent.

After the step of performing development using a developer including an organic solvent, more preferably, a step of performing washing using a rinsing solution containing at least one of organic solvent selected from the group consisting of a ketone-based solvent, an ester-based solvent, an alcohol-based solvent and an amide-based solvent is preformed, a step of performing washing using a rinsing solution containing an alcohol-based solvent or an ester-based solvent is still more preferably performed, a step of performing washing using a rinsing solution containing a monohydric alcohol is particularly preferably performed, and a step of performing washing using a rinsing solution containing a monohydric alcohol having 5 or more carbon atoms is most preferably performed.

Here, examples of the monohydric alcohol used in the rinsing step includes a straight chained, branched or cyclic monohydric alcohol, and specifically, it is possible to use 1-butanol, 2-butanol, 3-methyl-1-butanol, t-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol and the like, and as the particularly preferred monohydric alcohol having 5 or more carbon atoms, it is possible to use 1-hexanol, 2-hexanol, 4-methyl-2-pentanol, 1-pentanol, 3-methyl-1-butanol and the like.

A plurality of the components may be mixed, or the solvent may be used by being mixed with an organic solvent other than those described above.

The water content ratio in the rinsing solution is preferably 10% by mass or less, more preferably 5% by mass or less, and particularly preferably 3% by mass or less. By setting the water content ratio to 10% by mass or less, good development characteristics may be obtained.

The vapor pressure of the rinsing solution used after the step of performing development using a developer including an organic solvent is preferably 0.05 kPa to 5 kPa, still more preferably 0.1 kPa to 5 kPa, and most preferably 0.12 kPa to 3 kPa, at 20° C. By setting the vapor pressure of the rinsing solution to 0.05 kPa to 5 kPa, the temperature uniformity in the wafer plane is improved, and furthermore, swelling caused by permeation of the rinsing solution is suppressed, and as a result, the dimensional uniformity in the wafer plane is improved.

The rinsing solution may also be used by adding an appropriate amount of a surfactant thereto.

In the rinsing step, the wafer subjected to development using a developer including an organic solvent is rinsed by using the above-described rinsing solution including an organic solvent. The method of rinsing treatment is not particularly limited, but it is possible to apply, for example, a method of continuously ejecting a rinsing solution on a substrate spinning at a constant speed (spin coating method), a method of dipping a substrate in a bath filled with a rinsing solution for a fixed time (dipping method), a method of spraying a rinsing solution on a substrate surface (spraying method), and the like, and among them, it is preferred that the rinsing treatment is performed by the spin coating method and after the rinsing, the substrate is spun at a rotational speed from 2,000 rpm to 4,000 rpm to remove the rinsing solution from the substrate. It is also preferred that a heating step (post baking) is included after the rinsing step. The developer and rinsing solution remaining between patterns and in the inside of the pattern are removed by the baking. The heating step after the rinsing step is performed at usually 40° C. to 160° C., and preferably 70° C. to 95° C., for usually 10 seconds to 3 minutes, and preferably 30 to 90 seconds.

Further, the present invention also relates to a method for manufacturing an electronic device, including the above-described pattern forming method of the present invention, and an electronic device manufactured by this manufacturing method.

The electronic device of the present invention is suitably mounted on electric electronic devices (such as home appliances, OA media-related devices, optical devices and communication devices).

### EXAMPLES

Hereinafter, the present invention will be described in detail with reference to Examples, but the scope of the present invention is not limited thereby.

### Synthesis Example

### Synthesis of Resin A-1

102.3 parts by mass of cyclohexanone was heated at 80° C. under nitrogen flow. While the liquid was stirred, a mixed solution of 22.2 parts by mass of a monomer represented by the following structural formula M-1, 22.8 parts by mass of a monomer represented by the following structural formula M-2, 6.6 parts by mass of a monomer represented by the following structural formula M-3, 189.9 parts by mass of cyclohexanone and 2.40 parts by mass of 2,2′-dimethyl azobisisobutyrate [V-601, manufactured by Wako Pure Chemical Industries, Ltd.] was added dropwise thereto over 5 hours. After the completion of dropwise addition, the solution was further stirred at 80° C. for 2 hours. The reaction solution was allowed to cool, then subjected to reprecipitation with a large amount of hexane/ethyl acetate (mass ratio 9:1), and filtered to obtain a solid, and the solid was vacuum dried to obtain 41.1 parts by mass of Resin (A-1).

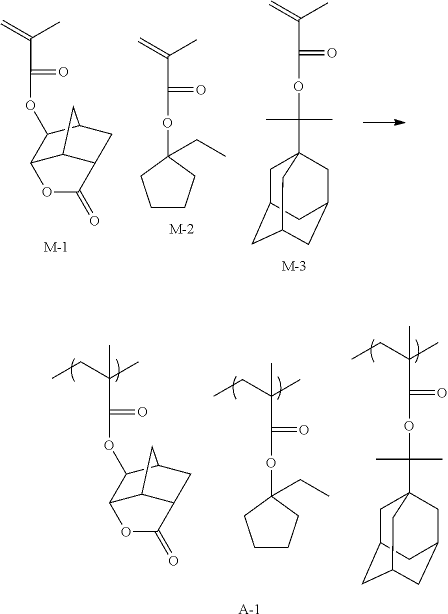

The weight average molecular weight (Mw: in terms of polystyrene) obtained from the GPC (carrier: tetrahydrofuran (THF)) of the obtained resin was Mw=9,500 with the polydispersity Mw/Mn=1.60. The composition ratio measured by ¹³C-NMR was 40/50/10.

<Acid-Decomposable Resin>

Hereinafter, Resins A-2 to A-9 were synthesized in the same manner. The structure of the synthesized polymer will be described below.

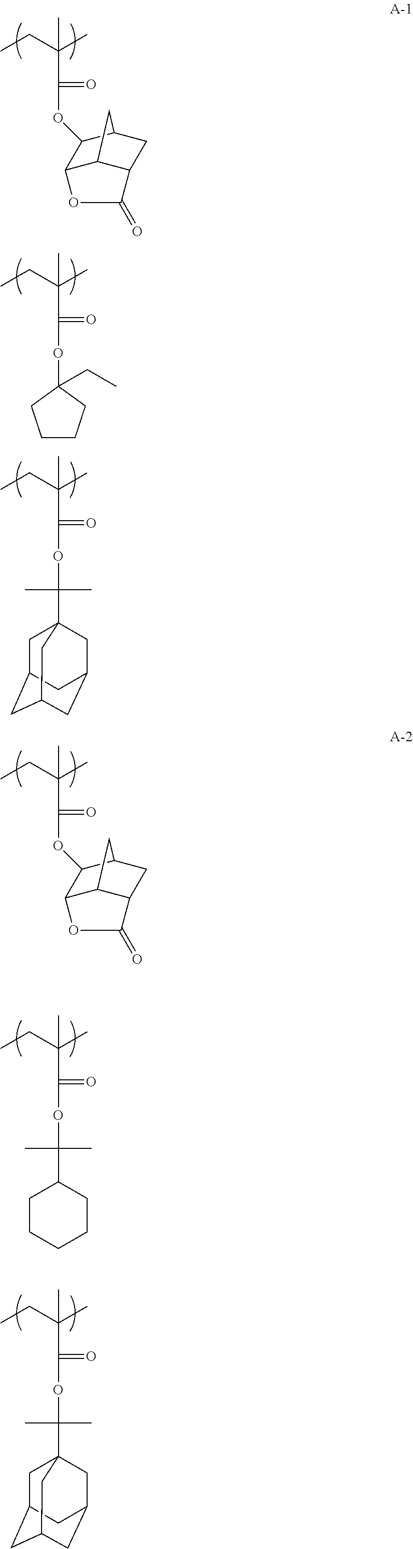

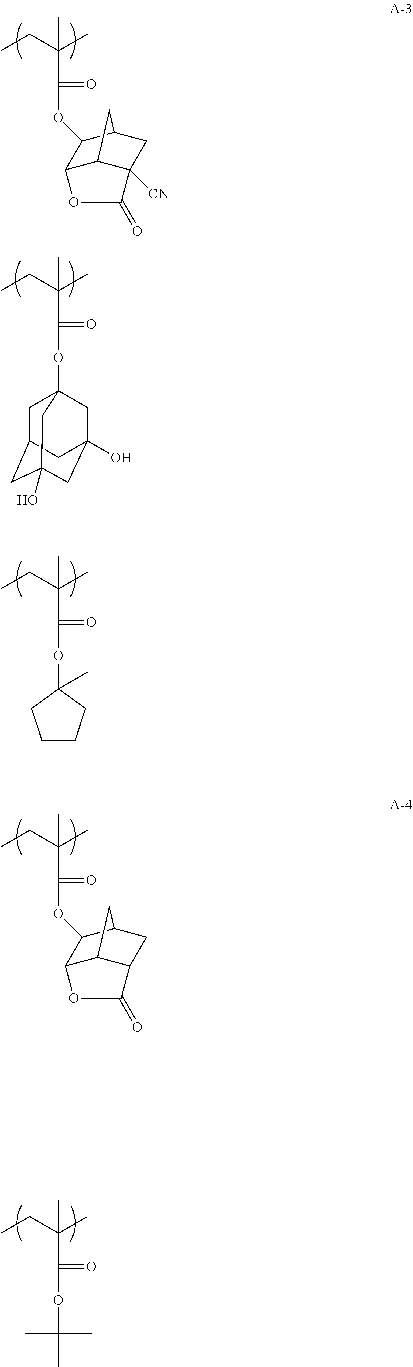

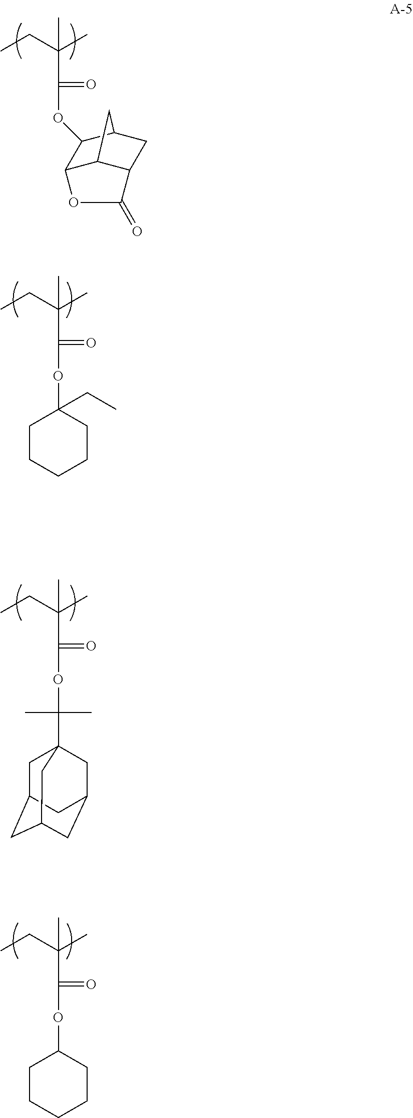

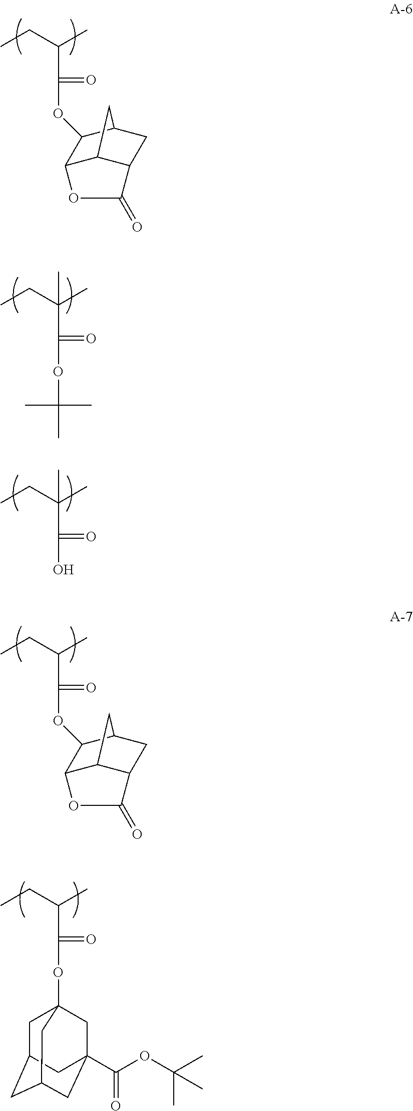

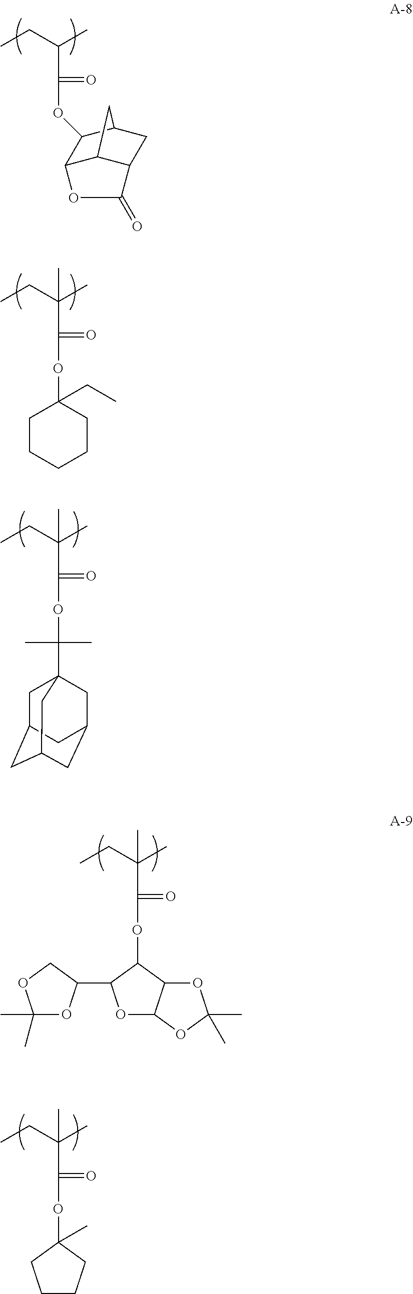

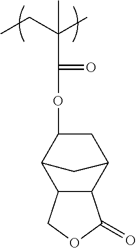

Further, the composition ratio (molar ratio; corresponding to the order starting from the left), the weight average molecular weight and the polydispersity of each repeating unit are shown in the following Table.

TABLE 3

| No. | Composition ratio (mol %) | | | | Mw | Mw/Mn |
|---|---|---|---|---|---|---|
| A-1 | 40 | 50 | 10 | — | 9500 | 1.60 |
| A-2 | 35 | 45 | 20 | — | 16300 | 1.65 |
| A-3 | 45 | 5 | 50 | — | 11100 | 1.63 |
| A-4 | 45 | 55 | — | — | 18000 | 1.70 |
| A-5 | 40 | 40 | 10 | 10 | 13500 | 1.67 |
| A-6 | 40 | 50 | 10 | — | 15500 | 1.71 |
| A-7 | 50 | 50 | — | — | 21000 | 1.75 |
| A-8 | 40 | 40 | 20 | — | 15000 | 1.64 |
| A-9 | 25 | 25 | 50 | — | 11000 | 1.68 |

### Synthesis Example

### Synthesis of Resin D-1

68.3 parts by mass of cyclohexanone was heated at 80° C. under nitrogen flow. While the liquid was stirred, a mixed solution of 12.0 parts by mass of a monomer represented by the following structural formula M-4, 22.4 parts by mass of a monomer represented by the following structural formula M-5, 126.9 parts by mass of cyclohexanone and 2.40 parts by mass of 2,2′-dimethyl azobisisobutyrate [V-601, manufactured by Wako Pure Chemical Industries, Ltd.] was added dropwise thereto over 6 hours. After the completion of dropwise addition, the solution was further stirred at 80° C. for 2 hours. The reaction solution was allowed to cool, then subjected to reprecipitation with a large amount of hexane/ethyl acetate (mass ratio 9:1), and filtered to obtain a solid, and the solid was vacuum dried to obtain 16.9 parts by mass of Resin (D-1).

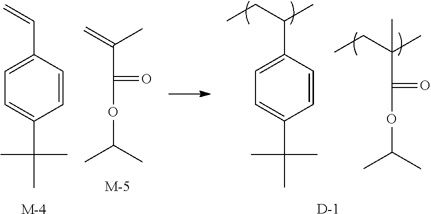

The weight average molecular weight (Mw: in terms of polystyrene) obtained from the GPC (carrier: tetrahydrofuran (THF)) of the obtained resin was Mw=11,700 with the polydispersity Mw/Mn=1.66. The composition ratio measured by ¹³C-NMR was 30/70.

<Hydrophobic Resin>

Hereinafter, Resins D-2 to D-19 were synthesized in the same manner. The structure of the synthesized polymer will be described below.

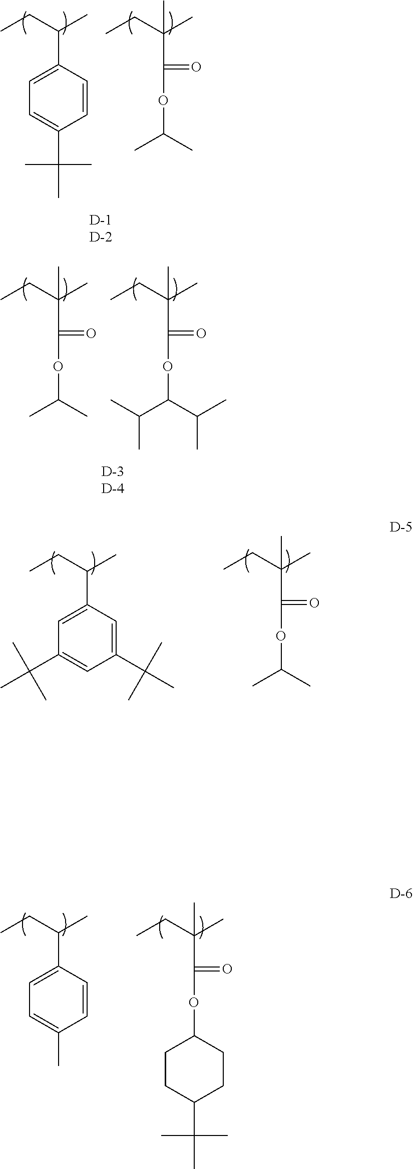

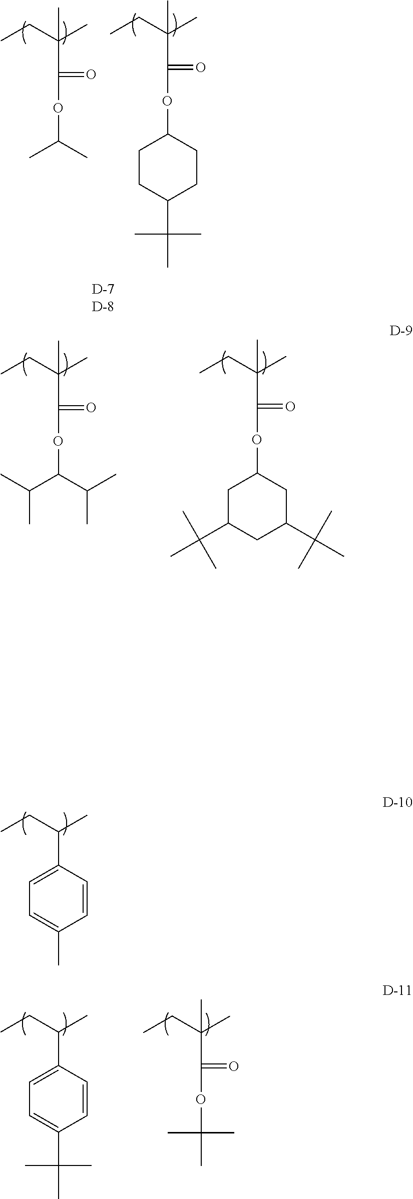

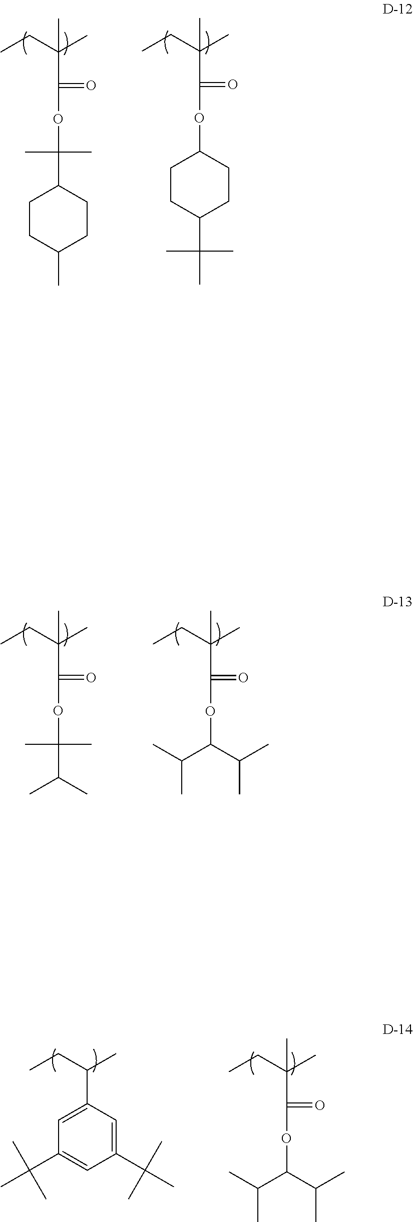

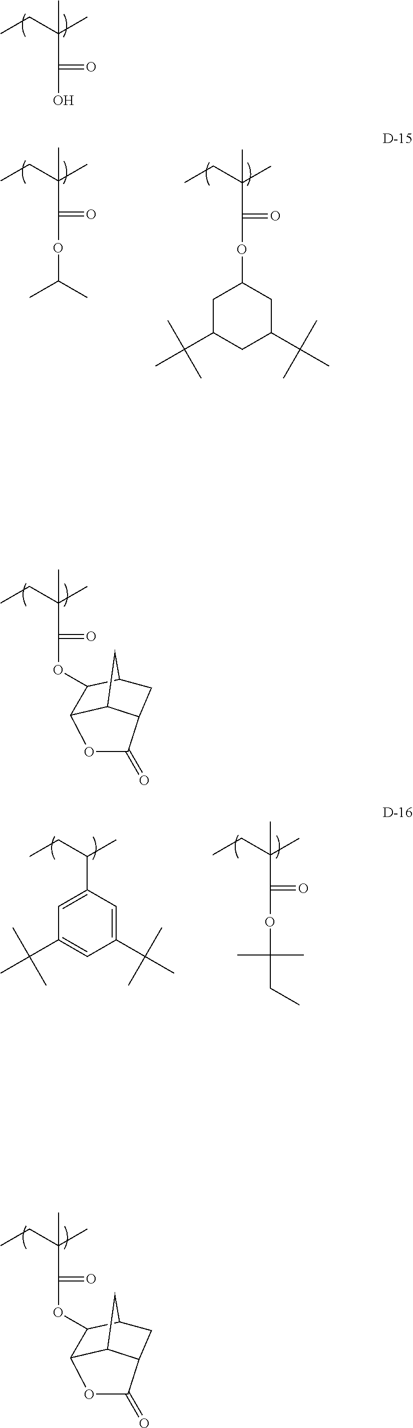

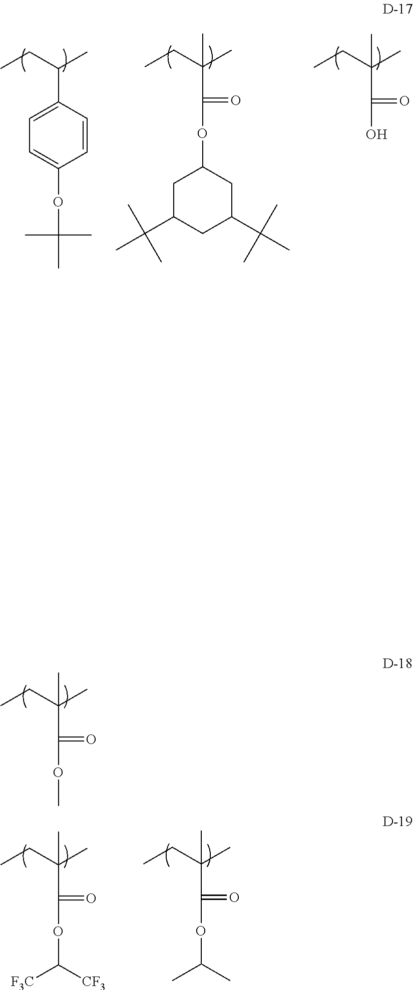

Further, the composition ratio (molar ratio; corresponding to the order starting from the left), the weight average molecular weight and the polydispersity of each repeating unit, the C Log P value of each resin, and the mass content ratio, of the CH₃ partial structure in the side chain moiety of each resin, in each resin are shown in the following Table.

In addition, the C Log P value of each resin is calculated as a total sum of multiplications of the mole fraction of the repeating unit in the resin by the CLoP value of the monomer corresponding to each repeating unit constituting the resin.

Here, the C Log P value of the monomer corresponding to each repeating unit constituting the resin is calculated by using ChemDraw Ultra ver. 8.0 manufactured by Cambridgesoft Corp.

TABLE 4

| | | | | | | | Mass content |
|---|---|---|---|---|---|---|---|
| | | | | | | | of side |
| | Composition | | | | | | chain CH₃ |
| | ratio | | | | | ClogP | moiety structure |
| No. | (mol %) | | | Mw | Mw/Mn | value | in resin (%) |
| D-1 | 30 | 70 | | 11700 | 1.66 | 2.8 | 24.9% |
| D-2 | 30 | 70 | | 23300 | 1.71 | 2.8 | 24.9% |
| D-3 | 40 | 60 | | 8500 | 1.62 | 3.1 | 29.0% |
| D-4 | 40 | 60 | | 15200 | 1.67 | 3.1 | 29.0% |
| D-5 | 40 | 60 | | 13300 | 1.61 | 3.8 | 28.7% |
| D-6 | 70 | 30 | | 12000 | 1.60 | 3.9 | 14.9% |
| D-7 | 50 | 50 | | 13500 | 1.72 | 3.5 | 21.8% |
| D-8 | 95 | 5 | | 31500 | 1.73 | 2.1 | 23.3% |
| D-9 | 80 | 20 | | 12500 | 1.65 | 4.4 | 31.9% |
| D-10 | 100 | | | 10600 | 1.60 | 3.4 | 12.7% |
| D-11 | 20 | 80 | | 17800 | 1.68 | 2.8 | 31.0% |
| D-12 | 40 | 60 | | 21100 | 1.65 | 5.0 | 20.1% |
| D-13 | 60 | 40 | | 22800 | 1.65 | 3.5 | 36.1% |
| D-14 | 30 | 60 | 10 | 19900 | 1.63 | 4.2 | 30.6% |
| D-15 | 70 | 20 | 10 | 18500 | 1.62 | 2.8 | 22.2% |
| D-16 | 30 | 65 | 5 | 20700 | 1.60 | 3.9 | 29.7% |
| D-17 | 75 | 20 | 5 | 20200 | 1.71 | 4.4 | 22.2% |
| D-18 | 100 | | | 19300 | 1.70 | 1.1 | 15.0% |
| D-19 | 30 | 70 | | 18500 | 1.70 | 2.1 | 16.4% |

<Acid Generator>

The following compounds were used as the acid generator.

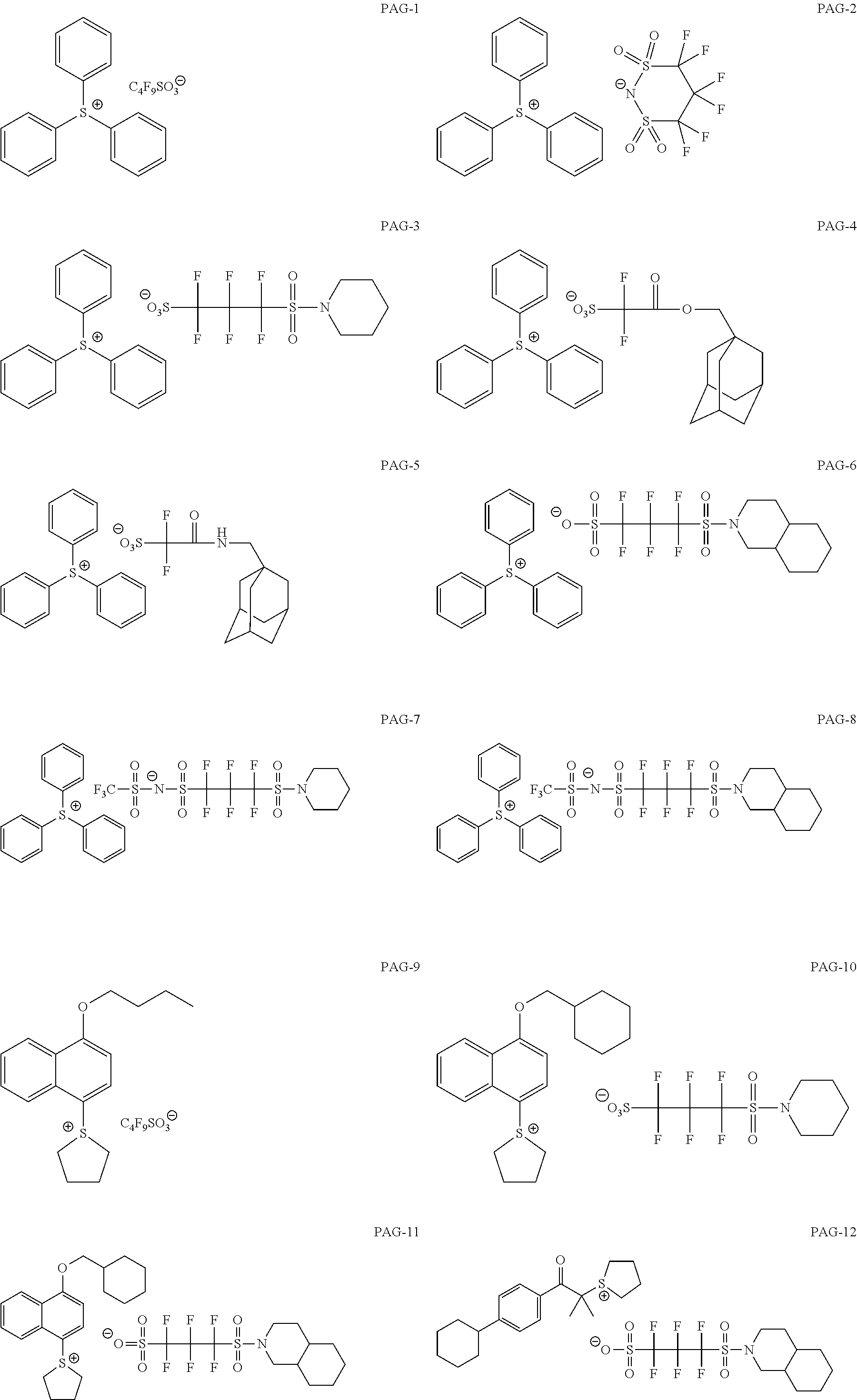

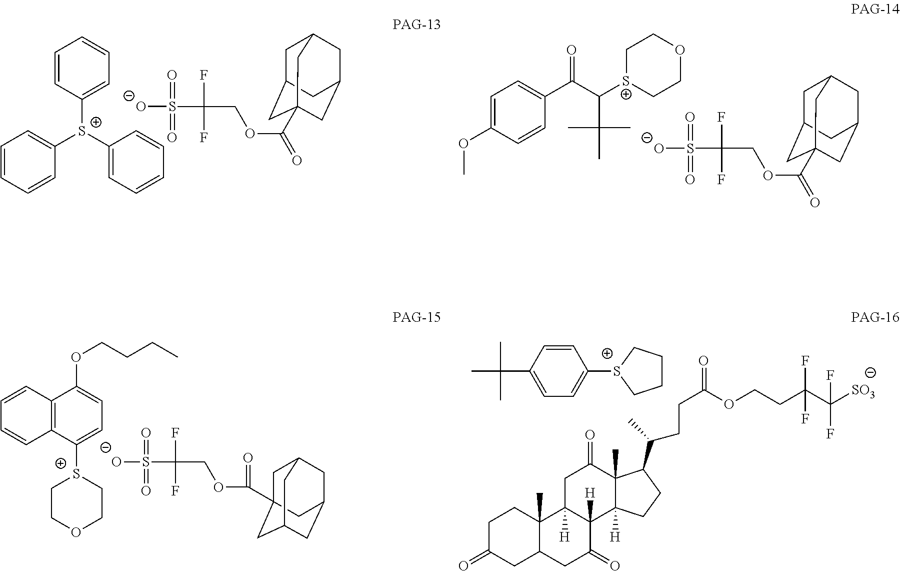

<Basic Compound (N) Whose Basicity Decreases Upon Irradiation with Actinic Ray or Radiation, and Basic Compound (N′)>

The following compounds were used as the basic compound whose basicity decreases upon irradiation with an actinic ray or radiation, or the basic compound.

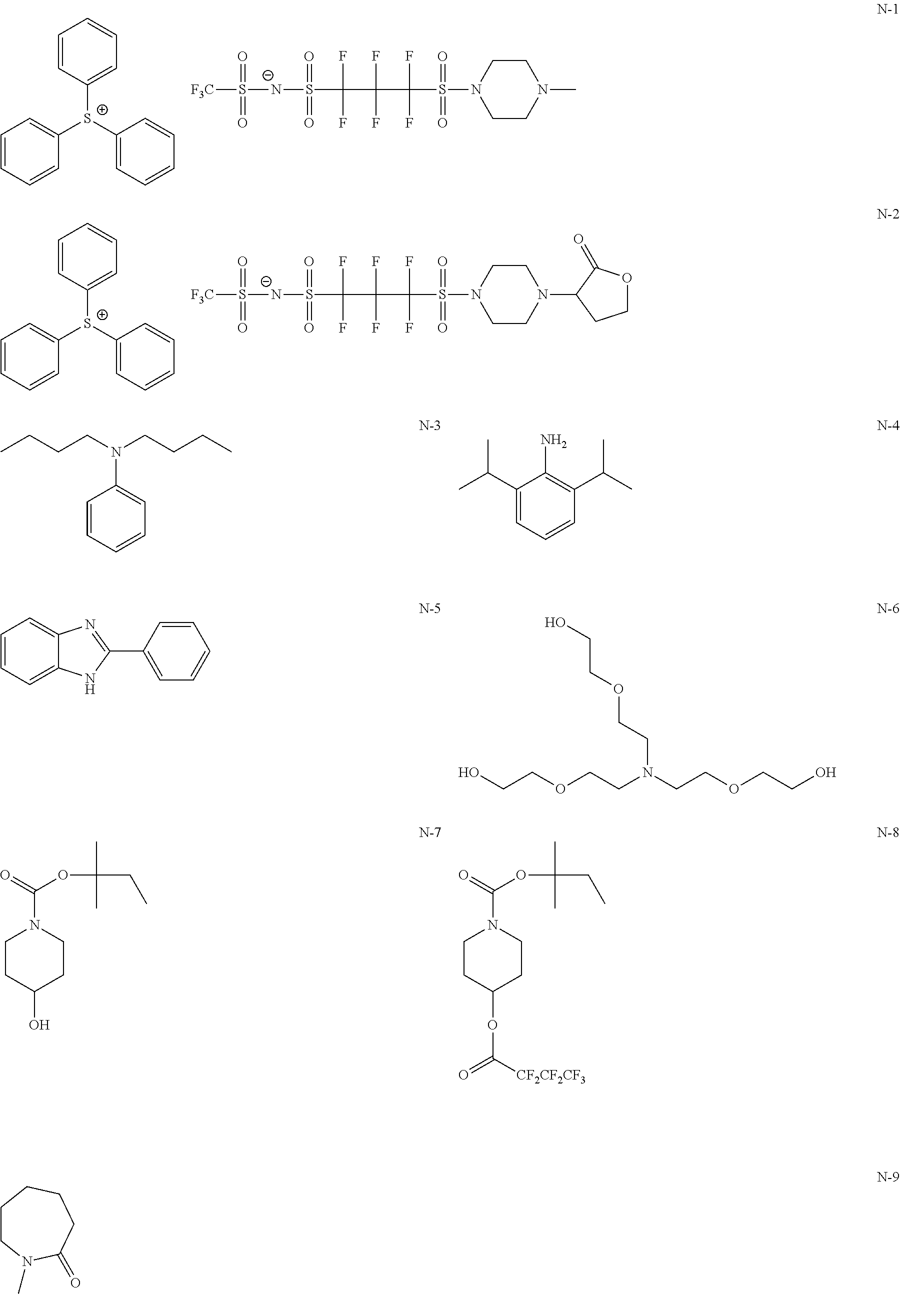

<Combined Hydrophobic Resin (E)>

A resin was appropriately selected from Resins (HR-1) to (HR-80) previously exemplified as the combined hydrophobic resin (E), and then is used.

<Surfactant>

The followings were prepared as the surfactant.

W-1: Megaface F176 (manufactured by DIC Corporation; fluorine-based)

W-2: Megaface R08 (manufactured by DIC Corporation; fluorine and silicon-based)

W-3: Polysiloxane Polymer KP-341 (manufactured by Shin-Etsu Chemical Co., Ltd.; silicon-based)

W-4: Troysol S-366 (manufactured by Troy Chemical Corp.)

W-5: KH-20 (manufactured by Asahi Glass Co., Ltd.)

W-6: PolyFox PF-6320 (manufactured by OMNOVA Solutions Inc.; fluorine-based)

<Solvent>

The followings were prepared as the solvent.

(Group a)

SL-1: Propylene glycol monomethyl ether acetate (PGMEA), Boiling point 146° C.

SL-2: Propylene glycol monomethyl ether propionate, Boiling point 160° C.

SL-3: 2-Heptanone, Boiling point 151° C.

(Group b)

SL-4: Ethyl lactate, Boiling point 154° C.

SL-5: Propylene glycol monomethyl ether (PGME), Boiling point 120° C.

SL-6: Cyclohexanone, Boiling point 156° C.

(Group c)

SL-7: γ-Butyrolactone, Boiling point 204° C.

SL-8: Propylene carbonate, Boiling point 242° C.

<Developer>

The followings were prepared as the developer.

SG-1: Butyl acetate

SG-2: Methyl amyl ketone

SG-3: Ethyl-3-ethoxypropionate

SG-4: Pentyl acetate

SG-5: Isopentyl acetate

SG-6: Propylene glycol monomethyl ether acetate (PGMEA)

SG-7: Cyclohexanone

<Rinsing Solution>

The followings were used as the rinsing solution.

SR-1: 4-methyl-2-pentanol

SR-2: 1-hexanol

SR-3: Butyl acetate

SR-4: Methyl amyl ketone

SR-5: Ethyl-3-ethoxypropionate

### Examples 1 to 34 and Comparative Examples 1 to 4

### ArF Immersion Exposure

(Preparation of Resist)

The components shown in the following Table 5 were dissolved in the solvent shown in the same Table to have an solid content of 3.5% by mass, and each was filtered through a polyethylene filter having a pore size of 0.03 μm to prepare an actinic ray-sensitive or radiation-sensitive resin composition (resist composition). An organic antireflection film ARC29SR (manufactured by Nissan Chemical Industries, Ltd.) was applied on a silicon wafer and baked at 205° C. for 60 seconds to form an antireflection film having a thickness of 95 nm. The actinic ray-sensitive or radiation-sensitive resin composition was applied thereon and baked (PB: prebaking) at 100° C. over 60 seconds to form a resist film having a thickness of 90 nm.

The obtained wafer was subjected to pattern exposure by using an ArF excimer laser immersion scanner (manufactured by ASML Co., Ltd.; XT1700i, NA 1.20, C-Quad, outer sigma 0.900, inner sigma 0.812, XY deflection) through a halftone mask having a pitch of 100 nm and a mask width of 40 nm. As the immersion liquid, ultrapure water was used. Thereafter, heating (PEB: post exposure baking) was performed at 105° C. for 60 seconds. Subsequently, the wafer was developed by puddling the developer shown in the following Table for 30 seconds, and then rinsed by puddling the rinsing solution shown in the following Table for 30 seconds while spinning the wafer at a rotational speed of 1,000 rpm (however, the rinsing step was not performed in Example 17, 25, and Comparative Example 4). Subsequently, a line-and-space pattern having a line width of 55 nm was obtained by spinning the wafer at a rotational speed of 2,000 rpm for 30 seconds.

However, in Comparative Example 3, pattern exposure was performed through a halftone mask having a pitch of 100 nm and a mask width of 60 nm, and used in a development treatment (so-called alkali development) using 2.38% by mass of an aqueous tetramethylammonium hydroxide solution for 30 seconds. Thereafter, the wafer was rinsed by using pure water, and subjected to spin drying.

[Evaluation of Receding Contact Angle of Water]

Each prepared resist composition shown in the following Table 5 was spin coated (applied with spin) onto the silicon wafer, and then baked at 100° C. for 60 seconds with a hot plate to form a resist film having a film thickness of 90 nm. The receding contact angle)(° of the water drop was measured by an expansion and contraction method of a dynamic contact angle meter (manufactured by Kyowa Interface Science Co., Ltd.). 35 μL of the initial water drop size at a room temperature of 23±3° C. and a humidity of 45±5% was sucked at a speed of 6 pt/sec for 5 seconds, and a stabilized value of the dynamic contact angle during the suction was defined as a receding contact angle.

[Uniformity of Film Thickness]

For the obtained resist film, the film thickness in the wafer plane was measured at 550 points by VM-3110 (manufactured by Dainippon Screen Mfg. Co., Ltd.) to calculate a standard deviation (3σ). The smaller value indicates the better uniformity of the film thickness.

[Watermark Defect Performance]

In the observation of a line-and-space pattern resolved at the optimum exposure dose when a line-and-space pattern having a line width of 55 nm was resolved, the number of watermark (WM) defects on the wafer was measured by using 2360 manufactured by KLA TENCOR Corp. to set the pixel size of a defect inspection apparatus and the threshold value to 0.16 μm and 20, respectively, making measurements at random mode, detecting a development defect extracted from the difference produced by superposition of comparative images and pixel units, and then observing the development defect by SEMVISION G3 (manufactured by APPLIED MATERIALS Inc.).

A, B, C and D indicate 0, from 1 to 4, from 5 to 9, and 10 or more, respectively, in the number of WM defects observed on the wafer. The smaller the value is, the better the WM defect reduction performance indicates.

[Bridge Defect Performance]

In the observation of a line-and-space pattern resolved at the optimum exposure dose when a line-and-space pattern having a line width of 55 nm was resolved, the number of bridge defects per an unit area (number/cm²) on the wafer was measured by using 2360 manufactured by KLA TENCOR Corp. to set the pixel size of a defect inspection apparatus and the threshold value to 0.16 μm and 20, respectively, making measurements at random mode, detecting a development defect extracted from the difference produced by superposition of comparative images and pixel units, and then observing the development defect by SEMVISION G3 (manufactured by APPLIED MATERIALS Inc.).

A, B, C and D indicate 0.1/cm² or less, more than 0.1/cm² and 1/cm² or less, more than 1/cm² and 10/cm² or less, and 10/cm² or more, respectively, in the number of WM defects observed on the wafer. The smaller the value is, the better the bridge defect reduction performance indicates.

These evaluation results will be shown in the following Table.

TABLE 5

| | | | | | | | | | | ClogP | | | |
|---|---|---|---|---|---|---|---|---|---|---|---|---|---|
| | | | Com- | | Com- | | Basic | | | value | | | |
| | Resin | | pound | | pound | | com- | | Resin | of | | Resin | |
| Ex | (A) | (g) | (B) | (g) | (N) | (g) | pound | (g) | (D) | Resin (D) | (g) | (E) | (g) |
| Ex. 1 | A-1 | 10 | PAG-2 | 0.85 | | | N-3 | 0.14 | D-1 | 2.8 | 0.34 | None | |
| Ex. 2 | A-2 | 10 | PAG-3 | 1.00 | | | N-4 | 0.13 | D-2 | 2.8 | 0.34 | None | |
| Ex. 3 | A-3 | 10 | PAG-4 | 1.15 | | | N-5 | 0.17 | D-3 | 3.1 | 0.29 | None | |
| Ex. 4 | A-4 | 10 | PAG-5 | 1.10 | | | N-6 | 0.25 | D-4 | 3.1 | 0.23 | None | |
| Ex. 5 | A-5 | 10 | PAG-6 | 1.25 | | | N-7 | 0.17 | D-5 | 3.8 | 0.15 | None | |
| Ex. 6 | A-6 | 10 | PAG-7 | 1.28 | | | N-8 | 0.31 | D-6 | 3.9 | 0.05 | HR-47 | 0.06 |
| Ex. 7 | A-1 | 10 | PAG-8 | 1.40 | | | N-3/ | 0.08/ | D-7 | 3.5 | 0.18 | None | |
| | | | | | | | N-5 | 0.08 | | | | | |
| Ex. 8 | A-2 | 10 | PAG-2/ | 0.80/ | | | N-3 | 0.18 | D-8 | 2.1 | 0.40 | None | |
| | | | PAG-3 | 0.20 | | | | | | | | | |
| Ex. 9 | A-3 | 10 | PAG-1/ | 0.40/ | | | N-7 | 0.15 | D-9 | 4.4 | 0.18 | None | |
| | | | PAG-9 | 1.25 | | | | | | | | | |
| Ex. 10 | A-4 | 10 | PAG-3/ | 0.75/ | | | N-3 | 0.24 | D-10 | 3.4 | 0.26 | None | |
| | | | PAG-10 | 2.00 | | | | | | | | | |
| Ex. 11 | A-5 | 10 | PAG-6/ | 0.70/ | | | N-3 | 0.22 | D-11 | 2.8 | 0.62 | None | |
| | | | PAG-11 | 2.25 | | | | | | | | | |
| Ex. 12 | A-6 | 10 | PAG-6/ | 0.80/ | | | N-7 | 0.23 | D-12 | 5.0 | 0.16 | None | |
| | | | PAG-12 | 2.35 | | | | | | | | | |
| Ex. 13 | A-1 | 10 | PAG-3 | 0.50 | N-1 | 0.55 | | | D-13 | 3.5 | 0.28 | None | |
| Ex. 14 | A-2 | 10 | PAG-4 | 0.55 | N-1 | 0.65 | | | D-14 | 4.2 | 0.35 | HR-24 | 0.03 |
| Ex. 15 | A-3 | 10 | PAG-5 | 0.53 | N-1 | 0.60 | | | D-15 | 2.6 | 0.65 | None | |
| Ex. 16 | A-4 | 10 | PAG-6 | 0.60 | N-2 | 0.65 | | | D-16 | 3.9 | 0.59 | None | |
| Ex. 17 | A-5 | 10 | PAG-7 | 0.60 | N-2 | 0.64 | | | D-17 | 4.4 | 0.72 | None | |
| Ex. 18 | A-7 | 10 | PAG-2 | 0.85 | | | N-3 | 0.14 | D-1 | 2.8 | 0.34 | None | |
| Ex. 19 | A-8 | 10 | PAG-3 | 1.00 | | | N-4 | 0.13 | D-2 | 2.8 | 0.34 | None | |
| Ex. 20 | A-1/A-2 | 5/5 | PAG-4 | 1.15 | | | N-5 | 0.17 | D-3 | 3.1 | 0.29 | None | |
| Ex. 21 | A-4 | 10 | PAG-5 | 1.10 | | | N-6 | 0.25 | D-1/ | 2.8/ | 0.17/ | None | |
| | | | | | | | | | D-4 | 3.1 | 0.11 | | |
| Ex. 22 | A-1 | 10 | PAG-2 | 0.85 | | | N-8 | 0.31 | D-1 | 2.8 | 0.36 | None | |
| Ex. 23 | A-2 | 10 | PAG-3 | 1.00 | | | N-7 | 0.17 | D-2 | 2.8 | 0.36 | None | |
| Ex. 24 | A-3 | 10 | PAG-13 | 1.15 | | | N-6 | 0.25 | D-3 | 3.1 | 0.30 | None | |
| Ex. 25 | A-4 | 10 | PAG-15 | 1.10 | | | N-5 | 0.17 | D-4 | 3.1 | 0.24 | None | |
| Ex. 26 | A-5 | 10 | PAG-6 | 1.25 | | | N-9 | 0.12 | D-5 | 3.8 | 0.16 | None | |
| Ex. 27 | A-9 | 10 | PAG-16 | 1.28 | | | N-3 | 0.14 | D-6 | 3.9 | 0.05 | None | |
| Ex. 28 | A-1 | 10 | PAG-8 | 1.40 | | | N-3/ | 0.08/ | D-7 | 3.5 | 0.19 | None | |
| | | | | | | | N-5 | 0.08 | | | | | |
| Ex. 29 | A-2 | 10 | PAG-2/ | 0.80/ | | | N-3 | 0.18 | D-8 | 2.1 | 0.42 | None | |
| | | | PAG-3 | 0.20 | | | | | | | | | |
| Ex. 30 | A-3 | 10 | PAG-1/ | 0.40/ | | | N-7 | 0.15 | D-9 | 4.4 | 0.19 | None | |
| | | | PAG-14 | 1.25 | | | | | | | | | |
| Ex. 31 | A-4 | 10 | PAG-13/ | 0.30/ | | | N-5 | 0.15 | D-10 | 3.4 | 0.27 | None | |
| | | | PAG-14 | 1.25 | | | | | | | | | |
| Ex. 32 | A-5 | 10 | PAG-2 | 0.85 | | | N-9 | 0.11 | D-11 | 2.8 | 0.65 | None | |
| Ex. 33 | A-6 | 10 | PAG-3 | 1.00 | | | N-4 | 0.13 | D-12 | 5.0 | 0.17 | None | |
| Ex. 34 | A-9 | 10 | PAG-13 | 1.15 | | | N-5 | 0.17 | D-13 | 3.5 | 0.29 | None | |
| C. Ex. 1 | A-1 | 10 | PAG-3 | 1.00 | | | N-4 | 0.13 | None | — | — | None | |
| C. Ex. 2 | A-1 | 10 | PAG-3 | 1.00 | | | N-4 | 0.13 | D-19 | 2.1 | 0.17 | None | |
| C. Ex. 3 | A-1 | 10 | PAG-3 | 1.00 | | | N-4 | 0.13 | D-1 | 2.8 | 0.34 | None | |
| C. Ex. 4 | A-1 | 10 | PAG-3 | 1.00 | | | N-4 | 0.13 | D-18 | 1.1 | 0.85 | None | |

| | | | | | | | | | Reced- | Film | Reduc- | Reduc- |
|---|---|---|---|---|---|---|---|---|---|---|---|---|
| | | | | | | | | | ing | thick- | tion | tion |
| | | | | | | | | | con- | ness | in | in |
| | | Mass | | | | Mass | Rinse | Mass | tact | eveness | WM | bridge |
| Ex | Solvent | ratio | Surfactant | (g) | Developer | ratio | liquid | ratio | angle(° ) | (mm, 3σ) | defect | defect |
| Ex. 1 | SL-1/SL-5 | 60/40 | W-1 | 0.003 | SG-1 | 100 | SR-1 | 100 | 78 | 1.5 | B | B |
| Ex. 2 | SL-1 | 100 | W-3 | 0.003 | SG-1/ | 95/5 | SR-1 | 100 | 79 | 1.6 | B | B |
| | | | | | SG-7 | | | | | | | |
| Ex. 3 | SL-1/SL-5 | 60/40 | W-1 | 0.003 | SG-1 | 100 | SR-1 | 100 | 80 | 1.7 | B | B |
| Ex. 4 | SL-1/SL-5 | 60/40 | W-1 | 0.003 | SG-1 | 100 | SR-1 | 100 | 78 | 1.8 | B | B |
| Ex. 5 | SL-1/SL-2 | 90/10 | W-2 | 0.003 | SG-1 | 100 | SR-1 | 100 | 81 | 1.3 | A | B |
| Ex. 6 | SL-1/ | 92/5/3 | W-1 | 0.003 | SG-1 | 100 | SR-1 | 100 | 82 | 0.9 | A | A |
| | SL-5/SL-7 | | | | | | | | | | | |
| Ex. 7 | SL-5/SL-6 | 30/70 | None | — | SG-1/ | 50/50 | SG-1/ | 90/10 | 80 | 1.1 | A | B |
| | | | | | SG-4 | | SG-4 | | | | | |
| Ex. 8 | SL-1/SL-7 | 95/5 | W-1 | 0.003 | SG-1 | 100 | SR-1 | 100 | 76 | 1.5 | B | A |
| Ex. 9 | SL-1/ | 75/20/5 | W-5 | 0.003 | SG-1 | 100 | SR-1 | 100 | 83 | 1.0 | A | A |
| | SL-6/SL-7 | | | | | | | | | | | |
| Ex. 10 | SL-1/SL-5 | 60/40 | W-4 | 0.003 | SG-1 | 100 | SR-2 | 100 | 82 | 1.4 | A | B |
| Ex. 11 | SL-1/SL-3 | 80/20 | W-1 | 0.003 | SG-1 | 100 | SR-1 | 100 | 79 | 1.8 | B | B |
| Ex. 12 | SL-1/SL-5 | 60/40 | W-2 | 0.003 | SG-1/ | 90/10 | SR-1 | 100 | 78 | 1.6 | B | B |
| | | | | | SG-3 | | | | | | | |
| Ex. 13 | SL-1/SL-5 | 70/30 | W-3 | 0.001 | SG-1 | 100 | SR-1/ | 90/10 | 77 | 1.8 | B | B |
| | | | | | | | SR-5 | | | | | |
| Ex. 14 | SL-1/SL-8 | 95/5 | None | — | SG-1 | 100 | SR-1 | 100 | 83 | 1.2 | A | A |
| Ex. 15 | SL-1 | 100 | W-1 | 0.003 | SG-1 | 100 | SR-1 | 100 | 80 | 1.9 | B | B |
| Ex. 16 | SL-1/SL-5 | 60/40 | W-6 | 0.003 | SG-2 | 100 | SR-1/ | 90/10 | 79 | 1.8 | B | B |
| | | | | | | | SR-3 | | | | | |
| Ex. 17 | SL-1/SL-4 | 80/20 | W-1 | 0.003 | SG-1 | 100 | — | — | 79 | 1.8 | B | B |
| Ex. 18 | SL-1/SL-5 | 60/40 | W-1 | 0.003 | SG-1 | 100 | SR-1 | 100 | 77 | 1.6 | B | B |
| Ex. 19 | SL-1 | 100 | W-3 | 0.003 | SG-1/ | 95/5 | SR-1 | 100 | 78 | 1.7 | B | B |
| | | | | | SG-7 | | | | | | | |
| Ex. 20 | SL-1/SL-5 | 60/40 | W-1 | 0.003 | SG-1 | 100 | SR-1 | 100 | 80 | 1.5 | B | B |
| Ex. 21 | SL-1/SL-5 | 60/40 | W-1 | 0.003 | SG-1 | 100 | SR-1 | 100 | 78 | 1.6 | B | B |
| Ex. 22 | SL-1/SL-7 | 95/5 | W-1 | 0.003 | SG-1 | 100 | SR-1 | 100 | 82 | 1.1 | A | A |
| Ex. 23 | SL-1/SL-7 | 97/3 | W-2 | 0.003 | SG-1 | 100 | SR-1 | 100 | 83 | 1.4 | A | A |
| Ex. 24 | SL-1/SL-7 | 98/2 | None | — | SG-1 | 100 | SR-1 | 100 | 80 | 1.2 | A | A |
| Ex. 25 | SL-1/SL-7 | 94/6 | W-6 | 0.003 | SG-1 | 100 | — | | 81 | 1.3 | A | A |
| Ex. 26 | SL-1/SL-8 | 97/3 | W-3 | 0.003 | SG-1 | 100 | SR-1 | 100 | 82 | 1.0 | A | A |
| Ex. 27 | SL-1/SL-8 | 98/2 | W-2 | 0.003 | SG-1 | 100 | SR-1/SR-5 | 90/10 | 84 | 1.4 | A | A |
| Ex. 28 | SL-1/SL-8 | 94/6 | W-3 | 0.003 | SG-1 | 100 | SR-1 | 100 | 81 | 1.0 | A | A |
| Ex. 29 | SL-1/SL-8 | 95/5 | W-6 | 0.003 | SG-1 | 100 | SR-1 | 100 | 81 | 1.9 | B | A |
| Ex. 30 | SL-1/ | 92/5/3 | None | — | SG-1 | 100 | SR-1 | 100 | 85 | 1.4 | A | A |
| | SL-5/SL-7 | | | | | | | | | | | |
| Ex. 31 | SL-1/ | 85/10/5 | W-1 | 0.003 | SG-1/ | 50/50 | SR-1 | 100 | 80 | 1.3 | A | A |
| | SL-5/SL-7 | | | | SG-4 | | | | | | | |
| Ex. 32 | SL-1/ | 95/3/2 | W-3 | 0.003 | SG-1/ | 95/5 | SR-1 | 100 | 81 | 1.0 | A | A |
| | SL-5/SL-7 | | | | SG-3 | | | | | | | |
| Ex. 33 | SL-1/ | 77/20/3 | None | — | SG-1/ | 90/10 | SR-1/SR5 | 90/10 | 81 | 1.8 | B | A |
| | SL-6/SL-7 | | | | SG-7 | | | | | | | |
| Ex. 34 | SL-1/ | 75/20/5 | W-1 | 0.003 | SG-1/ | 95/5 | SR-1 | 100 | 80 | 1.8 | B | A |
| | SL-6/SL-7 | | | | SG-7 | | | | | | | |
| C. Ex. 1 | SL-1/SL-5 | 60/40 | W-1 | 0.003 | SG-1 | 100 | SR-1 | 100 | 58 | 5.2 | D | D |
| C. Ex. 2 | SL-1/SL-5 | 60/40 | W-1 | 0.003 | SG-1 | 100 | SR-1 | 100 | 78 | 6.5 | D | D |
| C. Ex. 3 | SL-1/SL-5 | 60/40 | W-1 | 0.003 | | Alkali development performed | | | 78 | No evaluation due to non-resolution | | |
| C. Ex. 4 | SL-1/SL-5 | 80/20 | W-6 | 0.003 | SG-5/ | 95/5 | — | — | 62 | 2.2 | D | D |
| | | | | | SG-6 | | | | | | | |

As apparent from the results shown in Table 5, it can be known that any of Comparative Example 1 in which the resin (D) is not contained, Comparative Example 2 in which a resin (hereinafter, simply referred to as “addition resin” in some cases) mixed with the resin (A) has a fluorine atom, and Comparative Example 4 in which the C Log P value of the addition resin is low, and thus the receding contact angle does not satisfy the value of 70° deteriorates in uniformity of the film thickness, and thus there are a lot of bridge defects and watermark defects.

It can be known that in Comparative Example 3 in which the resin (D) containing substantially no fluorine atom and silicon atom is used to perform a positive type development (alkali development) having a receding contact angle of 70° or more, no image may be formed and no evaluation may be made.

On one hand, it can be known that in Examples 1 to 34 in which no fluorine atom and silicon atom is substantially contained and the resin (D) having a receding contact angle of 70° or more is used to perform an organic solvent development, uniformity of the film thickness is excellent and the number of bridge defects and watermark defects is small in immersion exposure.

Among them, it can be known that in Examples 6, 8, 9, 14, and 22 to 34 in which a mixed solvent containing two or more solvents, the two or more solvents containing at least one solvent having a boiling point of 200° C. or more is used, the number of bridge defects is particularly small.

### INDUSTRIAL APPLICABILITY

According to the present invention, it is possible to provide a pattern forming method in which uniformity of the film thickness is excellent and bridge defects and watermark defects are suppressed from occurring in the formation of a fine pattern having a line width of 60 nm or less by an immersion method using an organic-based developer, an actinic ray-sensitive or radiation-sensitive resin composition used therein, a resist film, a method for manufacturing an electronic device, and an electronic device.

This application is based on a Japanese patent application filed on Feb. 17, 2012 (Japanese Patent Application No. 2012-033396), and Japanese patent application filed on Feb. 13, 2013 (Japanese Patent Application No. 2013-25645), and the contents thereof are incorporated herein by reference.

1. A pattern forming method, comprising:
(a) forming a film by using an actinic ray-sensitive or radiation-sensitive resin composition containing:
(A) a resin capable of increasing polarity by an action of an acid to decrease solubility in an organic solvent-containing developer,
(B) a compound capable of generating an acid upon irradiation with an actinic ray or radiation,
(C) a solvent, and
(D) a resin, which contains substantially no fluorine atom and silicon atom and is different from the resin (A),
(b) exposing the film; and
(c) performing development by using the organic solvent-containing developer to form a negative pattern,
wherein a receding contact angle of water on the film formed by (a) is 70° or more.

2. The method according to claim 1,
wherein the solvent (C) is a mixed solvent containing two or more solvents, the two or more solvents containing at least one solvent having a boiling point of 200° C. or more.

3. The method according to claim 2,
wherein the at least one solvent having a boiling point of 200° C. or more is a solvent represented by one of Formulas (S1) to (S3): 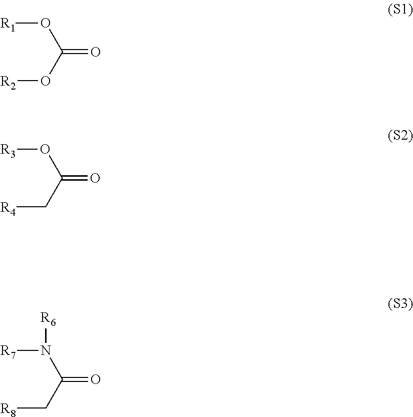
wherein, each of R₁ to R₄ and R₆ to R₈ independently represents an alkyl group, a cycloalkyl group or an aryl group, and
R₁ and R₂, R₃ and R₄, or R₇ and R₈ may be linked to each other to form a ring.

4. The method according to claim 2,
wherein a content of the at least one solvent having a boiling point of 200° C. or more is 1% by mass or more based on the mixed solvent.

5. The method according to claim 1,
wherein the resin (A) contains a repeating unit including a group capable of decomposing by the action of an acid to generate a polar group, and
the repeating unit consists of at least one repeating unit represented by Formula (I): 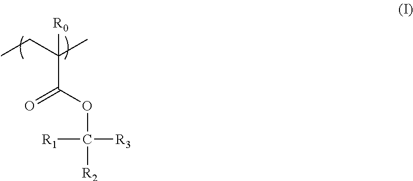
wherein, R₀ represents a hydrogen atom or an alkyl group,
each of R₁ to R₃ independently represents an alkyl group or a cycloalkyl group, and
two of R₁ to R₃ may be bonded to each other to form a monocyclic or polycyclic cycloalkyl group.

6. The method according to claim 1,
wherein the resin (D) has at least one repeating unit represented by the following Formula (II) or (III): 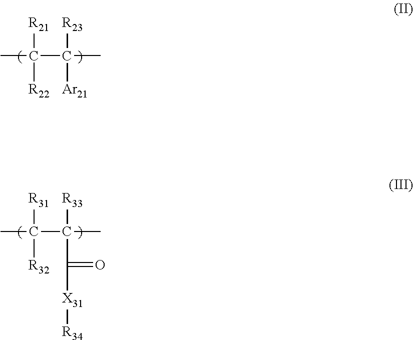
wherein, in Formula (II), each of R₂₁ to R₂₃ independently represents a hydrogen atom or an alkyl group,
Ar₂₁ represents an aromatic group,
R₂₂ and Ar₂₁ may form a ring, and in that case, R₂₂ represents an alkylene group,
in Formula (III), each of R₃₁ to R₃₃ independently represents a hydrogen atom or an alkyl group,
X₃₁ represents —O— or —NR₃₅—,
R₃₅ represents a hydrogen atom or an alkyl group, and
R₃₄ represents an alkyl group or a cycloalkyl group.

7. The method according to claim 6,
wherein a content of the repeating unit represented by Formula (II) or (III) is 50% by mole to 100% by mole based on all the repeating units in the resin (D).

8. The method according to claim 1,
wherein the organic solvent-containing developer is a developer containing at least one organic solvent selected from the group consisting of a ketone-based solvent, an ester-based solvent, an alcohol-based solvent, an amide-based solvent and an ether-based solvent.

9. The method according to claim 1, further comprising: (d) performing washing by using a rinsing solution containing an organic solvent.

10. The method according to claim 1,
wherein the exposure in (b) is an immersion exposure.

11. An actinic ray-sensitive or radiation-sensitive resin composition, comprising:
(A) a resin capable of increasing polarity by an action of an acid to decrease solubility in an organic solvent-containing developer;
(B) a compound capable of generating an acid upon irradiation with an actinic ray or radiation;
(C) a solvent; and
(D) a resin, which contains substantially no fluorine atom and silicon atom and is different from the resin (A).

12. The actinic ray-sensitive or radiation-sensitive resin composition according to claim 11,
wherein the solvent (C) is a mixed solvent containing two or more solvents, the two or more solvents containing at least one solvent having a boiling point of 200° C. or more.

13. The actinic ray-sensitive or radiation-sensitive resin composition according to claim 12,
wherein the at least one solvent having a boiling point of 200° C. or more is a solvent represented by one of Formulas (S1) to (S3): 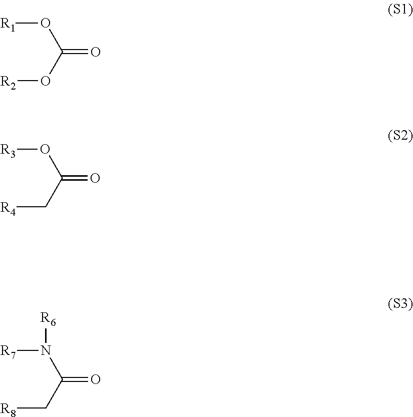
wherein, each of R₁ to R₄ and R₆ to R₈ independently represents an alkyl group, a cycloalkyl group or an aryl group, and
R₁ and R₂, R₃ and R₄, or R₇ and R₈ may be linked to each other to form a ring.

14. The actinic ray-sensitive or radiation-sensitive resin composition according to claim 12,
wherein a content of the at least one solvent having a boiling point of 200° C. or more is 1% by mass or more based on the mixed solvent.

15. The actinic ray-sensitive or radiation-sensitive resin composition according to claim 11,
wherein the resin (A) contains a repeating unit including a group capable of decomposing by the action of an acid to generate a polar group, and
the repeating unit consists of at least one repeating unit represented by Formula (I): 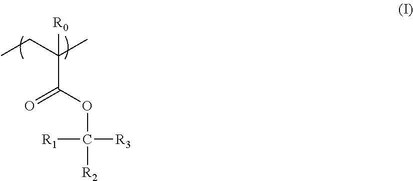
wherein, R₀ represents a hydrogen atom or an alkyl group,
each of R₁ to R₃ independently represents an alkyl group or a cycloalkyl group, and
two of R₁ to R₃ may be bonded to each other to form a monocyclic or polycyclic cycloalkyl group.

16. The actinic ray-sensitive or radiation-sensitive resin composition according to claim 11,
wherein the resin (D) has at least one repeating unit represented by the following Formula (II) or (III): 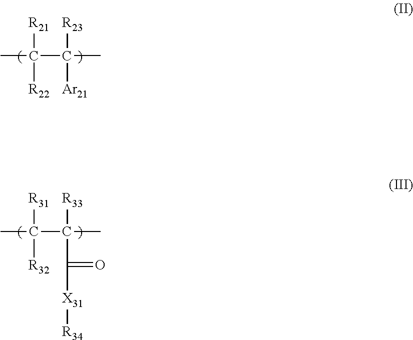
wherein, in Formula (II), each of R₂₁ to R₂₃ independently represents a hydrogen atom or an alkyl group,
Ar₂₁ represents an aromatic group,
R₂₂ and Ar₂₁ may form a ring, and in that case, R₂₂ represents an alkylene group,
in Formula (III), each of R₃₁ to R₃₃ independently represents a hydrogen atom or an alkyl group,
X₃₁ represents —O— or —NR₃₅—,
R₃₅ represents a hydrogen atom or an alkyl group, and
R₃₄ represents an alkyl group or a cycloalkyl group.

17. The actinic ray-sensitive or radiation-sensitive resin composition according to claim 16.
wherein a content of the repeating unit represented by Formula (II) or (III) is 50% by mole to 100% by mole based on all the repeating units in the resin (D).

18. A resist film formed by the actinic ray-sensitive or radiation-sensitive resin composition according to claim 11.

19. A method for manufacturing an electronic device comprising the method according to claim 1.

20. An electronic device manufactured by the method according to claim 19.
